(19) United States
(12) Patent Application Publication
(10) Pub. No.: US 2022/0165967 A1
(43) Pub. Date: May 26, 2022

(54) ORGANIC ELECTROLUMINESCENT MATERIALS AND DEVICES

(71) Applicant: UNIVERSAL DISPLAY CORPORATION, Ewing, NJ (US)

(72) Inventors: Zhiqiang JI, Chalfont, PA (US); Tongxiang LU, Lawrenceville, NJ (US); Wei-Chun SHIH, Lawrenceville, NJ (US); Pierre-Luc T. BOUDREAULT, Pennington, NJ (US); George FITZGERALD, Lambertville, NJ (US)

(73) Assignee: UNIVERSAL DISPLAY CORPORATION, Ewing, NJ (US)

(21) Appl. No.: 17/516,647

(22) Filed: Nov. 1, 2021

Related U.S. Application Data
(60) Provisional application No. 63/192,228, filed on May 24, 2021.
(60) Provisional application No. 63/168,419, filed on Mar. 31, 2021.
(60) Provisional application No. 63/154,188, filed on Feb. 26, 2021.
(60) Provisional application No. 63/117,727, filed on Nov. 24, 2020.

(51) Int. Cl. H01L 51/00; C09K 11/06; C09K 11/02; C07F 15/00

(52) U.S. Cl. CPC H01L 51/0085; C09K 11/06; C09K 11/02; H01L 51/5012; C09K 2211/185; C09K 2211/1092; C09K 2211/1037; C07F 15/0033

(57) ABSTRACT

Provided are organometallic complexes including 5-membered heterocyclic rings. The compounds include a ligand L_{A} having a structure of

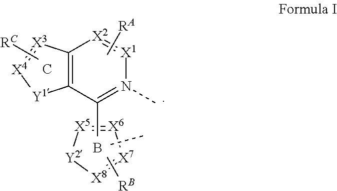

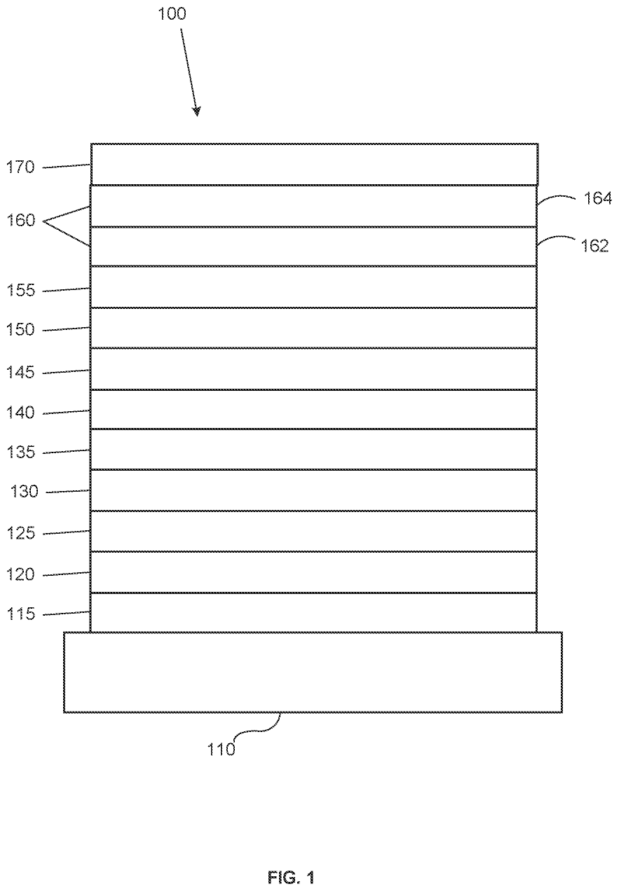

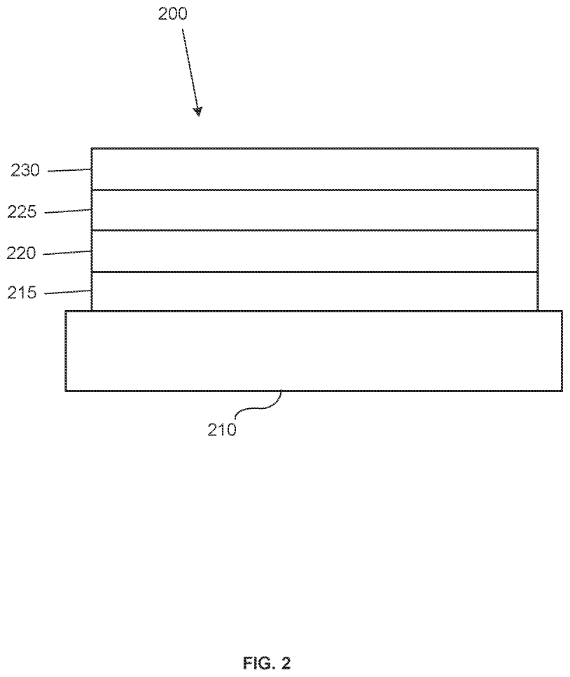

Also provided are formulations comprising these compounds. Further provided are OLEDs and related consumer products that utilize these compounds.

In some embodiments, when the compound has formula Ir(L_{Ai-m-X})₃, i is an integer from 1 to 4524; m is an integer from 1 to 108; and the compound is selected from the group consisting of Ir(L_{A1-1-1})₃ to Ir(L_{A4524-108-4})₃;

when the compound has formula Ir(L_{Ai-m-X})(L_{Bk})₂, i is an integer from 1 to 4542; m is an integer from 1 to 108; k is an integer from 1 to 324; and the compound is selected from the group consisting of Ir(L_{A1-1-1})(L_{B1})₂ to Ir(L_{A4542-108-4})(L_{B324})₂;

when the compound has formula Ir(L_{Ai-m-X})₂(L_{Bk}), i is an integer from 1 to 4542; m is an integer from 1 to 108; k is an integer from 1 to 324; and the compound is selected from the group consisting of Ir(L_{A1-1-1})₂(L_{B1}) to Ir(L_{A4542-108-4})₂(L_{B324});

when the compound has formula Ir(L_{Ai-m-X})₂(L_{Cj-I}), i is an integer from 1 to 4542; m is an integer from 1 to 108;j is an integer from 1 to 1416; and the compound is selected from the group consisting of Ir(L_{A1-1-1})₂(L_{C1-I}) to Ir(L_{A4542-108-4})₂(L_{C1416-I}); and when the compound has formula Ir(L_{Ai-m-X})₂(L_{Cj-II}), i is an integer from 1 to 4542; m is an integer from 1 to 108;j is an integer from 1 to 1416; and the compound is selected from the group consisting of Ir(L_{A1-1-1})₂(L_{C1-II}) to Ir(L_{A4542-108-4})₂(L_{C1416-II});

wherein each L_{Bk} is defined by the structures in the following LIST 8:

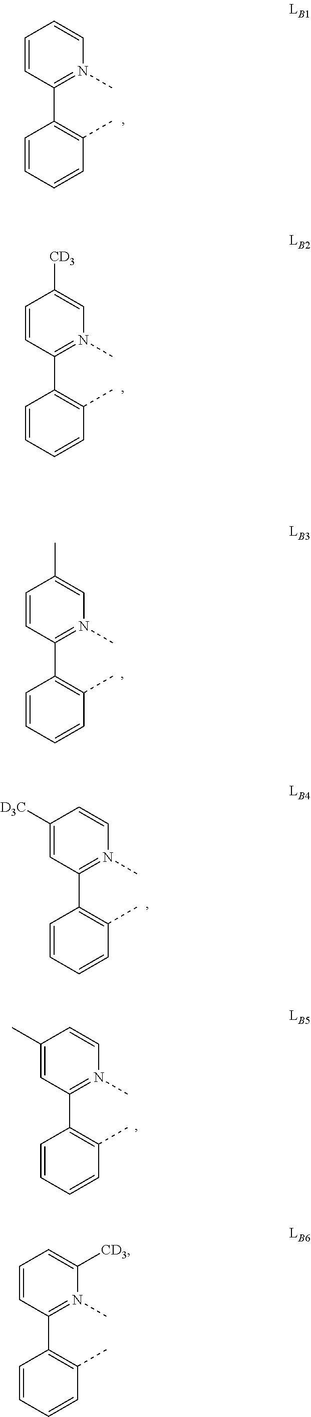

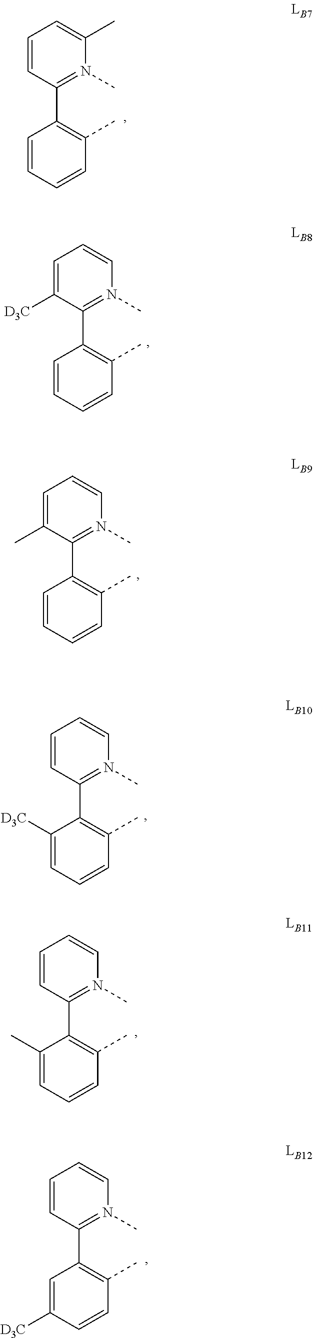

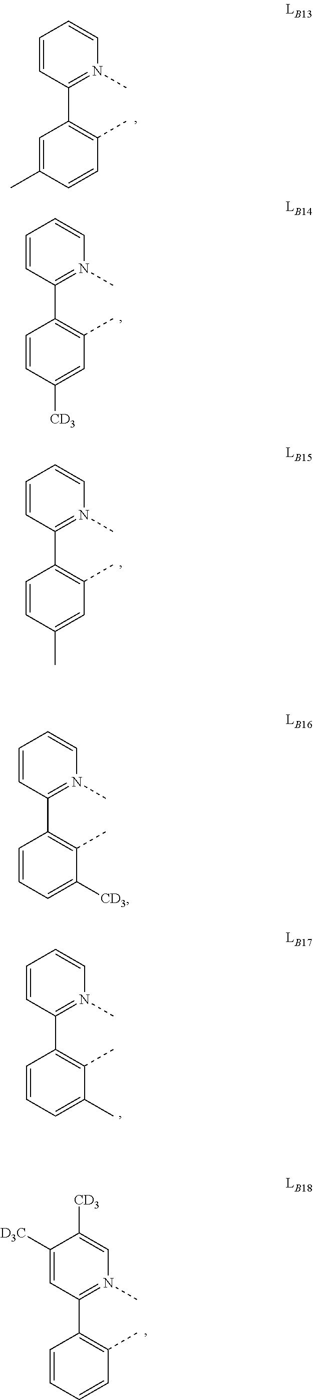

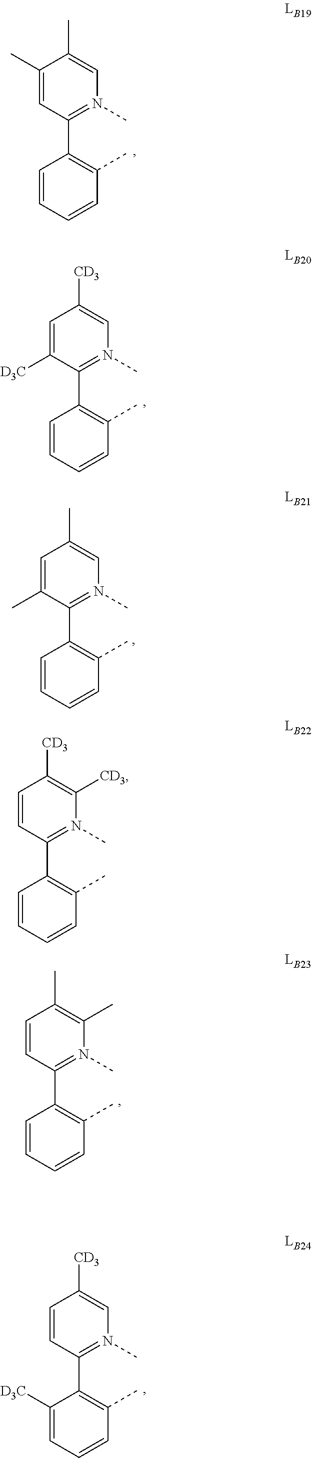

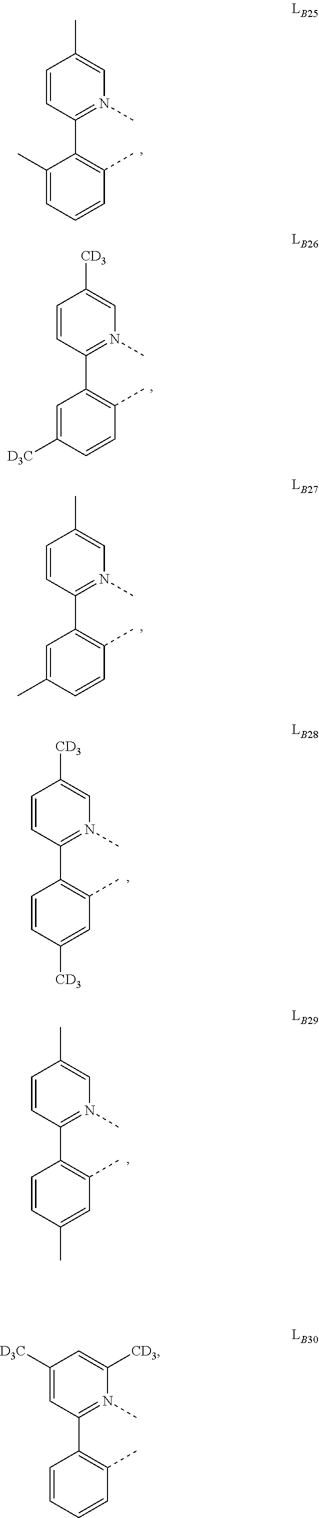

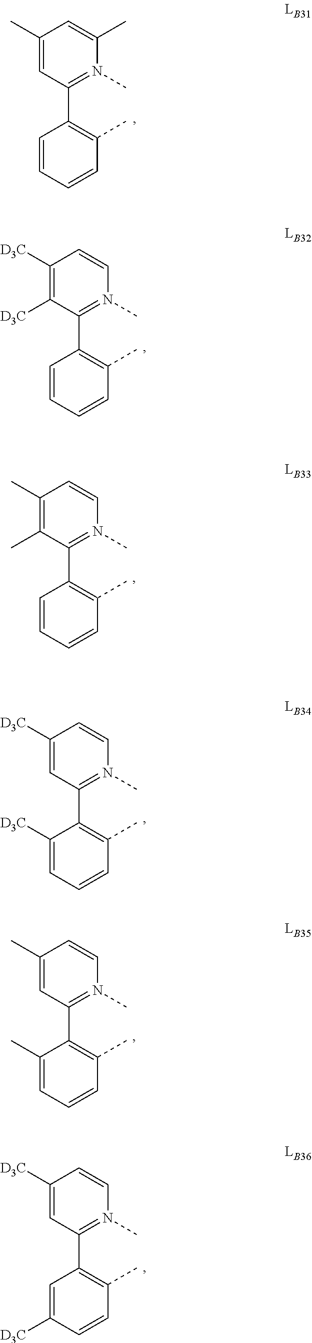

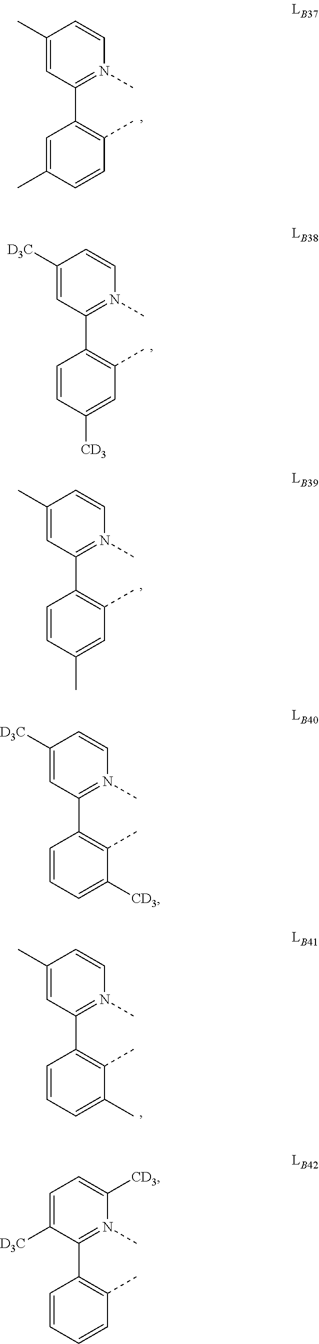

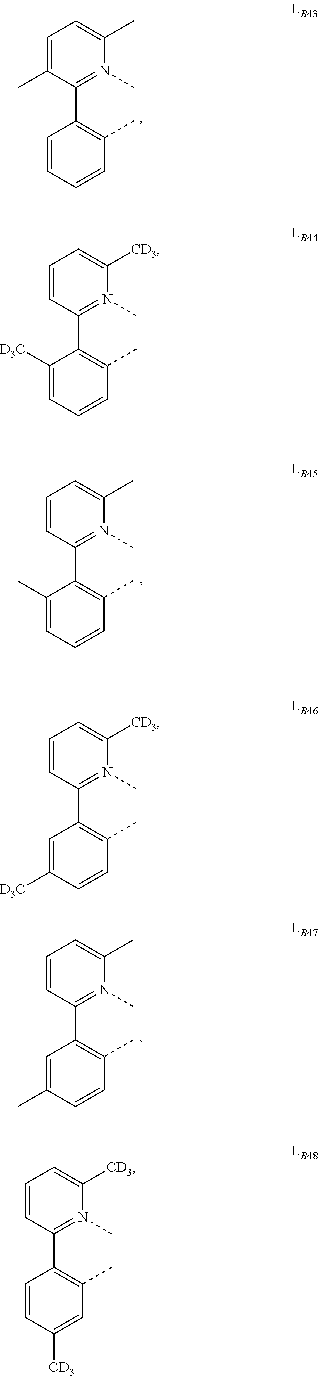

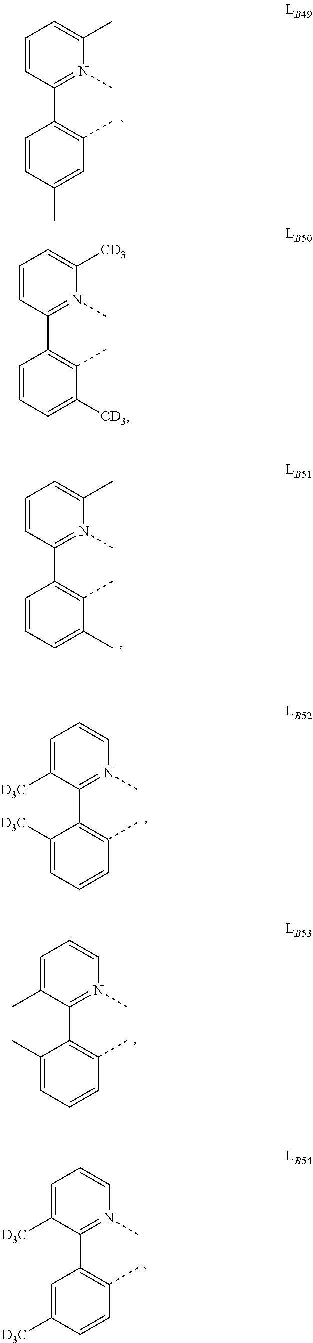

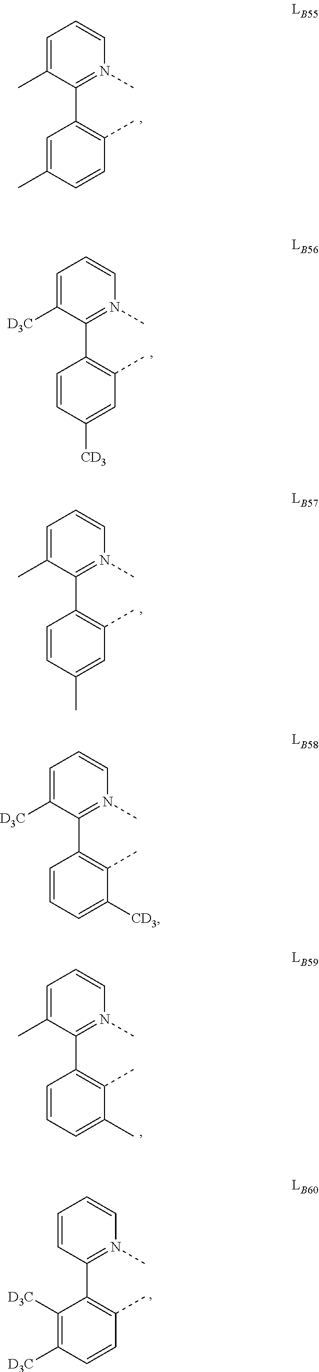

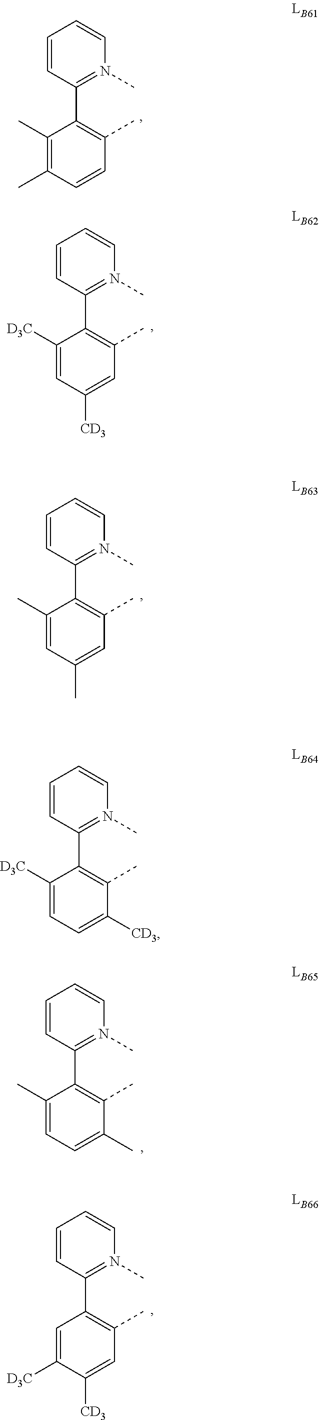

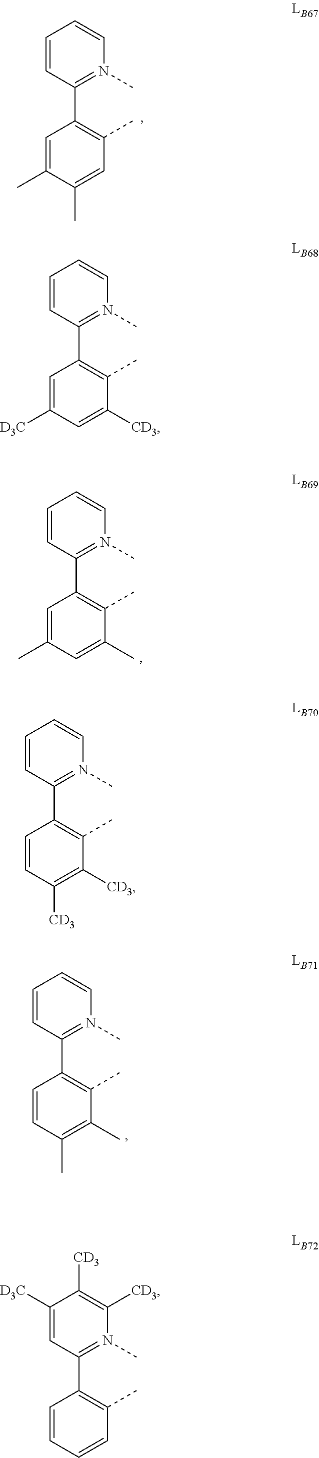

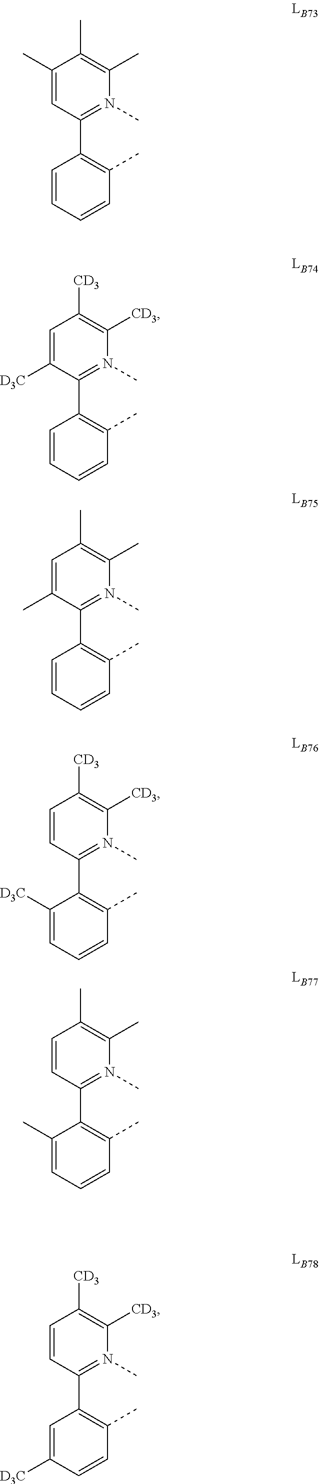

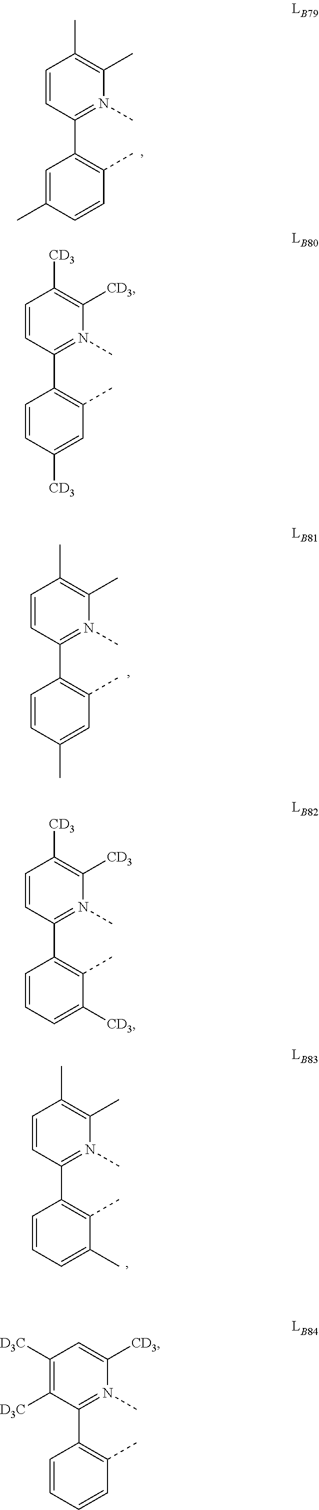

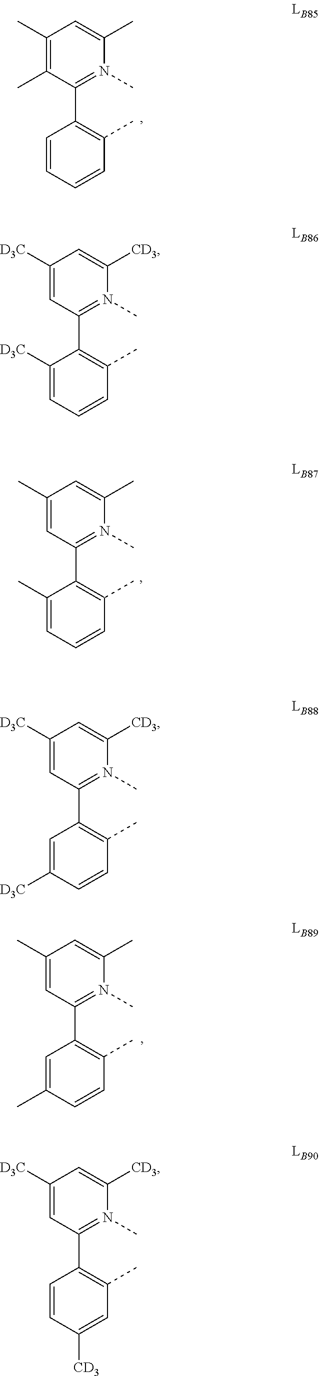

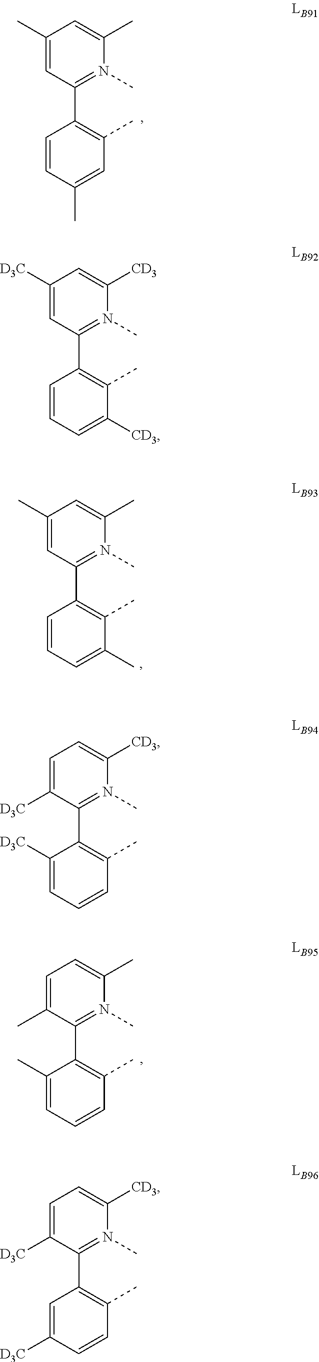

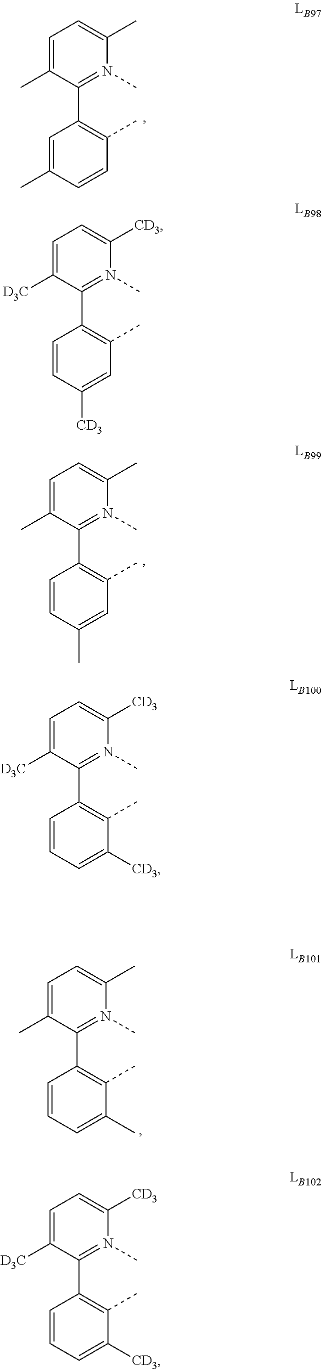

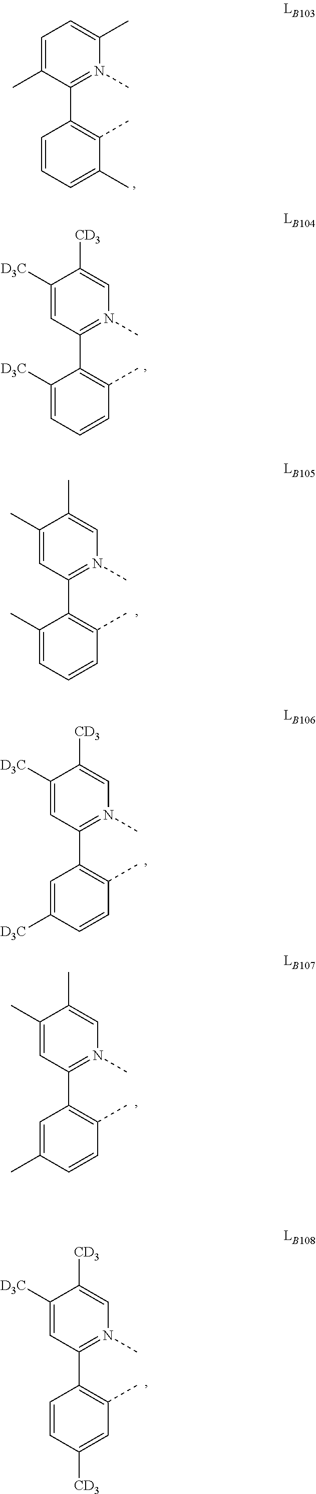

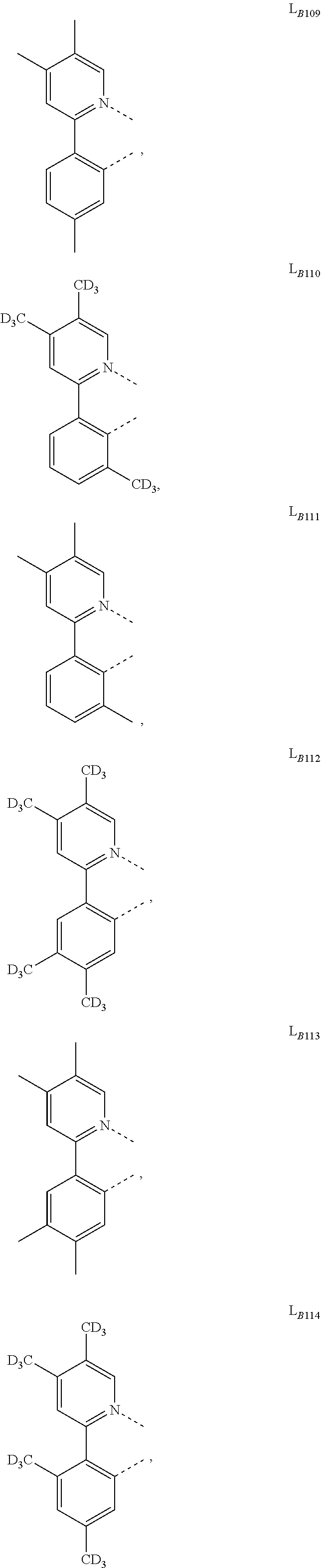

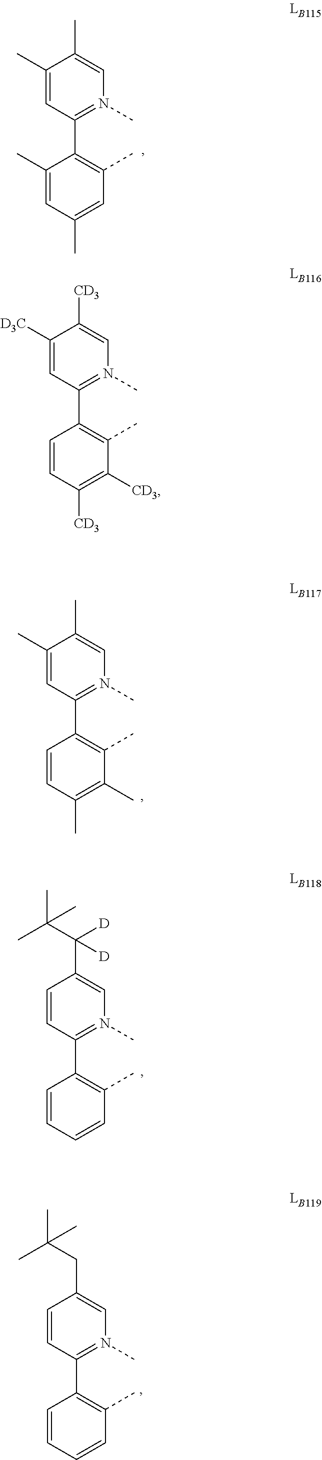

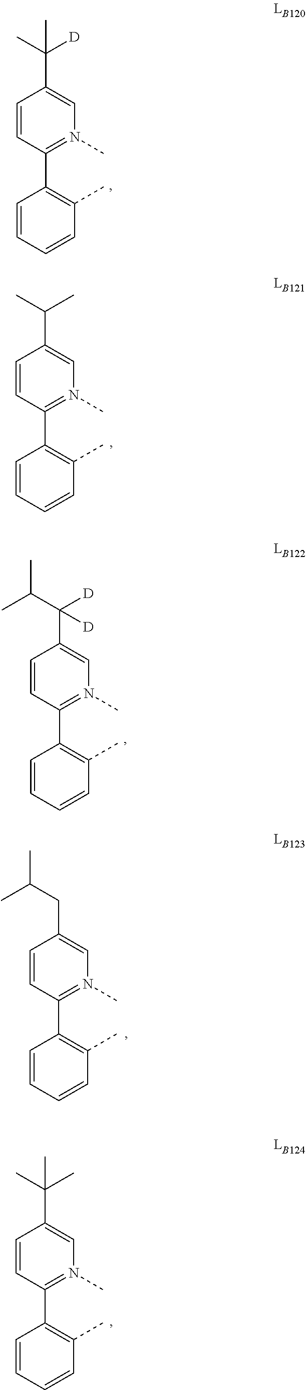

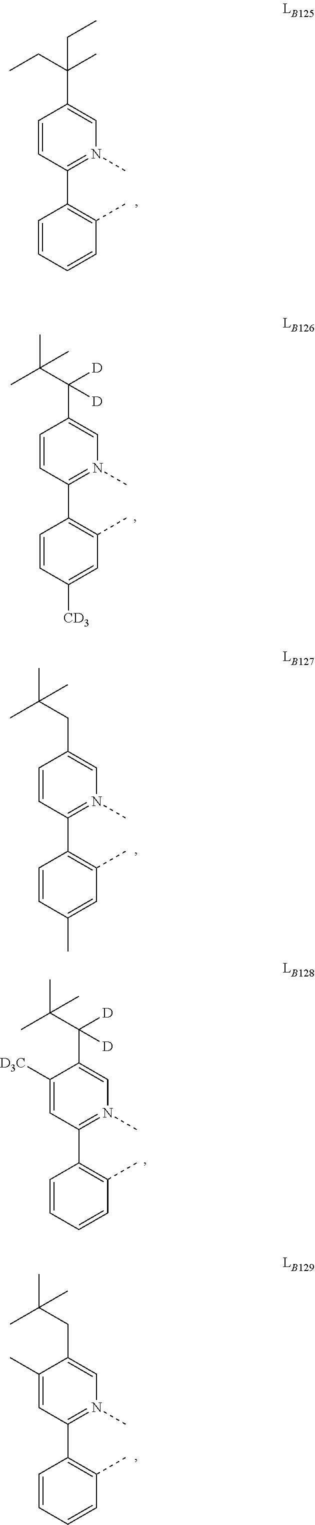

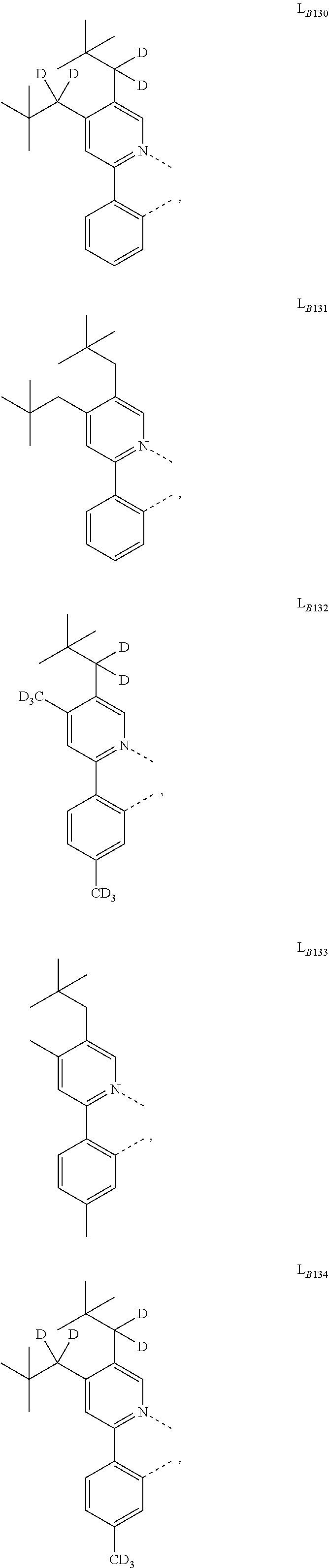

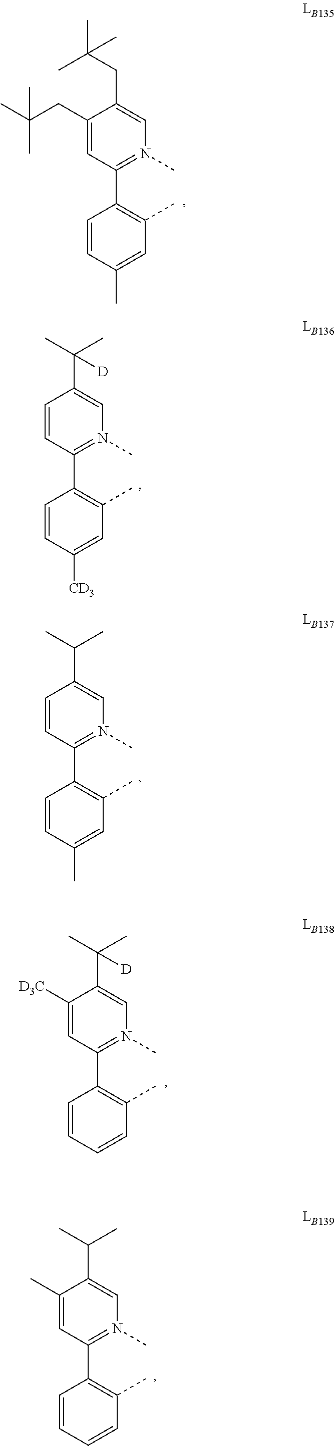

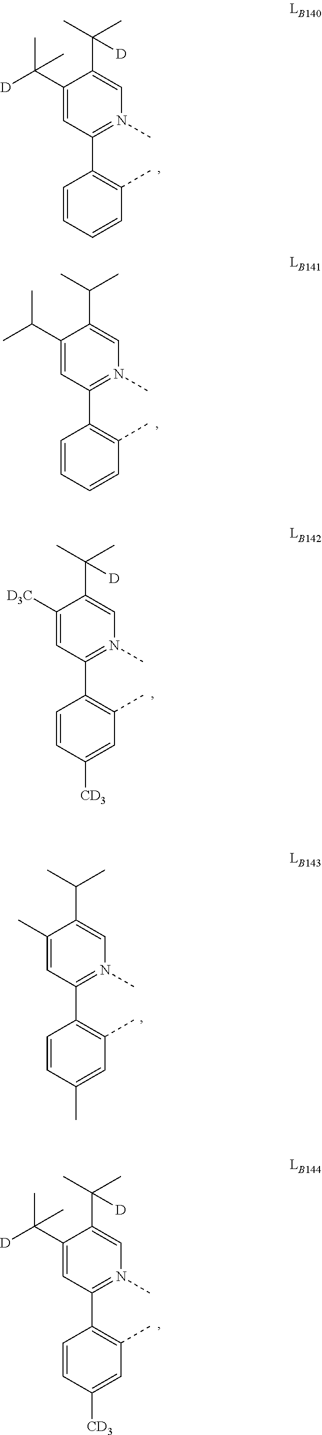

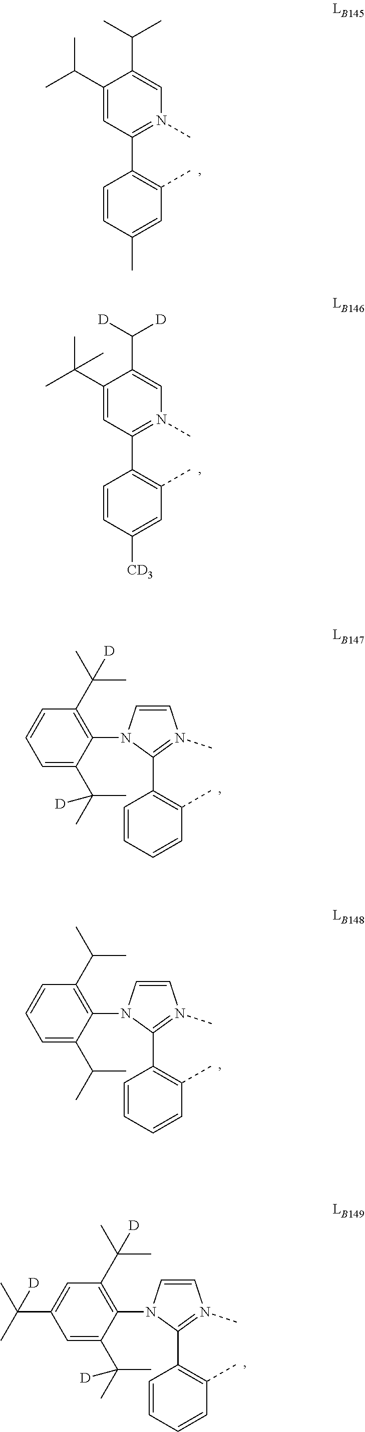

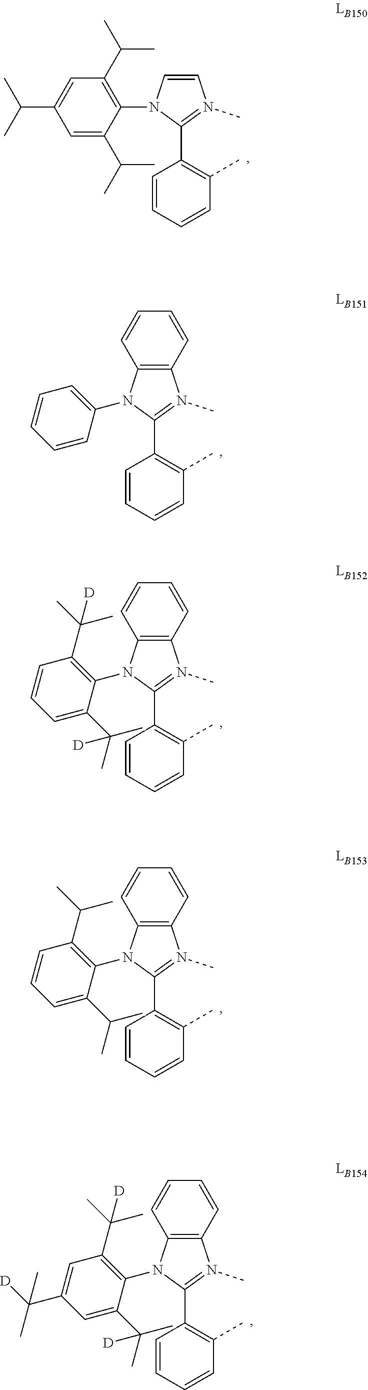

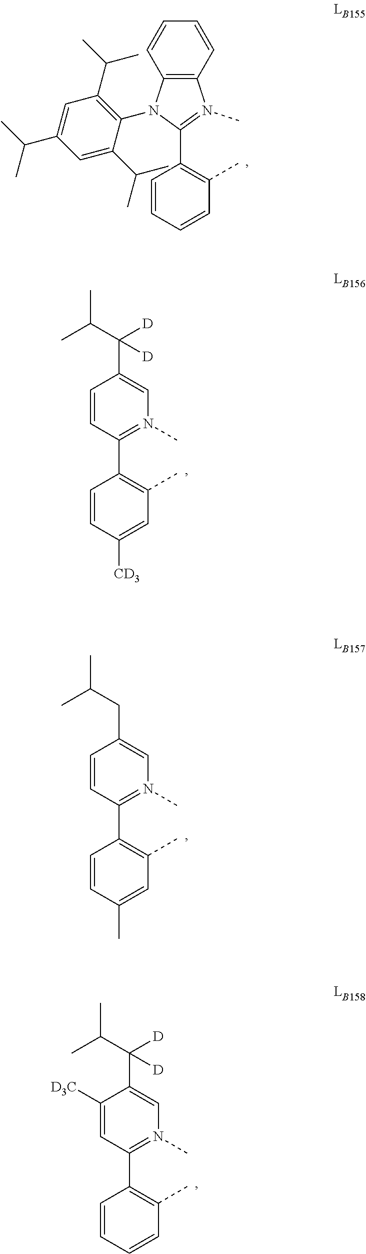

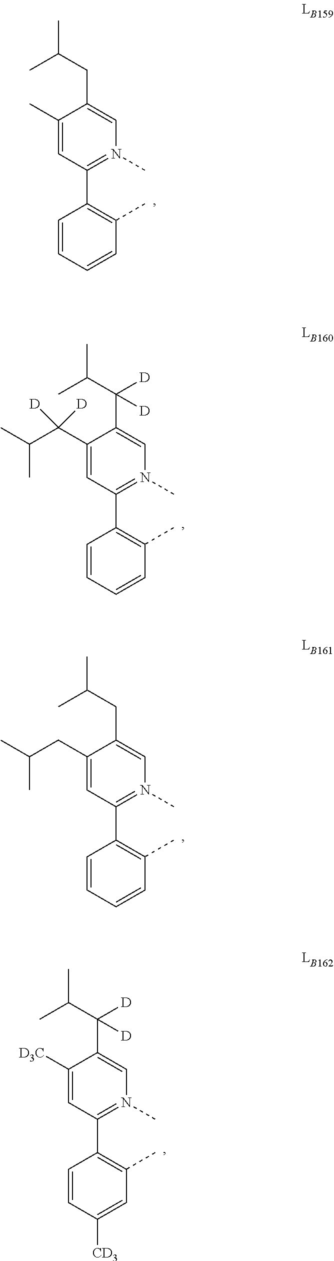

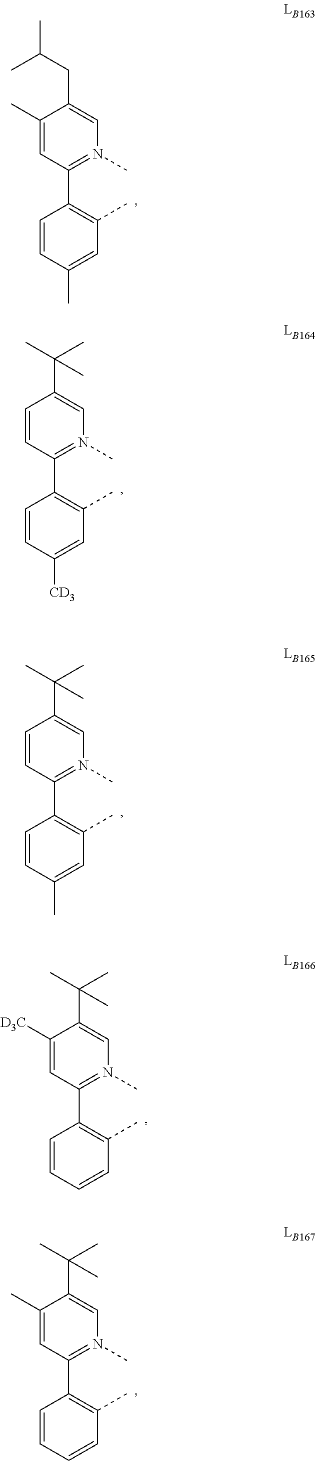

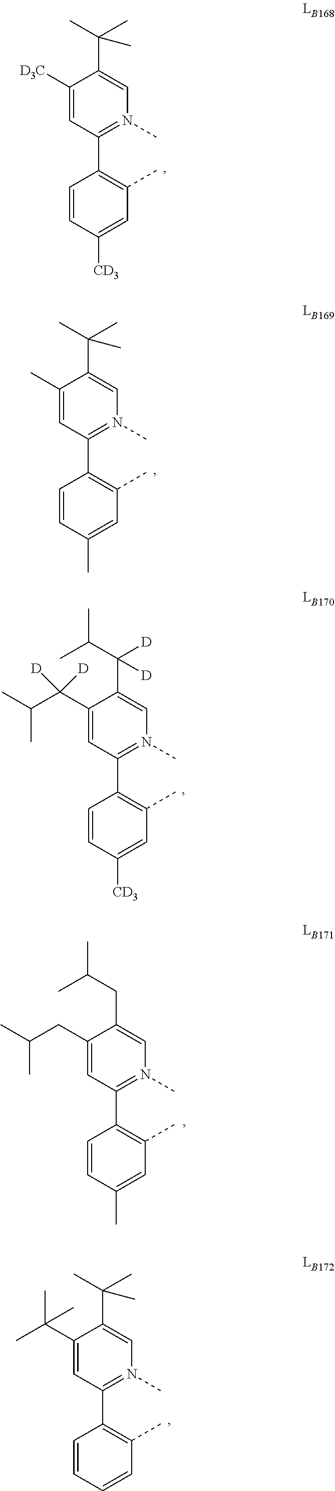

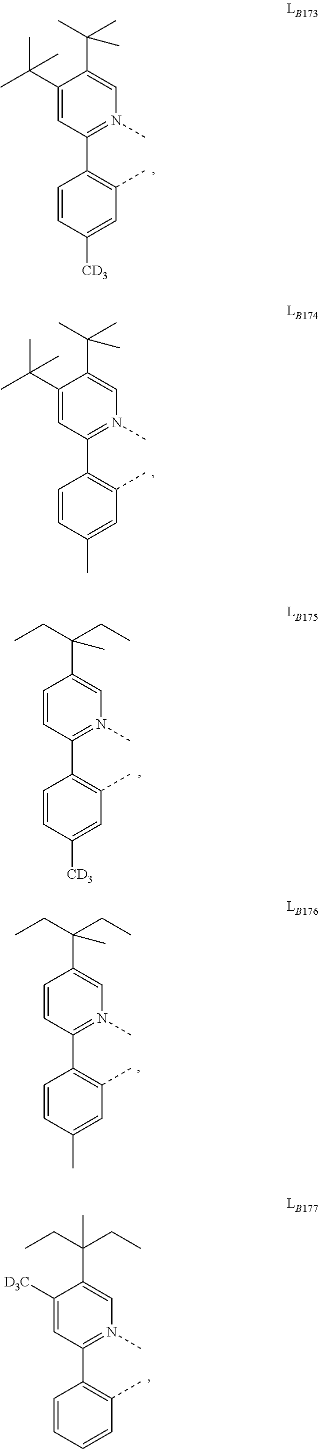

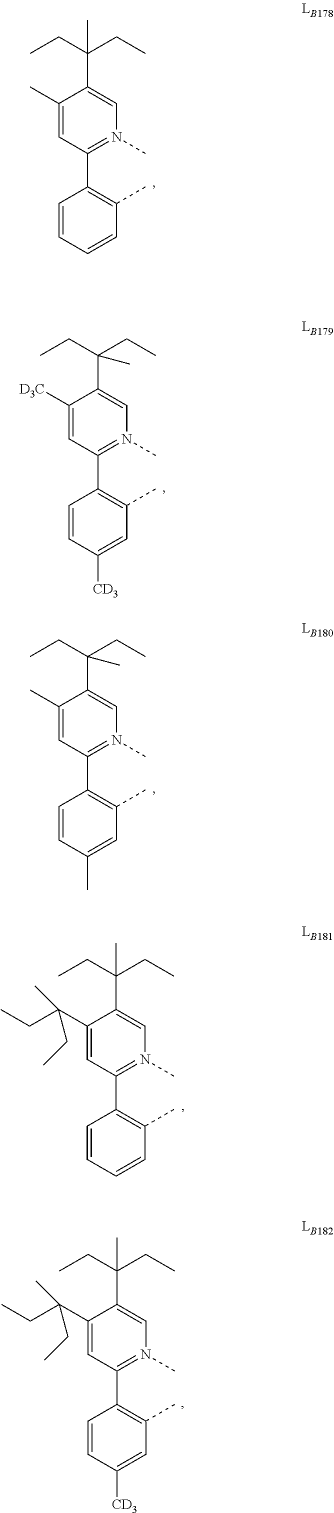

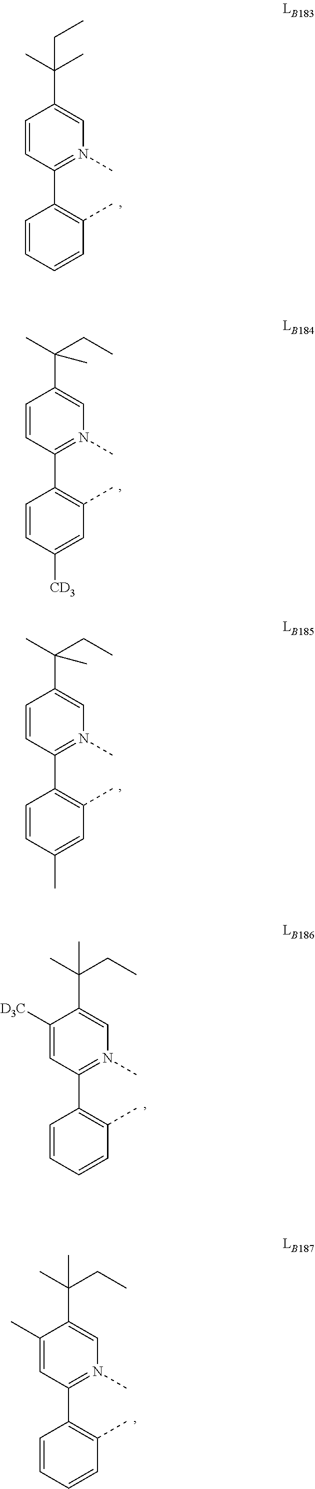

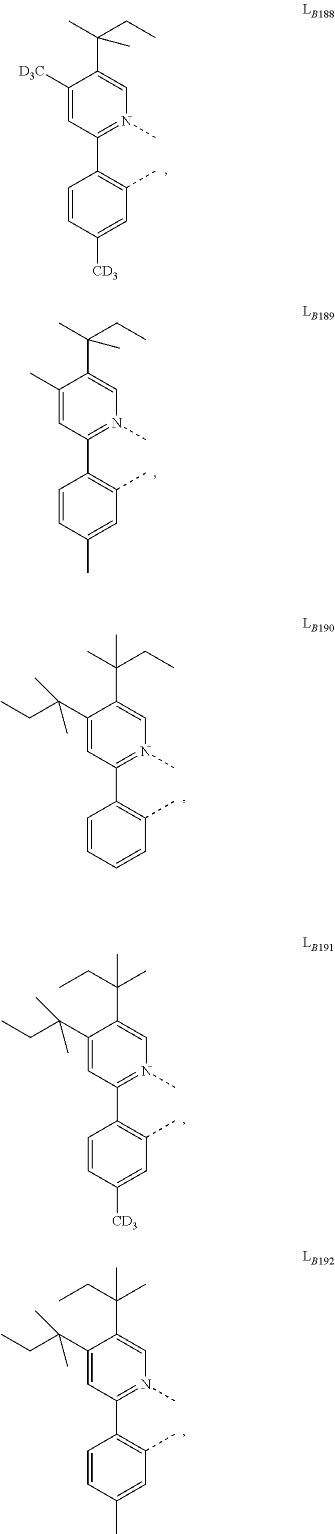

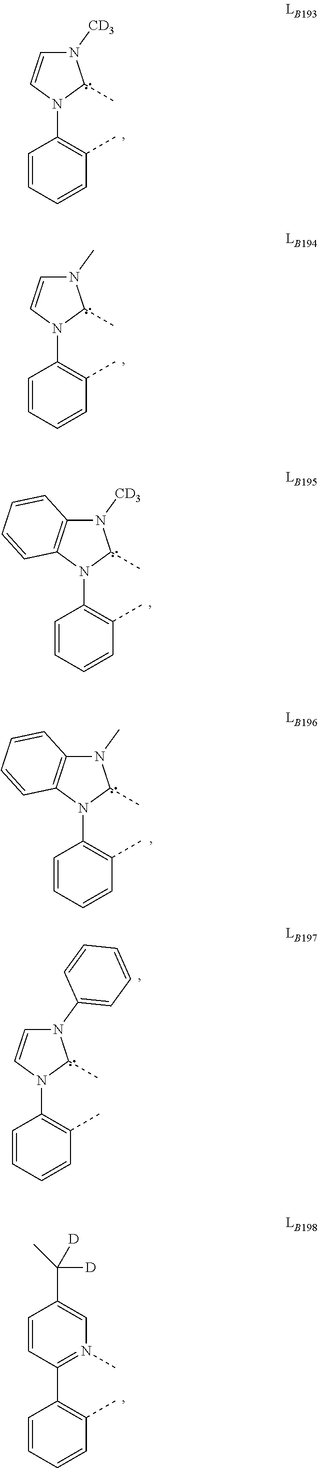

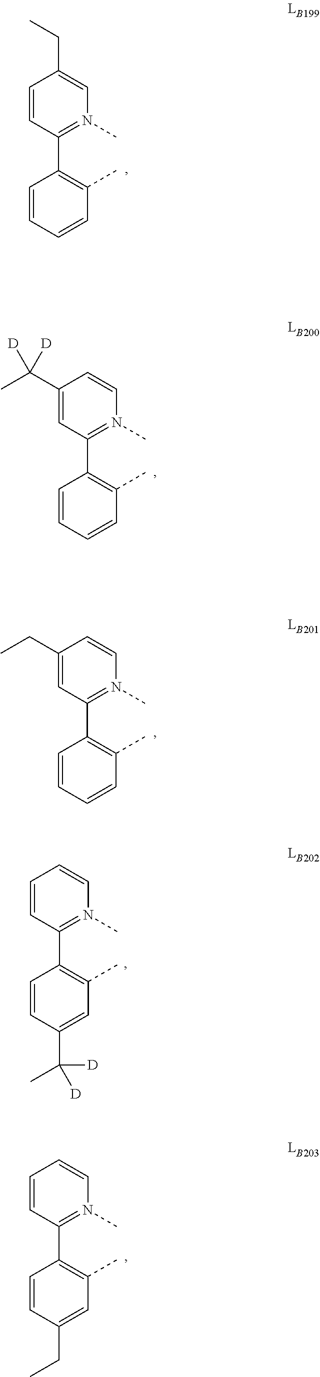

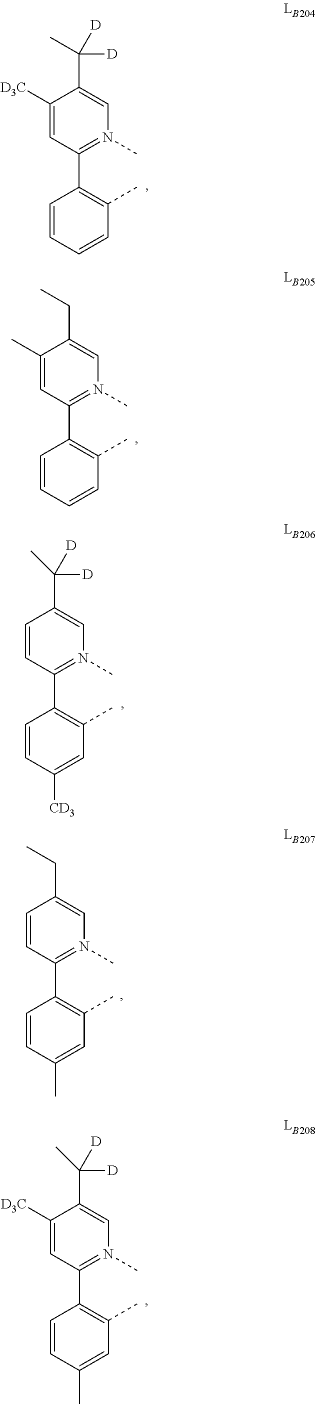

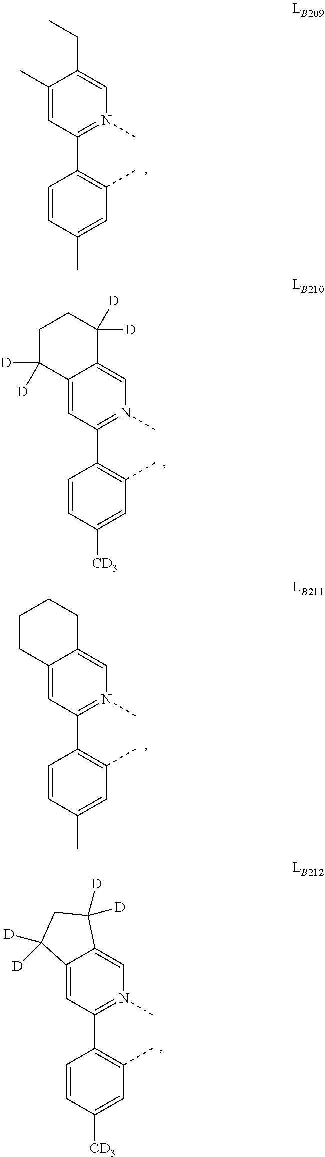

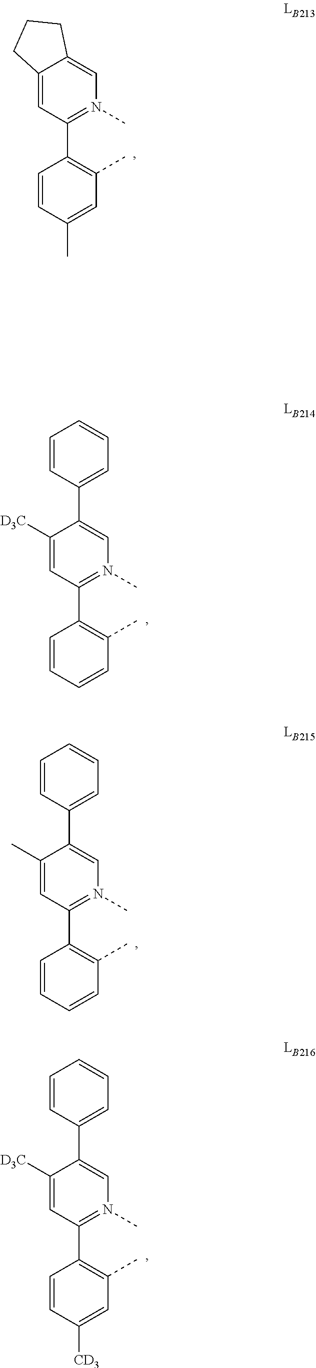

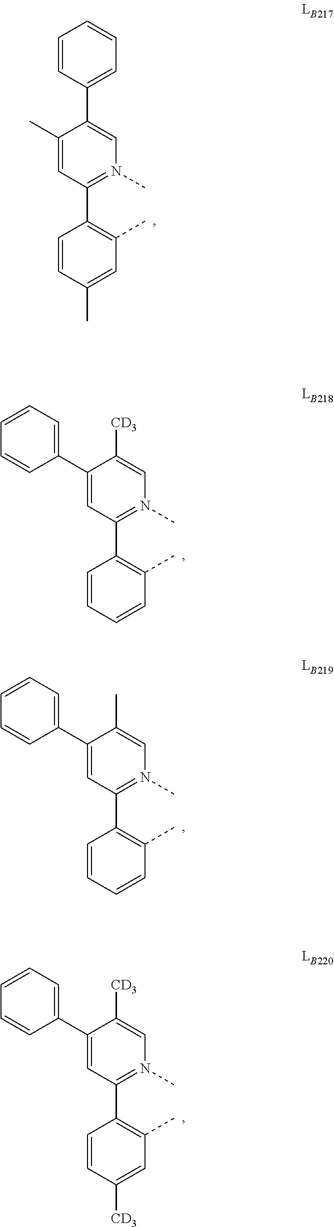

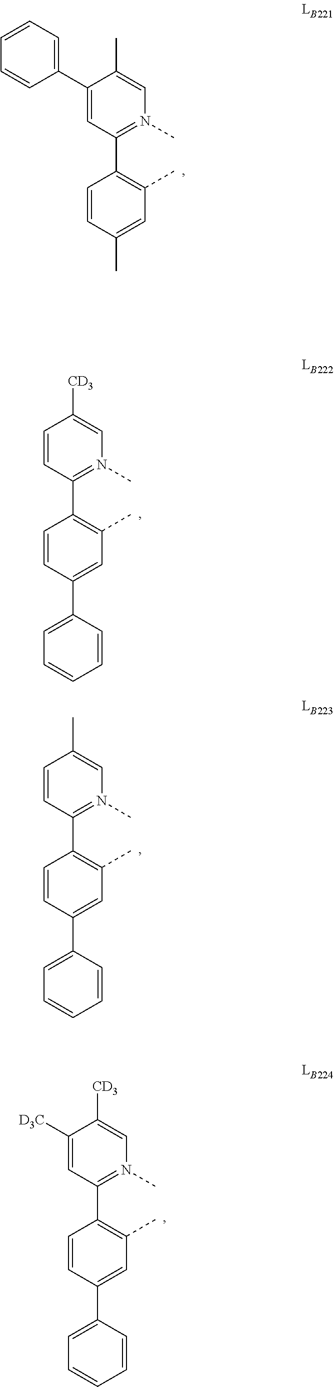

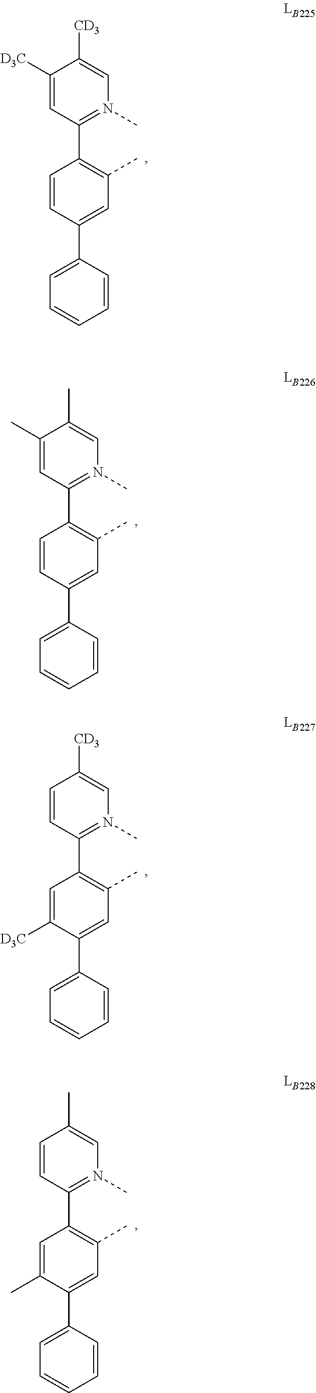

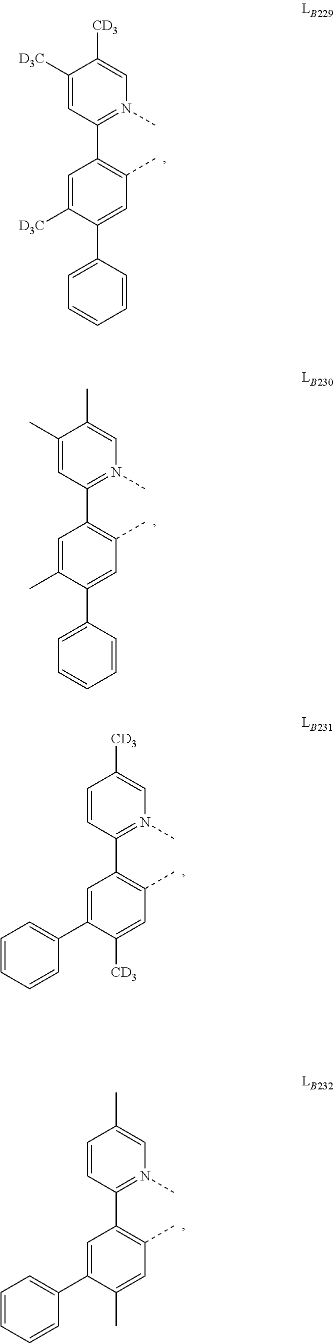

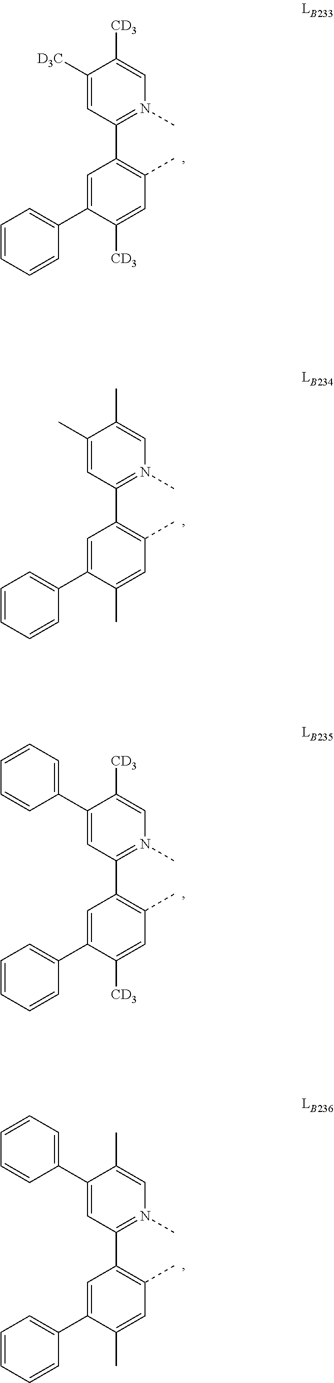

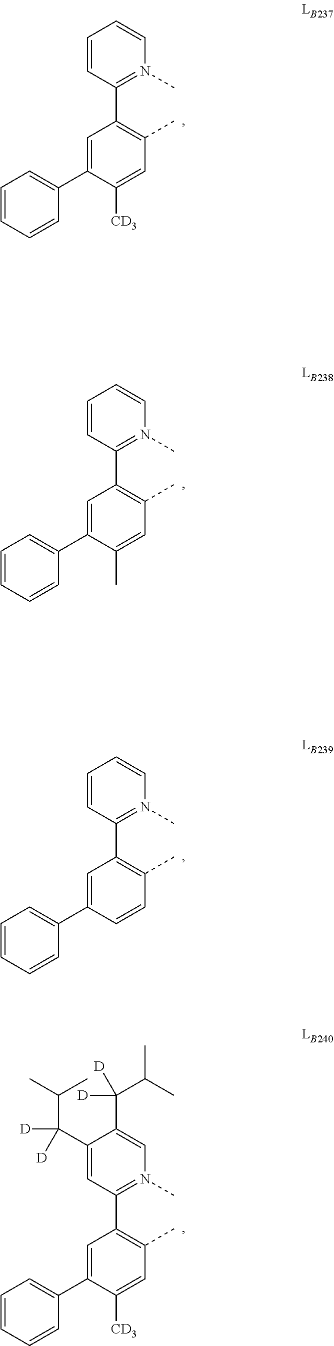

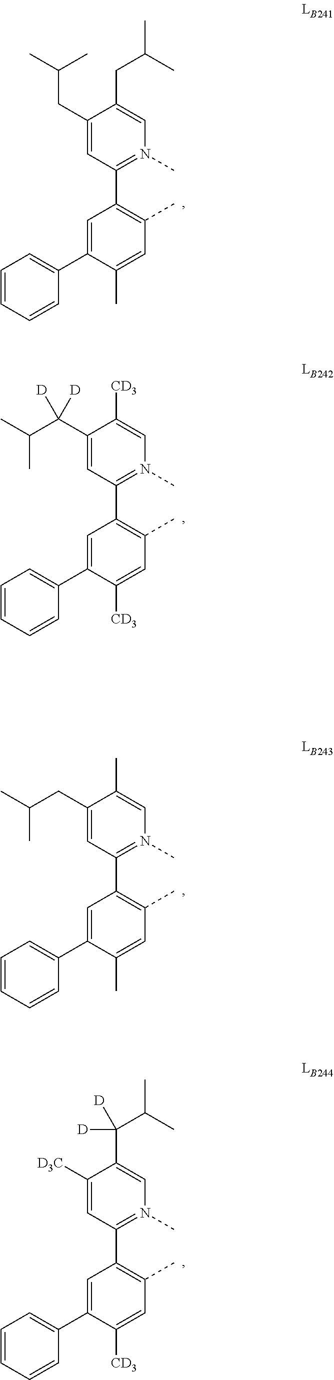

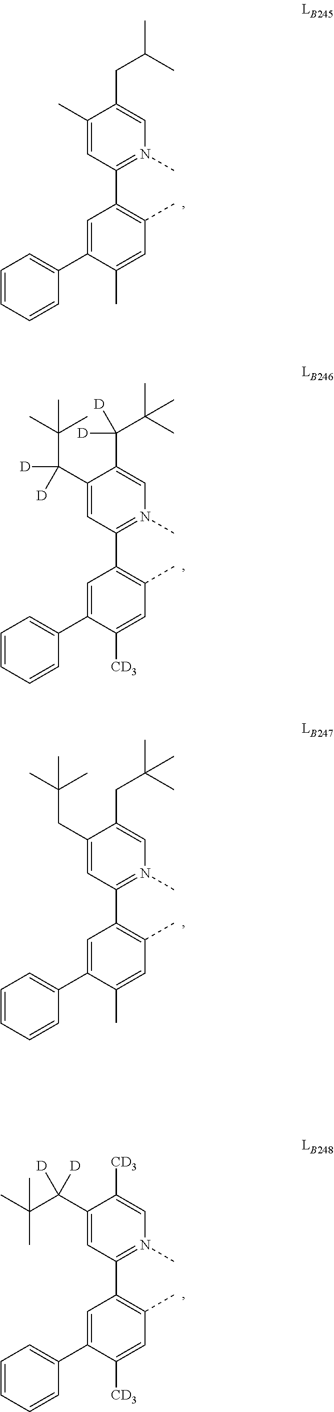

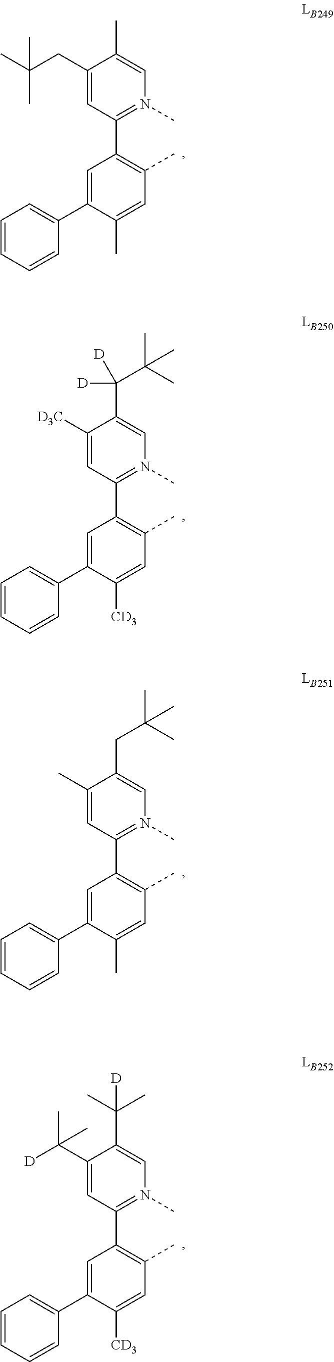

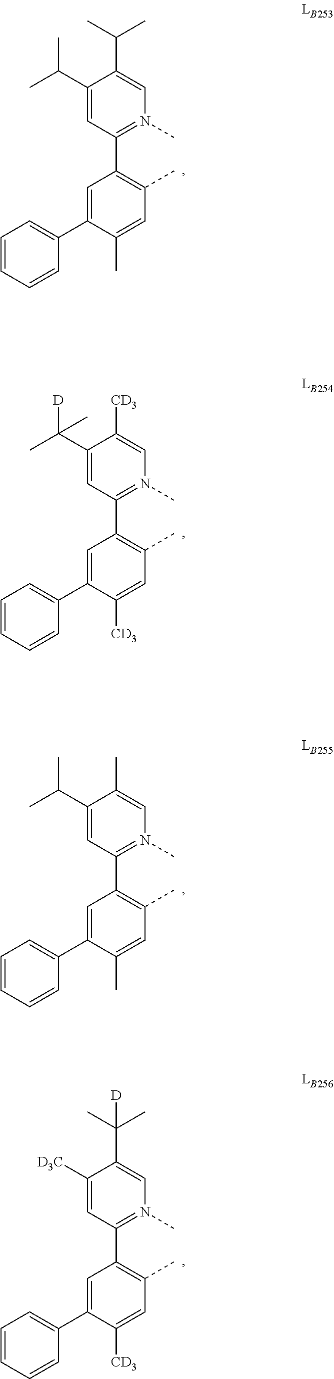

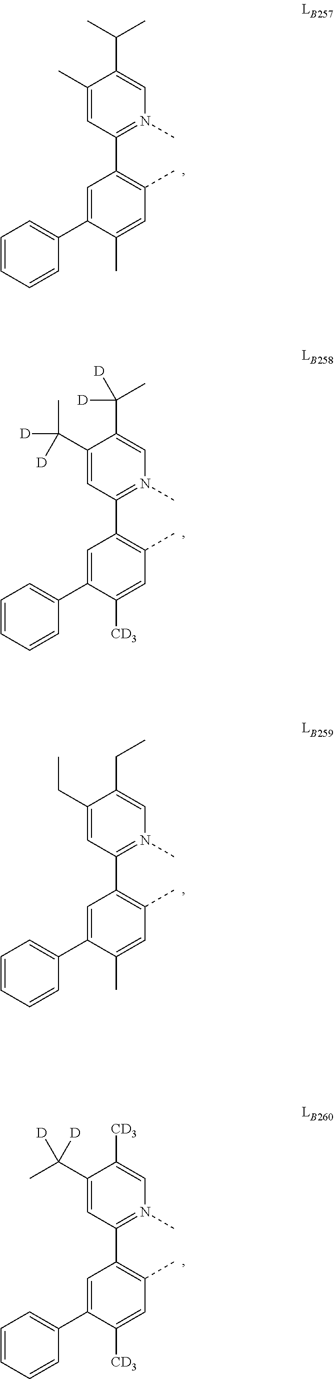

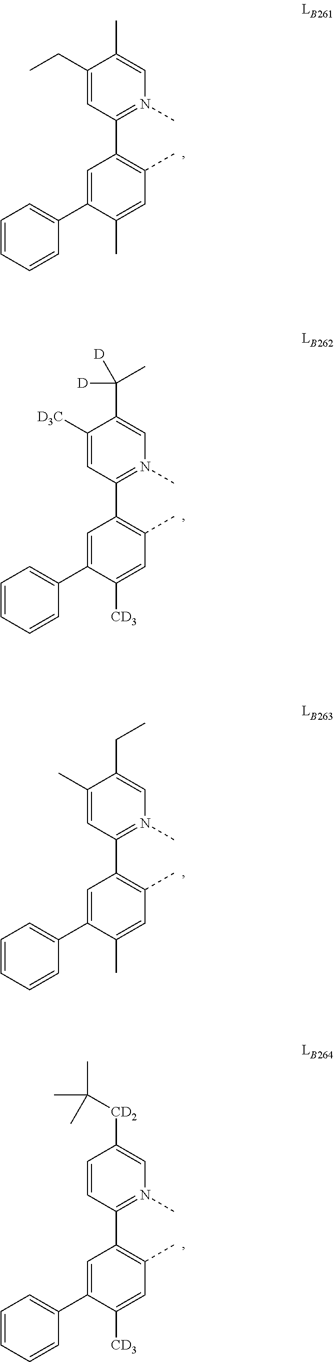

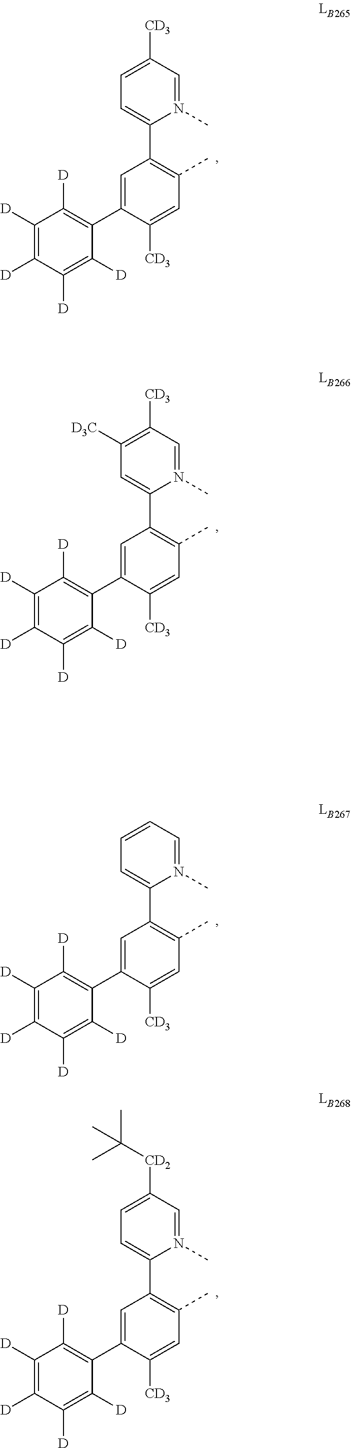

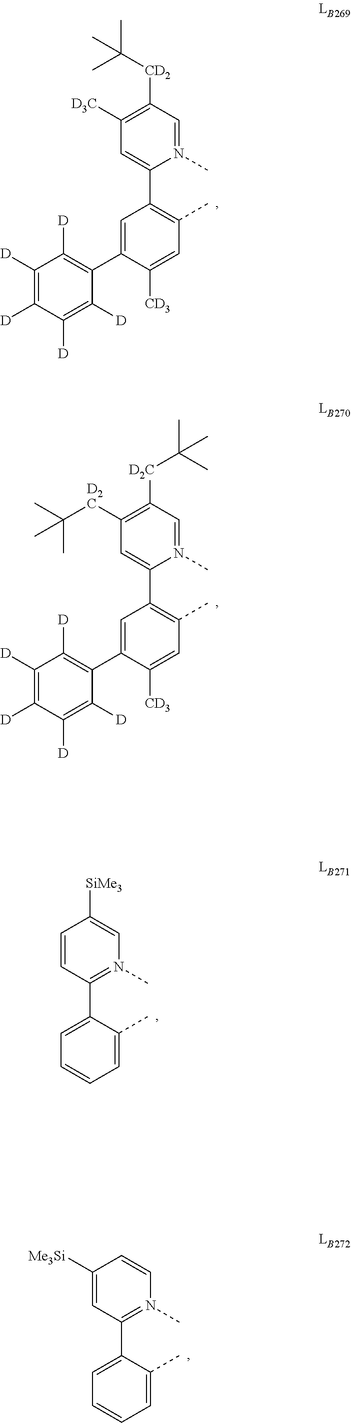

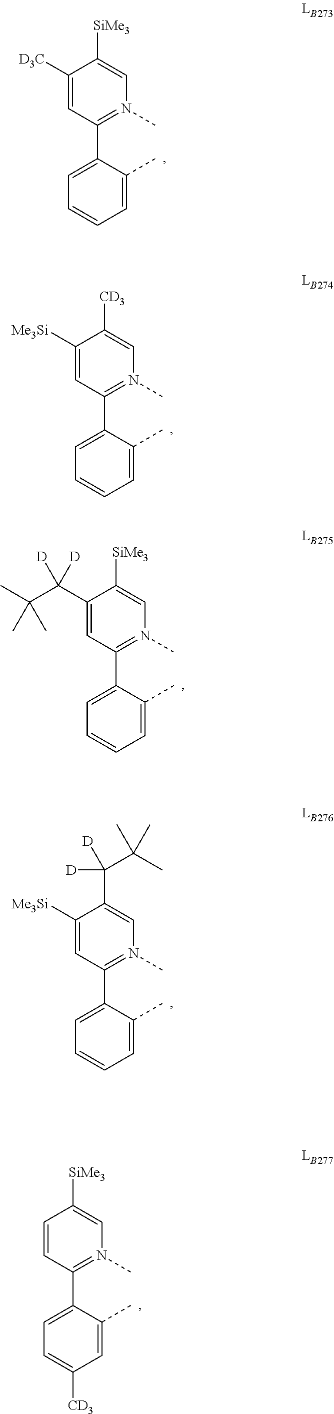

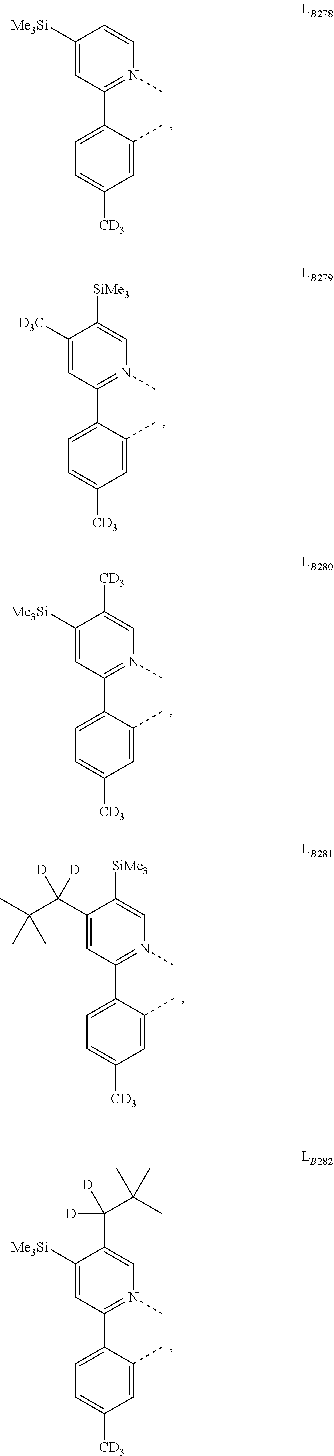

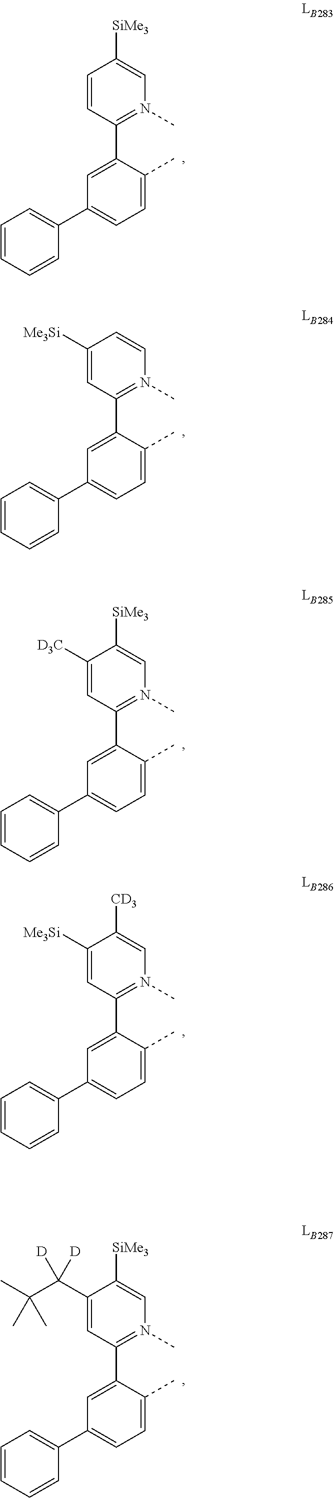

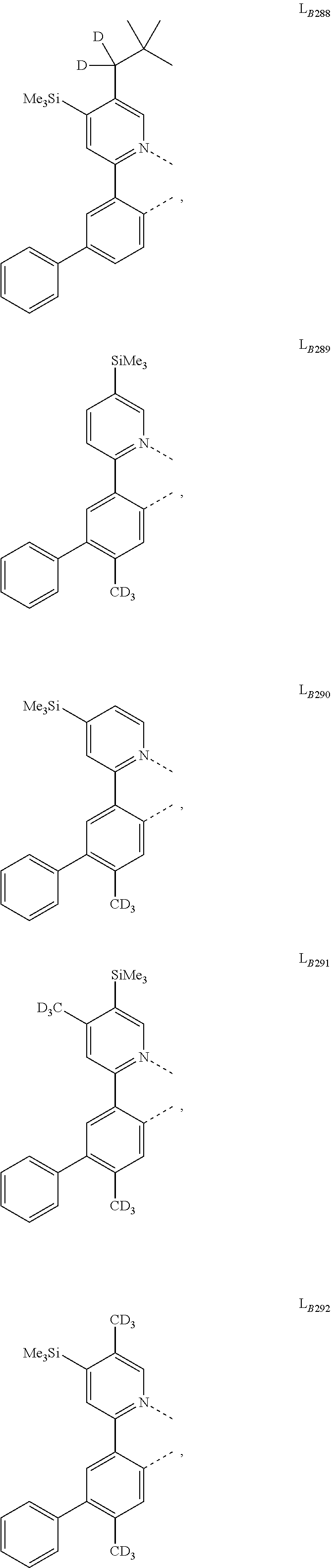

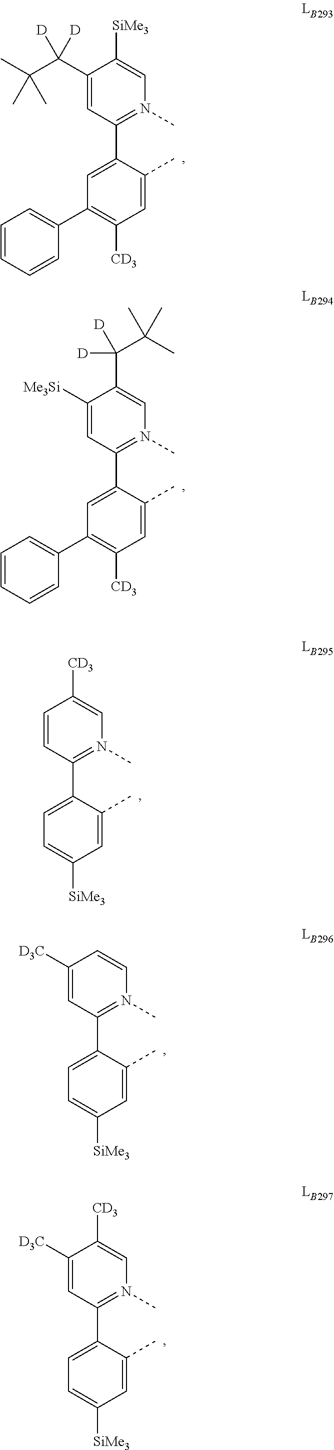

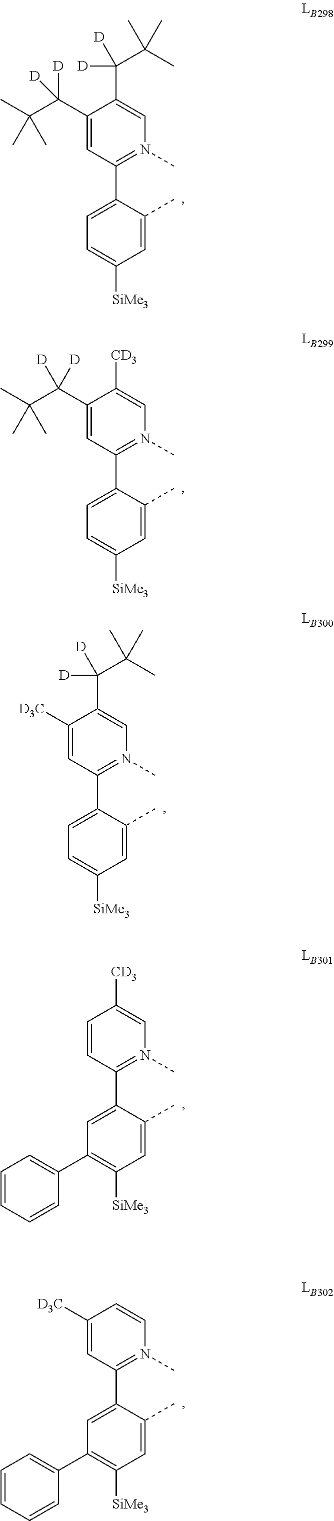

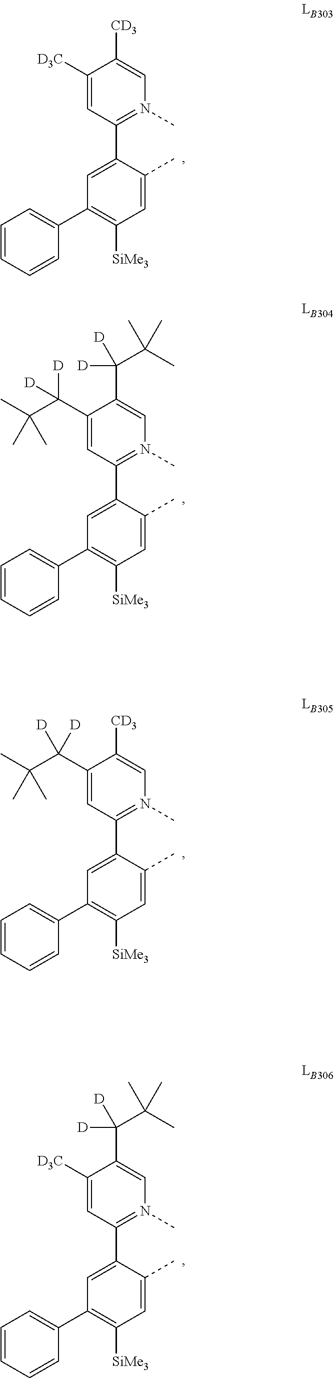

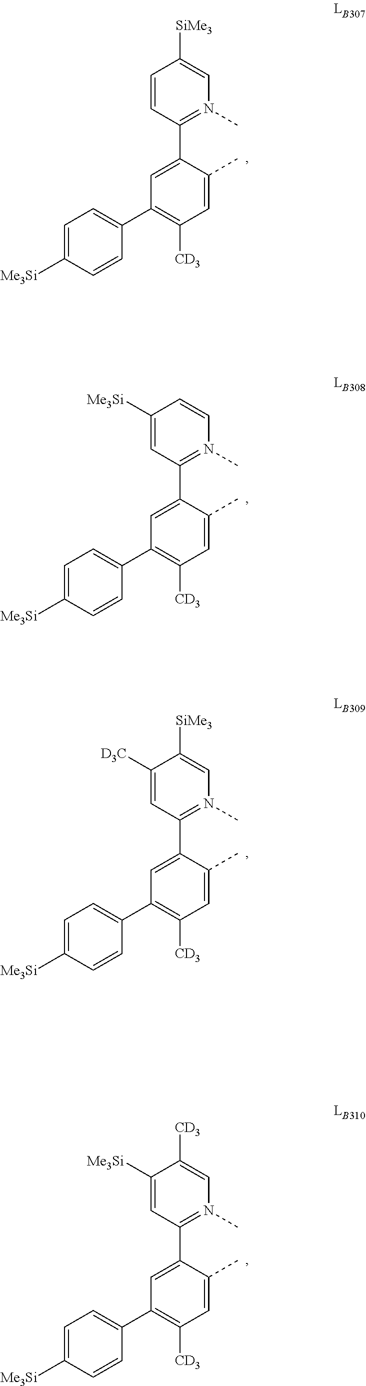

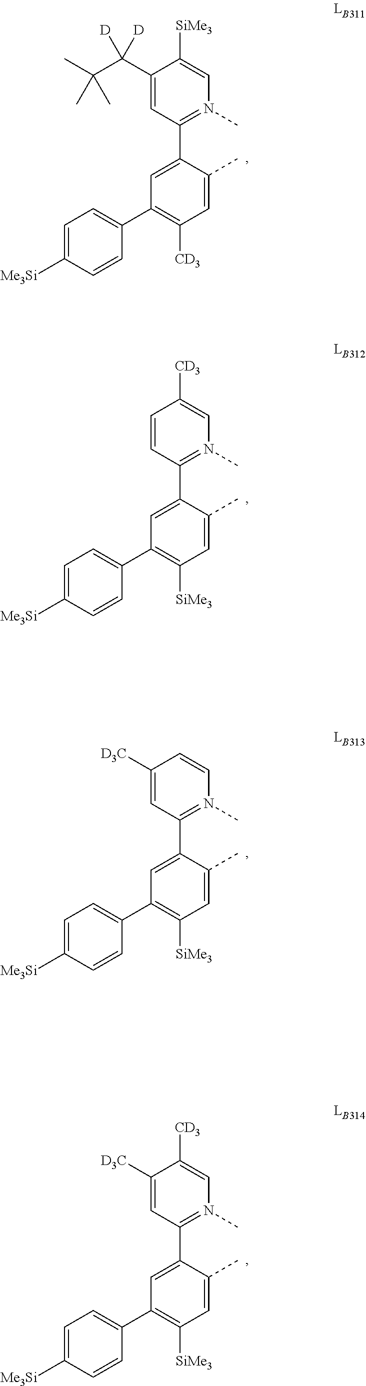

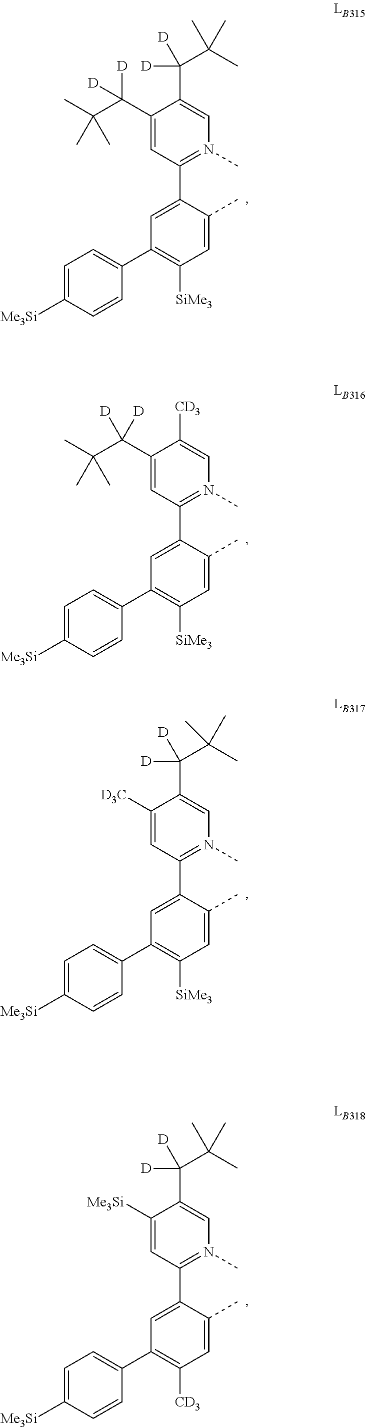

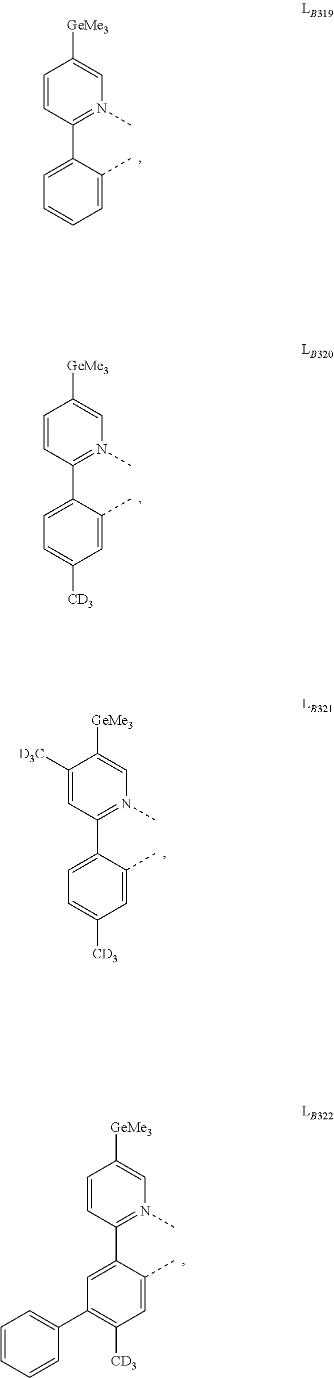

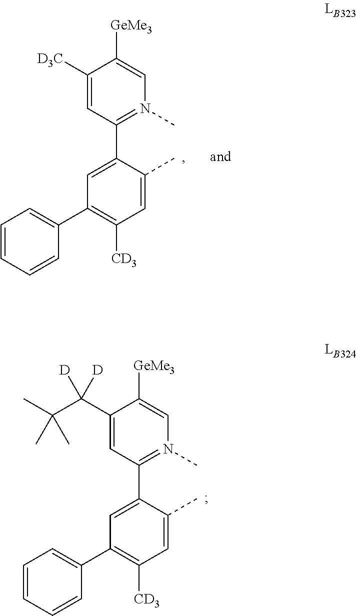

wherein each L_{Cj-I} has a structure based on formula

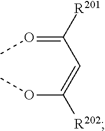

and

each L_{Cj-II} has a structure based on formula

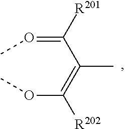

wherein for each L_{Cj} in L_{Cj-I} and L_{Cj-II}, R²⁰¹ and R²⁰² are each independently defined in the following LIST 9:

| L_{Cj} | R²⁰¹ | R²⁰² | L_{Cj} | R²⁰¹ | R²⁰² | L_{Cj} | R²⁰¹ | R²⁰² | L_{Cj} | R²⁰¹ | R²⁰² |
|---|---|---|---|---|---|---|---|---|---|---|---|
| L_{C1} | R^{D1} | R^{D1} | L_{C193} | R^{D1} | R^{D3} | L_{C385} | R^{D17} | R^{D40} | L_{C577} | R^{D143} | R^{D120} |
| L_{C2} | R^{D2} | R^{D2} | L_{C194} | R^{D1} | R^{D4} | L_{C386} | R^{D17} | R^{D41} | L_{C578} | R^{D143} | R^{D133} |
| L_{C3} | R^{D3} | R^{D3} | L_{C195} | R^{D1} | R^{D5} | L_{C387} | R^{D17} | R^{D42} | L_{C579} | R^{D143} | R^{D134} |
| L_{C4} | R^{D4} | R^{D4} | L_{C196} | R^{D1} | R^{D9} | L_{C388} | R^{D17} | R^{D43} | L_{C580} | R^{D143} | R^{D135} |
| L_{C5} | R^{D5} | R^{D5} | L_{C197} | R^{D1} | R^{D10} | L_{C389} | R^{D17} | R^{D48} | L_{C581} | R^{D143} | R^{D136} |
| L_{C6} | R^{D6} | R^{D6} | L_{C198} | R^{D1} | R^{D17} | L_{C390} | R^{D17} | R^{D49} | L_{C582} | R^{D143} | R^{D143} |
| L_{C7} | R^{D7} | R^{D7} | L_{C199} | R^{D1} | R^{D18} | L_{C391} | R^{D17} | R^{D50} | L_{C583} | R^{D143} | R^{D144} |
| L_{C8} | R^{D8} | R^{D8} | L_{C200} | R^{D1} | R^{D20} | L_{C392} | R^{D17} | R^{D54} | L_{C584} | R^{D143} | R^{D145} |
| L_{C9} | R^{D9} | R^{D9} | L_{C201} | R^{D1} | R^{D22} | L_{C393} | R^{D17} | R^{D55} | L_{C585} | R^{D143} | R^{D146} |
| L_{C10} | R^{D10} | R^{D10} | L_{C202} | R^{D1} | R^{D37} | L_{C394} | R^{D17} | R^{D58} | L_{C586} | R^{D143} | R^{D147} |
| L_{C11} | R^{D11} | R^{D11} | L_{C203} | R^{D1} | R^{D40} | L_{C395} | R^{D17} | R^{D59} | L_{C587} | R^{D143} | R^{D149} |
| L_{C12} | R^{D12} | R^{D12} | L_{C204} | R^{D1} | R^{D41} | L_{C396} | R^{D17} | R^{D78} | L_{C588} | R^{D143} | R^{D151} |
| L_{C13} | R^{D13} | R^{D13} | L_{C205} | R^{D1} | R^{D42} | L_{C397} | R^{D17} | R^{D79} | L_{C589} | R^{D143} | R^{D154} |
| L_{C14} | R^{D14} | R^{D14} | L_{C206} | R^{D1} | R^{D43} | L_{C398} | R^{D17} | R^{D81} | L_{C590} | R^{D143} | R^{D155} |
| L_{C15} | R^{D15} | R^{D15} | L_{C207} | R^{D1} | R^{D48} | L_{C399} | R^{D17} | R^{D87} | L_{C591} | R^{D143} | R^{D161} |
| L_{C16} | R^{D16} | R^{D16} | L_{C208} | R^{D1} | R^{D49} | L_{C400} | R^{D17} | R^{D88} | L_{C592} | R^{D144} | R^{D3} |
| L_{C17} | R^{D17} | R^{D17} | L_{C209} | R^{D1} | R^{D50} | L_{C401} | R^{D17} | R^{D89} | L_{C593} | R^{D144} | R^{D5} |
| L_{C18} | R^{D18} | R^{D18} | L_{C210} | R^{D1} | R^{D54} | L_{C402} | R^{D17} | R^{D93} | L_{C594} | R^{D144} | R^{D17} |
| L_{C19} | R^{D19} | R^{D19} | L_{C211} | R^{D1} | R^{D55} | L_{C403} | R^{D17} | R^{D116} | L_{C595} | R^{D144} | R^{D18} |
| L_{C20} | R^{D20} | R^{D20} | L_{C212} | R^{D1} | R^{D58} | L_{C404} | R^{D17} | R^{D117} | L_{C596} | R^{D144} | R^{D20} |
| L_{C21} | R^{D21} | R^{D21} | L_{C213} | R^{D1} | R^{D59} | L_{C405} | R^{D17} | R^{D118} | L_{C597} | R^{D144} | R^{D22} |
| L_{C22} | R^{D22} | R^{D22} | L_{C214} | R^{D1} | R^{D78} | L_{C406} | R^{D17} | R^{D119} | L_{C598} | R^{D144} | R^{D37} |
| L_{C23} | R^{D23} | R^{D23} | L_{C215} | R^{D1} | R^{D79} | L_{C407} | R^{D17} | R^{D120} | L_{C599} | R^{D144} | R^{D40} |
| L_{C24} | R^{D24} | R^{D24} | L_{C216} | R^{D1} | R^{D81} | L_{C408} | R^{D17} | R^{D133} | L_{C600} | R^{D144} | R^{D41} |
| L_{C25} | R^{D25} | R^{D25} | L_{C217} | R^{D1} | R^{D87} | L_{C409} | R^{D17} | R^{D134} | L_{C601} | R^{D144} | R^{D42} |
| L_{C26} | R^{D26} | R^{D26} | L_{C218} | R^{D1} | R^{D88} | L_{C410} | R^{D17} | R^{D135} | L_{C602} | R^{D144} | R^{D43} |
| L_{C27} | R^{D27} | R^{D27} | L_{C219} | R^{D1} | R^{D89} | L_{C411} | R^{D17} | R^{D136} | L_{C603} | R^{D144} | R^{D48} |
| L_{C28} | R^{D28} | R^{D28} | L_{C220} | R^{D1} | R^{D93} | L_{C412} | R^{D17} | R^{D143} | L_{C604} | R^{D144} | R^{D49} |
| L_{C29} | R^{D29} | R^{D29} | L_{C221} | R^{D1} | R^{D116} | L_{C413} | R^{D17} | R^{D144} | L_{C605} | R^{D144} | R^{D54} |
| L_{C30} | R^{D30} | R^{D30} | L_{C222} | R^{D1} | R^{D117} | L_{C414} | R^{D17} | R^{D145} | L_{C606} | R^{D144} | R^{D58} |
| L_{C31} | R^{D31} | R^{D31} | L_{C223} | R^{D1} | R^{D118} | L_{C415} | R^{D17} | R^{D146} | L_{C607} | R^{D144} | R^{D59} |
| L_{C32} | R^{D32} | R^{D32} | L_{C224} | R^{D1} | R^{D119} | L_{C416} | R^{D17} | R^{D147} | L_{C608} | R^{D144} | R^{D78} |
| L_{C33} | R^{D33} | R^{D33} | L_{C225} | R^{D1} | R^{D120} | L_{C417} | R^{D17} | R^{D149} | L_{C609} | R^{D144} | R^{D79} |
| L_{C34} | R^{D34} | R^{D34} | L_{C226} | R^{D1} | R^{D133} | L_{C418} | R^{D17} | R^{D151} | L_{C610} | R^{D144} | R^{D81} |
| L_{C35} | R^{D35} | R^{D35} | L_{C227} | R^{D1} | R^{D134} | L_{C419} | R^{D17} | R^{D154} | L_{C611} | R^{D144} | R^{D87} |
| L_{C36} | R^{D36} | R^{D36} | L_{C228} | R^{D1} | R^{D135} | L_{C420} | R^{D17} | R^{D155} | L_{C612} | R^{D144} | R^{D88} |
| L_{C37} | R^{D37} | R^{D37} | L_{C229} | R^{D1} | R^{D136} | L_{C421} | R^{D17} | R^{D161} | L_{C613} | R^{D144} | R^{D89} |
| L_{C38} | R^{D38} | R^{D38} | L_{C230} | R^{D1} | R^{D143} | L_{C422} | R^{D17} | R^{D175} | L_{C614} | R^{D144} | R^{D93} |
| L_{C39} | R^{D39} | R^{D39} | L_{C231} | R^{D1} | R^{D144} | L_{C423} | R^{D50} | R^{D3} | L_{C615} | R^{D144} | R^{D116} |
| L_{C40} | R^{D40} | R^{D40} | L_{C232} | R^{D1} | R^{D145} | L_{C424} | R^{D50} | R^{D5} | L_{C616} | R^{D144} | R^{D117} |
| L_{C41} | R^{D41} | R^{D41} | L_{C233} | R^{D1} | R^{D146} | L_{C425} | R^{D50} | R^{D18} | L_{C617} | R^{D144} | R^{D118} |
| L_{C42} | R^{D42} | R^{D42} | L_{C234} | R^{D1} | R^{D147} | L_{C426} | R^{D50} | R^{D20} | L_{C618} | R^{D144} | R^{D119} |
| L_{C43} | R^{D43} | R^{D43} | L_{C235} | R^{D1} | R^{D149} | L_{C427} | R^{D50} | R^{D22} | L_{C619} | R^{D144} | R^{D120} |
| L_{C44} | R^{D44} | R^{D44} | L_{C236} | R^{D1} | R^{D151} | L_{C428} | R^{D50} | R^{D37} | L_{C620} | R^{D144} | R^{D133} |
| L_{C45} | R^{D45} | R^{D45} | L_{C237} | R^{D1} | R^{D154} | L_{C429} | R^{D50} | R^{D40} | L_{C621} | R^{D144} | R^{D134} |
| L_{C46} | R^{D46} | R^{D46} | L_{C238} | R^{D1} | R^{D155} | L_{C430} | R^{D50} | R^{D41} | L_{C622} | R^{D144} | R^{D135} |
| L_{C47} | R^{D47} | R^{D47} | L_{C239} | R^{D1} | R^{D161} | L_{C431} | R^{D50} | R^{D42} | L_{C623} | R^{D144} | R^{D136} |
| L_{C48} | R^{D48} | R^{D48} | L_{C240} | R^{D1} | R^{D175} | L_{C432} | R^{D50} | R^{D43} | L_{C624} | R^{D144} | R^{D145} |
| L_{C49} | R^{D49} | R^{D49} | L_{C241} | R^{D4} | R^{D3} | L_{C433} | R^{D50} | R^{D48} | L_{C625} | R^{D144} | R^{D146} |
| L_{C50} | R^{D50} | R^{D50} | L_{C242} | R^{D4} | R^{D5} | L_{C434} | R^{D50} | R^{D49} | L_{C626} | R^{D144} | R^{D147} |
| L_{C51} | R^{D51} | R^{D51} | L_{C243} | R^{D4} | R^{D9} | L_{C435} | R^{D50} | R^{D54} | L_{C627} | R^{D144} | R^{D149} |
| L_{C52} | R^{D52} | R^{D52} | L_{C244} | R^{D4} | R^{D10} | L_{C436} | R^{D50} | R^{D55} | L_{C628} | R^{D144} | R^{D151} |
| L_{C53} | R^{D53} | R^{D53} | L_{C245} | R^{D4} | R^{D17} | L_{C437} | R^{D50} | R^{D58} | L_{C629} | R^{D144} | R^{D154} |
| L_{C54} | R^{D54} | R^{D54} | L_{C246} | R^{D4} | R^{D18} | L_{C438} | R^{D50} | R^{D59} | L_{C630} | R^{D144} | R^{D155} |
| L_{C55} | R^{D55} | R^{D55} | L_{C247} | R^{D4} | R^{D20} | L_{C439} | R^{D50} | R^{D78} | L_{C631} | R^{D144} | R^{D161} |
| L_{C56} | R^{D56} | R^{D56} | L_{C248} | R^{D4} | R^{D22} | L_{C440} | R^{D50} | R^{D79} | L_{C632} | R^{D144} | R^{D175} |
| L_{C57} | R^{D57} | R^{D57} | L_{C249} | R^{D4} | R^{D37} | L_{C441} | R^{D50} | R^{D81} | L_{C633} | R^{D145} | R^{D3} |
| L_{C58} | R^{D58} | R^{D58} | L_{C250} | R^{D4} | R^{D40} | L_{C442} | R^{D50} | R^{D87} | L_{C634} | R^{D145} | R^{D5} |
| L_{C59} | R^{D59} | R^{D59} | L_{C251} | R^{D4} | R^{D41} | L_{C443} | R^{D50} | R^{D88} | L_{C635} | R^{D145} | R^{D17} |
| L_{C60} | R^{D60} | R^{D60} | L_{C252} | R^{D4} | R^{D42} | L_{C444} | R^{D50} | R^{D89} | L_{C636} | R^{D145} | R^{D18} |
| L_{C61} | R^{D61} | R^{D61} | L_{C253} | R^{D4} | R^{D43} | L_{C445} | R^{D50} | R^{D93} | L_{C637} | R^{D145} | R^{D20} |
| L_{C62} | R^{D62} | R^{D62} | L_{C254} | R^{D4} | R^{D48} | L_{C446} | R^{D50} | R^{D116} | L_{C638} | R^{D145} | R^{D22} |
| L_{C63} | R^{D63} | R^{D63} | L_{C255} | R^{D4} | R^{D49} | L_{C447} | R^{D50} | R^{D117} | L_{C639} | R^{D145} | R^{D37} |
| L_{C64} | R^{D64} | R^{D64} | L_{C256} | R^{D4} | R^{D50} | L_{C448} | R^{D50} | R^{D118} | L_{C640} | R^{D145} | R^{D40} |
| L_{C65} | R^{D65} | R^{D65} | L_{C257} | R^{D4} | R^{D54} | L_{C449} | R^{D50} | R^{D119} | L_{C641} | R^{D145} | R^{D41} |
| L_{C66} | R^{D66} | R^{D66} | L_{C258} | R^{D4} | R^{D55} | L_{C450} | R^{D50} | R^{D120} | L_{C642} | R^{D145} | R^{D42} |
| L_{C67} | R^{D67} | R^{D67} | L_{C259} | R^{D4} | R^{D58} | L_{C451} | R^{D50} | R^{D133} | L_{C643} | R^{D145} | R^{D43} |
| L_{C68} | R^{D68} | R^{D68} | L_{C260} | R^{D4} | R^{D59} | L_{C452} | R^{D50} | R^{D134} | L_{C644} | R^{D145} | R^{D48} |
| L_{C69} | R^{D69} | R^{D69} | L_{C261} | R^{D4} | R^{D78} | L_{C453} | R^{D50} | R^{D135} | L_{C645} | R^{D145} | R^{D49} |
| L_{C70} | R^{D70} | R^{D70} | L_{C262} | R^{D4} | R^{D79} | L_{C454} | R^{D50} | R^{D136} | L_{C646} | R^{D145} | R^{D54} |
| L_{C71} | R^{D71} | R^{D71} | L_{C263} | R^{D4} | R^{D81} | L_{C455} | R^{D50} | R^{D143} | L_{C647} | R^{D145} | R^{D58} |
| L_{C72} | R^{D72} | R^{D72} | L_{C264} | R^{D4} | R^{D87} | L_{C456} | R^{D50} | R^{D144} | L_{C648} | R^{D145} | R^{D59} |
| L_{C73} | R^{D73} | R^{D73} | L_{C265} | R^{D4} | R^{D88} | L_{C457} | R^{D50} | R^{D145} | L_{C649} | R^{D145} | R^{D78} |
| L_{C74} | R^{D74} | R^{D74} | L_{C266} | R^{D4} | R^{D89} | L_{C458} | R^{D50} | R^{D146} | L_{C650} | R^{D145} | R^{D79} |
| L_{C75} | R^{D75} | R^{D75} | L_{C267} | R^{D4} | R^{D93} | L_{C459} | R^{D50} | R^{D147} | L_{C651} | R^{D145} | R^{D81} |
| L_{C76} | R^{D76} | R^{D76} | L_{C268} | R^{D4} | R^{D116} | L_{C460} | R^{D50} | R^{D149} | L_{C652} | R^{D145} | R^{D87} |
| L_{C77} | R^{D77} | R^{D77} | L_{C269} | R^{D4} | R^{D117} | L_{C461} | R^{D50} | R^{D151} | L_{C653} | R^{D145} | R^{D88} |
| L_{C78} | R^{D78} | R^{D78} | L_{C270} | R^{D4} | R^{D118} | L_{C462} | R^{D50} | R^{D154} | L_{C654} | R^{D145} | R^{D89} |
| L_{C79} | R^{D79} | R^{D79} | L_{C271} | R^{D4} | R^{D119} | L_{C463} | R^{D50} | R^{D155} | L_{C655} | R^{D145} | R^{D93} |
| L_{C80} | R^{D80} | R^{D80} | L_{C272} | R^{D4} | R^{D120} | L_{C464} | R^{D50} | R^{D161} | L_{C656} | R^{D145} | R^{D116} |
| L_{C81} | R^{D81} | R^{D81} | L_{C273} | R^{D4} | R^{D133} | L_{C465} | R^{D50} | R^{D175} | L_{C657} | R^{D145} | R^{D117} |
| L_{C82} | R^{D82} | R^{D82} | L_{C274} | R^{D4} | R^{D134} | L_{C466} | R^{D55} | R^{D3} | L_{C658} | R^{D145} | R^{D118} |
| L_{C83} | R^{D83} | R^{D83} | L_{C275} | R^{D4} | R^{D135} | L_{C467} | R^{D55} | R^{D5} | L_{C659} | R^{D145} | R^{D119} |
| L_{C84} | R^{D84} | R^{D84} | L_{C276} | R^{D4} | R^{D136} | L_{C468} | R^{D55} | R^{D18} | L_{C660} | R^{D145} | R^{D120} |
| L_{C85} | R^{D85} | R^{D85} | L_{C277} | R^{D4} | R^{D143} | L_{C469} | R^{D55} | R^{D20} | L_{C661} | R^{D145} | R^{D133} |
| L_{C86} | R^{D86} | R^{D86} | L_{C278} | R^{D4} | R^{D144} | L_{C470} | R^{D55} | R^{D22} | L_{C662} | R^{D145} | R^{D134} |
| L_{C87} | R^{D87} | R^{D87} | L_{C279} | R^{D4} | R^{D145} | L_{C471} | R^{D55} | R^{D37} | L_{C663} | R^{D145} | R^{D135} |
| L_{C88} | R^{D88} | R^{D88} | L_{C280} | R^{D4} | R^{D146} | L_{C472} | R^{D55} | R^{D40} | L_{C664} | R^{D145} | R^{D136} |
| L_{C89} | R^{D89} | R^{D89} | L_{C281} | R^{D4} | R^{D147} | L_{C473} | R^{D55} | R^{D41} | L_{C665} | R^{D145} | R^{D146} |
| L_{C90} | R^{D90} | R^{D90} | L_{C282} | R^{D4} | R^{D149} | L_{C474} | R^{D55} | R^{D42} | L_{C666} | R^{D145} | R^{D147} |
| L_{C91} | R^{D91} | R^{D91} | L_{C283} | R^{D4} | R^{D151} | L_{C475} | R^{D55} | R^{D43} | L_{C667} | R^{D145} | R^{D149} |
| L_{C92} | R^{D92} | R^{D92} | L_{C284} | R^{D4} | R^{D154} | L_{C476} | R^{D55} | R^{D48} | L_{C668} | R^{D145} | R^{D151} |
| L_{C93} | R^{D93} | R^{D93} | L_{C285} | R^{D4} | R^{D155} | L_{C477} | R^{D55} | R^{D49} | L_{C669} | R^{D145} | R^{D154} |
| L_{C94} | R^{D94} | R^{D94} | L_{C286} | R^{D4} | R^{D161} | L_{C478} | R^{D55} | R^{D54} | L_{C670} | R^{D145} | R^{D155} |
| L_{C95} | R^{D95} | R^{D95} | L_{C287} | R^{D4} | R^{D175} | L_{C479} | R^{D55} | R^{D58} | L_{C671} | R^{D145} | R^{D161} |
| L_{C96} | R^{D96} | R^{D96} | L_{C288} | R^{D9} | R^{D3} | L_{C480} | R^{D55} | R^{D59} | L_{C672} | R^{D145} | R^{D175} |
| L_{C97} | R^{D97} | R^{D97} | L_{C289} | R^{D9} | R^{D5} | L_{C481} | R^{D55} | R^{D78} | L_{C673} | R^{D146} | R^{D3} |
| L_{C98} | R^{D98} | R^{D98} | L_{C290} | R^{D9} | R^{D10} | L_{C482} | R^{D55} | R^{D79} | L_{C674} | R^{D146} | R^{D5} |
| L_{C99} | R^{D99} | R^{D99} | L_{C291} | R^{D9} | R^{D17} | L_{C483} | R^{D55} | R^{D81} | L_{C675} | R^{D146} | R^{D17} |
| L_{C100} | R^{D100} | R^{D100} | L_{C292} | R^{D9} | R^{D18} | L_{C484} | R^{D55} | R^{D87} | L_{C676} | R^{D146} | R^{D18} |
| L_{C101} | R^{D101} | R^{D101} | L_{C293} | R^{D9} | R^{D20} | L_{C485} | R^{D55} | R^{D88} | L_{C677} | R^{D146} | R^{D20} |
| L_{C102} | R^{D102} | R^{D102} | L_{C294} | R^{D9} | R^{D22} | L_{C486} | R^{D55} | R^{D89} | L_{C678} | R^{D146} | R^{D22} |
| L_{C103} | R^{D103} | R^{D103} | L_{C295} | R^{D9} | R^{D37} | L_{C487} | R^{D55} | R^{D93} | L_{C679} | R^{D146} | R^{D37} |
| L_{C104} | R^{D104} | R^{D104} | L_{C296} | R^{D9} | R^{D40} | L_{C488} | R^{D55} | R^{D116} | L_{C680} | R^{D146} | R^{D40} |
| L_{C105} | R^{D105} | R^{D105} | L_{C297} | R^{D9} | R^{D41} | L_{C489} | R^{D55} | R^{D117} | L_{C681} | R^{D146} | R^{D41} |
| L_{C106} | R^{D106} | R^{D106} | L_{C298} | R^{D9} | R^{D42} | L_{C490} | R^{D55} | R^{D118} | L_{C682} | R^{D146} | R^{D42} |
| L_{C107} | R^{D107} | R^{D107} | L_{C299} | R^{D9} | R^{D43} | L_{C491} | R^{D55} | R^{D119} | L_{C683} | R^{D146} | R^{D43} |
| L_{C108} | R^{D108} | R^{D108} | L_{C300} | R^{D9} | R^{D48} | L_{C492} | R^{D55} | R^{D120} | L_{C684} | R^{D146} | R^{D48} |
| L_{C109} | R^{D109} | R^{D109} | L_{C301} | R^{D9} | R^{D49} | L_{C493} | R^{D55} | R^{D133} | L_{C685} | R^{D146} | R^{D49} |
| L_{C110} | R^{D110} | R^{D110} | L_{C302} | R^{D9} | R^{D50} | L_{C494} | R^{D55} | R^{D134} | L_{C686} | R^{D146} | R^{D54} |
| L_{C111} | R^{D111} | R^{D111} | L_{C303} | R^{D9} | R^{D54} | L_{C495} | R^{D55} | R^{D135} | L_{C687} | R^{D146} | R^{D58} |
| L_{C112} | R^{D112} | R^{D112} | L_{C304} | R^{D9} | R^{D55} | L_{C496} | R^{D55} | R^{D136} | L_{C688} | R^{D146} | R^{D59} |
| L_{C113} | R^{D113} | R^{D113} | L_{C305} | R^{D9} | R^{D58} | L_{C497} | R^{D55} | R^{D143} | L_{C689} | R^{D146} | R^{D78} |
| L_{C114} | R^{D114} | R^{D114} | L_{C306} | R^{D9} | R^{D59} | L_{C498} | R^{D55} | R^{D144} | L_{C690} | R^{D146} | R^{D79} |
| L_{C115} | R^{D115} | R^{D115} | L_{C307} | R^{D9} | R^{D78} | L_{C499} | R^{D55} | R^{D145} | L_{C691} | R^{D146} | R^{D81} |
| L_{C116} | R^{D116} | R^{D116} | L_{C308} | R^{D9} | R^{D79} | L_{C500} | R^{D55} | R^{D146} | L_{C692} | R^{D146} | R^{D87} |
| L_{C117} | R^{D117} | R^{D117} | L_{C309} | R^{D9} | R^{D81} | L_{C501} | R^{D55} | R^{D147} | L_{C693} | R^{D146} | R^{D88} |
| L_{C118} | R^{D118} | R^{D118} | L_{C310} | R^{D9} | R^{D87} | L_{C502} | R^{D55} | R^{D149} | L_{C694} | R^{D146} | R^{D89} |
| L_{C119} | R^{D119} | R^{D119} | L_{C311} | R^{D9} | R^{D88} | L_{C503} | R^{D55} | R^{D151} | L_{C695} | R^{D146} | R^{D93} |
| L_{C120} | R^{D120} | R^{D120} | L_{C312} | R^{D9} | R^{D89} | L_{C504} | R^{D55} | R^{D154} | L_{C696} | R^{D146} | R^{D117} |
| L_{C121} | R^{D121} | R^{D121} | L_{C313} | R^{D9} | R^{D93} | L_{C505} | R^{D55} | R^{D155} | L_{C697} | R^{D146} | R^{D118} |
| L_{C122} | R^{D122} | R^{D122} | L_{C314} | R^{D9} | R^{D116} | L_{C506} | R^{D55} | R^{D161} | L_{C698} | R^{D146} | R^{D119} |
| L_{C123} | R^{D123} | R^{D123} | L_{C315} | R^{D9} | R^{D117} | L_{C507} | R^{D55} | R^{D175} | L_{C699} | R^{D146} | R^{D120} |
| L_{C124} | R^{D124} | R^{D124} | L_{C316} | R^{D9} | R^{D118} | L_{C508} | R^{D116} | R^{D3} | L_{C700} | R^{D146} | R^{D133} |
| L_{C125} | R^{D125} | R^{D125} | L_{C317} | R^{D9} | R^{D119} | L_{C509} | R^{D116} | R^{D5} | L_{C701} | R^{D146} | R^{D134} |
| L_{C126} | R^{D126} | R^{D126} | L_{C318} | R^{D9} | R^{D120} | L_{C510} | R^{D116} | R^{D17} | L_{C702} | R^{D146} | R^{D135} |
| L_{C127} | R^{D127} | R^{D127} | L_{C319} | R^{D9} | R^{D133} | L_{C511} | R^{D116} | R^{D18} | L_{C703} | R^{D146} | R^{D136} |
| L_{C128} | R^{D128} | R^{D128} | L_{C320} | R^{D9} | R^{D134} | L_{C512} | R^{D116} | R^{D20} | L_{C704} | R^{D146} | R^{D146} |
| L_{C129} | R^{D129} | R^{D129} | L_{C321} | R^{D9} | R^{D135} | L_{C513} | R^{D116} | R^{D22} | L_{C705} | R^{D146} | R^{D147} |
| L_{C130} | R^{D130} | R^{D130} | L_{C322} | R^{D9} | R^{D136} | L_{C514} | R^{D116} | R^{D37} | L_{C706} | R^{D146} | R^{D149} |
| L_{C131} | R^{D131} | R^{D131} | L_{C323} | R^{D9} | R^{D143} | L_{C515} | R^{D116} | R^{D40} | L_{C707} | R^{D146} | R^{D151} |
| L_{C132} | R^{D132} | R^{D132} | L_{C324} | R^{D9} | R^{D144} | L_{C516} | R^{D116} | R^{D41} | L_{C708} | R^{D146} | R^{D154} |
| L_{C133} | R^{D133} | R^{D133} | L_{C325} | R^{D9} | R^{D145} | L_{C517} | R^{D116} | R^{D42} | L_{C709} | R^{D146} | R^{D155} |
| L_{C134} | R^{D134} | R^{D134} | L_{C326} | R^{D9} | R^{D146} | L_{C518} | R^{D116} | R^{D43} | L_{C710} | R^{D146} | R^{D161} |
| L_{C135} | R^{D135} | R^{D135} | L_{C327} | R^{D9} | R^{D147} | L_{C519} | R^{D116} | R^{D48} | L_{C711} | R^{D146} | R^{D175} |
| L_{C136} | R^{D136} | R^{D136} | L_{C328} | R^{D9} | R^{D149} | L_{C520} | R^{D116} | R^{D49} | L_{C712} | R^{D133} | R^{D3} |
| L_{C137} | R^{D137} | R^{D137} | L_{C329} | R^{D9} | R^{D151} | L_{C521} | R^{D116} | R^{D54} | L_{C713} | R^{D133} | R^{D5} |
| L_{C138} | R^{D138} | R^{D138} | L_{C330} | R^{D9} | R^{D154} | L_{C522} | R^{D116} | R^{D58} | L_{C714} | R^{D133} | R^{D3} |
| L_{C139} | R^{D139} | R^{D139} | L_{C331} | R^{D9} | R^{D155} | L_{C523} | R^{D116} | R^{D59} | L_{C715} | R^{D133} | R^{D18} |
| L_{C140} | R^{D140} | R^{D140} | L_{C332} | R^{D9} | R^{D161} | L_{C524} | R^{D116} | R^{D78} | L_{C716} | R^{D133} | R^{D20} |
| L_{C141} | R^{D141} | R^{D141} | L_{C333} | R^{D9} | R^{D175} | L_{C525} | R^{D116} | R^{D79} | L_{C717} | R^{D133} | R^{D22} |
| L_{C142} | R^{D142} | R^{D142} | L_{C334} | R^{D10} | R^{D3} | L_{C526} | R^{D116} | R^{D81} | L_{C718} | R^{D133} | R^{D37} |
| L_{C143} | R^{D143} | R^{D143} | L_{C335} | R^{D10} | R^{D5} | L_{C527} | R^{D116} | R^{D87} | L_{C719} | R^{D133} | R^{D40} |
| L_{C144} | R^{D144} | R^{D144} | L_{C336} | R^{D10} | R^{D17} | L_{C528} | R^{D116} | R^{D88} | L_{C720} | R^{D133} | R^{D41} |
| L_{C145} | R^{D145} | R^{D145} | L_{C337} | R^{D10} | R^{D18} | L_{C529} | R^{D116} | R^{D89} | L_{C721} | R^{D133} | R^{D42} |
| L_{C146} | R^{D146} | R^{D146} | L_{C338} | R^{D10} | R^{D20} | L_{C530} | R^{D116} | R^{D93} | L_{C722} | R^{D133} | R^{D43} |
| L_{C147} | R^{D147} | R^{D147} | L_{C339} | R^{D10} | R^{D22} | L_{C531} | R^{D116} | R^{D117} | L_{C723} | R^{D133} | R^{D48} |
| L_{C148} | R^{D148} | R^{D148} | L_{C340} | R^{D10} | R^{D37} | L_{C532} | R^{D116} | R^{D118} | L_{C724} | R^{D133} | R^{D49} |
| L_{C149} | R^{D149} | R^{D149} | L_{C341} | R^{D10} | R^{D40} | L_{C533} | R^{D116} | R^{D119} | L_{C725} | R^{D133} | R^{D54} |
| L_{C150} | R^{D150} | R^{D150} | L_{C342} | R^{D10} | R^{D41} | L_{C534} | R^{D116} | R^{D120} | L_{C726} | R^{D133} | R^{D58} |
| L_{C151} | R^{D151} | R^{D151} | L_{C343} | R^{D10} | R^{D42} | L_{C535} | R^{D116} | R^{D133} | L_{C727} | R^{D133} | R^{D59} |
| L_{C152} | R^{D152} | R^{D152} | L_{C344} | R^{D10} | R^{D43} | L_{C536} | R^{D116} | R^{D134} | L_{C728} | R^{D133} | R^{D78} |
| L_{C153} | R^{D153} | R^{D153} | L_{C345} | R^{D10} | R^{D48} | L_{C537} | R^{D116} | R^{D135} | L_{C729} | R^{D133} | R^{D79} |
| L_{C154} | R^{D154} | R^{D154} | L_{C346} | R^{D10} | R^{D49} | L_{C538} | R^{D116} | R^{D136} | L_{C730} | R^{D133} | R^{D81} |
| L_{C155} | R^{D155} | R^{D155} | L_{C347} | R^{D10} | R^{D50} | L_{C539} | R^{D116} | R^{D143} | L_{C731} | R^{D133} | R^{D87} |
| L_{C156} | R^{D156} | R^{D156} | L_{C348} | R^{D10} | R^{D54} | L_{C540} | R^{D116} | R^{D144} | L_{C732} | R^{D133} | R^{D88} |
| L_{C157} | R^{D157} | R^{D157} | L_{C349} | R^{D10} | R^{D55} | L_{C541} | R^{D116} | R^{D145} | L_{C733} | R^{D133} | R^{D89} |
| L_{C158} | R^{D158} | R^{D158} | L_{C350} | R^{D10} | R^{D58} | L_{C542} | R^{D116} | R^{D146} | L_{C734} | R^{D133} | R^{D93} |
| L_{C159} | R^{D159} | R^{D159} | L_{C351} | R^{D10} | R^{D59} | L_{C543} | R^{D116} | R^{D147} | L_{C735} | R^{D133} | R^{D117} |
| L_{C160} | R^{D160} | R^{D160} | L_{C352} | R^{D10} | R^{D78} | L_{C544} | R^{D116} | R^{D149} | L_{C736} | R^{D133} | R^{D118} |
| L_{C161} | R^{D161} | R^{D161} | L_{C353} | R^{D10} | R^{D79} | L_{C545} | R^{D116} | R^{D151} | L_{C737} | R^{D133} | R^{D119} |
| L_{C162} | R^{D162} | R^{D162} | L_{C354} | R^{D10} | R^{D81} | L_{C546} | R^{D116} | R^{D154} | L_{C738} | R^{D133} | R^{D120} |
| L_{C163} | R^{D163} | R^{D163} | L_{C355} | R^{D10} | R^{D87} | L_{C547} | R^{D116} | R^{D155} | L_{C739} | R^{D133} | R^{D133} |
| L_{C164} | R^{D164} | R^{D164} | L_{C356} | R^{D10} | R^{D88} | L_{C548} | R^{D116} | R^{D161} | L_{C740} | R^{D133} | R^{D134} |
| L_{C165} | R^{D165} | R^{D165} | L_{C357} | R^{D10} | R^{D89} | L_{C549} | R^{D116} | R^{D175} | L_{C741} | R^{D133} | R^{D135} |
| L_{C166} | R^{D166} | R^{D166} | L_{C358} | R^{D10} | R^{D93} | L_{C550} | R^{D143} | R^{D3} | L_{C742} | R^{D133} | R^{D136} |
| L_{C167} | R^{D167} | R^{D167} | L_{C359} | R^{D10} | R^{D116} | L_{C551} | R^{D143} | R^{D5} | L_{C743} | R^{D133} | R^{D146} |
| L_{C168} | R^{D168} | R^{D168} | L_{C360} | R^{D10} | R^{D117} | L_{C552} | R^{D143} | R^{D17} | L_{C744} | R^{D133} | R^{D147} |
| L_{C169} | R^{D169} | R^{D169} | L_{C361} | R^{D10} | R^{D118} | L_{C553} | R^{D143} | R^{D18} | L_{C745} | R^{D133} | R^{D149} |
| L_{C170} | R^{D170} | R^{D170} | L_{C362} | R^{D10} | R^{D119} | L_{C554} | R^{D143} | R^{D20} | L_{C746} | R^{D133} | R^{D151} |
| L_{C171} | R^{D171} | R^{D171} | L_{C363} | R^{D10} | R^{D120} | L_{C555} | R^{D143} | R^{D22} | L_{C747} | R^{D133} | R^{D154} |
| L_{C172} | R^{D172} | R^{D172} | L_{C364} | R^{D10} | R^{D133} | L_{C556} | R^{D143} | R^{D37} | L_{C748} | R^{D133} | R^{D155} |
| L_{C173} | R^{D173} | R^{D173} | L_{C365} | R^{D10} | R^{D134} | L_{C557} | R^{D143} | R^{D40} | L_{C749} | R^{D133} | R^{D161} |
| L_{C174} | R^{D174} | R^{D174} | L_{C366} | R^{D10} | R^{D135} | L_{C558} | R^{D143} | R^{D41} | L_{C750} | R^{D133} | R^{D175} |
| L_{C175} | R^{D175} | R^{D175} | L_{C367} | R^{D10} | R^{D136} | L_{C559} | R^{D143} | R^{D42} | L_{C751} | R^{D175} | R^{D3} |
| L_{C176} | R^{D176} | R^{D176} | L_{C368} | R^{D10} | R^{D143} | L_{C560} | R^{D143} | R^{D43} | L_{C752} | R^{D175} | R^{D5} |
| L_{C177} | R^{D177} | R^{D177} | L_{C369} | R^{D10} | R^{D144} | L_{C561} | R^{D143} | R^{D48} | L_{C753} | R^{D175} | R^{D18} |
| L_{C178} | R^{D178} | R^{D178} | L_{C370} | R^{D10} | R^{D145} | L_{C562} | R^{D143} | R^{D49} | L_{C754} | R^{D175} | R^{D20} |
| L_{C179} | R^{D179} | R^{D179} | L_{C371} | R^{D10} | R^{D146} | L_{C563} | R^{D143} | R^{D54} | L_{C755} | R^{D175} | R^{D22} |
| L_{C180} | R^{D180} | R^{D180} | L_{C372} | R^{D10} | R^{D147} | L_{C564} | R^{D143} | R^{D58} | L_{C756} | R^{D175} | R^{D37} |
| L_{C181} | R^{D181} | R^{D181} | L_{C373} | R^{D10} | R^{D149} | L_{C565} | R^{D143} | R^{D59} | L_{C757} | R^{D175} | R^{D40} |
| L_{C182} | R^{D182} | R^{D182} | L_{C374} | R^{D10} | R^{D151} | L_{C566} | R^{D143} | R^{D78} | L_{C758} | R^{D175} | R^{D41} |
| L_{C183} | R^{D183} | R^{D183} | L_{C375} | R^{D10} | R^{D154} | L_{C567} | R^{D143} | R^{D79} | L_{C759} | R^{D175} | R^{D42} |
| L_{C184} | R^{D184} | R^{D184} | L_{C376} | R^{D10} | R^{D155} | L_{C568} | R^{D143} | R^{D81} | L_{C760} | R^{D175} | R^{D43} |
| L_{C185} | R^{D185} | R^{D185} | L_{C377} | R^{D10} | R^{D161} | L_{C569} | R^{D143} | R^{D87} | L_{C761} | R^{D175} | R^{D48} |
| L_{C186} | R^{D186} | R^{D186} | L_{C378} | R^{D10} | R^{D175} | L_{C570} | R^{D143} | R^{D88} | L_{C762} | R^{D175} | R^{D49} |
| L_{C187} | R^{D187} | R^{D187} | L_{C379} | R^{D17} | R^{D3} | L_{C571} | R^{D143} | R^{D89} | L_{C763} | R^{D175} | R^{D54} |
| L_{C188} | R^{D188} | R^{D188} | L_{C380} | R^{D17} | R^{D5} | L_{C572} | R^{D143} | R^{D93} | L_{C764} | R^{D175} | R^{D58} |
| L_{C189} | R^{D189} | R^{D189} | L_{C381} | R^{D17} | R^{D18} | L_{C573} | R^{D143} | R^{D116} | L_{C765} | R^{D175} | R^{D59} |
| L_{C190} | R^{D190} | R^{D190} | L_{C382} | R^{D17} | R^{D20} | L_{C574} | R^{D143} | R^{D117} | L_{C766} | R^{D175} | R^{D78} |
| L_{C191} | R^{D191} | R^{D191} | L_{C383} | R^{D17} | R^{D22} | L_{C575} | R^{D143} | R^{D118} | L_{C767} | R^{D175} | R^{D79} |
| L_{C192} | R^{D192} | R^{D192} | L_{C384} | R^{D17} | R^{D37} | L_{C576} | R^{D143} | R^{D119} | L_{C768} | R^{D175} | R^{D81} |
| L_{C769} | R^{D193} | R^{D193} | L_{C877} | R^{D1} | R^{D193} | L_{C985} | R^{D4} | R^{D193} | L_{C1093} | R^{D9} | R^{D193} |
| L_{C770} | R^{D194} | R^{D194} | L_{C878} | R^{D1} | R^{D194} | L_{C986} | R^{D4} | R^{D194} | L_{C1094} | R^{D9} | R^{D194} |
| L_{C771} | R^{D195} | R^{D195} | L_{C879} | R^{D1} | R^{D195} | L_{C987} | R^{D4} | R^{D195} | L_{C1095} | R^{D9} | R^{D195} |
| L_{C772} | R^{D196} | R^{D196} | L_{C880} | R^{D1} | R^{D196} | L_{C988} | R^{D4} | R^{D196} | L_{C1096} | R^{D9} | R^{D196} |
| L_{C773} | R^{D197} | R^{D197} | L_{C881} | R^{D1} | R^{D197} | L_{C989} | R^{D4} | R^{D197} | L_{C1097} | R^{D9} | R^{D197} |
| L_{C774} | R^{D198} | R^{D198} | L_{C882} | R^{D1} | R^{D198} | L_{C990} | R^{D4} | R^{D198} | L_{C1098} | R^{D9} | R^{D198} |
| L_{C775} | R^{D199} | R^{D199} | L_{C883} | R^{D1} | R^{D199} | L_{C991} | R^{D4} | R^{D199} | L_{C1099} | R^{D9} | R^{D199} |
| L_{C776} | R^{D200} | R^{D200} | L_{C884} | R^{D1} | R^{D200} | L_{C992} | R^{D4} | R^{D200} | L_{C1100} | R^{D9} | R^{D200} |
| L_{C777} | R^{D201} | R^{D201} | L_{C885} | R^{D1} | R^{D201} | L_{C993} | R^{D4} | R^{D201} | L_{C1101} | R^{D9} | R^{D201} |
| L_{C778} | R^{D202} | R^{D202} | L_{C886} | R^{D1} | R^{D202} | L_{C994} | R^{D4} | R^{D202} | L_{C1102} | R^{D9} | R^{D202} |
| L_{C779} | R^{D203} | R^{D203} | L_{C887} | R^{D1} | R^{D203} | L_{C995} | R^{D4} | R^{D203} | L_{C1103} | R^{D9} | R^{D203} |
| L_{C780} | R^{D204} | R^{D204} | L_{C888} | R^{D1} | R^{D204} | L_{C996} | R^{D4} | R^{D204} | L_{C1104} | R^{D9} | R^{D204} |
| L_{C781} | R^{D205} | R^{D205} | L_{C889} | R^{D1} | R^{D205} | L_{C997} | R^{D4} | R^{D205} | L_{C1105} | R^{D9} | R^{D205} |
| L_{C782} | R^{D206} | R^{D206} | L_{C890} | R^{D1} | R^{D206} | L_{C998} | R^{D4} | R^{D206} | L_{C1106} | R^{D9} | R^{D206} |
| L_{C783} | R^{D207} | R^{D207} | L_{C891} | R^{D1} | R^{D207} | L_{C999} | R^{D4} | R^{D207} | L_{C1107} | R^{D9} | R^{D207} |
| L_{C784} | R^{D208} | R^{D208} | L_{C892} | R^{D1} | R^{D208} | L_{C1000} | R^{D4} | R^{D208} | L_{C1108} | R^{D9} | R^{D208} |
| L_{C785} | R^{D209} | R^{D209} | L_{C893} | R^{D1} | R^{D209} | L_{C1001} | R^{D4} | R^{D209} | L_{C1109} | R^{D9} | R^{D209} |
| L_{C786} | R^{D210} | R^{D210} | L_{C894} | R^{D1} | R^{D210} | L_{C1002} | R^{D4} | R^{D210} | L_{C1110} | R^{D9} | R^{D210} |
| L_{C787} | R^{D211} | R^{D211} | L_{C895} | R^{D1} | R^{D211} | L_{C1003} | R^{D4} | R^{D211} | L_{C1111} | R^{D9} | R^{D211} |
| L_{C788} | R^{D212} | R^{D212} | L_{C896} | R^{D1} | R^{D212} | L_{C1004} | R^{D4} | R^{D212} | L_{C1112} | R^{D9} | R^{D212} |
| L_{C789} | R^{D213} | R^{D213} | L_{C897} | R^{D1} | R^{D213} | L_{C1005} | R^{D4} | R^{D213} | L_{C1113} | R^{D9} | R^{D213} |
| L_{C790} | R^{D214} | R^{D214} | L_{C898} | R^{D1} | R^{D214} | L_{C1006} | R^{D4} | R^{D214} | L_{C1114} | R^{D9} | R^{D214} |
| L_{C791} | R^{D215} | R^{D215} | L_{C899} | R^{D1} | R^{D215} | L_{C1007} | R^{D4} | R^{D215} | L_{C1115} | R^{D9} | R^{D215} |
| L_{C792} | R^{D216} | R^{D216} | L_{C900} | R^{D1} | R^{D216} | L_{C1008} | R^{D4} | R^{D216} | L_{C1116} | R^{D9} | R^{D216} |
| L_{C793} | R^{D217} | R^{D217} | L_{C901} | R^{D1} | R^{D217} | L_{C1009} | R^{D4} | R^{D217} | L_{C1117} | R^{D9} | R^{D217} |
| L_{C794} | R^{D218} | R^{D218} | L_{C902} | R^{D1} | R^{D218} | L_{C1010} | R^{D4} | R^{D218} | L_{C1118} | R^{D9} | R^{D218} |
| L_{C795} | R^{D219} | R^{D219} | L_{C903} | R^{D1} | R^{D219} | L_{C1011} | R^{D4} | R^{D219} | L_{C1119} | R^{D9} | R^{D219} |
| L_{C796} | R^{D220} | R^{D220} | L_{C904} | R^{D1} | R^{D220} | L_{C1012} | R^{D4} | R^{D220} | L_{C1120} | R^{D9} | R^{D220} |
| L_{C797} | R^{D221} | R^{D221} | L_{C905} | R^{D1} | R^{D221} | L_{C1013} | R^{D4} | R^{D221} | L_{C1121} | R^{D9} | R^{D221} |
| L_{C798} | R^{D222} | R^{D222} | L_{C906} | R^{D1} | R^{D222} | L_{C1014} | R^{D4} | R^{D222} | L_{C1122} | R^{D9} | R^{D222} |
| L_{C799} | R^{D223} | R^{D223} | L_{C907} | R^{D1} | R^{D223} | L_{C1015} | R^{D4} | R^{D223} | L_{C1123} | R^{D9} | R^{D223} |
| L_{C800} | R^{D224} | R^{D224} | L_{C908} | R^{D1} | R^{D224} | L_{C1016} | R^{D4} | R^{D224} | L_{C1124} | R^{D9} | R^{D224} |
| L_{C801} | R^{D225} | R^{D225} | L_{C909} | R^{D1} | R^{D225} | L_{C1017} | R^{D4} | R^{D225} | L_{C1125} | R^{D9} | R^{D225} |
| L_{C802} | R^{D226} | R^{D226} | L_{C910} | R^{D1} | R^{D226} | L_{C1018} | R^{D4} | R^{D226} | L_{C1126} | R^{D9} | R^{D226} |
| L_{C803} | R^{D227} | R^{D227} | L_{C911} | R^{D1} | R^{D227} | L_{C1019} | R^{D4} | R^{D227} | L_{C1127} | R^{D9} | R^{D227} |
| L_{C804} | R^{D228} | R^{D228} | L_{C912} | R^{D1} | R^{D228} | L_{C1020} | R^{D4} | R^{D228} | L_{C1128} | R^{D9} | R^{D228} |
| L_{C805} | R^{D229} | R^{D229} | L_{C913} | R^{D1} | R^{D229} | L_{C1021} | R^{D4} | R^{D229} | L_{C1129} | R^{D9} | R^{D229} |
| L_{C806} | R^{D230} | R^{D230} | L_{C914} | R^{D1} | R^{D230} | L_{C1022} | R^{D4} | R^{D230} | L_{C1130} | R^{D9} | R^{D230} |
| L_{C807} | R^{D231} | R^{D231} | L_{C915} | R^{D1} | R^{D231} | L_{C1023} | R^{D4} | R^{D231} | L_{C1131} | R^{D9} | R^{D231} |
| L_{C808} | R^{D232} | R^{D232} | L_{C916} | R^{D1} | R^{D232} | L_{C1024} | R^{D4} | R^{D232} | L_{C1132} | R^{D9} | R^{D232} |
| L_{C809} | R^{D233} | R^{D233} | L_{C917} | R^{D1} | R^{D233} | L_{C1025} | R^{D4} | R^{D233} | L_{C1133} | R^{D9} | R^{D233} |
| L_{C810} | R^{D234} | R^{D234} | L_{C918} | R^{D1} | R^{D234} | L_{C1026} | R^{D4} | R^{D234} | L_{C1134} | R^{D9} | R^{D234} |
| L_{C811} | R^{D235} | R^{D235} | L_{C919} | R^{D1} | R^{D235} | L_{C1027} | R^{D4} | R^{D235} | L_{C1135} | R^{D9} | R^{D235} |
| L_{C812} | R^{D236} | R^{D236} | L_{C920} | R^{D1} | R^{D236} | L_{C1028} | R^{D4} | R^{D236} | L_{C1136} | R^{D9} | R^{D236} |
| L_{C813} | R^{D237} | R^{D237} | L_{C921} | R^{D1} | R^{D237} | L_{C1029} | R^{D4} | R^{D237} | L_{C1137} | R^{D9} | R^{D237} |
| L_{C814} | R^{D238} | R^{D238} | L_{C922} | R^{D1} | R^{D238} | L_{C1030} | R^{D4} | R^{D238} | L_{C1138} | R^{D9} | R^{D238} |
| L_{C815} | R^{D239} | R^{D239} | L_{C923} | R^{D1} | R^{D239} | L_{C1031} | R^{D4} | R^{D239} | L_{C1139} | R^{D9} | R^{D239} |
| L_{C816} | R^{D240} | R^{D240} | L_{C924} | R^{D1} | R^{D240} | L_{C1032} | R^{D4} | R^{D240} | L_{C1140} | R^{D9} | R^{D240} |
| L_{C817} | R^{D241} | R^{D241} | L_{C925} | R^{D1} | R^{D241} | L_{C1033} | R^{D4} | R^{D241} | L_{C1141} | R^{D9} | R^{D241} |
| L_{C818} | R^{D242} | R^{D242} | L_{C926} | R^{D1} | R^{D242} | L_{C1034} | R^{D4} | R^{D242} | L_{C1142} | R^{D9} | R^{D242} |
| L_{C819} | R^{D243} | R^{D243} | L_{C927} | R^{D1} | R^{D243} | L_{C1035} | R^{D4} | R^{D243} | L_{C1143} | R^{D9} | R^{D243} |
| L_{C820} | R^{D244} | R^{D244} | L_{C928} | R^{D1} | R^{D244} | L_{C1036} | R^{D4} | R^{D244} | L_{C1144} | R^{D9} | R^{D244} |
| L_{C821} | R^{D245} | R^{D245} | L_{C929} | R^{D1} | R^{D245} | L_{C1037} | R^{D4} | R^{D245} | L_{C1145} | R^{D9} | R^{D245} |
| L_{C822} | R^{D246} | R^{D246} | L_{C930} | R^{D1} | R^{D246} | L_{C1038} | R^{D4} | R^{D246} | L_{C1146} | R^{D9} | R^{D246} |
| L_{C823} | R^{D17} | R^{D193} | L_{C931} | R^{D50} | R^{D193} | L_{C1039} | R^{D145} | R^{D193} | L_{C1147} | R^{D168} | R^{D193} |
| L_{C824} | R^{D17} | R^{D194} | L_{C932} | R^{D50} | R^{D194} | L_{C1040} | R^{D145} | R^{D194} | L_{C1148} | R^{D168} | R^{D194} |
| L_{C825} | R^{D17} | R^{D195} | L_{C933} | R^{D50} | R^{D195} | L_{C1041} | R^{D145} | R^{D195} | L_{C1149} | R^{D168} | R^{D195} |
| L_{C826} | R^{D17} | R^{D196} | L_{C934} | R^{D50} | R^{D196} | L_{C1042} | R^{D145} | R^{D196} | L_{C1150} | R^{D168} | R^{D196} |
| L_{C827} | R^{D17} | R^{D197} | L_{C935} | R^{D50} | R^{D197} | L_{C1043} | R^{D145} | R^{D197} | L_{C1151} | R^{D168} | R^{D197} |
| L_{C828} | R^{D17} | R^{D198} | L_{C936} | R^{D50} | R^{D198} | L_{C1044} | R^{D145} | R^{D198} | L_{C1152} | R^{D168} | R^{D198} |
| L_{C829} | R^{D17} | R^{D199} | L_{C937} | R^{D50} | R^{D199} | L_{C1045} | R^{D145} | R^{D199} | L_{C1153} | R^{D168} | R^{D199} |
| L_{C830} | R^{D17} | R^{D200} | L_{C938} | R^{D50} | R^{D200} | L_{C1046} | R^{D145} | R^{D200} | L_{C1154} | R^{D168} | R^{D200} |
| L_{C831} | R^{D17} | R^{D201} | L_{C939} | R^{D50} | R^{D201} | L_{C1047} | R^{D145} | R^{D201} | L_{C1155} | R^{D168} | R^{D201} |
| L_{C832} | R^{D17} | R^{D202} | L_{C940} | R^{D50} | R^{D202} | L_{C1048} | R^{D145} | R^{D202} | L_{C1156} | R^{D168} | R^{D202} |
| L_{C833} | R^{D17} | R^{D203} | L_{C941} | R^{D50} | R^{D203} | L_{C1049} | R^{D145} | R^{D203} | L_{C1157} | R^{D168} | R^{D203} |
| L_{C834} | R^{D17} | R^{D204} | L_{C942} | R^{D50} | R^{D204} | L_{C1050} | R^{D145} | R^{D204} | L_{C1158} | R^{D168} | R^{D204} |
| L_{C835} | R^{D17} | R^{D205} | L_{C943} | R^{D50} | R^{D205} | L_{C1051} | R^{D145} | R^{D205} | L_{C1159} | R^{D168} | R^{D205} |
| L_{C836} | R^{D17} | R^{D206} | L_{C944} | R^{D50} | R^{D206} | L_{C1052} | R^{D145} | R^{D206} | L_{C1160} | R^{D168} | R^{D206} |
| L_{C837} | R^{D17} | R^{D207} | L_{C945} | R^{D50} | R^{D207} | L_{C1053} | R^{D145} | R^{D207} | L_{C1161} | R^{D168} | R^{D207} |
| L_{C838} | R^{D17} | R^{D208} | L_{C946} | R^{D50} | R^{D208} | L_{C1054} | R^{D145} | R^{D208} | L_{C1162} | R^{D168} | R^{D208} |
| L_{C839} | R^{D17} | R^{D209} | L_{C947} | R^{D50} | R^{D209} | L_{C1055} | R^{D145} | R^{D209} | L_{C1163} | R^{D168} | R^{D209} |
| L_{C840} | R^{D17} | R^{D210} | L_{C948} | R^{D50} | R^{D210} | L_{C1056} | R^{D145} | R^{D210} | L_{C1164} | R^{D168} | R^{D210} |
| L_{C841} | R^{D17} | R^{D211} | L_{C949} | R^{D50} | R^{D211} | L_{C1057} | R^{D145} | R^{D211} | L_{C1165} | R^{D168} | R^{D211} |
| L_{C842} | R^{D17} | R^{D212} | L_{C950} | R^{D50} | R^{D212} | L_{C1058} | R^{D145} | R^{D212} | L_{C1166} | R^{D168} | R^{D212} |
| L_{C843} | R^{D17} | R^{D213} | L_{C951} | R^{D50} | R^{D213} | L_{C1059} | R^{D145} | R^{D213} | L_{C1167} | R^{D168} | R^{D213} |
| L_{C844} | R^{D17} | R^{D214} | L_{C952} | R^{D50} | R^{D214} | L_{C1060} | R^{D145} | R^{D214} | L_{C1168} | R^{D168} | R^{D214} |
| L_{C845} | R^{D17} | R^{D215} | L_{C953} | R^{D50} | R^{D215} | L_{C1061} | R^{D145} | R^{D215} | L_{C1169} | R^{D168} | R^{D215} |
| L_{C846} | R^{D17} | R^{D216} | L_{C954} | R^{D50} | R^{D216} | L_{C1062} | R^{D145} | R^{D216} | L_{C1170} | R^{D168} | R^{D216} |
| L_{C847} | R^{D17} | R^{D217} | L_{C955} | R^{D50} | R^{D217} | L_{C1063} | R^{D145} | R^{D217} | L_{C1171} | R^{D168} | R^{D217} |
| L_{C848} | R^{D17} | R^{D218} | L_{C956} | R^{D50} | R^{D218} | L_{C1064} | R^{D145} | R^{D218} | L_{C1172} | R^{D168} | R^{D218} |
| L_{C849} | R^{D17} | R^{D219} | L_{C957} | R^{D50} | R^{D219} | L_{C1065} | R^{D145} | R^{D219} | L_{C1173} | R^{D168} | R^{D219} |
| L_{C850} | R^{D17} | R^{D220} | L_{C958} | R^{D50} | R^{D220} | L_{C1066} | R^{D145} | R^{D220} | L_{C1174} | R^{D168} | R^{D220} |
| L_{C851} | R^{D17} | R^{D221} | L_{C959} | R^{D50} | R^{D221} | L_{C1067} | R^{D145} | R^{D221} | L_{C1175} | R^{D168} | R^{D221} |
| L_{C852} | R^{D17} | R^{D222} | L_{C960} | R^{D50} | R^{D222} | L_{C1068} | R^{D145} | R^{D222} | L_{C1176} | R^{D168} | R^{D222} |
| L_{C853} | R^{D17} | R^{D223} | L_{C961} | R^{D50} | R^{D223} | L_{C1069} | R^{D145} | R^{D223} | L_{C1177} | R^{D168} | R^{D223} |
| L_{C854} | R^{D17} | R^{D224} | L_{C962} | R^{D50} | R^{D224} | L_{C1070} | R^{D145} | R^{D224} | L_{C1178} | R^{D168} | R^{D224} |
| L_{C855} | R^{D17} | R^{D225} | L_{C963} | R^{D50} | R^{D225} | L_{C1071} | R^{D145} | R^{D225} | L_{C1179} | R^{D168} | R^{D225} |
| L_{C856} | R^{D17} | R^{D226} | L_{C964} | R^{D50} | R^{D226} | L_{C1072} | R^{D145} | R^{D226} | L_{C1180} | R^{D168} | R^{D226} |
| L_{C857} | R^{D17} | R^{D227} | L_{C965} | R^{D50} | R^{D227} | L_{C1073} | R^{D145} | R^{D227} | L_{C1181} | R^{D168} | R^{D227} |
| L_{C858} | R^{D17} | R^{D228} | L_{C966} | R^{D50} | R^{D228} | L_{C1074} | R^{D145} | R^{D228} | L_{C1182} | R^{D168} | R^{D228} |
| L_{C859} | R^{D17} | R^{D229} | L_{C967} | R^{D50} | R^{D229} | L_{C1075} | R^{D145} | R^{D229} | L_{C1183} | R^{D168} | R^{D229} |
| L_{C860} | R^{D17} | R^{D230} | L_{C968} | R^{D50} | R^{D230} | L_{C1076} | R^{D145} | R^{D230} | L_{C1184} | R^{D168} | R^{D230} |
| L_{C861} | R^{D17} | R^{D231} | L_{C969} | R^{D50} | R^{D231} | L_{C1077} | R^{D145} | R^{D231} | L_{C1185} | R^{D168} | R^{D231} |
| L_{C862} | R^{D17} | R^{D232} | L_{C970} | R^{D50} | R^{D232} | L_{C1078} | R^{D145} | R^{D232} | L_{C1186} | R^{D168} | R^{D232} |
| L_{C863} | R^{D17} | R^{D233} | L_{C971} | R^{D50} | R^{D233} | L_{C1079} | R^{D145} | R^{D233} | L_{C1187} | R^{D168} | R^{D233} |
| L_{C864} | R^{D17} | R^{D234} | L_{C972} | R^{D50} | R^{D234} | L_{C1080} | R^{D145} | R^{D234} | L_{C1188} | R^{D168} | R^{D234} |
| L_{C865} | R^{D17} | R^{D235} | L_{C973} | R^{D50} | R^{D235} | L_{C1081} | R^{D145} | R^{D235} | L_{C1189} | R^{D168} | R^{D235} |
| L_{C866} | R^{D17} | R^{D236} | L_{C974} | R^{D50} | R^{D236} | L_{C1082} | R^{D145} | R^{D236} | L_{C1190} | R^{D168} | R^{D236} |
| L_{C867} | R^{D17} | R^{D237} | L_{C975} | R^{D50} | R^{D237} | L_{C1083} | R^{D145} | R^{D237} | L_{C1191} | R^{D168} | R^{D237} |
| L_{C868} | R^{D17} | R^{D238} | L_{C976} | R^{D50} | R^{D238} | L_{C1084} | R^{D145} | R^{D238} | L_{C1192} | R^{D168} | R^{D238} |
| L_{C869} | R^{D17} | R^{D239} | L_{C977} | R^{D50} | R^{D239} | L_{C1085} | R^{D145} | R^{D239} | L_{C1193} | R^{D168} | R^{D239} |
| L_{C870} | R^{D17} | R^{D240} | L_{C978} | R^{D50} | R^{D240} | L_{C1086} | R^{D145} | R^{D240} | L_{C1194} | R^{D168} | R^{D240} |
| L_{C871} | R^{D17} | R^{D241} | L_{C979} | R^{D50} | R^{D241} | L_{C1087} | R^{D145} | R^{D241} | L_{C1195} | R^{D168} | R^{D241} |
| L_{C872} | R^{D17} | R^{D242} | L_{C980} | R^{D50} | R^{D242} | L_{C1088} | R^{D145} | R^{D242} | L_{C1196} | R^{D168} | R^{D242} |
| L_{C873} | R^{D17} | R^{D243} | L_{C981} | R^{D50} | R^{D243} | L_{C1089} | R^{D145} | R^{D243} | L_{C1197} | R^{D168} | R^{D243} |
| L_{C874} | R^{D17} | R^{D244} | L_{C982} | R^{D50} | R^{D244} | L_{C1090} | R^{D145} | R^{D244} | L_{C1198} | R^{D168} | R^{D244} |
| L_{C875} | R^{D17} | R^{D245} | L_{C983} | R^{D50} | R^{D245} | L_{C1091} | R^{D145} | R^{D245} | L_{C1199} | R^{D168} | R^{D245} |
| L_{C876} | R^{D17} | R^{D246} | L_{C984} | R^{D50} | R^{D246} | L_{C1092} | R^{D145} | R^{D246} | L_{C1200} | R^{D168} | R^{D246} |
| L_{C1201} | R^{D10} | R^{D193} | L_{C1255} | R^{D55} | R^{D193} | L_{C1309} | R^{D37} | R^{D193} | L_{C1363} | R^{D143} | R^{D193} |
| L_{C1202} | R^{D10} | R^{D194} | L_{C1256} | R^{D55} | R^{D194} | L_{C1310} | R^{D37} | R^{D194} | L_{C1364} | R^{D143} | R^{D194} |
| L_{C1203} | R^{D10} | R^{D195} | L_{C1257} | R^{D55} | R^{D195} | L_{C1311} | R^{D37} | R^{D195} | L_{C1365} | R^{D143} | R^{D195} |
| L_{C1204} | R^{D10} | R^{D196} | L_{C1258} | R^{D55} | R^{D196} | L_{C1312} | R^{D37} | R^{D196} | L_{C1366} | R^{D143} | R^{D196} |
| L_{C1205} | R^{D10} | R^{D197} | L_{C1259} | R^{D55} | R^{D197} | L_{C1313} | R^{D37} | R^{D197} | L_{C1367} | R^{D143} | R^{D197} |
| L_{C1206} | R^{D10} | R^{D198} | L_{C1260} | R^{D55} | R^{D198} | L_{C1314} | R^{D37} | R^{D198} | L_{C1368} | R^{D143} | R^{D198} |
| L_{C1207} | R^{D10} | R^{D199} | L_{C1261} | R^{D55} | R^{D199} | L_{C1315} | R^{D37} | R^{D199} | L_{C1369} | R^{D143} | R^{D199} |
| L_{C1208} | R^{D10} | R^{D200} | L_{C1262} | R^{D55} | R^{D200} | L_{C1316} | R^{D37} | R^{D200} | L_{C1370} | R^{D143} | R^{D200} |
| L_{C1209} | R^{D10} | R^{D201} | L_{C1263} | R^{D55} | R^{D201} | L_{C1317} | R^{D37} | R^{D201} | L_{C1371} | R^{D143} | R^{D201} |
| L_{C1210} | R^{D10} | R^{D202} | L_{C1264} | R^{D55} | R^{D202} | L_{C1318} | R^{D37} | R^{D202} | L_{C1372} | R^{D143} | R^{D202} |
| L_{C1211} | R^{D10} | R^{D203} | L_{C1265} | R^{D55} | R^{D203} | L_{C1319} | R^{D37} | R^{D203} | L_{C1373} | R^{D143} | R^{D203} |
| L_{C1212} | R^{D10} | R^{D204} | L_{C1266} | R^{D55} | R^{D204} | L_{C1320} | R^{D37} | R^{D204} | L_{C1374} | R^{D143} | R^{D204} |
| L_{C1213} | R^{D10} | R^{D205} | L_{C1267} | R^{D55} | R^{D205} | L_{C1321} | R^{D37} | R^{D205} | L_{C1375} | R^{D143} | R^{D205} |
| L_{C1214} | R^{D10} | R^{D206} | L_{C1268} | R^{D55} | R^{D206} | L_{C1322} | R^{D37} | R^{D206} | L_{C1376} | R^{D143} | R^{D206} |
| L_{C1215} | R^{D10} | R^{D207} | L_{C1269} | R^{D55} | R^{D207} | L_{C1323} | R^{D37} | R^{D207} | L_{C1377} | R^{D143} | R^{D207} |
| L_{C1216} | R^{D10} | R^{D208} | L_{C1270} | R^{D55} | R^{D208} | L_{C1324} | R^{D37} | R^{D208} | L_{C1378} | R^{D143} | R^{D208} |
| L_{C1217} | R^{D10} | R^{D209} | L_{C1271} | R^{D55} | R^{D209} | L_{C1325} | R^{D37} | R^{D209} | L_{C1379} | R^{D143} | R^{D209} |
| L_{C1218} | R^{D10} | R^{D210} | L_{C1272} | R^{D55} | R^{D210} | L_{C1326} | R^{D37} | R^{D210} | L_{C1380} | R^{D143} | R^{D210} |
| L_{C1219} | R^{D10} | R^{D211} | L_{C1273} | R^{D55} | R^{D211} | L_{C1327} | R^{D37} | R^{D211} | L_{C1381} | R^{D143} | R^{D211} |
| L_{C1220} | R^{D10} | R^{D212} | L_{C1274} | R^{D55} | R^{D212} | L_{C1328} | R^{D37} | R^{D212} | L_{C1382} | R^{D143} | R^{D212} |
| L_{C1221} | R^{D10} | R^{D213} | L_{C1275} | R^{D55} | R^{D213} | L_{C1329} | R^{D37} | R^{D213} | L_{C1383} | R^{D143} | R^{D213} |
| L_{C1222} | R^{D10} | R^{D214} | L_{C1276} | R^{D55} | R^{D214} | L_{C1330} | R^{D37} | R^{D214} | L_{C1384} | R^{D143} | R^{D214} |
| L_{C1223} | R^{D10} | R^{D215} | L_{C1277} | R^{D55} | R^{D215} | L_{C1331} | R^{D37} | R^{D215} | L_{C1385} | R^{D143} | R^{D215} |
| L_{C1224} | R^{D10} | R^{D216} | L_{C1278} | R^{D55} | R^{D216} | L_{C1332} | R^{D37} | R^{D216} | L_{C1386} | R^{D143} | R^{D216} |
| L_{C1225} | R^{D10} | R^{D217} | L_{C1279} | R^{D55} | R^{D217} | L_{C1333} | R^{D37} | R^{D217} | L_{C1387} | R^{D143} | R^{D217} |
| L_{C1226} | R^{D10} | R^{D218} | L_{C1280} | R^{D55} | R^{D218} | L_{C1334} | R^{D37} | R^{D218} | L_{C1388} | R^{D143} | R^{D218} |
| L_{C1227} | R^{D10} | R^{D219} | L_{C1281} | R^{D55} | R^{D219} | L_{C1335} | R^{D37} | R^{D219} | L_{C1389} | R^{D143} | R^{D219} |
| L_{C1228} | R^{D10} | R^{D220} | L_{C1282} | R^{D55} | R^{D220} | L_{C1336} | R^{D37} | R^{D220} | L_{C1390} | R^{D143} | R^{D220} |
| L_{C1229} | R^{D10} | R^{D221} | L_{C1283} | R^{D55} | R^{D221} | L_{C1337} | R^{D37} | R^{D221} | L_{C1391} | R^{D143} | R^{D221} |
| L_{C1230} | R^{D10} | R^{D222} | L_{C1284} | R^{D55} | R^{D222} | L_{C1338} | R^{D37} | R^{D222} | L_{C1392} | R^{D143} | R^{D222} |
| L_{C1231} | R^{D10} | R^{D223} | L_{C1285} | R^{D55} | R^{D223} | L_{C1339} | R^{D37} | R^{D223} | L_{C1393} | R^{D143} | R^{D223} |
| L_{C1232} | R^{D10} | R^{D224} | L_{C1286} | R^{D55} | R^{D224} | L_{C1340} | R^{D37} | R^{D224} | L_{C1394} | R^{D143} | R^{D224} |
| L_{C1233} | R^{D10} | R^{D225} | L_{C1287} | R^{D55} | R^{D225} | L_{C1341} | R^{D37} | R^{D225} | L_{C1395} | R^{D143} | R^{D225} |
| L_{C1234} | R^{D10} | R^{D226} | L_{C1288} | R^{D55} | R^{D226} | L_{C1342} | R^{D37} | R^{D226} | L_{C1396} | R^{D143} | R^{D226} |
| L_{C1235} | R^{D10} | R^{D227} | L_{C1289} | R^{D55} | R^{D227} | L_{C1343} | R^{D37} | R^{D227} | L_{C1397} | R^{D143} | R^{D227} |
| L_{C1236} | R^{D10} | R^{D228} | L_{C1290} | R^{D55} | R^{D228} | L_{C1344} | R^{D37} | R^{D228} | L_{C1398} | R^{D143} | R^{D228} |
| L_{C1237} | R^{D10} | R^{D229} | L_{C1291} | R^{D55} | R^{D229} | L_{C1345} | R^{D37} | R^{D229} | L_{C1399} | R^{D143} | R^{D229} |
| L_{C1238} | R^{D10} | R^{D230} | L_{C1292} | R^{D55} | R^{D230} | L_{C1346} | R^{D37} | R^{D230} | L_{C1400} | R^{D143} | R^{D230} |
| L_{C1239} | R^{D10} | R^{D231} | L_{C1293} | R^{D55} | R^{D231} | L_{C1347} | R^{D37} | R^{D231} | L_{C1401} | R^{D143} | R^{D231} |
| L_{C1240} | R^{D10} | R^{D232} | L_{C1294} | R^{D55} | R^{D232} | L_{C1348} | R^{D37} | R^{D232} | L_{C1402} | R^{D143} | R^{D232} |
| L_{C1241} | R^{D10} | R^{D233} | L_{C1295} | R^{D55} | R^{D233} | L_{C1349} | R^{D37} | R^{D233} | L_{C1403} | R^{D143} | R^{D233} |
| L_{C1242} | R^{D10} | R^{D234} | L_{C1296} | R^{D55} | R^{D234} | L_{C1350} | R^{D37} | R^{D234} | L_{C1404} | R^{D143} | R^{D234} |
| L_{C1243} | R^{D10} | R^{D235} | L_{C1297} | R^{D55} | R^{D235} | L_{C1351} | R^{D37} | R^{D235} | L_{C1405} | R^{D143} | R^{D235} |
| L_{C1244} | R^{D10} | R^{D236} | L_{C1298} | R^{D55} | R^{D236} | L_{C1352} | R^{D37} | R^{D236} | L_{C1406} | R^{D143} | R^{D236} |
| L_{C1245} | R^{D10} | R^{D237} | L_{C1299} | R^{D55} | R^{D237} | L_{C1353} | R^{D37} | R^{D237} | L_{C1407} | R^{D143} | R^{D237} |
| L_{C1246} | R^{D10} | R^{D238} | L_{C1300} | R^{D55} | R^{D238} | L_{C1354} | R^{D37} | R^{D238} | L_{C1408} | R^{D143} | R^{D238} |
| L_{C1247} | R^{D10} | R^{D239} | L_{C1301} | R^{D55} | R^{D239} | L_{C1355} | R^{D37} | R^{D239} | L_{C1409} | R^{D143} | R^{D239} |
| L_{C1248} | R^{D10} | R^{D240} | L_{C1302} | R^{D55} | R^{D240} | L_{C1356} | R^{D37} | R^{D240} | L_{C1410} | R^{D143} | R^{D240} |
| L_{C1249} | R^{D10} | R^{D241} | L_{C1303} | R^{D55} | R^{D241} | L_{C1357} | R^{D37} | R^{D241} | L_{C1411} | R^{D143} | R^{D241} |
| L_{C1250} | R^{D10} | R^{D242} | L_{C1304} | R^{D55} | R^{D242} | L_{C1358} | R^{D37} | R^{D242} | L_{C1412} | R^{D143} | R^{D242} |
| L_{C1251} | R^{D10} | R^{D243} | L_{C1305} | R^{D55} | R^{D243} | L_{C1359} | R^{D37} | R^{D243} | L_{C1413} | R^{D143} | R^{D243} |
| L_{C1252} | R^{D10} | R^{D244} | L_{C1306} | R^{D55} | R^{D244} | L_{C1360} | R^{D37} | R^{D244} | L_{C1414} | R^{D143} | R^{D244} |
| L_{C1253} | R^{D10} | R^{D245} | L_{C1307} | R^{D55} | R^{D245} | L_{C1361} | R^{D37} | R^{D245} | L_{C1415} | R^{D143} | R^{D245} |
| L_{C1254} | R^{D10} | R^{D246} | L_{C1308} | R^{D55} | R^{D246} | L_{C1362} | R^{D37} | R^{D246} | L_{C1416} | R^{D143} | R^{D246} |

wherein R^{D1} to R^{D246} have the structures of the following LIST 10:

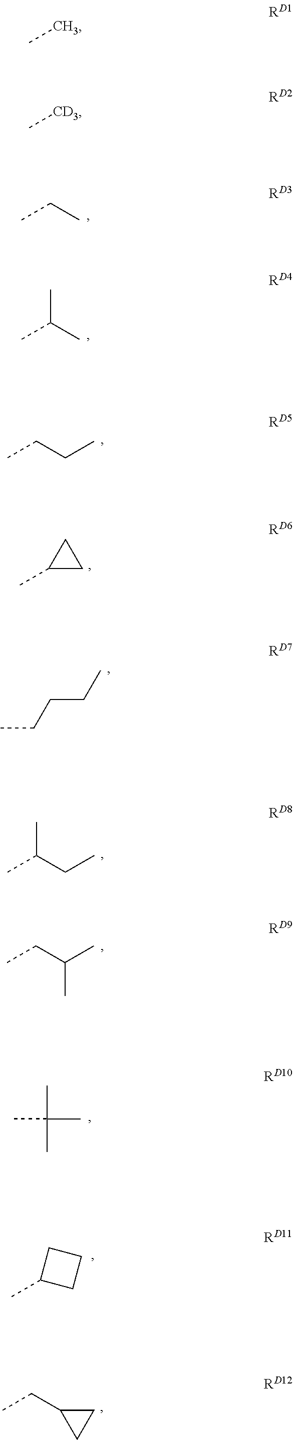

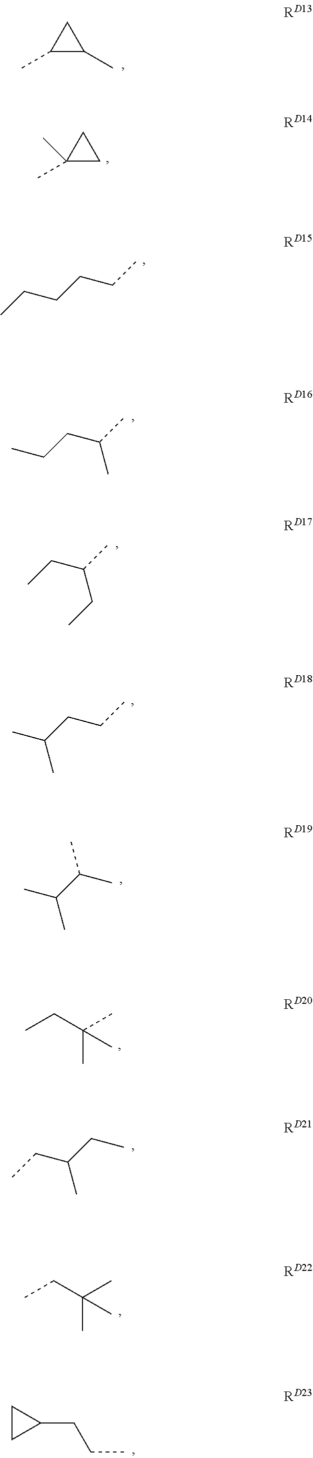

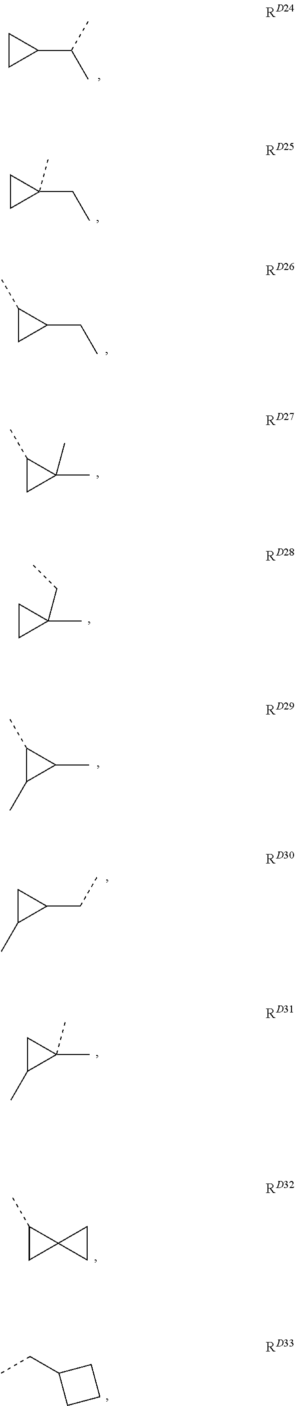

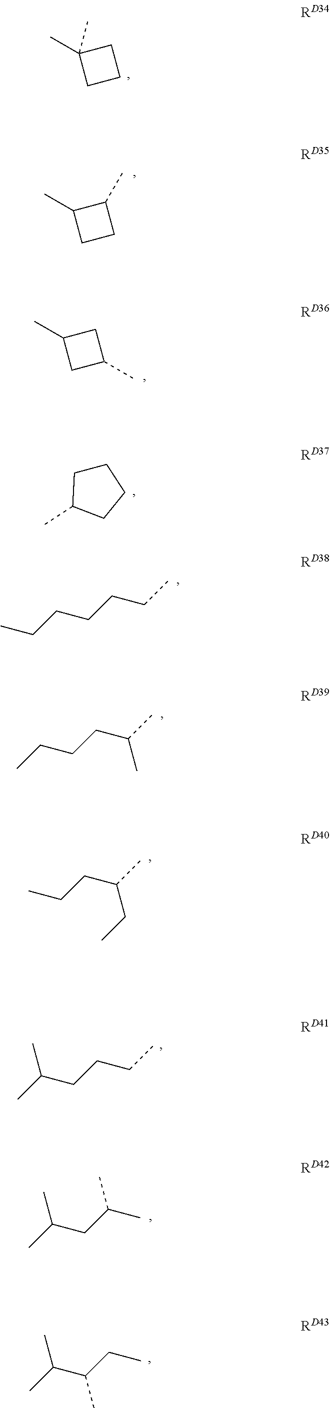

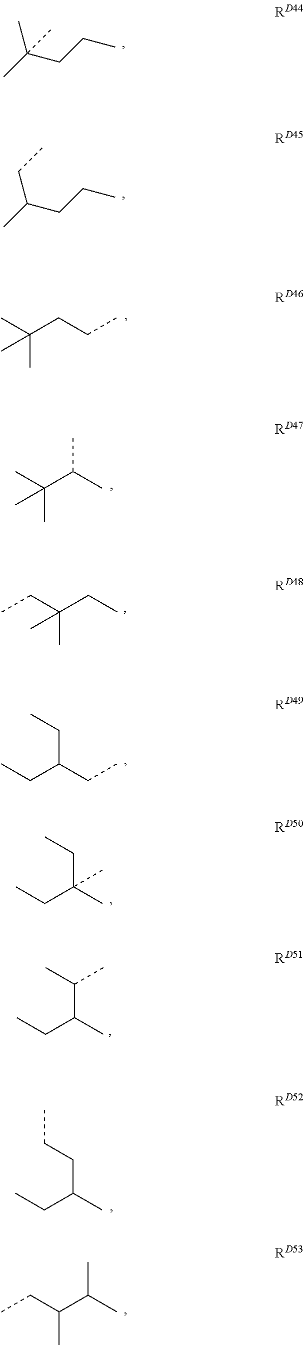

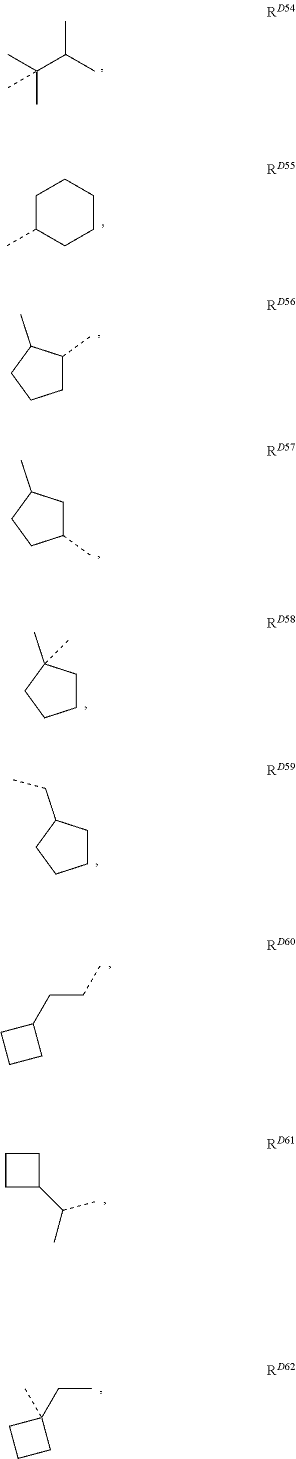

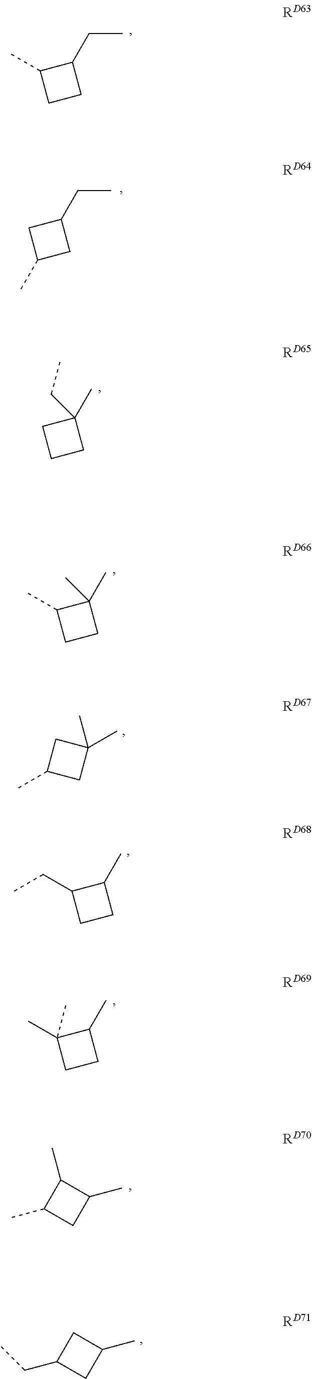

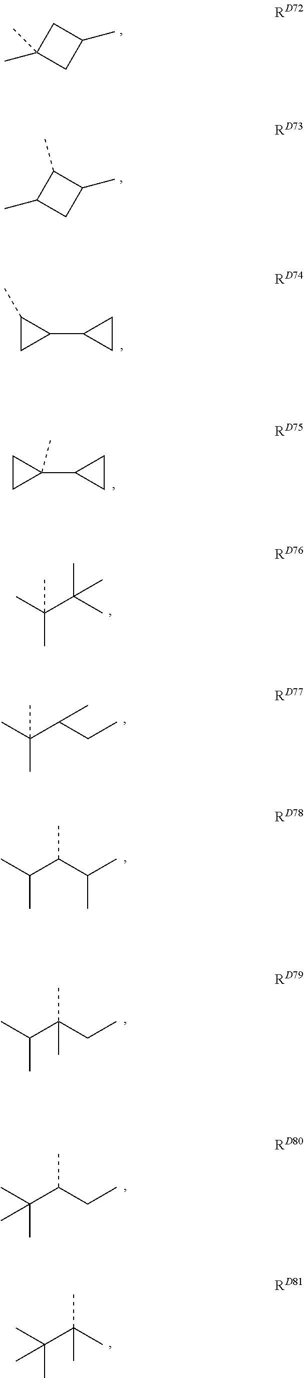

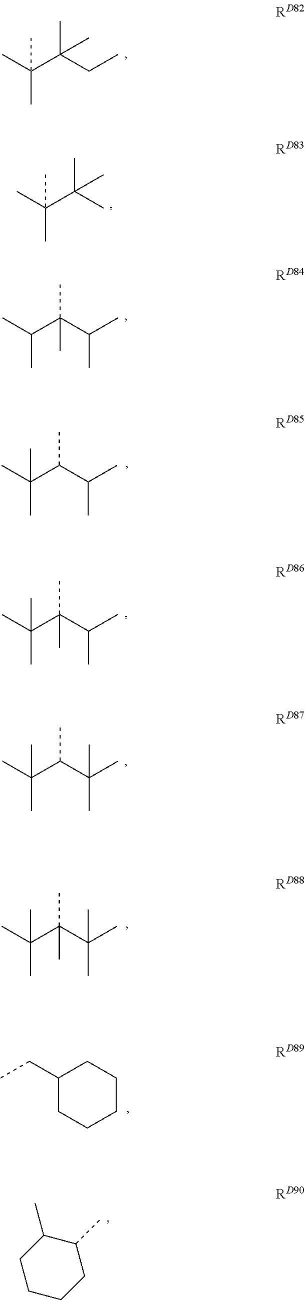

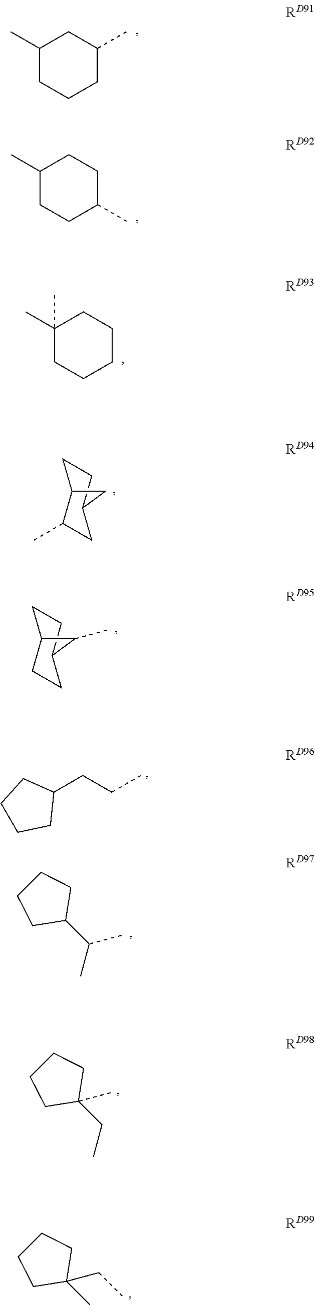

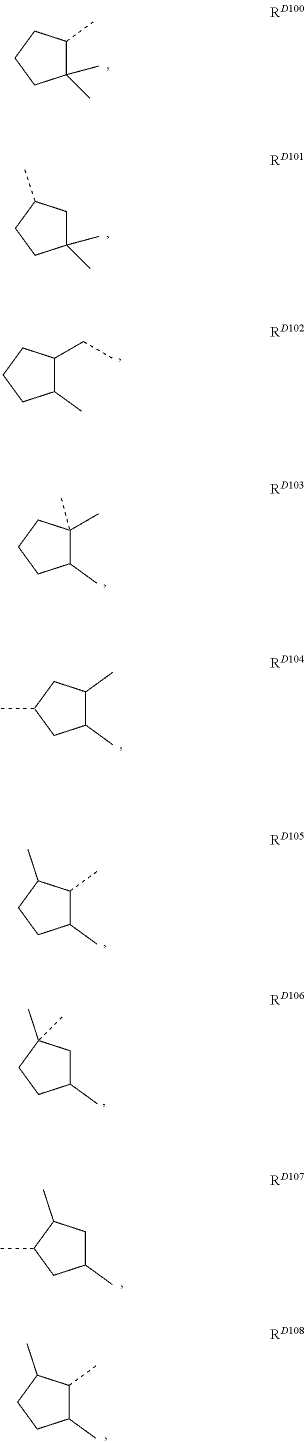

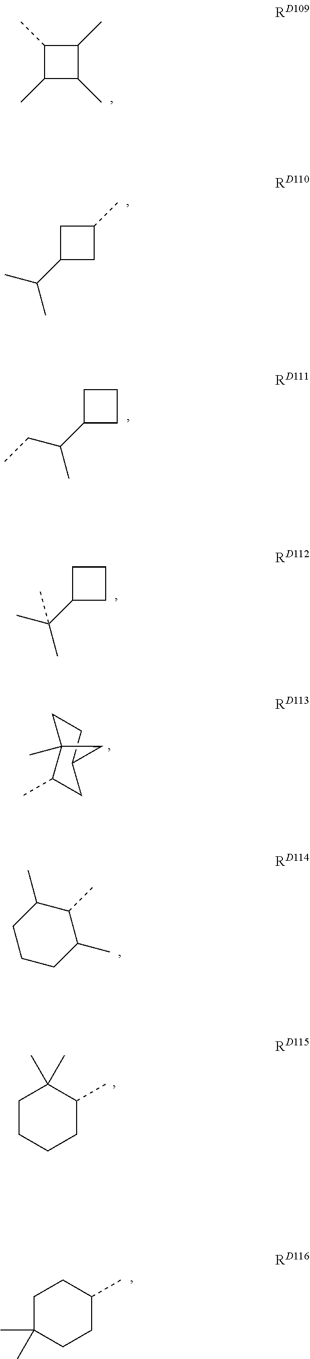

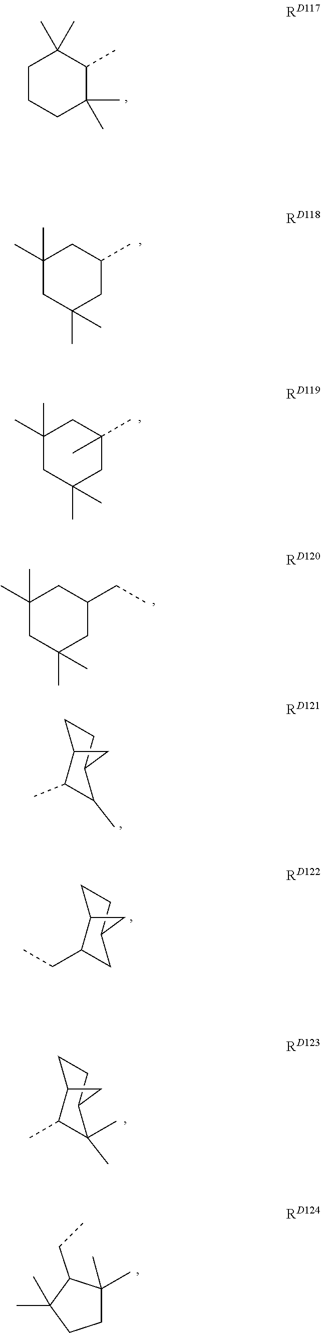

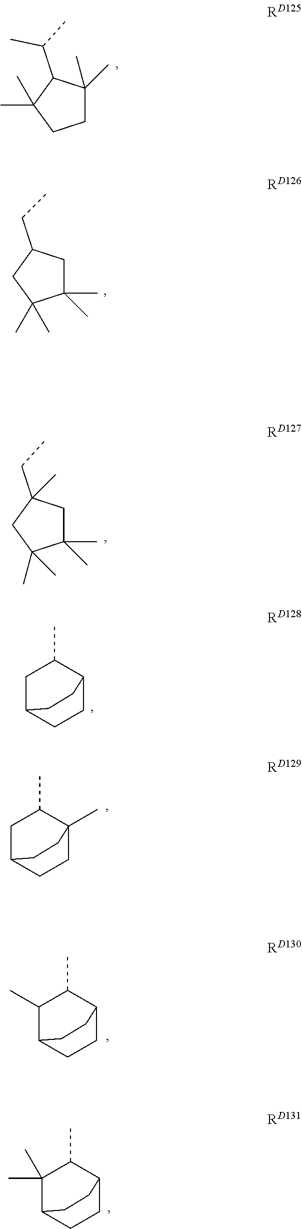

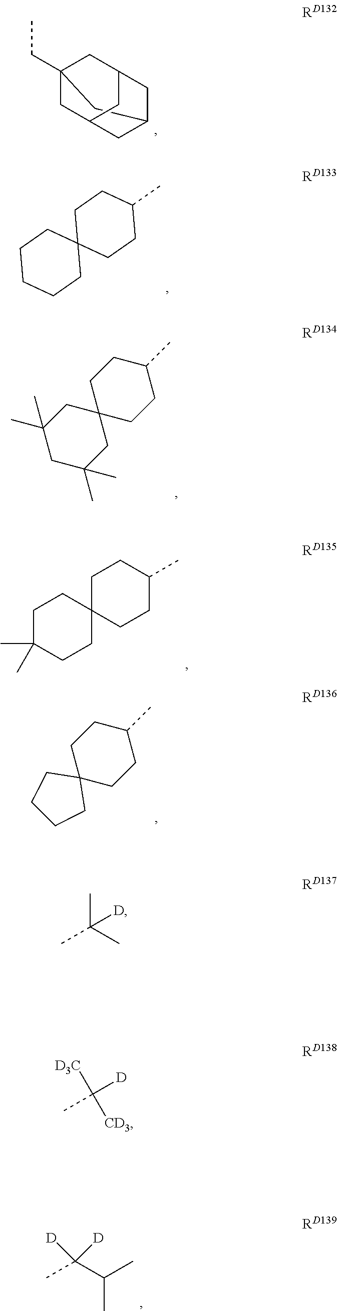

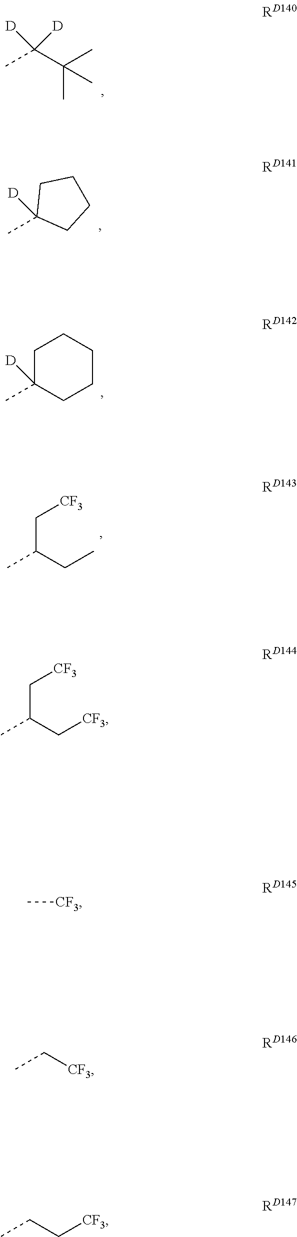

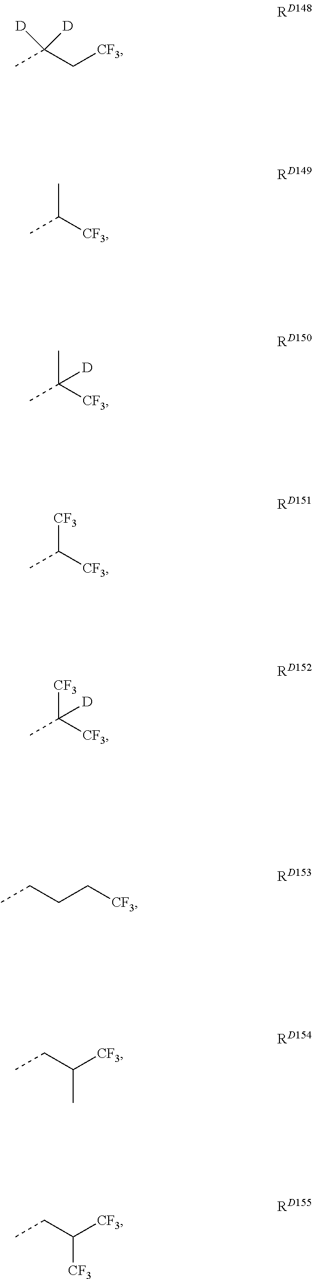

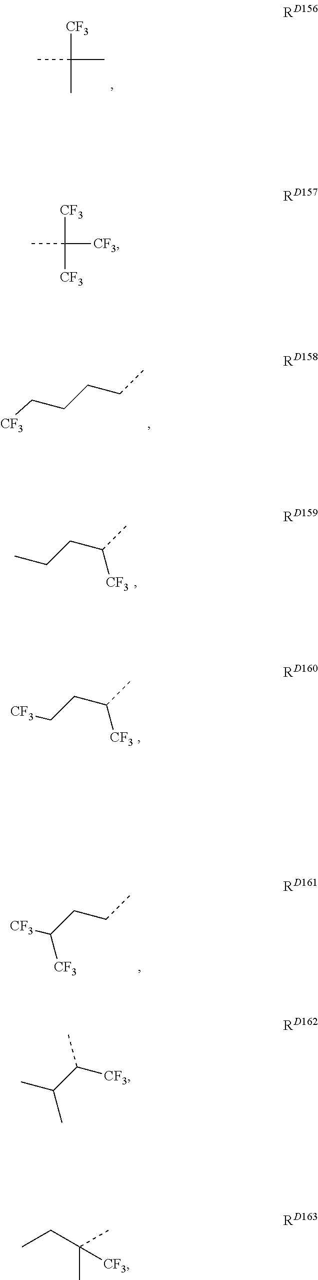

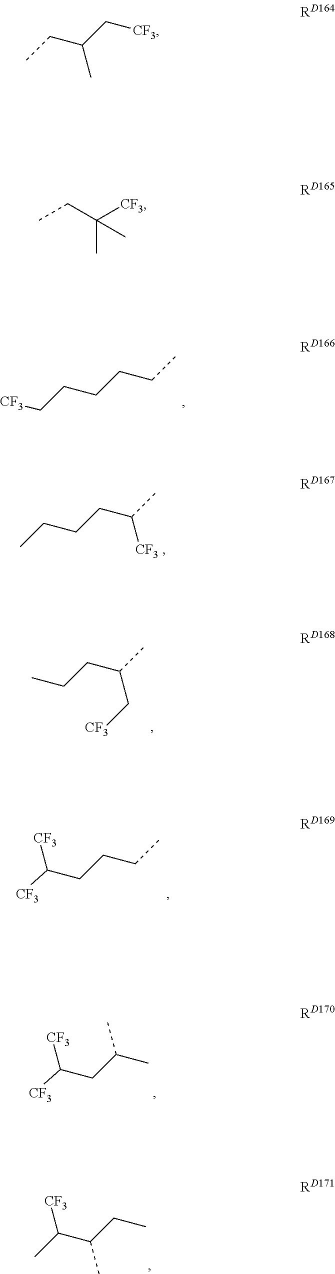

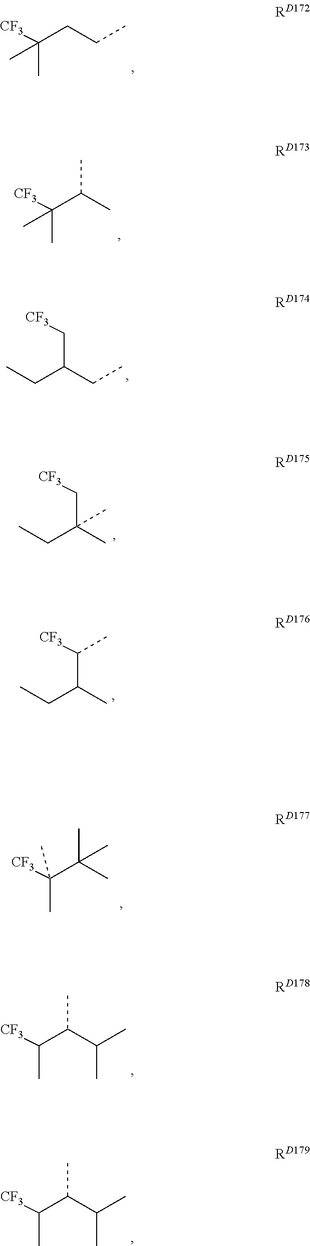

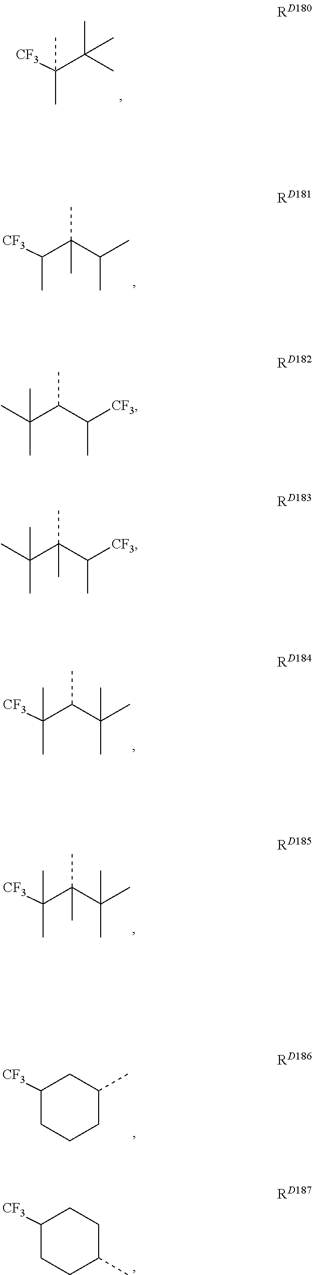

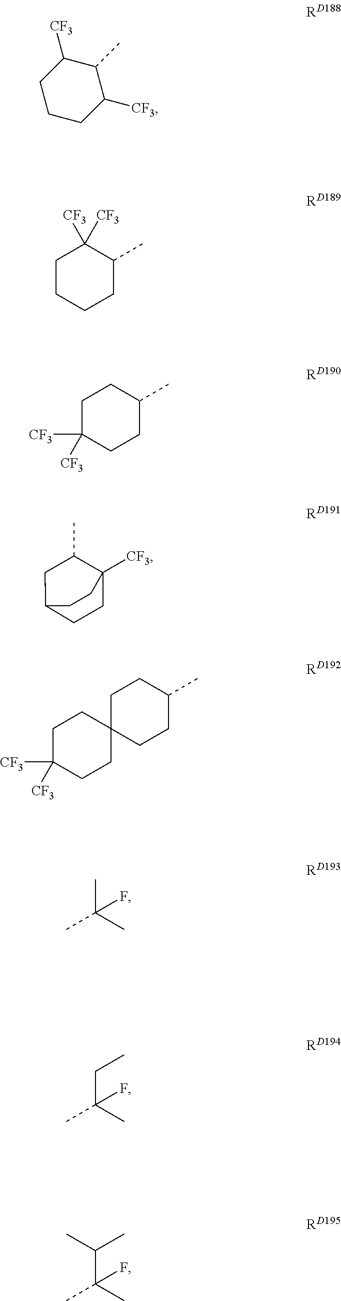

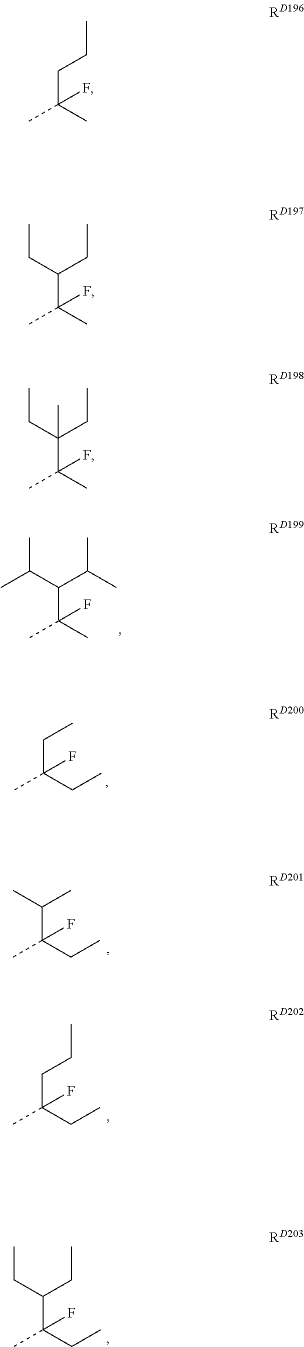

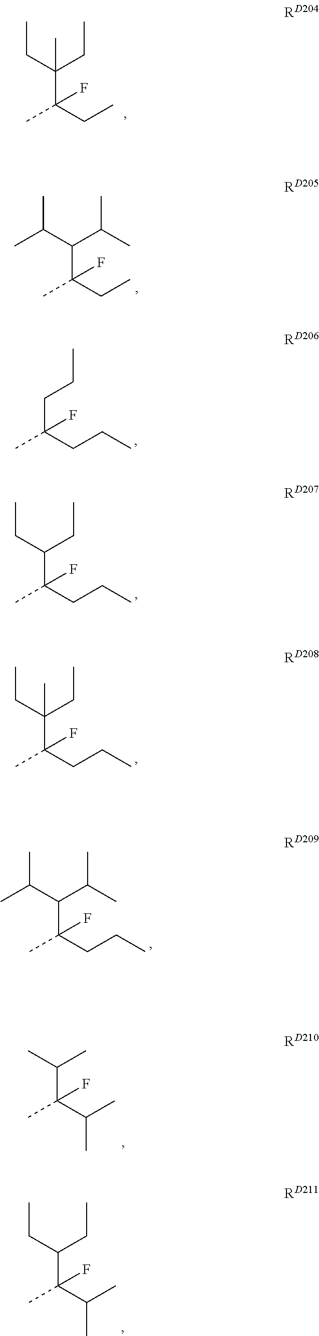

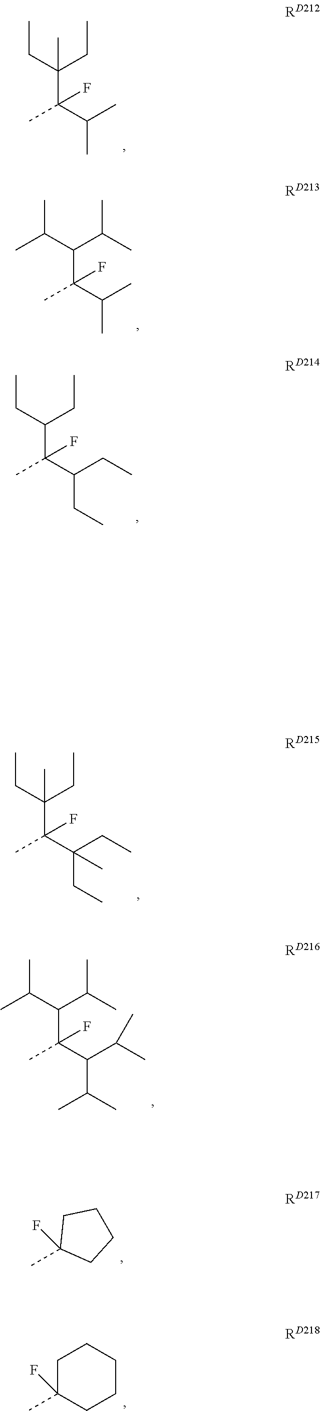

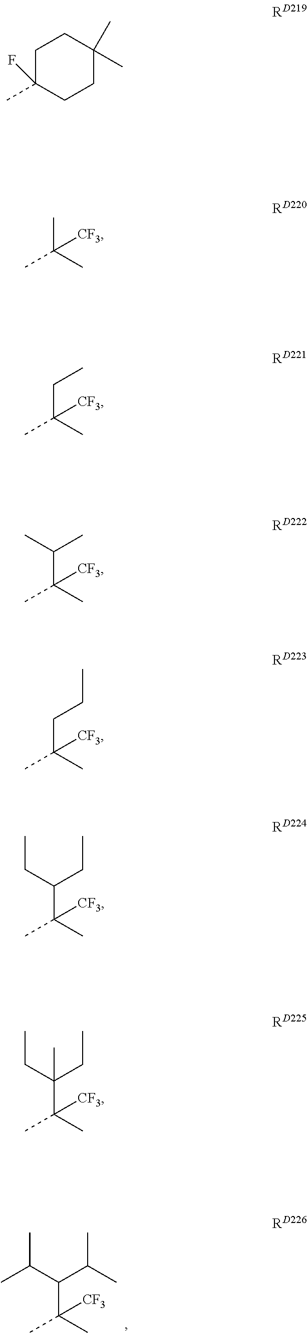

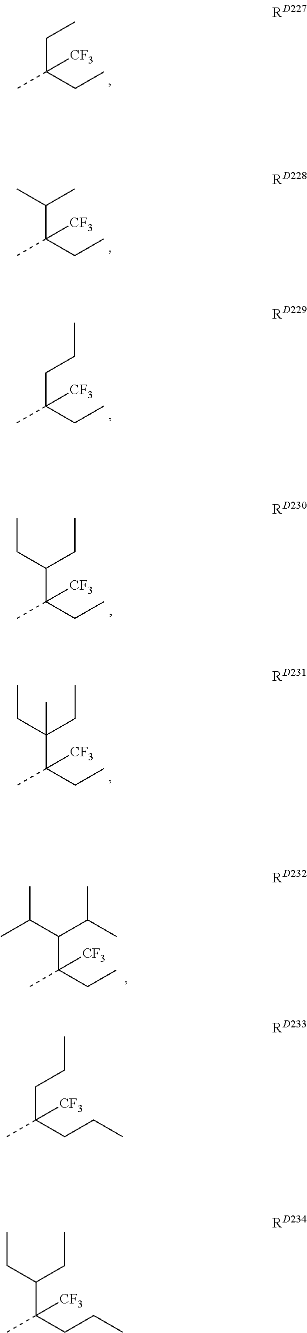

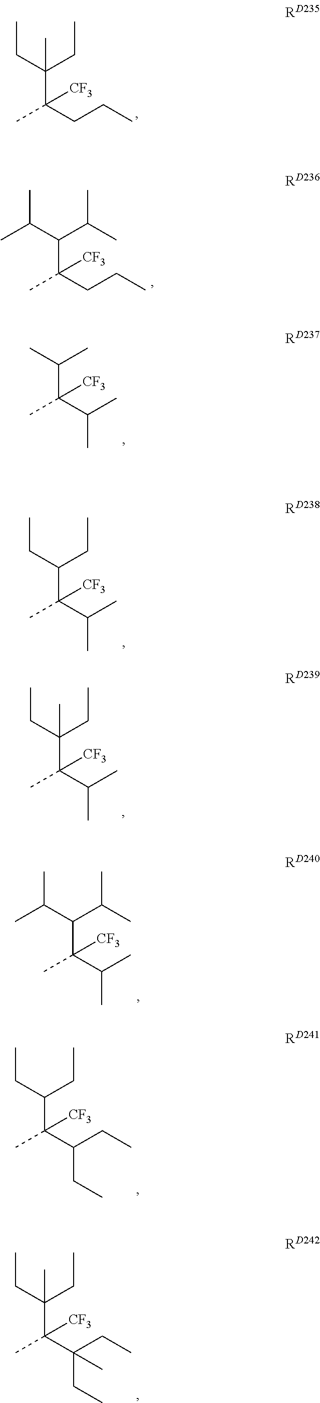

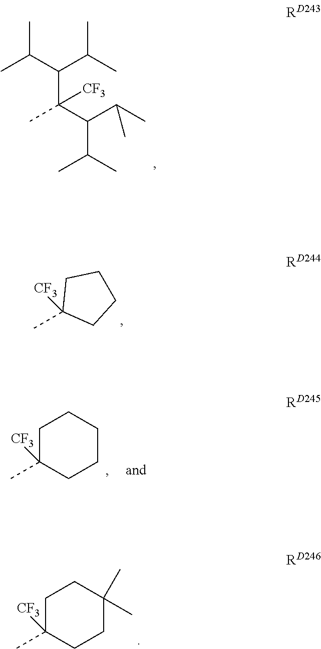

1. A compound comprising a ligand L_{A} having a structure of 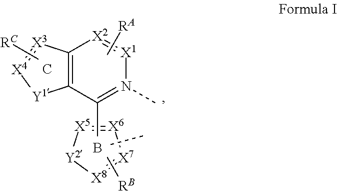
wherein:
each of X¹, X², X³, X⁴, X⁵, X⁶, X⁷, and X⁸ is independently C or N;
each of Y^{1′} and Y^{2′} is independently selected from the group consisting of O, S, Se, CRR′, and SiRR′;
each of R^{A}, R^{B}, and R^{C} is independently represent mono to the maximum allowable substitution, or no substitution;
each of R^{A}, R^{B}, and R^{C} is independently a hydrogen or a substituent selected from the group consisting of deuterium, halogen, alkyl, cycloalkyl, heteroalkyl, heterocycloalkyl, boryl, selenyl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
L_{A} is coordinated to metal M through the indicated dashed lines to form a 5-membered chelate ring;
metal M is selected from the group consisting of Ru, Os, Ir, Pd, Pt, Cu, Ag, and Au;
Ring B is coordinated to M by a C-M bond;
M may be coordinated to other ligands;
L_{A} can be joined with other ligands to form a tridentate, tetradentate, pentadentate, or hexadentate ligand; and
any two adjacent R^{A}, R^{B}, and R^{C} can be joined or fused to form a ring.

2. The compound of claim 1, wherein each of R^{A}, R^{B}, and R^{C} is independently a hydrogen or a substituent selected from the group consisting of deuterium, fluorine, alkyl, cycloalkyl, heteroalkyl, alkoxy, aryloxy, amino, silyl, boryl, alkenyl, cycloalkenyl, heteroalkenyl, aryl, heteroaryl, nitrile, isonitrile, sulfanyl, and combinations thereof.

3. The compound of either of claim 1 or claim 2, wherein each of X¹, X², X³, X⁴, X⁵, X⁶, X⁷, and X⁸ is C; or at least one of X¹, X², X³, X⁴, X⁵, X⁶, X⁷, and X⁸ is N.

4. The compound of claim 1, wherein one of X¹ and X² is N; or one of X³ and X⁴ is N.

5. The compound of claim 1, wherein at least one of Y^{1′} and Y^{2′} is selected from the group consisting of O, S, and Se.

6. The compound of claim 1, wherein X³ and X⁴ are C, and two R^{C} are joined to form a ring system fused with ring C.

7. The compound of claim 6, wherein the ring system comprises one ring fused to ring C; or at least two rings fused to ring C; or at least three rings fused to ring C.

8. The compound of claim 1, wherein L_{A} has a structure of 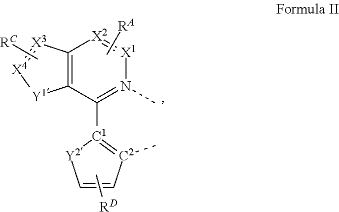
wherein C¹ and C² are carbon atoms joined by a double bond;
wherein R^{D} represents mono- or di-substitution, or no substitution; and
each R^{D} is independently a hydrogen or a substituent selected from the group consisting of deuterium, halogen, alkyl, cycloalkyl, heteroalkyl, heterocycloalkyl, boryl, selenyl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof.

9. The compound of claim 1, wherein the ligand L_{A} is selected from the group consisting of the structures of: 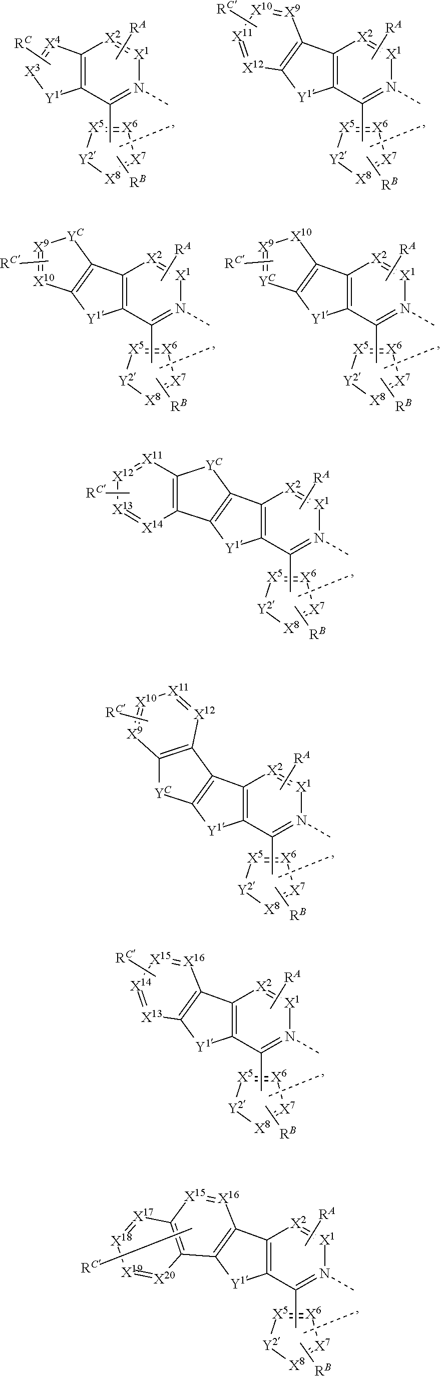 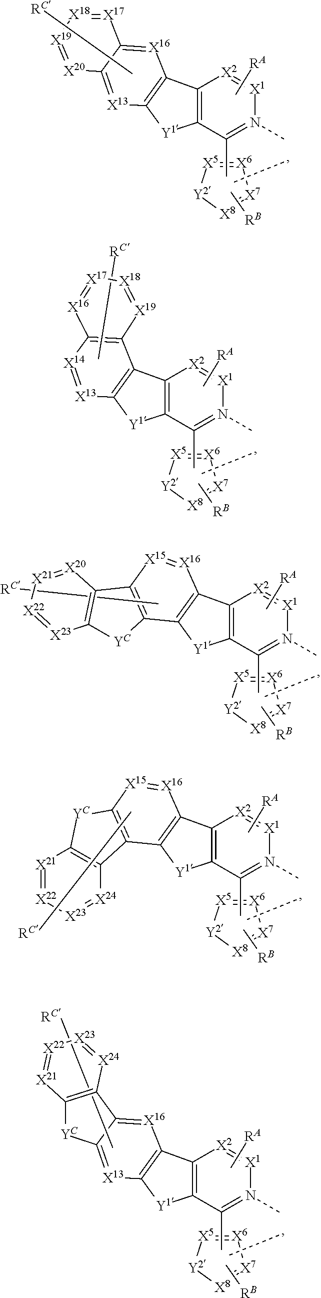 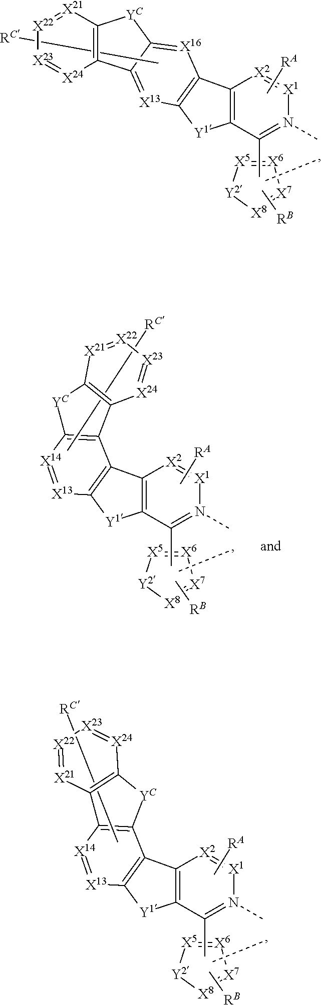
wherein
each of X⁹ to X²⁴ is independently C or N;
Y^{C} is selected from the group consisting of O, S, CR′R″, SiR′R″, BR′, and NR′;
R^{C′} represents mono to the maximum allowable substitution, or no substitution; and
each R^{C′} is independently a hydrogen or a substituent selected from the group consisting of deuterium, halogen, alkyl, cycloalkyl, heteroalkyl, heterocycloalkyl, boryl, selenyl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;

10. The compound of claim 1, wherein the ligand L_{A} is selected from the group consisting of L_{Ai-m-X}, wherein i is an integer from 1 to 4524, m is an integer from 1 to 108, and X is from 1 to 4, with 1 being for O, 2 for S, 3 for Se, and 4 for NCH₃, wherein each of L_{Ai-1-X} to L_{Ai-108-X} has the structure defined as follows: 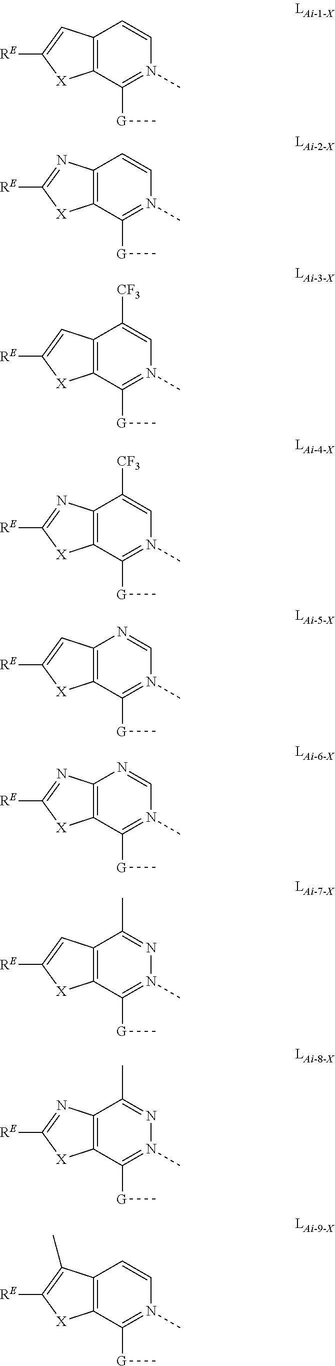 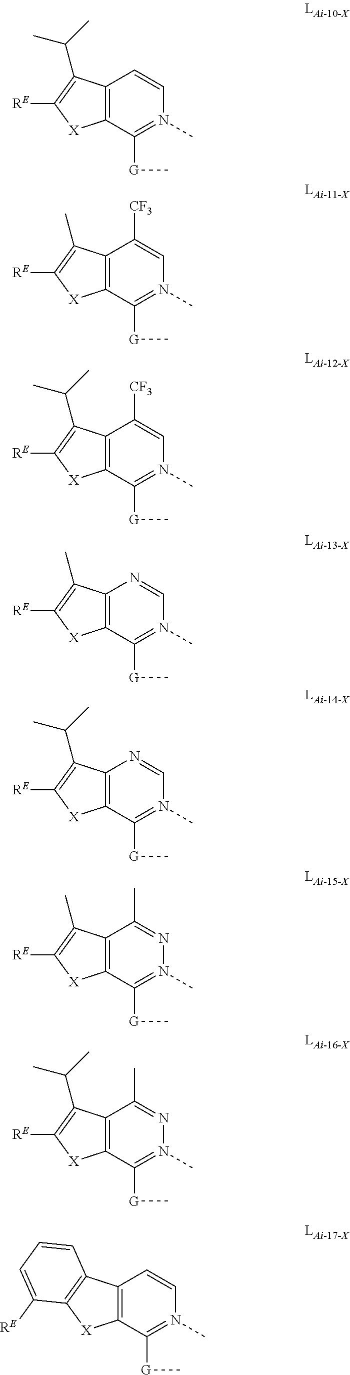 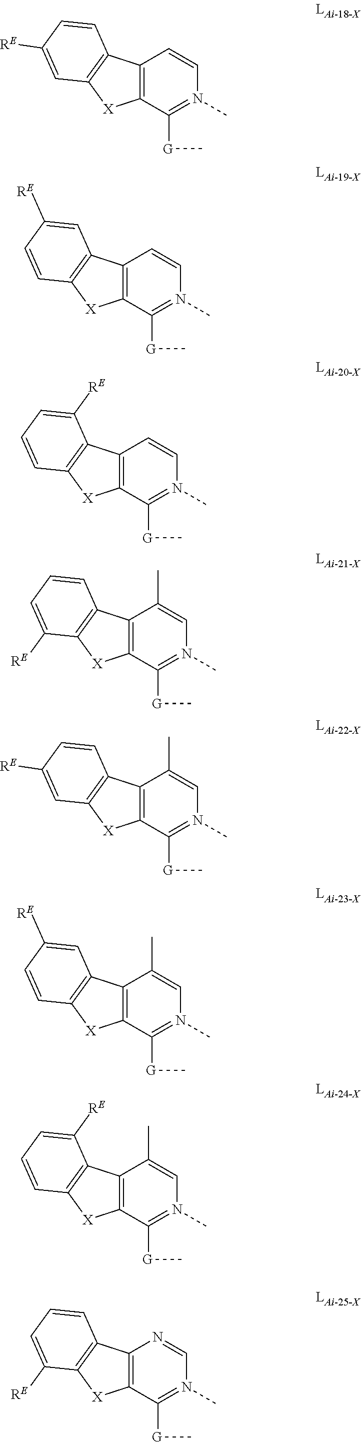 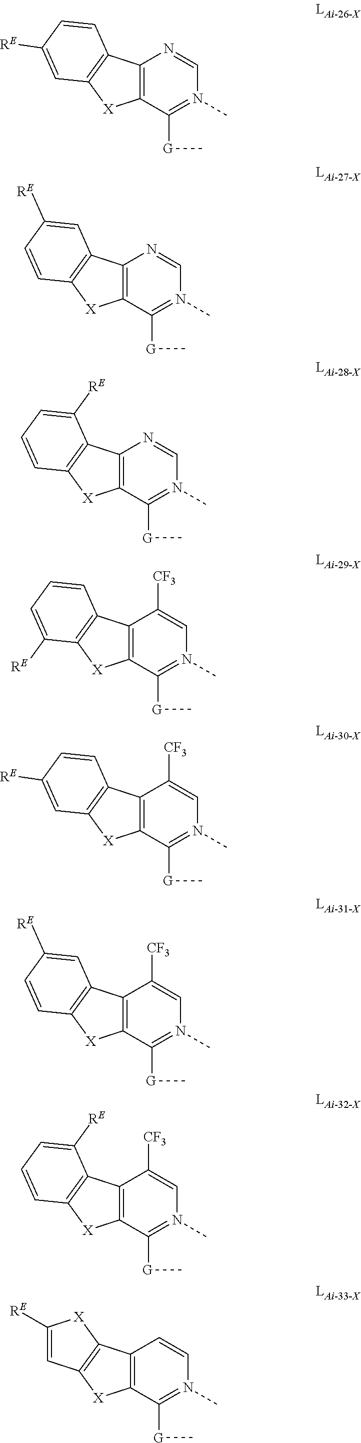 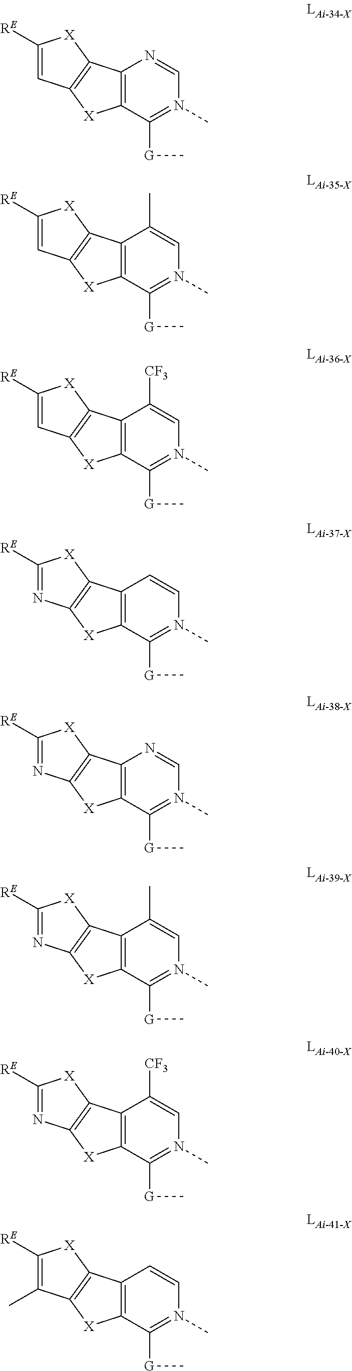 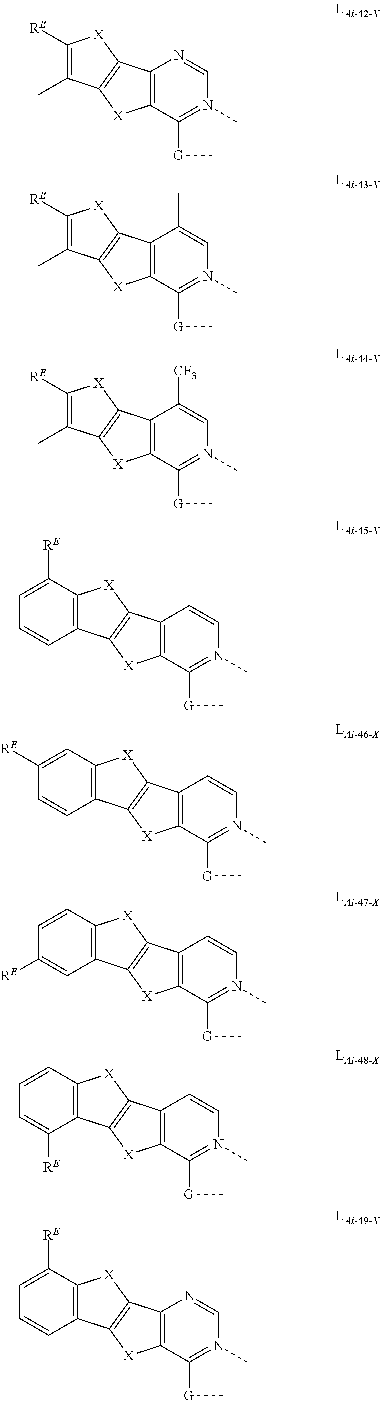 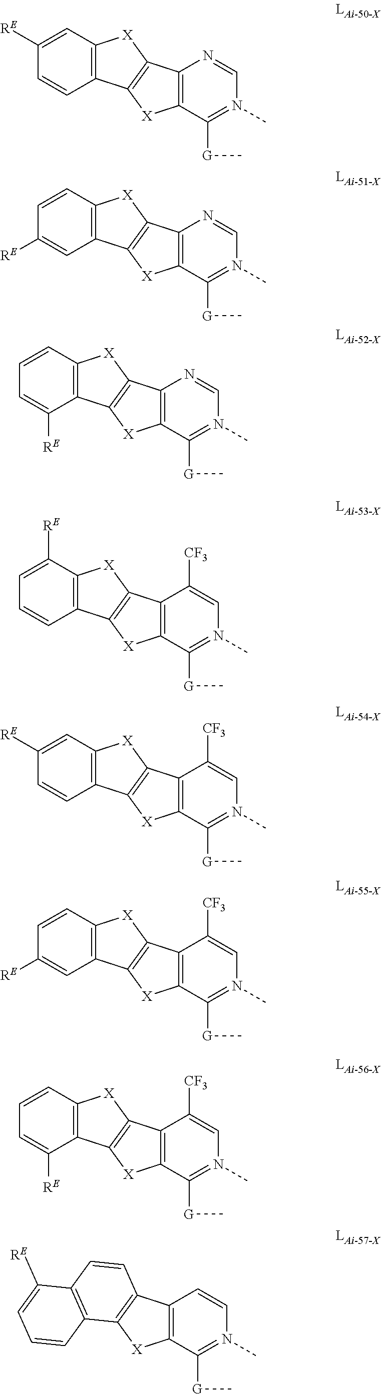 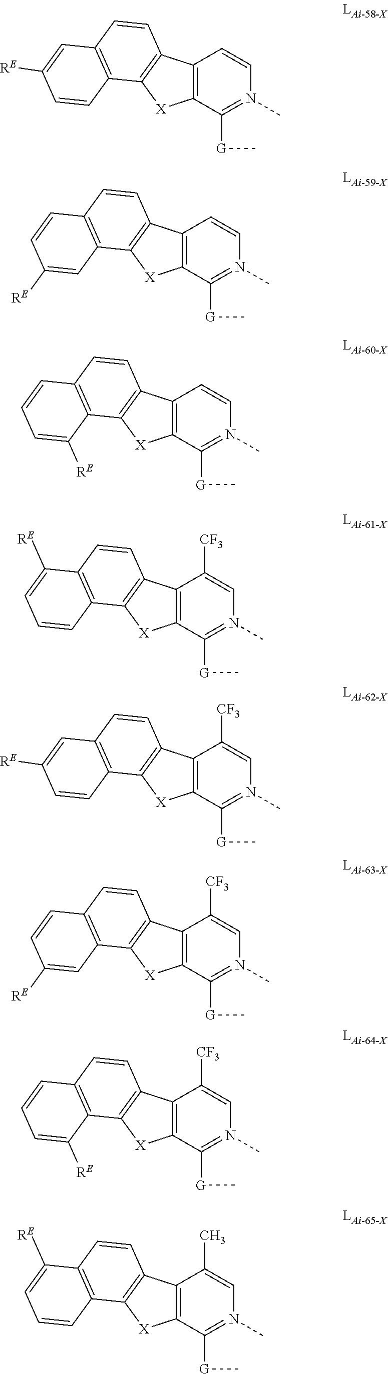 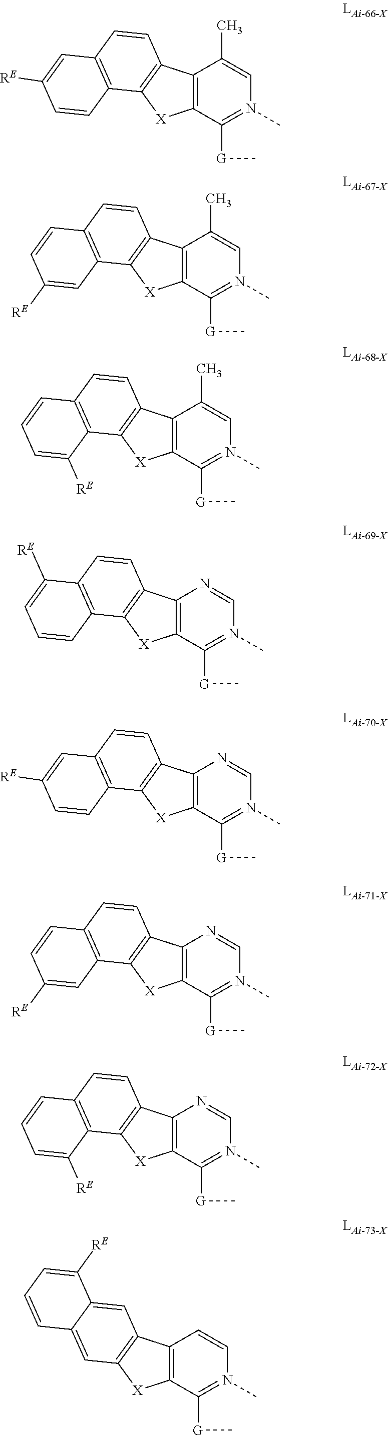 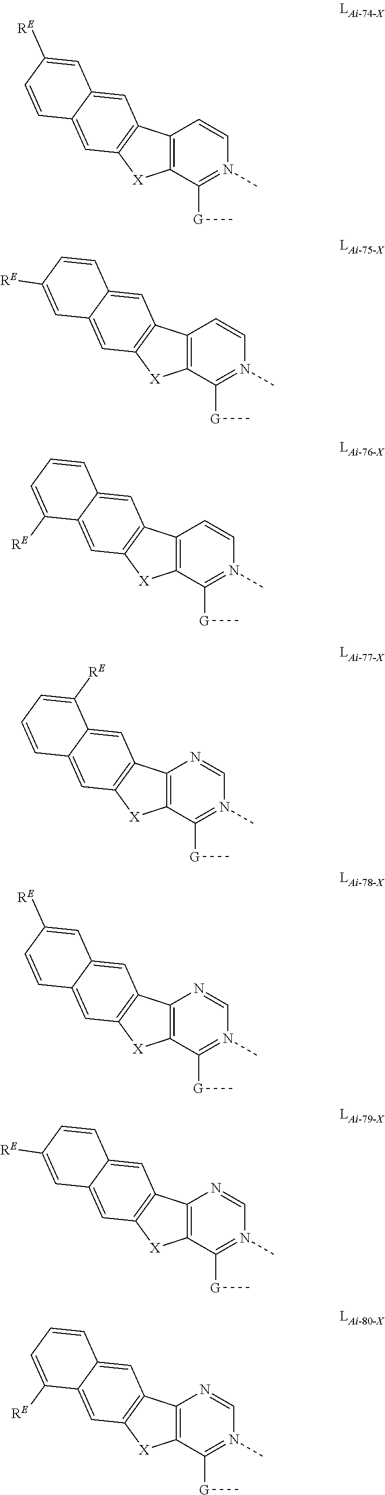 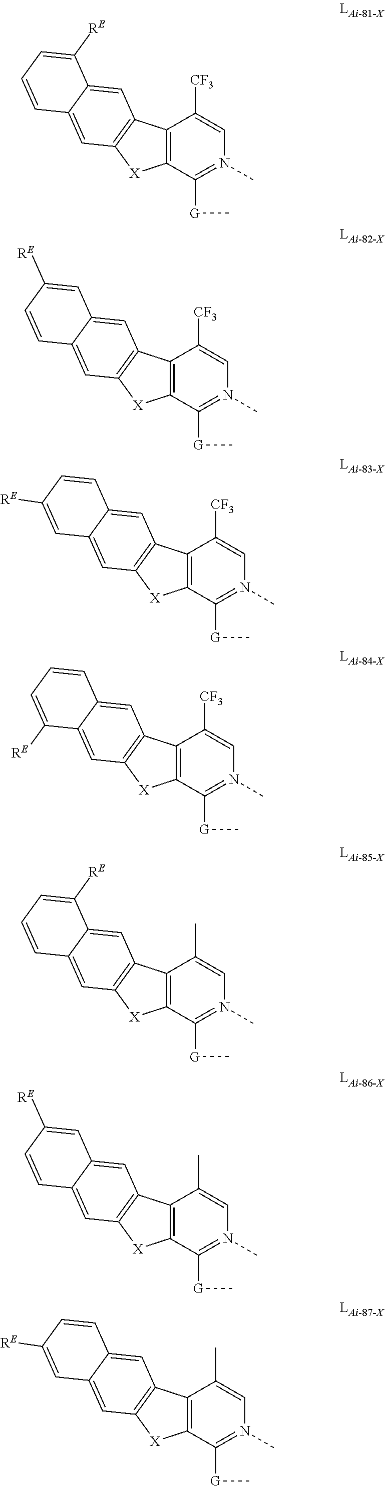 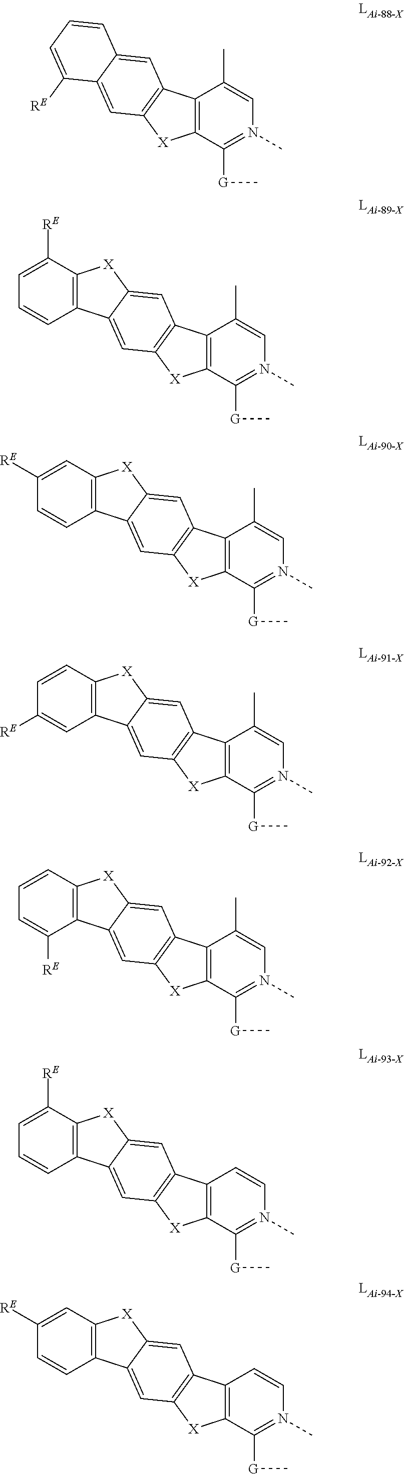 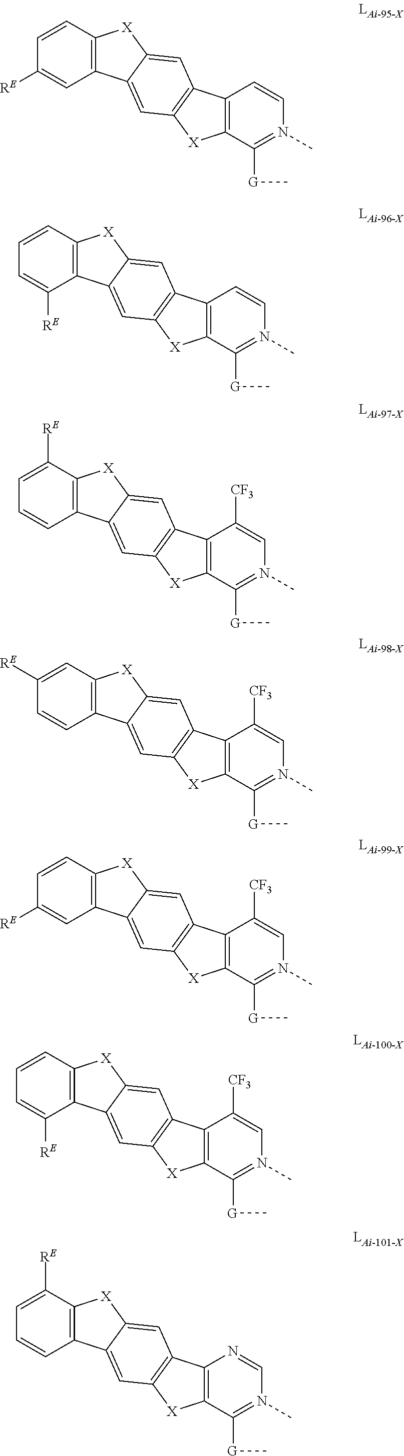 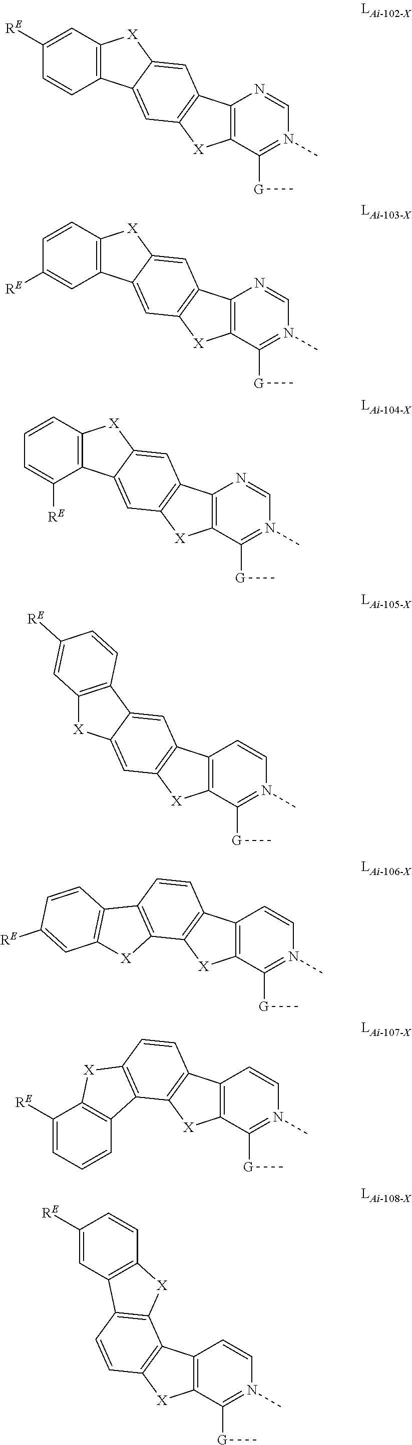
wherein for each of L_{A1} to L_{A4524}, R^{E} and G are defined as follows:

| L_{Ai} | R^{E} | G | L_{Ai} | R^{E} | G | L_{Ai} | R^{E} | G | L_{Ai} | R^{E} | G |
|---|---|---|---|---|---|---|---|---|---|---|---|
| L_{A1} | R¹ | G¹ | L_{A2} | R¹ | G² | L_{A3} | R¹ | G³ | L_{A4} | R¹ | G⁴ |
| L_{A5} | R² | G¹ | L_{A6} | R² | G² | L_{A7} | R² | G³ | L_{A8} | R² | G⁴ |
| L_{A9} | R³ | G¹ | L_{A10} | R³ | G² | L_{A11} | R³ | G³ | L_{A12} | R³ | G⁴ |
| L_{A13} | R⁴ | G¹ | L_{A14} | R⁴ | G² | L_{A15} | R⁴ | G³ | L_{A16} | R⁴ | G⁴ |
| L_{A17} | R⁵ | G¹ | L_{A18} | R⁵ | G² | L_{A19} | R⁵ | G³ | L_{A20} | R⁵ | G⁴ |
| L_{A21} | R⁶ | G¹ | L_{A22} | R⁶ | G² | L_{A23} | R⁶ | G³ | L_{A24} | R⁶ | G⁴ |
| L_{A25} | R⁷ | G¹ | L_{A26} | R⁷ | G² | L_{A27} | R⁷ | G³ | L_{A28} | R⁷ | G⁴ |
| L_{A29} | R⁸ | G¹ | L_{A30} | R⁸ | G² | L_{A31} | R⁸ | G³ | L_{A32} | R⁸ | G⁴ |
| L_{A33} | R⁹ | G¹ | L_{A34} | R⁹ | G² | L_{A35} | R⁹ | G³ | L_{A36} | R⁹ | G⁴ |
| L_{A37} | R¹⁰ | G¹ | L_{A38} | R¹⁰ | G² | L_{A39} | R¹⁰ | G³ | L_{A40} | R¹⁰ | G⁴ |
| L_{A41} | R¹¹ | G¹ | L_{A42} | R¹¹ | G² | L_{A43} | R¹¹ | G³ | L_{A44} | R¹¹ | G⁴ |
| L_{A45} | R¹² | G¹ | L_{A46} | R¹² | G² | L_{A47} | R¹² | G³ | L_{A48} | R¹² | G⁴ |
| L_{A49} | R¹³ | G¹ | L_{A50} | R¹³ | G² | L_{A51} | R¹³ | G³ | L_{A52} | R¹³ | G⁴ |
| L_{A53} | R¹⁴ | G¹ | L_{A54} | R¹⁴ | G² | L_{A55} | R¹⁴ | G³ | L_{A56} | R¹⁴ | G⁴ |
| L_{A57} | R¹⁵ | G¹ | L_{A58} | R¹⁵ | G² | L_{A59} | R¹⁵ | G³ | L_{A60} | R¹⁵ | G⁴ |
| L_{A61} | R¹⁶ | G¹ | L_{A62} | R¹⁶ | G² | L_{A63} | R¹⁶ | G³ | L_{A64} | R¹⁶ | G⁴ |
| L_{A65} | R¹⁷ | G¹ | L_{A66} | R¹⁷ | G² | L_{A67} | R¹⁷ | G³ | L_{A68} | R¹⁷ | G⁴ |
| L_{A69} | R¹⁸ | G¹ | L_{A70} | R¹⁸ | G² | L_{A71} | R¹⁸ | G³ | L_{A72} | R¹⁸ | G⁴ |
| L_{A73} | R¹⁹ | G¹ | L_{A74} | R¹⁹ | G² | L_{A75} | R¹⁹ | G³ | L_{A76} | R¹⁹ | G⁴ |
| L_{A77} | R²⁰ | G¹ | L_{A78} | R²⁰ | G² | L_{A79} | R²⁰ | G³ | L_{A80} | R²⁰ | G⁴ |
| L_{A81} | R²¹ | G¹ | L_{A82} | R²¹ | G² | L_{A83} | R²¹ | G³ | L_{A84} | R²¹ | G⁴ |
| L_{A85} | R²² | G¹ | L_{A86} | R²² | G² | L_{A87} | R²² | G³ | L_{A88} | R²² | G⁴ |
| L_{A89} | R²³ | G¹ | L_{A90} | R²³ | G² | L_{A91} | R²³ | G³ | L_{A92} | R²³ | G⁴ |
| L_{A93} | R²⁴ | G¹ | L_{A94} | R²⁴ | G² | L_{A95} | R²⁴ | G³ | L_{A96} | R²⁴ | G⁴ |
| L_{A97} | R²⁵ | G¹ | L_{A98} | R²⁵ | G² | L_{A99} | R²⁵ | G³ | L_{A100} | R²⁵ | G⁴ |
| L_{A101} | R²⁶ | G¹ | L_{A102} | R²⁶ | G² | L_{A103} | R²⁶ | G³ | L_{A104} | R²⁶ | G⁴ |
| L_{A105} | R²⁷ | G¹ | L_{A106} | R²⁷ | G² | L_{A107} | R²⁷ | G³ | L_{A108} | R²⁷ | G⁴ |
| L_{A109} | R²⁸ | G¹ | L_{A110} | R²⁸ | G² | L_{A111} | R²⁸ | G³ | L_{A112} | R²⁸ | G⁴ |
| L_{A113} | RE | G¹ | L_{A114} | R²⁹ | G² | L_{A115} | R²⁹ | G³ | L_{A116} | R²⁹ | G⁴ |
| L_{A117} | R³⁰ | G¹ | L_{A118} | R³⁰ | G² | L_{A119} | R³⁰ | G³ | L_{A120} | R³⁰ | G⁴ |
| L_{A121} | R³¹ | G¹ | L_{A122} | R³¹ | G² | L_{A123} | R³¹ | G³ | L_{A124} | R³¹ | G⁴ |
| L_{A125} | R³² | G¹ | L_{A126} | R³² | G² | L_{A127} | R³² | G³ | L_{A128} | R³² | G⁴ |
| L_{A129} | R³³ | G¹ | L_{A130} | R³³ | G² | L_{A131} | R³³ | G³ | L_{A132} | R³³ | G⁴ |
| L_{A133} | R³⁴ | G¹ | L_{A134} | R³⁴ | G² | L_{A135} | R³⁴ | G³ | L_{A136} | R³⁴ | G⁴ |
| L_{A137} | R³⁵ | G¹ | L_{A138} | R³⁵ | G² | L_{A139} | R³⁵ | G³ | L_{A140} | R³⁵ | G⁴ |
| L_{A141} | R³⁶ | G¹ | L_{A142} | R³⁶ | G² | L_{A143} | R³⁶ | G³ | L_{A144} | R³⁶ | G⁴ |
| L_{A145} | R³⁷ | G¹ | L_{A146} | R³⁷ | G² | L_{A147} | R³⁷ | G³ | L_{A148} | R³⁷ | G⁴ |
| L_{A149} | R³⁸ | G¹ | L_{A150} | R³⁸ | G² | L_{A151} | R³⁸ | G³ | L_{A152} | R³⁸ | G⁴ |
| L_{A153} | R³⁹ | G¹ | L_{A154} | R³⁹ | G² | L_{A155} | R³⁹ | G³ | L_{A156} | R³⁹ | G⁴ |
| L_{A157} | R⁴⁰ | G¹ | L_{A158} | R⁴⁰ | G² | L_{A159} | R⁴⁰ | G³ | L_{A160} | R⁴⁰ | G⁴ |
| L_{A161} | R⁴¹ | G¹ | L_{A162} | R⁴¹ | G² | L_{A163} | R⁴¹ | G³ | L_{A164} | R⁴¹ | G⁴ |
| L_{A165} | R⁴² | G¹ | L_{A166} | R⁴² | G² | L_{A167} | R⁴² | G³ | L_{A168} | R⁴² | G⁴ |
| L_{A169} | R⁴³ | G¹ | L_{A170} | R⁴³ | G² | L_{A171} | R⁴³ | G³ | L_{A172} | R⁴³ | G⁴ |
| L_{A173} | R⁴⁴ | G¹ | L_{A174} | R⁴⁴ | G² | L_{A175} | R⁴⁴ | G³ | L_{A176} | R⁴⁴ | G⁴ |
| L_{A177} | R⁴⁵ | G¹ | L_{A178} | R⁴⁵ | G² | L_{A179} | R⁴⁵ | G³ | L_{A180} | R⁴⁵ | G⁴ |
| L_{A181} | R⁴⁶ | G¹ | L_{A182} | R⁴⁶ | G² | L_{A183} | R⁴⁶ | G³ | L_{A184} | R⁴⁶ | G⁴ |
| L_{A185} | R⁴⁷ | G¹ | L_{A186} | R⁴⁷ | G² | L_{A187} | R⁴⁷ | G³ | L_{A188} | R⁴⁷ | G⁴ |
| L_{A189} | R⁴⁸ | G¹ | L_{A190} | R⁴⁸ | G² | L_{A191} | R⁴⁸ | G³ | L_{A192} | R⁴⁸ | G⁴ |
| L_{A193} | R⁴⁹ | G¹ | L_{A194} | R⁴⁹ | G² | L_{A195} | R⁴⁹ | G³ | L_{A196} | R⁴⁹ | G⁴ |
| L_{A197} | R⁵⁰ | G¹ | L_{A198} | R⁵⁰ | G² | L_{A199} | R⁵⁰ | G³ | L_{A200} | R⁵⁰ | G⁴ |
| L_{A201} | R⁵¹ | G¹ | L_{A202} | R⁵¹ | G² | L_{A203} | R⁵¹ | G³ | L_{A204} | R⁵¹ | G⁴ |
| L_{A205} | R⁵² | G¹ | L_{A206} | R⁵² | G² | L_{A207} | R⁵² | G³ | L_{A208} | R⁵² | G⁴ |
| L_{A209} | R⁵³ | G¹ | L_{A210} | R⁵³ | G² | L_{A211} | R⁵³ | G³ | L_{A212} | R⁵³ | G⁴ |
| L_{A213} | R⁵⁴ | G¹ | L_{A214} | R⁵⁴ | G² | L_{A215} | R⁵⁴ | G³ | L_{A216} | R⁵⁴ | G⁴ |
| L_{A217} | R⁵⁵ | G¹ | L_{A218} | R⁵⁵ | G² | L_{A219} | R⁵⁵ | G³ | L_{A220} | R⁵⁵ | G⁴ |
| L_{A221} | R⁵⁶ | G¹ | L_{A222} | R⁵⁶ | G² | L_{A223} | R⁵⁶ | G³ | L_{A224} | R⁵⁶ | G⁴ |
| L_{A225} | R⁵⁷ | G¹ | L_{A226} | R⁵⁷ | G² | L_{A227} | R⁵⁷ | G³ | L_{A228} | R⁵⁷ | G⁴ |
| L_{A229} | R⁵⁸ | G¹ | L_{A230} | R⁵⁸ | G² | L_{A231} | R⁵⁸ | G³ | L_{A232} | R⁵⁸ | G⁴ |
| L_{A233} | R⁵⁹ | G¹ | L_{A234} | R⁵⁹ | G² | L_{A235} | R⁵⁹ | G³ | L_{A236} | R⁵⁹ | G⁴ |
| L_{A237} | R⁶⁰ | G¹ | L_{A238} | R⁶⁰ | G² | L_{A239} | R⁶⁰ | G³ | L_{A240} | R⁶⁰ | G⁴ |
| L_{A241} | R⁶¹ | G¹ | L_{A242} | R⁶¹ | G² | L_{A243} | R⁶¹ | G³ | L_{A244} | R⁶¹ | G⁴ |
| L_{A245} | R⁶² | G¹ | L_{A246} | R⁶² | G² | L_{A247} | R⁶² | G³ | L_{A248} | R⁶² | G⁴ |
| L_{A249} | R⁶³ | G¹ | L_{A250} | R⁶³ | G² | L_{A251} | R⁶³ | G³ | L_{A252} | R⁶³ | G⁴ |
| L_{A253} | R⁶⁴ | G¹ | L_{A254} | R⁶⁴ | G² | L_{A255} | R⁶⁴ | G³ | L_{A256} | R⁶⁴ | G⁴ |
| L_{A257} | R⁶⁵ | G¹ | L_{A258} | R⁶⁵ | G² | L_{A259} | R⁶⁵ | G³ | L_{A260} | R⁶⁵ | G⁴ |
| L_{A261} | R⁶⁶ | G¹ | L_{A262} | R⁶⁶ | G² | L_{A263} | R⁶⁶ | G³ | L_{A264} | R⁶⁶ | G⁴ |
| L_{A265} | R⁶⁷ | G¹ | L_{A266} | R⁶⁷ | G² | L_{A267} | R⁶⁷ | G³ | L_{A268} | R⁶⁷ | G⁴ |
| L_{A269} | R⁶⁸ | G¹ | L_{A270} | R⁶⁸ | G² | L_{A271} | R⁶⁸ | G³ | L_{A272} | R⁶⁸ | G⁴ |
| L_{A273} | R⁶⁹ | G¹ | L_{A274} | R⁶⁹ | G² | L_{A275} | R⁶⁹ | G³ | L_{A276} | R⁶⁹ | G⁴ |
| L_{A277} | R⁷⁰ | G¹ | L_{A278} | R⁷⁰ | G² | L_{A279} | R⁷⁰ | G³ | L_{A280} | R⁷⁰ | G⁴ |
| L_{A281} | R⁷¹ | G¹ | L_{A282} | R⁷¹ | G² | L_{A283} | R⁷¹ | G³ | L_{A284} | R⁷¹ | G⁴ |
| L_{A285} | R⁷² | G¹ | L_{A286} | R⁷² | G² | L_{A287} | R⁷² | G³ | L_{A288} | R⁷² | G⁴ |
| L_{A289} | R⁷³ | G¹ | L_{A290} | R⁷³ | G² | L_{A291} | R⁷³ | G³ | L_{A292} | R⁷³ | G⁴ |
| L_{A293} | R⁷⁴ | G¹ | L_{A294} | R⁷⁴ | G² | L_{A295} | R⁷⁴ | G³ | L_{A296} | R⁷⁴ | G⁴ |
| L_{A297} | R⁷⁵ | G¹ | L_{A298} | R⁷⁵ | G² | L_{A299} | R⁷⁵ | G³ | L_{A300} | R⁷⁵ | G⁴ |
| L_{A301} | R⁷⁶ | G¹ | L_{A302} | R⁷⁶ | G² | L_{A303} | R⁷⁶ | G³ | L_{A304} | R⁷⁶ | G⁴ |
| L_{A305} | R⁷⁷ | G¹ | L_{A306} | R⁷⁷ | G² | L_{A307} | R⁷⁷ | G³ | L_{A308} | R⁷⁷ | G⁴ |
| L_{A309} | R⁷⁸ | G¹ | L_{A310} | R⁷⁸ | G² | L_{A311} | R⁷⁸ | G³ | L_{A312} | R⁷⁸ | G⁴ |
| L_{A313} | R⁷⁹ | G¹ | L_{A314} | R⁷⁹ | G² | L_{A315} | R⁷⁹ | G³ | L_{A316} | R⁷⁹ | G⁴ |
| L_{A317} | R⁸⁰ | G¹ | L_{A318} | R⁸⁰ | G² | L_{A319} | R⁸⁰ | G³ | L_{A320} | R⁸⁰ | G⁴ |
| L_{A321} | R⁸¹ | G¹ | L_{A322} | R⁸¹ | G² | L_{A323} | R⁸¹ | G³ | L_{A324} | R⁸¹ | G⁴ |
| L_{A325} | R⁸² | G¹ | L_{A326} | R⁸² | G² | L_{A327} | R⁸² | G³ | L_{A328} | R⁸² | G⁴ |
| L_{A329} | R⁸³ | G¹ | L_{A330} | R⁸³ | G² | L_{A331} | R⁸³ | G³ | L_{A332} | R⁸³ | G⁴ |
| L_{A333} | R⁸⁴ | G¹ | L_{A334} | R⁸⁴ | G² | L_{A335} | R⁸⁴ | G³ | L_{A336} | R⁸⁴ | G⁴ |
| L_{A337} | R⁸⁵ | G¹ | L_{A338} | R⁸⁵ | G² | L_{A339} | R⁸⁵ | G³ | L_{A340} | R⁸⁵ | G⁴ |
| L_{A341} | R⁸⁶ | G¹ | L_{A342} | R⁸⁶ | G² | L_{A343} | R⁸⁶ | G³ | L_{A344} | R⁸⁶ | G⁴ |
| L_{A345} | R⁸⁷ | G¹ | L_{A346} | R⁸⁷ | G² | L_{A347} | R⁸⁷ | G³ | L_{A348} | R⁸⁷ | G⁴ |
| L_{A349} | R¹ | G⁵ | L_{A350} | R¹ | G⁶ | L_{A351} | R¹ | G⁷ | L_{A352} | R¹ | G⁸ |
| L_{A353} | R² | G⁵ | L_{A354} | R² | G⁶ | L_{A355} | R² | G⁷ | L_{A356} | R² | G⁸ |
| L_{A357} | R³ | G⁵ | L_{A358} | R³ | G⁶ | L_{A359} | R³ | G⁷ | L_{A360} | R³ | G⁸ |
| L_{A361} | R⁴ | G⁵ | L_{A362} | R⁴ | G⁶ | L_{A363} | R⁴ | G⁷ | L_{A364} | R⁴ | G⁸ |
| L_{A365} | R⁵ | G⁵ | L_{A366} | R⁵ | G⁶ | L_{A367} | R⁵ | G⁷ | L_{A368} | R⁵ | G⁸ |
| L_{A369} | R⁶ | G⁵ | L_{A370} | R⁶ | G⁶ | L_{A371} | R⁶ | G⁷ | L_{A372} | R⁶ | G⁸ |
| L_{A373} | R² | G⁵ | L_{A374} | R² | G⁶ | L_{A375} | R² | G⁷ | L_{A376} | R² | G⁸ |
| L_{A377} | R⁸ | G⁵ | L_{A378} | R⁸ | G⁶ | L_{A379} | R⁸ | G⁷ | L_{A380} | R⁸ | G⁸ |
| L_{A381} | R⁹ | G⁵ | L_{A382} | R⁹ | G⁶ | L_{A383} | R⁹ | G⁷ | L_{A384} | R⁹ | G⁸ |
| L_{A385} | R¹⁰ | G⁵ | L_{A386} | R¹⁰ | G⁶ | L_{A387} | R¹⁰ | G⁷ | L_{A388} | R¹⁰ | G⁸ |
| L_{A389} | R¹¹ | G⁵ | L_{A390} | R¹¹ | G⁶ | L_{A391} | R¹¹ | G⁷ | L_{A392} | R¹¹ | G⁸ |
| L_{A393} | R¹² | G⁵ | L_{A394} | R¹² | G⁶ | L_{A395} | R¹² | G⁷ | L_{A396} | R¹² | G⁸ |
| L_{A397} | R¹³ | G⁵ | L_{A398} | R¹³ | G⁶ | L_{A399} | R¹³ | G⁷ | L_{A400} | R¹³ | G⁸ |
| L_{A401} | R¹⁴ | G⁵ | L_{A402} | R¹⁴ | G⁶ | L_{A403} | R¹⁴ | G⁷ | L_{A404} | R¹⁴ | G⁸ |
| L_{A405} | R¹⁵ | G⁵ | L_{A406} | R¹⁵ | G⁶ | L_{A407} | R¹⁵ | G⁷ | L_{A408} | R¹⁵ | G⁸ |
| L_{A409} | R¹⁶ | G⁵ | L_{A410} | R¹⁶ | G⁶ | L_{A411} | R¹⁶ | G⁷ | L_{A412} | R¹⁶ | G⁸ |
| L_{A413} | R¹⁷ | G⁵ | L_{A414} | R¹⁷ | G⁶ | L_{A415} | R¹⁷ | G⁷ | L_{A416} | R¹⁷ | G⁸ |
| L_{A417} | R¹⁸ | G⁵ | L_{A418} | R¹⁸ | G⁶ | L_{A419} | R¹⁸ | G⁷ | L_{A420} | R¹⁸ | G⁸ |
| L_{A421} | R¹⁹ | G⁵ | L_{A422} | R¹⁹ | G⁶ | L_{A423} | R¹⁹ | G⁷ | L_{A424} | R¹⁹ | G⁸ |
| L_{A425} | R²⁰ | G⁵ | L_{A426} | R²⁰ | G⁶ | L_{A427} | R²⁰ | G⁷ | L_{A428} | R²⁰ | G⁸ |
| L_{A429} | R²¹ | G⁵ | L_{A430} | R²¹ | G⁶ | L_{A431} | R²¹ | G⁷ | L_{A432} | R²¹ | G⁸ |
| L_{A433} | R²² | G⁵ | L_{A434} | R²² | G⁶ | L_{A435} | R²² | G⁷ | L_{A436} | R²² | G⁸ |
| L_{A437} | R²³ | G⁵ | L_{A438} | R²³ | G⁶ | L_{A439} | R²³ | G⁷ | L_{A440} | R²³ | G⁸ |
| L_{A441} | R²⁴ | G⁵ | L_{A442} | R²⁴ | G⁶ | L_{A443} | R²⁴ | G⁷ | L_{A444} | R²⁴ | G⁸ |
| L_{A445} | R²⁵ | G⁵ | L_{A446} | R²⁵ | G⁶ | L_{A447} | R²⁵ | G⁷ | L_{A448} | R²⁵ | G⁸ |
| L_{A449} | R²⁶ | G⁵ | L_{A450} | R²⁶ | G⁶ | L_{A451} | R²⁶ | G⁷ | L_{A452} | R²⁶ | G⁸ |
| L_{A453} | R²⁷ | G⁵ | L_{A454} | R²⁷ | G⁶ | L_{A455} | R²⁷ | G⁷ | L_{A456} | R²⁷ | G⁸ |
| L_{A457} | R²⁸ | G⁵ | L_{A458} | R²⁸ | G⁶ | L_{A459} | R²⁸ | G⁷ | L_{A460} | R²⁸ | G⁸ |
| L_{A461} | R²⁹ | G⁵ | L_{A462} | R²⁹ | G⁶ | L_{A463} | R²⁹ | G⁷ | L_{A464} | R²⁹ | G⁸ |
| L_{A465} | R³⁰ | G⁵ | L_{A466} | R³⁰ | G⁶ | L_{A467} | R³⁰ | G⁷ | L_{A468} | R³⁰ | G⁸ |
| L_{A469} | R³¹ | G⁵ | L_{A470} | R³¹ | G⁶ | L_{A471} | R³¹ | G⁷ | L_{A472} | R³¹ | G⁸ |
| L_{A473} | R³² | G⁵ | L_{A474} | R³² | G⁶ | L_{A475} | R³² | G⁷ | L_{A476} | R³² | G⁸ |
| L_{A477} | R³³ | G⁵ | L_{A478} | R³³ | G⁶ | L_{A479} | R³³ | G⁷ | L_{A480} | R³³ | G⁸ |
| L_{A481} | R³⁴ | G⁵ | L_{A482} | R³⁴ | G⁶ | L_{A483} | R³⁴ | G⁷ | L_{A484} | R³⁴ | G⁸ |
| L_{A485} | R³⁵ | G⁵ | L_{A486} | R³⁵ | G⁶ | L_{A487} | R³⁵ | G⁷ | L_{A488} | R³⁵ | G⁸ |
| L_{A489} | R³⁶ | G⁵ | L_{A490} | R³⁶ | G⁶ | L_{A491} | R³⁶ | G⁷ | L_{A492} | R³⁶ | G⁸ |
| L_{A493} | R³⁷ | G⁵ | L_{A494} | R³⁷ | G⁶ | L_{A495} | R³⁷ | G⁷ | L_{A496} | R³⁷ | G⁸ |
| L_{A497} | R³⁸ | G⁵ | L_{A498} | R³⁸ | G⁶ | L_{A499} | R³⁸ | G⁷ | L_{A500} | R³⁸ | G⁸ |
| L_{A501} | R³⁹ | G⁵ | L_{A502} | R³⁹ | G⁶ | L_{A503} | R³⁹ | G⁷ | L_{A504} | R³⁹ | G⁸ |
| L_{A505} | R⁴⁰ | G⁵ | L_{A506} | R⁴⁰ | G⁶ | L_{A507} | R⁴⁰ | G⁷ | L_{A508} | R⁴⁰ | G⁸ |
| L_{A509} | R⁴¹ | G⁵ | L_{A510} | R⁴¹ | G⁶ | L_{A511} | R⁴¹ | G⁷ | L_{A512} | R⁴¹ | G⁸ |
| L_{A513} | R⁴² | G⁵ | L_{A514} | R⁴² | G⁶ | L_{A515} | R⁴² | G⁷ | L_{A516} | R⁴² | G⁸ |
| L_{A517} | R⁴³ | G⁵ | L_{A518} | R⁴³ | G⁶ | L_{A519} | R⁴³ | G⁷ | L_{A520} | R⁴³ | G⁸ |
| L_{A521} | R⁴⁴ | G⁵ | L_{A522} | R⁴⁴ | G⁶ | L_{A523} | R⁴⁴ | G⁷ | L_{A524} | R⁴⁴ | G⁸ |
| L_{A525} | R⁴⁵ | G⁵ | L_{A526} | R⁴⁵ | G⁶ | L_{A527} | R⁴⁵ | G⁷ | L_{A528} | R⁴⁵ | G⁸ |
| L_{A529} | R⁴⁶ | G⁵ | L_{A530} | R⁴⁶ | G⁶ | L_{A531} | R⁴⁶ | G⁷ | L_{A532} | R⁴⁶ | G⁸ |
| L_{A533} | R⁴⁷ | G⁵ | L_{A534} | R⁴⁷ | G⁶ | L_{A535} | R⁴⁷ | G⁷ | L_{A536} | R⁴⁷ | G⁸ |
| L_{A537} | R⁴⁸ | G⁵ | L_{A538} | R⁴⁸ | G⁶ | L_{A539} | R⁴⁸ | G⁷ | L_{A540} | R⁴⁸ | G⁸ |
| L_{A541} | R⁴⁹ | G⁵ | L_{A542} | R⁴⁹ | G⁶ | L_{A543} | R⁴⁹ | G⁷ | L_{A544} | R⁴⁹ | G⁸ |
| L_{A545} | R⁵⁰ | G⁵ | L_{A546} | R⁵⁰ | G⁶ | L_{A547} | R⁵⁰ | G⁷ | L_{A548} | R⁵⁰ | G⁸ |
| L_{A549} | R⁵¹ | G⁵ | L_{A550} | R⁵¹ | G⁶ | L_{A551} | R⁵¹ | G⁷ | L_{A552} | R⁵¹ | G⁸ |
| L_{A553} | R⁵² | G⁵ | L_{A554} | R⁵² | G⁶ | L_{A555} | R⁵² | G⁷ | L_{A556} | R⁵² | G⁸ |
| L_{A557} | R⁵³ | G⁵ | L_{A558} | R⁵³ | G⁶ | L_{A559} | R⁵³ | G⁷ | L_{A560} | R⁵³ | G⁸ |
| L_{A561} | R⁵⁴ | G⁵ | L_{A562} | R⁵⁴ | G⁶ | L_{A563} | R⁵⁴ | G⁷ | L_{A564} | R⁵⁴ | G⁸ |
| L_{A565} | R⁵⁵ | G⁵ | L_{A566} | R⁵⁵ | G⁶ | L_{A567} | R⁵⁵ | G⁷ | L_{A568} | R⁵⁵ | G⁸ |
| L_{A569} | R⁵⁶ | G⁵ | L_{A570} | R⁵⁶ | G⁶ | L_{A571} | R⁵⁶ | G⁷ | L_{A572} | R⁵⁶ | G⁸ |
| L_{A573} | R⁵⁷ | G⁵ | L_{A574} | R⁵⁷ | G⁶ | L_{A575} | R⁵⁷ | G⁷ | L_{A576} | R⁵⁷ | G⁸ |
| L_{A577} | R⁵⁸ | G⁵ | L_{A578} | R⁵⁸ | G⁶ | L_{A579} | R⁵⁸ | G⁷ | L_{A580} | R⁵⁸ | G⁸ |
| L_{A581} | R⁵⁹ | G⁵ | L_{A582} | R⁵⁹ | G⁶ | L_{A583} | R⁵⁹ | G⁷ | L_{A584} | R⁵⁹ | G⁸ |
| L_{A585} | R⁶⁰ | G⁵ | L_{A586} | R⁶⁰ | G⁶ | L_{A587} | R⁶⁰ | G⁷ | L_{A588} | R⁶⁰ | G⁸ |
| L_{A589} | R⁶¹ | G⁵ | L_{A590} | R⁶¹ | G⁶ | L_{A591} | R⁶¹ | G⁷ | L_{A592} | R⁶¹ | G⁸ |
| L_{A593} | R⁶² | G⁵ | L_{A594} | R⁶² | G⁶ | L_{A595} | R⁶² | G⁷ | L_{A596} | R⁶² | G⁸ |
| L_{A597} | R⁶³ | G⁵ | L_{A598} | R⁶³ | G⁶ | L_{A599} | R⁶³ | G⁷ | L_{A600} | R⁶³ | G⁸ |
| L_{A601} | R⁶⁴ | G⁵ | L_{A602} | R⁶⁴ | G⁶ | L_{A603} | R⁶⁴ | G⁷ | L_{A604} | R⁶⁴ | G⁸ |
| L_{A605} | R⁶⁵ | G⁵ | L_{A606} | R⁶⁵ | G⁶ | L_{A607} | R⁶⁵ | G⁷ | L_{A608} | R⁶⁵ | G⁸ |
| L_{A609} | R⁶⁶ | G⁵ | L_{A610} | R⁶⁶ | G⁶ | L_{A611} | R⁶⁶ | G⁷ | L_{A612} | R⁶⁶ | G⁸ |
| L_{A613} | R⁶⁷ | G⁵ | L_{A614} | R⁶⁷ | G⁶ | L_{A615} | R⁶⁷ | G⁷ | L_{A616} | R⁶⁷ | G⁸ |
| L_{A617} | R⁶⁸ | G⁵ | L_{A618} | R⁶⁸ | G⁶ | L_{A619} | R⁶⁸ | G⁷ | L_{A620} | R⁶⁸ | G⁸ |
| L_{A621} | R⁶⁹ | G⁵ | L_{A622} | R⁶⁹ | G⁶ | L_{A623} | R⁶⁹ | G⁷ | L_{A624} | R⁶⁹ | G⁸ |
| L_{A625} | R⁷⁰ | G⁵ | L_{A626} | R⁷⁰ | G⁶ | L_{A627} | R⁷⁰ | G⁷ | L_{A628} | R⁷⁰ | G⁸ |
| L_{A629} | R⁷¹ | G⁵ | L_{A630} | R⁷¹ | G⁶ | L_{A631} | R⁷¹ | G⁷ | L_{A632} | R⁷¹ | G⁸ |
| L_{A633} | R⁷² | G⁵ | L_{A634} | R⁷² | G⁶ | L_{A635} | R⁷¹ | G⁷ | L_{A636} | R⁷² | G⁸ |
| L_{A637} | R⁷³ | G⁵ | L_{A638} | R⁷³ | G⁶ | L_{A639} | R⁷³ | G⁷ | L_{A640} | R⁷³ | G⁸ |
| L_{A641} | R⁷⁴ | G⁵ | L_{A642} | R⁷⁴ | G⁶ | L_{A643} | R⁷⁴ | G⁷ | L_{A644} | R⁷⁴ | G⁸ |
| L_{A645} | R⁷⁵ | G⁵ | L_{A646} | R⁷⁵ | G⁶ | L_{A647} | R⁷⁵ | G⁷ | L_{A648} | R⁷⁵ | G⁸ |
| L_{A649} | R⁷⁶ | G⁵ | L_{A650} | R⁷⁶ | G⁶ | L_{A651} | R⁷⁶ | G⁷ | L_{A652} | R⁷⁶ | G⁸ |
| L_{A653} | R⁷⁷ | G⁵ | L_{A654} | R⁷⁷ | G⁶ | L_{A655} | R⁷⁷ | G⁷ | L_{A656} | R⁷⁷ | G⁸ |
| L_{A657} | R⁷⁸ | G⁵ | L_{A658} | R⁷⁸ | G⁶ | L_{A659} | R⁷⁸ | G⁷ | L_{A660} | R⁷⁸ | G⁸ |
| L_{A661} | R⁷⁹ | G⁵ | L_{A662} | R⁷⁹ | G⁶ | L_{A663} | R⁷⁹ | G⁷ | L_{A664} | R⁷⁹ | G⁸ |
| L_{A665} | R⁸⁰ | G⁵ | L_{A666} | R⁸⁰ | G⁶ | L_{A667} | R⁸⁰ | G⁷ | L_{A668} | R⁸⁰ | G⁸ |
| L_{A669} | R⁸¹ | G⁵ | L_{A670} | R⁸¹ | G⁶ | L_{A671} | R⁸¹ | G⁷ | L_{A672} | R⁸¹ | G⁸ |
| L_{A673} | R⁸² | G⁵ | L_{A674} | R⁸² | G⁶ | L_{A675} | R⁸² | G⁷ | L_{A676} | R⁸² | G⁸ |
| L_{A677} | R⁸³ | G⁵ | L_{A678} | R⁸³ | G⁶ | L_{A679} | R⁸³ | G⁷ | L_{A680} | R⁸³ | G⁸ |
| L_{A681} | R⁸⁴ | G⁵ | L_{A682} | R⁸⁴ | G⁶ | L_{A683} | R⁸⁴ | G⁷ | L_{A684} | R⁸⁴ | G⁸ |
| L_{A685} | R⁸⁵ | G⁵ | L_{A686} | R⁸⁵ | G⁶ | L_{A687} | R⁸⁵ | G⁷ | L_{A688} | R⁸⁵ | G⁸ |
| L_{A689} | R⁸⁶ | G⁵ | L_{A690} | R⁸⁶ | G⁶ | L_{A691} | R⁸⁶ | G⁷ | L_{A692} | R⁸⁶ | G⁸ |
| L_{A693} | R⁸⁷ | G⁵ | L_{A694} | R⁸⁷ | G⁶ | L_{A695} | R⁸⁷ | G⁷ | L_{A696} | R⁸⁷ | G⁸ |
| L_{A697} | R¹ | G⁹ | L_{A698} | R¹ | G¹⁰ | L_{A699} | R¹ | G¹¹ | L_{A700} | R¹ | G¹² |
| L_{A701} | R² | G⁹ | L_{A702} | R² | G¹⁰ | L_{A703} | R² | G¹¹ | L_{A704} | R² | G¹² |
| L_{A705} | R³ | G⁹ | L_{A706} | R³ | G¹⁰ | L_{A707} | R³ | G¹¹ | L_{A708} | R³ | G¹² |
| L_{A709} | R⁴ | G⁹ | L_{A710} | R⁴ | G¹⁰ | L_{A711} | R⁴ | G¹¹ | L_{A712} | R⁴ | G¹² |
| L_{A713} | R⁵ | G⁹ | L_{A714} | R⁵ | G¹⁰ | L_{A715} | R⁵ | G¹¹ | L_{A716} | R⁵ | G¹² |
| L_{A717} | R⁶ | G⁹ | L_{A718} | R⁶ | G¹⁰ | L_{A719} | R⁶ | G¹¹ | L_{A720} | R⁶ | G¹² |
| L_{A721} | R⁷ | G⁹ | L_{A722} | R⁷ | G¹⁰ | L_{A723} | R⁷ | G¹¹ | L_{A724} | R⁷ | G¹² |
| L_{A725} | R⁸ | G⁹ | L_{A726} | R⁸ | G¹⁰ | L_{A727} | R⁸ | G¹¹ | L_{A728} | R⁸ | G¹² |
| L_{A729} | R⁹ | G⁹ | L_{A730} | R⁹ | G¹⁰ | L_{A731} | R⁹ | G¹¹ | L_{A732} | R⁹ | G¹² |
| L_{A733} | R¹⁰ | G⁹ | L_{A734} | R¹⁰ | G¹⁰ | L_{A735} | R¹⁰ | G¹¹ | L_{A736} | R¹⁰ | G¹² |
| L_{A737} | R¹¹ | G⁹ | L_{A738} | R¹¹ | G¹⁰ | L_{A739} | R¹¹ | G¹¹ | L_{A740} | R¹¹ | G¹² |
| L_{A741} | R¹² | G⁹ | L_{A742} | R¹² | G¹⁰ | L_{A743} | R¹² | G¹¹ | L_{A744} | R¹² | G¹² |
| L_{A745} | R¹³ | G⁹ | L_{A746} | R¹³ | G¹⁰ | L_{A747} | R¹³ | G¹¹ | L_{A748} | R¹³ | G¹² |
| L_{A749} | R¹⁴ | G⁹ | L_{A750} | R¹⁴ | G¹⁰ | L_{A751} | R¹⁴ | G¹¹ | L_{A752} | R¹⁴ | G¹² |
| L_{A753} | R¹⁵ | G⁹ | L_{A754} | R¹⁵ | G¹⁰ | L_{A755} | R¹⁵ | G¹¹ | L_{A756} | R¹⁵ | G¹² |
| L_{A757} | R¹⁶ | G⁹ | L_{A758} | R¹⁶ | G¹⁰ | L_{A759} | R¹⁶ | G¹¹ | L_{A760} | R¹⁶ | G¹² |
| L_{A761} | R¹⁷ | G⁹ | L_{A762} | R¹⁷ | G¹⁰ | L_{A763} | R¹⁷ | G¹¹ | L_{A764} | R¹⁷ | G¹² |
| L_{A765} | R¹⁸ | G⁹ | L_{A766} | R¹⁸ | G¹⁰ | L_{A767} | R¹⁸ | G¹¹ | L_{A768} | R¹⁸ | G¹² |
| L_{A769} | R¹⁹ | G⁹ | L_{A770} | R¹⁹ | G¹⁰ | L_{A771} | R¹⁹ | G¹¹ | L_{A772} | R¹⁹ | G¹² |
| L_{A773} | R²⁰ | G⁹ | L_{A774} | R²⁰ | G¹⁰ | L_{A775} | R²⁰ | G¹¹ | L_{A776} | R²⁰ | G¹² |
| L_{A777} | R²¹ | G⁹ | L_{A778} | R²¹ | G¹⁰ | L_{A779} | R²¹ | G¹¹ | L_{A780} | R²¹ | G¹² |
| L_{A781} | R²² | G⁹ | L_{A782} | R²² | G¹⁰ | L_{A783} | R²² | G¹¹ | L_{A784} | R²² | G¹² |
| L_{A785} | R²³ | G⁹ | L_{A786} | R²³ | G¹⁰ | L_{A787} | R²³ | G¹¹ | L_{A788} | R²³ | G¹² |
| L_{A789} | R²⁴ | G⁹ | L_{A790} | R²⁴ | G¹⁰ | L_{A791} | R²⁴ | G¹¹ | L_{A792} | R²⁴ | G¹² |
| L_{A793} | R²⁵ | G⁹ | L_{A794} | R²⁵ | G¹⁰ | L_{A795} | R²⁵ | G¹¹ | L_{A796} | R²⁵ | G¹² |
| L_{A797} | R²⁶ | G⁹ | L_{A798} | R²⁶ | G¹⁰ | L_{A799} | R²⁶ | G¹¹ | L_{A800} | R²⁶ | G¹² |
| L_{A801} | R²⁷ | G⁹ | L_{A802} | R²⁷ | G¹⁰ | L_{A803} | R²⁷ | G¹¹ | L_{A804} | R²⁷ | G¹² |
| L_{A805} | R²⁸ | G⁹ | L_{A806} | R²⁸ | G¹⁰ | L_{A807} | R²⁸ | G¹¹ | L_{A808} | R²⁸ | G¹² |
| L_{A809} | R²⁹ | G⁹ | L_{A810} | R²⁹ | G¹⁰ | L_{A811} | R²⁹ | G¹¹ | L_{A812} | R²⁹ | G¹² |
| L_{A813} | R³⁰ | G⁹ | L_{A814} | R³⁰ | G¹⁰ | L_{A815} | R³⁰ | G¹¹ | L_{A816} | R³⁰ | G¹² |
| L_{A817} | R³¹ | G⁹ | L_{A818} | R³¹ | G¹⁰ | L_{A819} | R³¹ | G¹¹ | L_{A820} | R³¹ | G¹² |
| L_{A821} | R³² | G⁹ | L_{A822} | R³² | G¹⁰ | L_{A823} | R³² | G¹¹ | L_{A824} | R³² | G¹² |
| L_{A825} | R³³ | G⁹ | L_{A826} | R³³ | G¹⁰ | L_{A827} | R³³ | G¹¹ | L_{A828} | R³³ | G¹² |
| L_{A829} | R³⁴ | G⁹ | L_{A830} | R³⁴ | G¹⁰ | L_{A831} | R³⁴ | G¹¹ | L_{A832} | R³⁴ | G¹² |
| L_{A833} | R³⁵ | G⁹ | L_{A834} | R³⁵ | G¹⁰ | L_{A835} | R³⁵ | G¹¹ | L_{A836} | R³⁵ | G¹² |
| L_{A837} | R³⁶ | G⁹ | L_{A838} | R³⁶ | G¹⁰ | L_{A839} | R³⁶ | G¹¹ | L_{A840} | R³⁶ | G¹² |
| L_{A841} | R³⁷ | G⁹ | L_{A842} | R³⁷ | G¹⁰ | L_{A843} | R³⁷ | G¹¹ | L_{A844} | R³⁷ | G¹² |
| L_{A845} | R³⁸ | G⁹ | L_{A846} | R³⁸ | G¹⁰ | L_{A847} | R³⁸ | G¹¹ | L_{A848} | R³⁸ | G¹² |
| L_{A849} | R³⁹ | G⁹ | L_{A850} | R³⁹ | G¹⁰ | L_{A851} | R³⁹ | G¹¹ | L_{A852} | R³⁹ | G¹² |
| L_{A853} | R⁴⁰ | G⁹ | L_{A854} | R⁴⁰ | G¹⁰ | L_{A855} | R⁴⁰ | G¹¹ | L_{A856} | R⁴⁰ | G¹² |
| L_{A857} | R⁴¹ | G⁹ | L_{A858} | R⁴¹ | G¹⁰ | L_{A859} | R⁴¹ | G¹¹ | L_{A860} | R⁴¹ | G¹² |
| L_{A861} | R⁴² | G⁹ | L_{A862} | R⁴² | G¹⁰ | L_{A863} | R⁴² | G¹¹ | L_{A864} | R⁴² | G¹² |
| L_{A865} | R⁴³ | G⁹ | L_{A866} | R⁴³ | G¹⁰ | L_{A867} | R⁴³ | G¹¹ | L_{A868} | R⁴³ | G¹² |
| L_{A869} | R⁴⁴ | G⁹ | L_{A870} | R⁴⁴ | G¹⁰ | L_{A871} | R⁴⁴ | G¹¹ | L_{A872} | R⁴⁴ | G¹² |
| L_{A873} | R⁴⁵ | G⁹ | L_{A874} | R⁴⁵ | G¹⁰ | L_{A875} | R⁴⁵ | G¹¹ | L_{A876} | R⁴⁵ | G¹² |
| L_{A877} | R⁴⁶ | G⁹ | L_{A878} | R⁴⁶ | G¹⁰ | L_{A879} | R⁴⁶ | G¹¹ | L_{A880} | R⁴⁶ | G¹² |
| L_{A881} | R⁴⁷ | G⁹ | L_{A882} | R⁴⁷ | G¹⁰ | L_{A883} | R⁴⁷ | G¹¹ | L_{A884} | R⁴⁷ | G¹² |
| L_{A885} | R⁴⁸ | G⁹ | L_{A886} | R⁴⁸ | G¹⁰ | L_{A887} | R⁴⁸ | G¹¹ | L_{A888} | R⁴⁸ | G¹² |
| L_{A889} | R⁴⁹ | G⁹ | L_{A890} | R⁴⁹ | G¹⁰ | L_{A891} | R⁴⁹ | G¹¹ | L_{A892} | R⁴⁹ | G¹² |
| L_{A893} | R⁵⁰ | G⁹ | L_{A894} | R⁵⁰ | G¹⁰ | L_{A895} | R⁵⁰ | G¹¹ | L_{A896} | R⁵⁰ | G¹² |
| L_{A897} | R⁵¹ | G⁹ | L_{A898} | R⁵¹ | G¹⁰ | L_{A899} | R⁵¹ | G¹¹ | L_{A900} | R⁵¹ | G¹² |
| L_{A901} | R⁵² | G⁹ | L_{A902} | R⁵² | G¹⁰ | L_{A903} | R⁵² | G¹¹ | L_{A904} | R⁵² | G¹² |
| L_{A905} | R⁵³ | G⁹ | L_{A906} | R⁵³ | G¹⁰ | L_{A907} | R⁵³ | G¹¹ | L_{A908} | R⁵³ | G¹² |
| L_{A909} | R⁵⁴ | G⁹ | L_{A910} | R⁵⁴ | G¹⁰ | L_{A911} | R⁵⁴ | G¹¹ | L_{A912} | R⁵⁴ | G¹² |
| L_{A913} | R⁵⁵ | G⁹ | L_{A914} | R⁵⁵ | G¹⁰ | L_{A915} | R⁵⁵ | G¹¹ | L_{A916} | R⁵⁵ | G¹² |
| L_{A917} | R⁵⁶ | G⁹ | L_{A918} | R⁵⁶ | G¹⁰ | L_{A919} | R⁵⁶ | G¹¹ | L_{A920} | R⁵⁶ | G¹² |
| L_{A921} | R⁵⁷ | G⁹ | L_{A922} | R⁵⁷ | G¹⁰ | L_{A923} | R⁵⁷ | G¹¹ | L_{A924} | R⁵⁷ | G¹² |
| L_{A925} | R⁵⁸ | G⁹ | L_{A926} | R⁵⁸ | G¹⁰ | L_{A927} | R⁵⁸ | G¹¹ | L_{A928} | R⁵⁸ | G¹² |
| L_{A929} | R⁵⁹ | G⁹ | L_{A930} | R⁵⁹ | G¹⁰ | L_{A931} | R⁵⁹ | G¹¹ | L_{A932} | R⁵⁹ | G¹² |
| L_{A933} | R⁶⁰ | G⁹ | L_{A934} | R⁶⁰ | G¹⁰ | L_{A935} | R⁶⁰ | G¹¹ | L_{A936} | R⁶⁰ | G¹² |
| L_{A937} | R⁶¹ | G⁹ | L_{A938} | R⁶¹ | G¹⁰ | L_{A939} | R⁶¹ | G¹¹ | L_{A940} | R⁶¹ | G¹² |
| L_{A941} | R⁶² | G⁹ | L_{A942} | R⁶² | G¹⁰ | L_{A943} | R⁶² | G¹¹ | L_{A944} | R⁶² | G¹² |
| L_{A945} | R⁶³ | G⁹ | L_{A946} | R⁶³ | G¹⁰ | L_{A947} | R⁶³ | G¹¹ | L_{A948} | R⁶³ | G¹² |
| L_{A949} | R⁶⁴ | G⁹ | L_{A950} | R⁶⁴ | G¹⁰ | L_{A951} | R⁶⁴ | G¹¹ | L_{A952} | R⁶⁴ | G¹² |
| L_{A953} | R⁶⁵ | G⁹ | L_{A954} | R⁶⁵ | G¹⁰ | L_{A955} | R⁶⁵ | G¹¹ | L_{A956} | R⁶⁵ | G¹² |
| L_{A957} | R⁶⁶ | G⁹ | L_{A958} | R⁶⁶ | G¹⁰ | L_{A959} | R⁶⁶ | G¹¹ | L_{A960} | R⁶⁶ | G¹² |
| L_{A961} | R⁶⁷ | G⁹ | L_{A962} | R⁶⁷ | G¹⁰ | L_{A963} | R⁶⁷ | G¹¹ | L_{A964} | R⁶⁷ | G¹² |
| L_{A965} | R⁶⁸ | G⁹ | L_{A966} | R⁶⁸ | G¹⁰ | L_{A967} | R⁶⁸ | G¹¹ | L_{A968} | R⁶⁸ | G¹² |
| L_{A969} | R⁶⁹ | G⁹ | L_{A970} | R⁶⁹ | G¹⁰ | L_{A971} | R⁶⁹ | G¹¹ | L_{A972} | R⁶⁹ | G¹² |
| L_{A973} | R⁷⁰ | G⁹ | L_{A974} | R⁷⁰ | G¹⁰ | L_{A975} | R⁷⁰ | G¹¹ | L_{A976} | R⁷⁰ | G¹² |
| L_{A977} | R⁷¹ | G⁹ | L_{A978} | R⁷¹ | G¹⁰ | L_{A979} | R⁷¹ | G¹¹ | L_{A980} | R⁷¹ | G¹² |
| L_{A981} | R⁷² | G⁹ | L_{A982} | R⁷² | G¹⁰ | L_{A983} | R⁷² | G¹¹ | L_{A984} | R⁷² | G¹² |
| L_{A985} | R⁷³ | G⁹ | L_{A986} | R⁷³ | G¹⁰ | L_{A987} | R⁷³ | G¹¹ | L_{A988} | R⁷³ | G¹² |
| L_{A989} | R⁷⁴ | G⁹ | L_{A990} | R⁷⁴ | G¹⁰ | L_{A991} | R⁷⁴ | G¹¹ | L_{A992} | R⁷⁴ | G¹² |
| L_{A993} | R⁷⁵ | G⁹ | L_{A994} | R⁷⁵ | G¹⁰ | L_{A995} | R⁷⁵ | G¹¹ | L_{A996} | R⁷⁵ | G¹² |
| L_{A997} | R⁷⁶ | G⁹ | L_{A998} | R⁷⁶ | G¹⁰ | L_{A999} | R⁷⁶ | G¹¹ | L_{A1000} | R⁷⁶ | G¹² |
| L_{A1001} | R⁷⁷ | G⁹ | L_{A1002} | R⁷⁷ | G¹⁰ | L_{A1003} | R⁷⁷ | G¹¹ | L_{A1004} | R⁷⁷ | G¹² |
| L_{A1005} | R⁷⁸ | G⁹ | L_{A1006} | R⁷⁸ | G¹⁰ | L_{A1007} | R⁷⁸ | G¹¹ | L_{A1008} | R⁷⁸ | G¹² |
| L_{A1009} | R⁷⁹ | G⁹ | L_{A1010} | R⁷⁹ | G¹⁰ | L_{A1011} | R⁷⁹ | G¹¹ | L_{A1012} | R⁷⁹ | G¹² |
| L_{A1013} | R⁸⁰ | G⁹ | L_{A1014} | R⁸⁰ | G¹⁰ | L_{A1015} | R⁸⁰ | G¹¹ | L_{A1016} | R⁸⁰ | G¹² |
| L_{A1017} | R⁸¹ | G⁹ | L_{A1018} | R⁸¹ | G¹⁰ | L_{A1019} | R⁸¹ | G¹¹ | L_{A1020} | R⁸¹ | G¹² |
| L_{A1021} | R⁸² | G⁹ | L_{A1022} | R⁸² | G¹⁰ | L_{A1023} | R⁸² | G¹¹ | L_{A1024} | R⁸² | G¹² |
| L_{A1025} | R⁸³ | G⁹ | L_{A1026} | R⁸³ | G¹⁰ | L_{A1027} | R⁸³ | G¹¹ | L_{A1028} | R⁸³ | G¹² |
| L_{A1029} | R⁸⁴ | G⁹ | L_{A1030} | R⁸⁴ | G¹⁰ | L_{A1031} | R⁸⁴ | G¹¹ | L_{A1032} | R⁸⁴ | G¹² |
| L_{A1033} | R⁸⁵ | G⁹ | L_{A1034} | R⁸⁵ | G¹⁰ | L_{A1035} | R⁸⁵ | G¹¹ | L_{A1036} | R⁸⁵ | G¹² |
| L_{A1037} | R⁸⁶ | G⁹ | L_{A1038} | R⁸⁶ | G¹⁰ | L_{A1039} | R⁸⁶ | G¹¹ | L_{A1040} | R⁸⁶ | G¹² |
| L_{A1041} | R⁸⁷ | G⁹ | L_{A1042} | R⁸⁷ | G¹⁰ | L_{A1043} | R⁸⁷ | G¹¹ | L_{A1044} | R⁸⁷ | G¹² |
| L_{A1045} | R¹ | G¹³ | L_{A1046} | R¹ | G¹⁴ | L_{A1047} | R¹ | G¹⁵ | L_{A1048} | R¹ | G¹⁶ |
| L_{A1049} | R² | G¹³ | L_{A1050} | R² | G¹⁴ | L_{A1051} | R² | G¹⁵ | L_{A1052} | R² | G¹⁶ |
| L_{A1053} | R³ | G¹³ | L_{A1054} | R³ | G¹⁴ | L_{A1055} | R³ | G¹⁵ | L_{A1056} | R³ | G¹⁶ |
| L_{A1057} | R⁴ | G¹³ | L_{A1058} | R⁴ | G¹⁴ | L_{A1059} | R⁴ | G¹⁵ | L_{A1060} | R⁴ | G¹⁶ |
| L_{A1061} | R⁵ | G¹³ | L_{A1062} | R⁵ | G¹⁴ | L_{A1063} | R⁵ | G¹⁵ | L_{A1064} | R⁵ | G¹⁶ |
| L_{A1065} | R⁶ | G¹³ | L_{A1066} | R⁶ | G¹⁴ | L_{A1067} | R⁶ | G¹⁵ | L_{A1068} | R⁶ | G¹⁶ |
| L_{A1069} | R⁷ | G¹³ | L_{A1070} | R⁷ | G¹⁴ | L_{A1071} | R⁷ | G¹⁵ | L_{A1072} | R⁷ | G¹⁶ |
| L_{A1073} | R⁸ | G¹³ | L_{A1074} | R⁸ | G¹⁴ | L_{A1075} | R⁸ | G¹⁵ | L_{A1076} | R⁸ | G¹⁶ |
| L_{A1077} | R⁹ | G¹³ | L_{A1078} | R⁹ | G¹⁴ | L_{A1079} | R⁹ | G¹⁵ | L_{A1080} | R⁹ | G¹⁶ |
| L_{A1081} | R¹⁰ | G¹³ | L_{A1082} | R¹⁰ | G¹⁴ | L_{A1083} | R¹⁰ | G¹⁵ | L_{A1084} | R¹⁰ | G¹⁶ |
| L_{A1085} | R¹¹ | G¹³ | L_{A1086} | R¹¹ | G¹⁴ | L_{A1087} | R¹¹ | G¹⁵ | L_{A1088} | R¹¹ | G¹⁶ |
| L_{A1089} | R¹² | G¹³ | L_{A1090} | R¹² | G¹⁴ | L_{A1091} | R¹² | G¹⁵ | L_{A1092} | R¹² | G¹⁶ |
| L_{A1093} | R¹³ | G¹³ | L_{A1094} | R¹³ | G¹⁴ | L_{A1095} | R¹³ | G¹⁵ | L_{A1096} | R¹³ | G¹⁶ |
| L_{A1097} | R¹⁴ | G¹³ | L_{A1098} | R¹⁴ | G¹⁴ | L_{A1099} | R¹⁴ | G¹⁵ | L_{A1100} | R¹⁴ | G¹⁶ |
| L_{A1101} | R¹⁵ | G¹³ | L_{A1102} | R¹⁵ | G¹⁴ | L_{A1103} | R¹⁵ | G¹⁵ | L_{A1104} | R¹⁵ | G¹⁶ |
| L_{A1105} | R¹⁶ | G¹³ | L_{A1106} | R¹⁶ | G¹⁴ | L_{A1107} | R¹⁶ | G¹⁵ | L_{A1108} | R¹⁶ | G¹⁶ |
| L_{A1109} | R¹⁷ | G¹³ | L_{A1110} | R¹⁷ | G¹⁴ | L_{A1111} | R¹⁷ | G¹⁵ | L_{A1112} | R¹⁷ | G¹⁶ |
| L_{A1113} | R¹⁸ | G¹³ | L_{A1114} | R¹⁸ | G¹⁴ | L_{A1115} | R¹⁸ | G¹⁵ | L_{A1116} | R¹⁸ | G¹⁶ |
| L_{A1117} | R¹⁹ | G¹³ | L_{A1118} | R¹⁹ | G¹⁴ | L_{A1119} | R¹⁹ | G¹⁵ | L_{A1120} | R¹⁹ | G¹⁶ |
| L_{A1121} | R²⁰ | G¹³ | L_{A1122} | R²⁰ | G¹⁴ | L_{A1123} | R²⁰ | G¹⁵ | L_{A1124} | R²⁰ | G¹⁶ |
| L_{A1125} | R²¹ | G¹³ | L_{A1126} | R²¹ | G¹⁴ | L_{A1127} | R²¹ | G¹⁵ | L_{A1128} | R²¹ | G¹⁶ |
| L_{A1129} | R²² | G¹³ | L_{A1130} | R²² | G¹⁴ | L_{A1131} | R²² | G¹⁵ | L_{A1132} | R²² | G¹⁶ |
| L_{A1133} | R²³ | G¹³ | L_{A1134} | R²³ | G¹⁴ | L_{A1135} | R²³ | G¹⁵ | L_{A1136} | R²³ | G¹⁶ |
| L_{A1137} | R²⁴ | G¹³ | L_{A1138} | R²⁴ | G¹⁴ | L_{A1139} | R²⁴ | G¹⁵ | L_{A1140} | R²⁴ | G¹⁶ |
| L_{A1141} | R²⁵ | G¹³ | L_{A1142} | R²⁵ | G¹⁴ | L_{A1143} | R²⁵ | G¹⁵ | L_{A1144} | R²⁵ | G¹⁶ |
| L_{A1145} | R²⁶ | G¹³ | L_{A1146} | R²⁶ | G¹⁴ | L_{A1147} | R²⁶ | G¹⁵ | L_{A1148} | R²⁶ | G¹⁶ |
| L_{A1149} | R²⁷ | G¹³ | L_{A1150} | R²⁷ | G¹⁴ | L_{A1151} | R²⁷ | G¹⁵ | L_{A1152} | R²⁷ | G¹⁶ |
| L_{A1153} | R²⁸ | G¹³ | L_{A1154} | R²⁸ | G¹⁴ | L_{A1155} | R²⁸ | G¹⁵ | L_{A1156} | R²⁸ | G¹⁶ |
| L_{A1157} | R²⁹ | G¹³ | L_{A1158} | R²⁹ | G¹⁴ | L_{A1159} | R²⁹ | G¹⁵ | L_{A1160} | R²⁹ | G¹⁶ |
| L_{A1161} | R³⁰ | G¹³ | L_{A1162} | R³⁰ | G¹⁴ | L_{A1163} | R³⁰ | G¹⁵ | L_{A1164} | R³⁰ | G¹⁶ |
| L_{A1165} | R³¹ | G¹³ | L_{A1166} | R³¹ | G¹⁴ | L_{A1167} | R³¹ | G¹⁵ | L_{A1168} | R³¹ | G¹⁶ |
| L_{A1169} | R³² | G¹³ | L_{A1170} | R³² | G¹⁴ | L_{A1171} | R³² | G¹⁵ | L_{A1172} | R³² | G¹⁶ |
| L_{A1173} | R³³ | G¹³ | L_{A1174} | R³³ | G¹⁴ | L_{A1175} | R³³ | G¹⁵ | L_{A1176} | R³³ | G¹⁶ |
| L_{A1177} | R³⁴ | G¹³ | L_{A1178} | R³⁴ | G¹⁴ | L_{A1179} | R³⁴ | G¹⁵ | L_{A1180} | R³⁴ | G¹⁶ |
| L_{A1181} | R³⁵ | G¹³ | L_{A1182} | R³⁵ | G¹⁴ | L_{A1183} | R³⁵ | G¹⁵ | L_{A1184} | R³⁵ | G¹⁶ |
| L_{A1185} | R³⁶ | G¹³ | L_{A1186} | R³⁶ | G¹⁴ | L_{A1187} | R³⁶ | G¹⁵ | L_{A1188} | R³⁶ | G¹⁶ |
| L_{A1189} | R³⁷ | G¹³ | L_{A1190} | R³⁷ | G¹⁴ | L_{A1191} | R³⁷ | G¹⁵ | L_{A1192} | R³⁷ | G¹⁶ |
| L_{A1193} | R³⁸ | G¹³ | L_{A1194} | R³⁸ | G¹⁴ | L_{A1195} | R³⁸ | G¹⁵ | L_{A1196} | R³⁸ | G¹⁶ |
| L_{A1197} | R³⁹ | G¹³ | L_{A1198} | R³⁹ | G¹⁴ | L_{A1199} | R³⁹ | G¹⁵ | L_{A1200} | R³⁹ | G¹⁶ |
| L_{A1201} | R⁴⁰ | G¹³ | L_{A1202} | R⁴⁰ | G¹⁴ | L_{A1203} | R⁴⁰ | G¹⁵ | L_{A1204} | R⁴⁰ | G¹⁶ |
| L_{A1205} | R⁴¹ | G¹³ | L_{A1206} | R⁴¹ | G¹⁴ | L_{A1207} | R⁴¹ | G¹⁵ | L_{A1208} | R⁴¹ | G¹⁶ |
| L_{A1209} | R⁴² | G¹³ | L_{A1210} | R⁴² | G¹⁴ | L_{A1211} | R⁴² | G¹⁵ | L_{A1212} | R⁴² | G¹⁶ |
| L_{A1213} | R⁴³ | G¹³ | L_{A1214} | R⁴³ | G¹⁴ | L_{A1215} | R⁴³ | G¹⁵ | L_{A1216} | R⁴³ | G¹⁶ |
| L_{A1217} | R⁴⁴ | G¹³ | L_{A1218} | R⁴⁴ | G¹⁴ | L_{A1219} | R⁴⁴ | G¹⁵ | L_{A1220} | R⁴⁴ | G¹⁶ |
| L_{A1221} | R⁴⁵ | G¹³ | L_{A1222} | R⁴⁵ | G¹⁴ | L_{A1223} | R⁴⁵ | G¹⁵ | L_{A1224} | R⁴⁵ | G¹⁶ |
| L_{A1225} | R⁴⁶ | G¹³ | L_{A1226} | R⁴⁶ | G¹⁴ | L_{A1227} | R⁴⁶ | G¹⁵ | L_{A1228} | R⁴⁶ | G¹⁶ |
| L_{A1229} | R⁴⁷ | G¹³ | L_{A1230} | R⁴⁷ | G¹⁴ | L_{A1231} | R⁴⁷ | G¹⁵ | L_{A1232} | R⁴⁷ | G¹⁶ |
| L_{A1233} | R⁴⁸ | G¹³ | L_{A1234} | R⁴⁸ | G¹⁴ | L_{A1235} | R⁴⁸ | G¹⁵ | L_{A1236} | R⁴⁸ | G¹⁶ |
| L_{A1237} | R⁴⁹ | G¹³ | L_{A1238} | R⁴⁹ | G¹⁴ | L_{A1239} | R⁴⁹ | G¹⁵ | L_{A1240} | R⁴⁹ | G¹⁶ |
| L_{A1241} | R⁵⁰ | G¹³ | L_{A1242} | R⁵⁰ | G¹⁴ | L_{A1243} | R⁵⁰ | G¹⁵ | L_{A1244} | R⁵⁰ | G¹⁶ |
| L_{A1245} | R⁵¹ | G¹³ | L_{A1246} | R⁵¹ | G¹⁴ | L_{A1247} | R⁵¹ | G¹⁵ | L_{A1248} | R⁵¹ | G¹⁶ |
| L_{A1249} | R⁵² | G¹³ | L_{A1250} | R⁵² | G¹⁴ | L_{A1251} | R⁵² | G¹⁵ | L_{A1252} | R⁵² | G¹⁶ |
| L_{A1253} | R⁵³ | G¹³ | L_{A1254} | R⁵³ | G¹⁴ | L_{A1255} | R⁵³ | G¹⁵ | L_{A1256} | R⁵³ | G¹⁶ |
| L_{A1257} | R⁵⁴ | G¹³ | L_{A1258} | R⁵⁴ | G¹⁴ | L_{A1259} | R⁵⁴ | G¹⁵ | L_{A1260} | R⁵⁴ | G¹⁶ |
| L_{A1261} | R⁵⁵ | G¹³ | L_{A1262} | R⁵⁵ | G¹⁴ | L_{A1263} | R⁵⁵ | G¹⁵ | L_{A1264} | R⁵⁵ | G¹⁶ |
| L_{A1265} | R⁵⁶ | G¹³ | L_{A1266} | R⁵⁶ | G¹⁴ | L_{A1267} | R⁵⁶ | G¹⁵ | L_{A1268} | R⁵⁶ | G¹⁶ |
| L_{A1269} | R⁵⁷ | G¹³ | L_{A1270} | R⁵⁷ | G¹⁴ | L_{A1271} | R⁵⁷ | G¹⁵ | L_{A1272} | R⁵⁷ | G¹⁶ |
| L_{A1273} | R⁵⁸ | G¹³ | L_{A1274} | R⁵⁸ | G¹⁴ | L_{A1275} | R⁵⁸ | G¹⁵ | L_{A1276} | R⁵⁸ | G¹⁶ |
| L_{A1277} | R⁵⁹ | G¹³ | L_{A1278} | R⁵⁹ | G¹⁴ | L_{A1279} | R⁵⁹ | G¹⁵ | L_{A1280} | R⁵⁹ | G¹⁶ |
| L_{A1281} | R⁶⁰ | G¹³ | L_{A1282} | R⁶⁰ | G¹⁴ | L_{A1283} | R⁶⁰ | G¹⁵ | L_{A1284} | R⁶⁰ | G¹⁶ |
| L_{A1285} | R⁶¹ | G¹³ | L_{A1286} | R⁶¹ | G¹⁴ | L_{A1287} | R⁶¹ | G¹⁵ | L_{A1288} | R⁶¹ | G¹⁶ |
| L_{A1289} | R⁶² | G¹³ | L_{A1290} | R⁶² | G¹⁴ | L_{A1291} | R⁶² | G¹⁵ | L_{A1292} | R⁶² | G¹⁶ |
| L_{A1293} | R⁶³ | G¹³ | L_{A1294} | R⁶³ | G¹⁴ | L_{A1295} | R⁶³ | G¹⁵ | L_{A1296} | R⁶³ | G¹⁶ |
| L_{A1297} | R⁶⁴ | G¹³ | L_{A1298} | R⁶⁴ | G¹⁴ | L_{A1299} | R⁶⁴ | G¹⁵ | L_{A1300} | R⁶⁴ | G¹⁶ |
| L_{A1301} | R⁶⁵ | G¹³ | L_{A1302} | R⁶⁵ | G¹⁴ | L_{A1303} | R⁶⁵ | G¹⁵ | L_{A1304} | R⁶⁵ | G¹⁶ |
| L_{A1305} | R⁶⁶ | G¹³ | L_{A1306} | R⁶⁶ | G¹⁴ | L_{A1307} | R⁶⁶ | G¹⁵ | L_{A1308} | R⁶⁶ | G¹⁶ |
| L_{A1309} | R⁶⁷ | G¹³ | L_{A1310} | R⁶⁷ | G¹⁴ | L_{A1311} | R⁶⁷ | G¹⁵ | L_{A1312} | R⁶⁷ | G¹⁶ |
| L_{A1313} | R⁶⁸ | G¹³ | L_{A1314} | R⁶⁸ | G¹⁴ | L_{A1315} | R⁶⁸ | G¹⁵ | L_{A1316} | R⁶⁸ | G¹⁶ |
| L_{A1317} | R⁶⁹ | G¹³ | L_{A1318} | R⁶⁹ | G¹⁴ | L_{A1319} | R⁶⁹ | G¹⁵ | L_{A1320} | R⁶⁹ | G¹⁶ |
| L_{A1321} | R⁷⁰ | G¹³ | L_{A1322} | R⁷⁰ | G¹⁴ | L_{A1323} | R⁷⁰ | G¹⁵ | L_{A1324} | R⁷⁰ | G¹⁶ |
| L_{A1325} | R⁷¹ | G¹³ | L_{A1326} | R⁷¹ | G¹⁴ | L_{A1327} | R⁷¹ | G¹⁵ | L_{A1328} | R⁷¹ | G¹⁶ |
| L_{A1329} | R⁷² | G¹³ | L_{A1330} | R⁷² | G¹⁴ | L_{A1331} | R⁷² | G¹⁵ | L_{A1332} | R⁷² | G¹⁶ |
| L_{A1333} | R⁷³ | G¹³ | L_{A1334} | R⁷³ | G¹⁴ | L_{A1335} | R⁷³ | G¹⁵ | L_{A1336} | R⁷³ | G¹⁶ |
| L_{A1337} | R⁷⁴ | G¹³ | L_{A1338} | R⁷⁴ | G¹⁴ | L_{A1339} | R⁷⁴ | G¹⁵ | L_{A1340} | R⁷⁴ | G¹⁶ |
| L_{A1341} | R⁷⁵ | G¹³ | L_{A1342} | R⁷⁵ | G¹⁴ | L_{A1343} | R⁷⁵ | G¹⁵ | L_{A1344} | R⁷⁶ | G¹⁶ |
| L_{A1345} | R⁷⁶ | G¹³ | L_{A1346} | R⁷⁶ | G¹⁴ | L_{A1347} | R⁷⁶ | G¹⁵ | L_{A1348} | R⁷⁶ | G¹⁶ |
| L_{A1349} | R⁷⁷ | G¹³ | L_{A1350} | R⁷⁷ | G¹⁴ | L_{A1351} | R⁷⁷ | G¹⁵ | L_{A1352} | R⁷⁷ | G¹⁶ |
| L_{A1353} | R⁷⁸ | G¹³ | L_{A1354} | R⁷⁸ | G¹⁴ | L_{A1355} | R⁷⁸ | G¹⁵ | L_{A1356} | R⁷⁸ | G¹⁶ |
| L_{A1357} | R⁷⁹ | G¹³ | L_{A1358} | R⁷⁹ | G¹⁴ | L_{A1359} | R⁷⁹ | G¹⁵ | L_{A1360} | R⁷⁹ | G¹⁶ |
| L_{A1361} | R⁸⁰ | G¹³ | L_{A1362} | R⁸⁰ | G¹⁴ | L_{A1363} | R⁸⁰ | G¹⁵ | L_{A1364} | R⁸⁰ | G¹⁶ |
| L_{A1365} | R⁸¹ | G¹³ | L_{A1366} | R⁸¹ | G¹⁴ | L_{A1367} | R⁸¹ | G¹⁵ | L_{A1368} | R⁸¹ | G¹⁶ |
| L_{A1369} | R⁸² | G¹³ | L_{A1370} | R⁸² | G¹⁴ | L_{A1371} | R⁸² | G¹⁵ | L_{A1372} | R⁸² | G¹⁶ |
| L_{A1373} | R⁸³ | G¹³ | L_{A1374} | R⁸³ | G¹⁴ | L_{A1375} | R⁸³ | G¹⁵ | L_{A1376} | R⁸³ | G¹⁶ |
| L_{A1377} | R⁸⁴ | G¹³ | L_{A1378} | R⁸⁴ | G¹⁴ | L_{A1379} | R⁸⁴ | G¹⁵ | L_{A1380} | R⁸⁴ | G¹⁶ |
| L_{A1381} | R⁸⁵ | G¹³ | L_{A1382} | R⁸⁵ | G¹⁴ | L_{A1383} | R⁸⁵ | G¹⁵ | L_{A1384} | R⁸⁵ | G¹⁶ |
| L_{A1385} | R⁸⁶ | G¹³ | L_{A1386} | R⁸⁶ | G¹⁴ | L_{A1387} | R⁸⁶ | G¹⁵ | L_{A1388} | R⁸⁶ | G¹⁶ |
| L_{A1389} | R⁸⁷ | G¹³ | L_{A1390} | R⁸⁷ | G¹⁴ | L_{A1391} | R⁸⁷ | G¹⁵ | L_{A1392} | R⁸⁷ | G¹⁶ |
| L_{A1393} | R¹ | G¹⁷ | L_{A1394} | R¹ | G¹⁸ | L_{A1395} | R¹ | G¹⁹ | L_{A1396} | R¹ | G²⁰ |
| L_{A1397} | R² | G¹⁷ | L_{A1398} | R² | G¹⁸ | L_{A1399} | R² | G¹⁹ | L_{A1400} | R² | G²⁰ |
| L_{A1401} | R³ | G¹⁷ | L_{A1402} | R³ | G¹⁸ | L_{A1403} | R³ | G¹⁹ | L_{A1404} | R³ | G²⁰ |
| L_{A1405} | R⁴ | G¹⁷ | L_{A1406} | R⁴ | G¹⁸ | L_{A1407} | R⁴ | G¹⁹ | L_{A1408} | R⁴ | G²⁰ |
| L_{A1409} | R⁵ | G¹⁷ | L_{A1410} | R⁵ | G¹⁸ | L_{A1411} | R⁵ | G¹⁹ | L_{A1412} | R⁵ | G²⁰ |
| L_{A1413} | R⁶ | G¹⁷ | L_{A1414} | R⁶ | G¹⁸ | L_{A1415} | R⁶ | G¹⁹ | L_{A1416} | R⁶ | G²⁰ |
| L_{A1417} | R⁷ | G¹⁷ | L_{A1418} | R⁷ | G¹⁸ | L_{A1419} | R⁷ | G¹⁹ | L_{A1420} | R⁷ | G²⁰ |
| L_{A1421} | R⁸ | G¹⁷ | L_{A1422} | R⁸ | G¹⁸ | L_{A1423} | R⁸ | G¹⁹ | L_{A1424} | R⁸ | G²⁰ |
| L_{A1425} | R⁹ | G¹⁷ | L_{A1426} | R⁹ | G¹⁸ | L_{A1427} | R⁹ | G¹⁹ | L_{A1428} | R⁹ | G²⁰ |
| L_{A1429} | R¹⁰ | G¹⁷ | L_{A1430} | R¹⁰ | G¹⁸ | L_{A1431} | R¹⁰ | G¹⁹ | L_{A1432} | R¹⁰ | G²⁰ |
| L_{A1433} | R¹¹ | G¹⁷ | L_{A1434} | R¹¹ | G¹⁸ | L_{A1435} | R¹¹ | G¹⁹ | L_{A1436} | R¹¹ | G²⁰ |
| L_{A1437} | R¹² | G¹⁷ | L_{A1438} | R¹² | G¹⁸ | L_{A1439} | R¹² | G¹⁹ | L_{A1440} | R¹² | G²⁰ |
| L_{A1441} | R¹³ | G¹⁷ | L_{A1442} | R¹³ | G¹⁸ | L_{A1443} | R¹³ | G¹⁹ | L_{A1444} | R¹³ | G²⁰ |
| L_{A1445} | R¹⁴ | G¹⁷ | L_{A1446} | R¹⁴ | G¹⁸ | L_{A1447} | R¹⁴ | G¹⁹ | L_{A1448} | R¹⁴ | G²⁰ |
| L_{A1449} | R¹⁵ | G¹⁷ | L_{A1450} | R¹⁵ | G¹⁸ | L_{A1451} | R¹⁵ | G¹⁹ | L_{A1452} | R¹⁵ | G²⁰ |
| L_{A1453} | R¹⁶ | G¹⁷ | L_{A1454} | R¹⁶ | G¹⁸ | L_{A1455} | R¹⁶ | G¹⁹ | L_{A1456} | R¹⁶ | G²⁰ |
| L_{A1457} | R¹⁷ | G¹⁷ | L_{A1458} | R¹⁷ | G¹⁸ | L_{A1459} | R¹⁷ | G¹⁹ | L_{A1460} | R¹⁷ | G²⁰ |
| L_{A1461} | R¹⁸ | G¹⁷ | L_{A1462} | R¹⁸ | G¹⁸ | L_{A1463} | R¹⁸ | G¹⁹ | L_{A1464} | R¹⁸ | G²⁰ |
| L_{A1465} | R¹⁹ | G¹⁷ | L_{A1466} | R¹⁹ | G¹⁸ | L_{A1467} | R¹⁹ | G¹⁹ | L_{A1468} | R¹⁹ | G²⁰ |
| L_{A1469} | R²⁰ | G¹⁷ | L_{A1470} | R²⁰ | G¹⁸ | L_{A1471} | R²⁰ | G¹⁹ | L_{A1472} | R²⁰ | G²⁰ |
| L_{A1473} | R²¹ | G¹⁷ | L_{A1474} | R²¹ | G¹⁸ | L_{A1475} | R²¹ | G¹⁹ | L_{A1476} | R²¹ | G²⁰ |
| L_{A1477} | R²² | G¹⁷ | L_{A1478} | R²² | G¹⁸ | L_{A1479} | R²² | G¹⁹ | L_{A1480} | R²² | G²⁰ |
| L_{A1481} | R²³ | G¹⁷ | L_{A1482} | R²³ | G¹⁸ | L_{A1483} | R²³ | G¹⁹ | L_{A1484} | R²³ | G²⁰ |
| L_{A1485} | R²⁴ | G¹⁷ | L_{A1486} | R²⁴ | G¹⁸ | L_{A1487} | R²⁴ | G¹⁹ | L_{A1488} | R²⁴ | G²⁰ |
| L_{A1489} | R²⁵ | G¹⁷ | L_{A1490} | R²⁵ | G¹⁸ | L_{A1491} | R²⁵ | G¹⁹ | L_{A1492} | R²⁵ | G²⁰ |
| L_{A1493} | R²⁶ | G¹⁷ | L_{A1494} | R²⁶ | G¹⁸ | L_{A1495} | R²⁶ | G¹⁹ | L_{A1496} | R²⁶ | G²⁰ |
| L_{A1497} | R²⁷ | G¹⁷ | L_{A1498} | R²⁷ | G¹⁸ | L_{A1499} | R²⁷ | G¹⁹ | L_{A1500} | R²⁷ | G²⁰ |
| L_{A1501} | R²⁸ | G¹⁷ | L_{A1502} | R²⁸ | G¹⁸ | L_{A1503} | R²⁸ | G¹⁹ | L_{A1504} | R²⁸ | G²⁰ |
| L_{A1505} | R²⁹ | G¹⁷ | L_{A1506} | R²⁹ | G¹⁸ | L_{A1507} | R²⁹ | G¹⁹ | L_{A1508} | R²⁹ | G²⁰ |
| L_{A1509} | R³⁰ | G¹⁷ | L_{A1510} | R³⁰ | G¹⁸ | L_{A1511} | R³⁰ | G¹⁹ | L_{A1512} | R³⁰ | G²⁰ |
| L_{A1513} | R³¹ | G¹⁷ | L_{A1514} | R³¹ | G¹⁸ | L_{A1515} | R³¹ | G¹⁹ | L_{A1516} | R³¹ | G²⁰ |
| L_{A1517} | R³² | G¹⁷ | L_{A1518} | R³² | G¹⁸ | L_{A1519} | R³² | G¹⁹ | L_{A1520} | R³² | G²⁰ |
| L_{A1521} | R³³ | G¹⁷ | L_{A1522} | R³³ | G¹⁸ | L_{A1523} | R³³ | G¹⁹ | L_{A1524} | R³³ | G²⁰ |
| L_{A1525} | R³⁴ | G¹⁷ | L_{A1526} | R³⁴ | G¹⁸ | L_{A1527} | R³⁴ | G¹⁹ | L_{A1528} | R³⁴ | G²⁰ |
| L_{A1529} | R³⁵ | G¹⁷ | L_{A1530} | R³⁵ | G¹⁸ | L_{A1531} | R³⁵ | G¹⁹ | L_{A1532} | R³⁵ | G²⁰ |
| L_{A1533} | R³⁶ | G¹⁷ | L_{A1534} | R³⁶ | G¹⁸ | L_{A1535} | R³⁶ | G¹⁹ | L_{A1536} | R³⁶ | G²⁰ |
| L_{A1537} | R³⁷ | G¹⁷ | L_{A1538} | R³⁷ | G¹⁸ | L_{A1539} | R³⁷ | G¹⁹ | L_{A1540} | R³⁷ | G²⁰ |
| L_{A1541} | R³⁸ | G¹⁷ | L_{A1542} | R³⁸ | G¹⁸ | L_{A1543} | R³⁸ | G¹⁹ | L_{A1544} | R³⁸ | G²⁰ |
| L_{A1545} | R³⁹ | G¹⁷ | L_{A1546} | R³⁹ | G¹⁸ | L_{A1547} | R³⁹ | G¹⁹ | L_{A1548} | R³⁹ | G²⁰ |
| L_{A1549} | R⁴⁰ | G¹⁷ | L_{A1550} | R⁴⁰ | G¹⁸ | L_{A1551} | R⁴⁰ | G¹⁹ | L_{A1552} | R⁴⁰ | G²⁰ |
| L_{A1553} | R⁴¹ | G¹⁷ | L_{A1554} | R⁴¹ | G¹⁸ | L_{A1555} | R⁴¹ | G¹⁹ | L_{A1556} | R⁴¹ | G²⁰ |
| L_{A1557} | R⁴² | G¹⁷ | L_{A1558} | R⁴² | G¹⁸ | L_{A1559} | R⁴² | G¹⁹ | L_{A1560} | R⁴² | G²⁰ |
| L_{A1561} | R⁴³ | G¹⁷ | L_{A1562} | R⁴³ | G¹⁸ | L_{A1563} | R⁴³ | G¹⁹ | L_{A1564} | R⁴³ | G²⁰ |
| L_{A1565} | R⁴⁴ | G¹⁷ | L_{A1566} | R⁴⁴ | G¹⁸ | L_{A1567} | R⁴⁴ | G¹⁹ | L_{A1568} | R⁴⁴ | G²⁰ |
| L_{A1569} | R⁴⁵ | G¹⁷ | L_{A1570} | R⁴⁵ | G¹⁸ | L_{A1571} | R⁴⁵ | G¹⁹ | L_{A1572} | R⁴⁵ | G²⁰ |
| L_{A1573} | R⁴⁶ | G¹⁷ | L_{A1574} | R⁴⁶ | G¹⁸ | L_{A1575} | R⁴⁶ | G¹⁹ | L_{A1576} | R⁴⁶ | G²⁰ |
| L_{A1577} | R⁴⁷ | G¹⁷ | L_{A1578} | R⁴⁷ | G¹⁸ | L_{A1579} | R⁴⁷ | G¹⁹ | L_{A1580} | R⁴⁷ | G²⁰ |
| L_{A1581} | R⁴⁸ | G¹⁷ | L_{A1582} | R⁴⁸ | G¹⁸ | L_{A1583} | R⁴⁸ | G¹⁹ | L_{A1584} | R⁴⁸ | G²⁰ |
| L_{A1585} | R⁴⁹ | G¹⁷ | L_{A1586} | R⁴⁹ | G¹⁸ | L_{A1587} | R⁴⁹ | G¹⁹ | L_{A1588} | R⁴⁹ | G²⁰ |
| L_{A1589} | R⁵⁰ | G¹⁷ | L_{A1590} | R⁵⁰ | G¹⁸ | L_{A1591} | R⁵⁰ | G¹⁹ | L_{A1592} | R⁵⁰ | G²⁰ |
| L_{A1593} | R⁵¹ | G¹⁷ | L_{A1594} | R⁵¹ | G¹⁸ | L_{A1595} | R⁵¹ | G¹⁹ | L_{A1596} | R⁵¹ | G²⁰ |
| L_{A1597} | R⁵² | G¹⁷ | L_{A1598} | R⁵² | G¹⁸ | L_{A1599} | R⁵² | G¹⁹ | L_{A1600} | R⁵² | G²⁰ |
| L_{A1601} | R⁵³ | G¹⁷ | L_{A1602} | R⁵³ | G¹⁸ | L_{A1603} | R⁵³ | G¹⁹ | L_{A1604} | R⁵³ | G²⁰ |
| L_{A1605} | R⁵⁴ | G¹⁷ | L_{A1606} | R⁵⁴ | G¹⁸ | L_{A1607} | R⁵⁴ | G¹⁹ | L_{A1608} | R⁵⁴ | G²⁰ |
| L_{A1609} | R⁵⁵ | G¹⁷ | L_{A1610} | R⁵⁵ | G¹⁸ | L_{A1611} | R⁵⁵ | G¹⁹ | L_{A1612} | R⁵⁵ | G²⁰ |
| L_{A1613} | R⁵⁶ | G¹⁷ | L_{A1614} | R⁵⁶ | G¹⁸ | L_{A1615} | R⁵⁶ | G¹⁹ | L_{A1616} | R⁵⁶ | G²⁰ |
| L_{A1617} | R⁵⁷ | G¹⁷ | L_{A1618} | R⁵⁷ | G¹⁸ | L_{A1619} | R⁵⁷ | G¹⁹ | L_{A1620} | R⁵⁷ | G²⁰ |
| L_{A1621} | R⁵⁸ | G¹⁷ | L_{A1622} | R⁵⁸ | G¹⁸ | L_{A1623} | R⁵⁸ | G¹⁹ | L_{A1624} | R⁵⁸ | G²⁰ |
| L_{A1625} | R⁵⁹ | G¹⁷ | L_{A1626} | R⁵⁹ | G¹⁸ | L_{A1627} | R⁵⁹ | G¹⁹ | L_{A1628} | R⁵⁹ | G²⁰ |
| L_{A1629} | R⁶⁰ | G¹⁷ | L_{A1630} | R⁶⁰ | G¹⁸ | L_{A1631} | R⁶⁰ | G¹⁹ | L_{A1632} | R⁶⁰ | G²⁰ |
| L_{A1633} | R⁶¹ | G¹⁷ | L_{A1634} | R⁶¹ | G¹⁸ | L_{A1635} | R⁶¹ | G¹⁹ | L_{A1636} | R⁶¹ | G²⁰ |
| L_{A1637} | R⁶² | G¹⁷ | L_{A1638} | R⁶² | G¹⁸ | L_{A1639} | R⁶² | G¹⁹ | L_{A1640} | R⁶² | G²⁰ |
| L_{A1641} | R⁶³ | G¹⁷ | L_{A1642} | R⁶³ | G¹⁸ | L_{A1643} | R⁶³ | G¹⁹ | L_{A1644} | R⁶³ | G²⁰ |
| L_{A1645} | R⁶⁴ | G¹⁷ | L_{A1646} | R⁶⁴ | G¹⁸ | L_{A1647} | R⁶⁴ | G¹⁹ | L_{A1648} | R⁶⁴ | G²⁰ |
| L_{A1649} | R⁶⁵ | G¹⁷ | L_{A1650} | R⁶⁵ | G¹⁸ | L_{A1651} | R⁶⁵ | G¹⁹ | L_{A1652} | R⁶⁵ | G²⁰ |
| L_{A1653} | R⁶⁶ | G¹⁷ | L_{A1654} | R⁶⁶ | G¹⁸ | L_{A1655} | R⁶⁶ | G¹⁹ | L_{A1656} | R⁶⁶ | G²⁰ |
| L_{A1657} | R⁶⁷ | G¹⁷ | L_{A1658} | R⁶⁷ | G¹⁸ | L_{A1659} | R⁶⁷ | G¹⁹ | L_{A1660} | R⁶⁷ | G²⁰ |
| L_{A1661} | R⁶⁸ | G¹⁷ | L_{A1662} | R⁶⁸ | G¹⁸ | L_{A1663} | R⁶⁸ | G¹⁹ | L_{A1664} | R⁶⁸ | G²⁰ |
| L_{A1665} | R⁶⁹ | G¹⁷ | L_{A1666} | R⁶⁹ | G¹⁸ | L_{A1667} | R⁶⁹ | G¹⁹ | L_{A1668} | R⁶⁹ | G²⁰ |
| L_{A1669} | R⁷⁰ | G¹⁷ | L_{A1670} | R⁷⁰ | G¹⁸ | L_{A1671} | R⁷⁰ | G¹⁹ | L_{A1672} | R⁷⁰ | G²⁰ |
| L_{A1673} | R⁷¹ | G¹⁷ | L_{A1674} | R⁷¹ | G¹⁸ | L_{A1675} | R⁷¹ | G¹⁹ | L_{A1676} | R⁷¹ | G²⁰ |
| L_{A1677} | R⁷² | G¹⁷ | L_{A1678} | R⁷² | G¹⁸ | L_{A1679} | R⁷² | G¹⁹ | L_{A1680} | R⁷² | G²⁰ |
| L_{A1681} | R⁷³ | G¹⁷ | L_{A1682} | R⁷³ | G¹⁸ | L_{A1683} | R⁷³ | G¹⁹ | L_{A1684} | R⁷³ | G²⁰ |
| L_{A1685} | R⁷⁴ | G¹⁷ | L_{A1686} | R⁷⁴ | G¹⁸ | L_{A1687} | R⁷⁴ | G¹⁹ | L_{A1688} | R⁷⁴ | G²⁰ |
| L_{A1689} | R⁷⁵ | G¹⁷ | L_{A1690} | R⁷⁵ | G¹⁸ | L_{A1691} | R⁷⁵ | G¹⁹ | L_{A1692} | R⁷⁵ | G²⁰ |
| L_{A1693} | R⁷⁶ | G¹⁷ | L_{A1694} | R⁷⁶ | G¹⁸ | L_{A1695} | R⁷⁶ | G¹⁹ | L_{A1696} | R⁷⁶ | G²⁰ |
| L_{A1697} | R⁷⁷ | G¹⁷ | L_{A1698} | R⁷⁷ | G¹⁸ | L_{A1699} | R⁷⁷ | G¹⁹ | L_{A1700} | R⁷⁷ | G²⁰ |
| L_{A1701} | R⁷⁸ | G¹⁷ | L_{A1702} | R⁷⁸ | G¹⁸ | L_{A1703} | R⁷⁸ | G¹⁹ | L_{A1704} | R⁷⁸ | G²⁰ |
| L_{A1705} | R⁷⁹ | G¹⁷ | L_{A1706} | R⁷⁹ | G¹⁸ | L_{A1707} | R⁷⁹ | G¹⁹ | L_{A1708} | R⁷⁹ | G²⁰ |
| L_{A1709} | R⁸⁰ | G¹⁷ | L_{A1710} | R⁸⁰ | G¹⁸ | L_{A1711} | R⁸⁰ | G¹⁹ | L_{A1712} | R⁸⁰ | G²⁰ |
| L_{A1713} | R⁸¹ | G¹⁷ | L_{A1714} | R⁸¹ | G¹⁸ | L_{A1715} | R⁸¹ | G¹⁹ | L_{A1716} | R⁸¹ | G²⁰ |
| L_{A1717} | R⁸² | G¹⁷ | L_{A1718} | R⁸² | G¹⁸ | L_{A1719} | R⁸² | G¹⁹ | L_{A1720} | R⁸² | G²⁰ |
| L_{A1721} | R⁸³ | G¹⁷ | L_{A1722} | R⁸³ | G¹⁸ | L_{A1723} | R⁸³ | G¹⁹ | L_{A1724} | R⁸³ | G²⁰ |
| L_{A1725} | R⁸⁴ | G¹⁷ | L_{A1726} | R⁸⁴ | G¹⁸ | L_{A1727} | R⁸⁴ | G¹⁹ | L_{A1728} | R⁸⁴ | G²⁰ |
| L_{A1729} | R⁸⁵ | G¹⁷ | L_{A1730} | R⁸⁵ | G¹⁸ | L_{A1731} | R⁸⁵ | G¹⁹ | L_{A1732} | R⁸⁵ | G²⁰ |
| L_{A1733} | R⁸⁶ | G¹⁷ | L_{A1734} | R⁸⁶ | G¹⁸ | L_{A1735} | R⁸⁶ | G¹⁹ | L_{A1736} | R⁸⁶ | G²⁰ |
| L_{A1737} | R⁸⁷ | G¹⁷ | L_{A1738} | R⁸⁷ | G¹⁸ | L_{A1739} | R⁸⁷ | G¹⁹ | L_{A1740} | R⁸⁷ | G²⁰ |
| L_{A1741} | R¹ | G²¹ | L_{A1742} | R¹ | G²² | L_{A1743} | R¹ | G²³ | L_{A1744} | R¹ | G²⁴ |
| L_{A1745} | R² | G²¹ | L_{A1746} | R² | G²² | L_{A1747} | R² | G²³ | L_{A1748} | R² | G²⁴ |
| L_{A1749} | R³ | G²¹ | L_{A1750} | R³ | G²² | L_{A1751} | R³ | G²³ | L_{A1752} | R³ | G²⁴ |
| L_{A1753} | R⁴ | G²¹ | L_{A1754} | R⁴ | G²² | L_{A1755} | R⁴ | G²³ | L_{A1756} | R⁴ | G²⁴ |
| L_{A1757} | R⁵ | G²¹ | L_{A1758} | R⁵ | G²² | L_{A1759} | R⁵ | G²³ | L_{A1760} | R⁵ | G²⁴ |
| L_{A1761} | R⁶ | G²¹ | L_{A1762} | R⁶ | G²² | L_{A1763} | R⁶ | G²³ | L_{A1764} | R⁶ | G²⁴ |
| L_{A1765} | R⁷ | G²¹ | L_{A1766} | R⁷ | G²² | L_{A1767} | R⁷ | G²³ | L_{A1768} | R⁷ | G²⁴ |
| L_{A1769} | R⁸ | G²¹ | L_{A1770} | R⁸ | G²² | L_{A1771} | R⁸ | G²³ | L_{A1772} | R⁸ | G²⁴ |
| L_{A1773} | R⁹ | G²¹ | L_{A1774} | R⁹ | G²² | L_{A1775} | R⁹ | G²³ | L_{A1776} | R⁹ | G²⁴ |
| L_{A1777} | R¹⁰ | G²¹ | L_{A1778} | R¹⁰ | G²² | L_{A1779} | R¹⁰ | G²³ | L_{A1780} | R¹⁰ | G²⁴ |
| L_{A1781} | R¹¹ | G²¹ | L_{A1782} | R¹¹ | G²² | L_{A1783} | R¹¹ | G²³ | L_{A1784} | R¹¹ | G²⁴ |
| L_{A1785} | R¹² | G²¹ | L_{A1786} | R¹² | G²² | L_{A1787} | R¹² | G²³ | L_{A1788} | R¹² | G²⁴ |
| L_{A1789} | R¹³ | G²¹ | L_{A1790} | R¹³ | G²² | L_{A1791} | R¹³ | G²³ | L_{A1792} | R¹³ | G²⁴ |
| L_{A1793} | R¹⁴ | G²¹ | L_{A1794} | R¹⁴ | G²² | L_{A1795} | R¹⁴ | G²³ | L_{A1796} | R¹⁴ | G²⁴ |
| L_{A1797} | R¹⁵ | G²¹ | L_{A1798} | R¹⁵ | G²² | L_{A1799} | R¹⁵ | G²³ | L_{A1800} | R¹⁵ | G²⁴ |
| L_{A1801} | R¹⁶ | G²¹ | L_{A1802} | R¹⁶ | G²² | L_{A1803} | R¹⁶ | G²³ | L_{A1804} | R¹⁶ | G²⁴ |
| L_{A1805} | R¹⁷ | G²¹ | L_{A1806} | R¹⁷ | G²² | L_{A1807} | R¹⁷ | G²³ | L_{A1808} | R¹⁷ | G²⁴ |
| L_{A1809} | R¹⁸ | G²¹ | L_{A1810} | R¹⁸ | G²² | L_{A1811} | R¹⁸ | G²³ | L_{A1812} | R¹⁸ | G²⁴ |
| L_{A1813} | R¹⁹ | G²¹ | L_{A1814} | R¹⁹ | G²² | L_{A1815} | R¹⁹ | G²³ | L_{A1816} | R¹⁹ | G²⁴ |
| L_{A1817} | R²⁰ | G²¹ | L_{A1818} | R²⁰ | G²² | L_{A1819} | R²⁰ | G²³ | L_{A1820} | R²⁰ | G²⁴ |
| L_{A1821} | R²¹ | G²¹ | L_{A1822} | R²¹ | G²² | L_{A1823} | R²¹ | G²³ | L_{A1824} | R²¹ | G²⁴ |
| L_{A1825} | R²² | G²¹ | L_{A1826} | R²² | G²² | L_{A1827} | R²² | G²³ | L_{A1828} | R²² | G²⁴ |
| L_{A1829} | R²³ | G²¹ | L_{A1830} | R²³ | G²² | L_{A1831} | R²³ | G²³ | L_{A1832} | R²³ | G²⁴ |
| L_{A1833} | R²⁴ | G²¹ | L_{A1834} | R²⁴ | G²² | L_{A1835} | R²⁴ | G²³ | L_{A1836} | R²⁴ | G²⁴ |
| L_{A1837} | R²⁵ | G²¹ | L_{A1838} | R²⁵ | G²² | L_{A1839} | R²⁵ | G²³ | L_{A1840} | R²⁵ | G²⁴ |
| L_{A1841} | R²⁶ | G²¹ | L_{A1842} | R²⁶ | G²² | L_{A1843} | R²⁶ | G²³ | L_{A1844} | R²⁶ | G²⁴ |
| L_{A1845} | R²⁷ | G²¹ | L_{A1846} | R²⁷ | G²² | L_{A1847} | R²⁷ | G²³ | L_{A1848} | R²⁷ | G²⁴ |
| L_{A1849} | R²⁸ | G²¹ | L_{A1850} | R²⁸ | G²² | L_{A1851} | R²⁸ | G²³ | L_{A1852} | R²⁸ | G²⁴ |
| L_{A1853} | R²⁹ | G²¹ | L_{A1854} | R²⁹ | G²² | L_{A1855} | R²⁹ | G²³ | L_{A1856} | R²⁹ | G²⁴ |
| L_{A1857} | R³⁰ | G²¹ | L_{A1858} | R³⁰ | G²² | L_{A1859} | R³⁰ | G²³ | L_{A1860} | R³⁰ | G²⁴ |
| L_{A1861} | R³¹ | G²¹ | L_{A1862} | R³¹ | G²² | L_{A1863} | R³¹ | G²³ | L_{A1864} | R³¹ | G²⁴ |
| L_{A1865} | R³² | G²¹ | L_{A1866} | R³² | G²² | L_{A1867} | R³² | G²³ | L_{A1868} | R³² | G²⁴ |
| L_{A1869} | R³³ | G²¹ | L_{A1870} | R³³ | G²² | L_{A1871} | R³³ | G²³ | L_{A1872} | R³³ | G²⁴ |
| L_{A1873} | R³⁴ | G²¹ | L_{A1874} | R³⁴ | G²² | L_{A1875} | R³⁴ | G²³ | L_{A1876} | R³⁴ | G²⁴ |
| L_{A1877} | R³⁵ | G²¹ | L_{A1878} | R³⁵ | G²² | L_{A1879} | R³⁵ | G²³ | L_{A1880} | R³⁵ | G²⁴ |
| L_{A1881} | R³⁶ | G²¹ | L_{A1882} | R³⁶ | G²² | L_{A1883} | R³⁶ | G²³ | L_{A1884} | R³⁶ | G²⁴ |
| L_{A1885} | R³⁷ | G²¹ | L_{A1886} | R³⁷ | G²² | L_{A1887} | R³⁷ | G²³ | L_{A1888} | R³⁷ | G²⁴ |
| L_{A1889} | R³⁸ | G²¹ | L_{A1890} | R³⁸ | G²² | L_{A1891} | R³⁸ | G²³ | L_{A1892} | R³⁸ | G²⁴ |
| L_{A1893} | R³⁹ | G²¹ | L_{A1894} | R³⁹ | G²² | L_{A1895} | R³⁹ | G²³ | L_{A1896} | R³⁹ | G²⁴ |
| L_{A1897} | R⁴⁰ | G²¹ | L_{A1898} | R⁴⁰ | G²² | L_{A1899} | R⁴⁰ | G²³ | L_{A1900} | R⁴⁰ | G²⁴ |
| L_{A1901} | R⁴¹ | G²¹ | L_{A1902} | R⁴¹ | G²² | L_{A1903} | R⁴¹ | G²³ | L_{A1904} | R⁴¹ | G²⁴ |
| L_{A1905} | R⁴² | G²¹ | L_{A1906} | R⁴² | G²² | L_{A1907} | R⁴² | G²³ | L_{A1908} | R⁴² | G²⁴ |
| L_{A1909} | R⁴³ | G²¹ | L_{A1910} | R⁴³ | G²² | L_{A1911} | R⁴³ | G²³ | L_{A1912} | R⁴³ | G²⁴ |
| L_{A1913} | R⁴⁴ | G²¹ | L_{A1914} | R⁴⁴ | G²² | L_{A1915} | R⁴⁴ | G²³ | L_{A1916} | R⁴⁴ | G²⁴ |
| L_{A1917} | R⁴⁵ | G²¹ | L_{A1918} | R⁴⁵ | G²² | L_{A1919} | R⁴⁵ | G²³ | L_{A1920} | R⁴⁵ | G²⁴ |
| L_{A1921} | R⁴⁶ | G²¹ | L_{A1922} | R⁴⁶ | G²² | L_{A1923} | R⁴⁶ | G²³ | L_{A1924} | R⁴⁶ | G²⁴ |
| L_{A1925} | R⁴⁷ | G²¹ | L_{A1926} | R⁴⁷ | G²² | L_{A1927} | R⁴⁷ | G²³ | L_{A1928} | R⁴⁷ | G²⁴ |
| L_{A1929} | R⁴⁸ | G²¹ | L_{A1930} | R⁴⁸ | G²² | L_{A1931} | R⁴⁸ | G²³ | L_{A1932} | R⁴⁸ | G²⁴ |
| L_{A1933} | R⁴⁹ | G²¹ | L_{A1934} | R⁴⁹ | G²² | L_{A1935} | R⁴⁹ | G²³ | L_{A1936} | R⁴⁹ | G²⁴ |
| L_{A1937} | R⁵⁰ | G²¹ | L_{A1938} | R⁵⁰ | G²² | L_{A1939} | R⁵⁰ | G²³ | L_{A1940} | R⁵⁰ | G²⁴ |
| L_{A1941} | R⁵¹ | G²¹ | L_{A1942} | R⁵¹ | G²² | L_{A1943} | R⁵¹ | G²³ | L_{A1944} | R⁵¹ | G²⁴ |
| L_{A1945} | R⁵² | G²¹ | L_{A1946} | R⁵² | G²² | L_{A1947} | R⁵² | G²³ | L_{A1948} | R⁵² | G²⁴ |
| L_{A1949} | R⁵³ | G²¹ | L_{A1950} | R⁵³ | G²² | L_{A1951} | R⁵³ | G²³ | L_{A1952} | R⁵³ | G²⁴ |
| L_{A1953} | R⁵⁴ | G²¹ | L_{A1954} | R⁵⁴ | G²² | L_{A1955} | R⁵⁴ | G²³ | L_{A1956} | R⁵⁴ | G²⁴ |
| L_{A1957} | R⁵⁵ | G²¹ | L_{A1958} | R⁵⁵ | G²² | L_{A1959} | R⁵⁵ | G²³ | L_{A1960} | R⁵⁵ | G²⁴ |
| L_{A1961} | R⁵⁶ | G²¹ | L_{A1962} | R⁵⁶ | G²² | L_{A1963} | R⁵⁶ | G²³ | L_{A1964} | R⁵⁶ | G²⁴ |
| L_{A1965} | R⁵⁷ | G²¹ | L_{A1966} | R⁵⁷ | G²² | L_{A1967} | R⁵⁷ | G²³ | L_{A1968} | R⁵⁷ | G²⁴ |
| L_{A1969} | R⁵⁸ | G²¹ | L_{A1970} | R⁵⁸ | G²² | L_{A1971} | R⁵⁸ | G²³ | L_{A1972} | R⁵⁸ | G²⁴ |
| L_{A1973} | R⁵⁹ | G²¹ | L_{A1974} | R⁵⁹ | G²² | L_{A1975} | R⁵⁹ | G²³ | L_{A1976} | R⁵⁹ | G²⁴ |
| L_{A1977} | R⁶⁰ | G²¹ | L_{A1978} | R⁶⁰ | G²² | L_{A1979} | R⁶⁰ | G²³ | L_{A1980} | R⁶⁰ | G²⁴ |
| L_{A1981} | R⁶¹ | G²¹ | L_{A1982} | R⁶¹ | G²² | L_{A1983} | R⁶¹ | G²³ | L_{A1984} | R⁶¹ | G²⁴ |
| L_{A1985} | R⁶² | G²¹ | L_{A1986} | R⁶² | G²² | L_{A1987} | R⁶² | G²³ | L_{A1988} | R⁶² | G²⁴ |
| L_{A1989} | R⁶³ | G²¹ | L_{A1990} | R⁶³ | G²² | L_{A1991} | R⁶³ | G²³ | L_{A1992} | R⁶³ | G²⁴ |
| L_{A1993} | R⁶⁴ | G²¹ | L_{A1994} | R⁶⁴ | G²² | L_{A1995} | R⁶⁴ | G²³ | L_{A1996} | R⁶⁴ | G²⁴ |
| L_{A1997} | R⁶⁵ | G²¹ | L_{A1998} | R⁶⁵ | G²² | L_{A1999} | R⁶⁵ | G²³ | L_{A2000} | R⁶⁵ | G²⁴ |
| L_{A2001} | R⁶⁶ | G²¹ | L_{A2002} | R⁶⁶ | G²² | L_{A2003} | R⁶⁶ | G²³ | L_{A2004} | R⁶⁶ | G²⁴ |
| L_{A2005} | R⁶⁷ | G²¹ | L_{A2006} | R⁶⁷ | G²² | L_{A2007} | R⁶⁷ | G²³ | L_{A2008} | R⁶⁷ | G²⁴ |
| L_{A2009} | R⁶⁸ | G²¹ | L_{A2010} | R⁶⁸ | G²² | L_{A2011} | R⁶⁸ | G²³ | L_{A2012} | R⁶⁸ | G²⁴ |
| L_{A2013} | R⁶⁹ | G²¹ | L_{A2014} | R⁶⁹ | G²² | L_{A2015} | R⁶⁹ | G²³ | L_{A2016} | R⁶⁹ | G²⁴ |
| L_{A2017} | R⁷⁰ | G²¹ | L_{A2018} | R⁷⁰ | G²² | L_{A2019} | R⁷⁰ | G²³ | L_{A2020} | R⁷⁰ | G²⁴ |
| L_{A2021} | R⁷¹ | G²¹ | L_{A2022} | R⁷¹ | G²² | L_{A2023} | R⁷¹ | G²³ | L_{A2024} | R⁷¹ | G²⁴ |
| L_{A2025} | R⁷² | G²¹ | L_{A2026} | R⁷² | G²² | L_{A2027} | R⁷² | G²³ | L_{A2028} | R⁷² | G²⁴ |
| L_{A2029} | R⁷³ | G²¹ | L_{A2030} | R⁷³ | G²² | L_{A2031} | R⁷³ | G²³ | L_{A2032} | R⁷³ | G²⁴ |
| L_{A2033} | R⁷⁴ | G²¹ | L_{A2034} | R⁷⁴ | G²² | L_{A2035} | R⁷⁴ | G²³ | L_{A2036} | R⁷⁴ | G²⁴ |
| L_{A2037} | R⁷⁵ | G²¹ | L_{A2038} | R⁷⁵ | G²² | L_{A2039} | R⁷⁵ | G²³ | L_{A2036} | R⁷⁵ | G²⁴ |
| L_{A2041} | R⁷⁶ | G²¹ | L_{A2042} | R⁷⁶ | G²² | L_{A2043} | R⁷⁶ | G²³ | L_{A2044} | R⁷⁶ | G²⁴ |
| L_{A2045} | R⁷⁷ | G²¹ | L_{A2046} | R⁷⁷ | G²² | L_{A2047} | R⁷⁷ | G²³ | L_{A2048} | R⁷⁷ | G²⁴ |
| L_{A2049} | R⁷⁸ | G²¹ | L_{A2050} | R⁷⁸ | G²² | L_{A2051} | R⁷⁸ | G²³ | L_{A2052} | R⁷⁸ | G²⁴ |
| L_{A2053} | R⁷⁹ | G²¹ | L_{A2054} | R⁷⁹ | G²² | L_{A2055} | R⁷⁹ | G²³ | L_{A2056} | R⁷⁹ | G²⁴ |
| L_{A2057} | R⁸⁰ | G²¹ | L_{A2058} | R⁸⁰ | G²² | L_{A2059} | R⁸⁰ | G²³ | L_{A2060} | R⁸⁰ | G²⁴ |
| L_{A2061} | R⁸¹ | G²¹ | L_{A2062} | R⁸¹ | G²² | L_{A2063} | R⁸¹ | G²³ | L_{A2064} | R⁸¹ | G²⁴ |
| L_{A2065} | R⁸² | G²¹ | L_{A2066} | R⁸² | G²² | L_{A2067} | R⁸² | G²³ | L_{A2068} | R⁸² | G²⁴ |
| L_{A2069} | R⁸³ | G²¹ | L_{A2070} | R⁸³ | G²² | L_{A2071} | R⁸³ | G²³ | L_{A2072} | R⁸³ | G²⁴ |
| L_{A2073} | R⁸⁴ | G²¹ | L_{A2074} | R⁸⁴ | G²² | L_{A2075} | R⁸⁴ | G²³ | L_{A2076} | R⁸⁴ | G²⁴ |
| L_{A2077} | R⁸⁵ | G²¹ | L_{A2078} | R⁸⁵ | G²² | L_{A2079} | R⁸⁵ | G²³ | L_{A2080} | R⁸⁵ | G²⁴ |
| L_{A2081} | R⁸⁶ | G²¹ | L_{A2082} | R⁸⁶ | G²² | L_{A2083} | R⁸⁶ | G²³ | L_{A2084} | R⁸⁶ | G²⁴ |
| L_{A2085} | R⁸⁷ | G²¹ | L_{A2086} | R⁸⁷ | G²² | L_{A2087} | R⁸⁷ | G²³ | L_{A2088} | R⁸⁷ | G²⁴ |
| L_{A2089} | R¹ | G²⁵ | L_{A2090} | R¹ | G²⁶ | L_{A2091} | R¹ | G²⁷ | L_{A2092} | R¹ | G²⁸ |
| L_{A2093} | R² | G²⁵ | L_{A2094} | R² | G²⁶ | L_{A2095} | R² | G²⁷ | L_{A2096} | R² | G²⁸ |
| L_{A2097} | R³ | G²⁵ | L_{A2098} | R³ | G²⁶ | L_{A2099} | R³ | G²⁷ | L_{A2100} | R³ | G²⁸ |
| L_{A2101} | R⁴ | G²⁵ | L_{A2102} | R⁴ | G²⁶ | L_{A2103} | R⁴ | G²⁷ | L_{A2104} | R⁴ | G²⁸ |
| L_{A2105} | R⁵ | G²⁵ | L_{A2106} | R⁵ | G²⁶ | L_{A2107} | R⁵ | G²⁷ | L_{A2108} | R⁵ | G²⁸ |
| L_{A2109} | R⁶ | G²⁵ | L_{A2110} | R⁶ | G²⁶ | L_{A2111} | R⁶ | G²⁷ | L_{A2112} | R⁶ | G²⁸ |
| L_{A2113} | R⁷ | G²⁵ | L_{A2114} | R⁷ | G²⁶ | L_{A2115} | R⁷ | G²⁷ | L_{A2116} | R⁷ | G²⁸ |
| L_{A2117} | R⁸ | G²⁵ | L_{A2118} | R⁸ | G²⁶ | L_{A2119} | R⁸ | G²⁷ | L_{A2120} | R⁸ | G²⁸ |
| L_{A2121} | R⁹ | G²⁵ | L_{A2122} | R⁹ | G²⁶ | L_{A2123} | R⁹ | G²⁷ | L_{A2124} | R⁹ | G²⁸ |
| L_{A2125} | R¹⁰ | G²⁵ | L_{A2126} | R¹⁰ | G²⁶ | L_{A2127} | R¹⁰ | G²⁷ | L_{A2128} | R¹⁰ | G²⁸ |
| L_{A2129} | R¹¹ | G²⁵ | L_{A2130} | R¹¹ | G²⁶ | L_{A2131} | R¹¹ | G²⁷ | L_{A2132} | R¹¹ | G²⁸ |
| L_{A2133} | R¹² | G²⁵ | L_{A2134} | R¹² | G²⁶ | L_{A2135} | R¹² | G²⁷ | L_{A2136} | R¹² | G²⁸ |
| L_{A2137} | R¹³ | G²⁵ | L_{A2138} | R¹³ | G²⁶ | L_{A2139} | R¹³ | G²⁷ | L_{A2140} | R¹³ | G²⁸ |
| L_{A2141} | R¹⁴ | G²⁵ | L_{A2142} | R¹⁴ | G²⁶ | L_{A2143} | R¹⁴ | G²⁷ | L_{A2144} | R¹⁴ | G²⁸ |
| L_{A2145} | R¹⁵ | G²⁵ | L_{A2146} | R¹⁵ | G²⁶ | L_{A2147} | R¹⁵ | G²⁷ | L_{A2148} | R¹⁵ | G²⁸ |
| L_{A2149} | R¹⁶ | G²⁵ | L_{A2150} | R¹⁶ | G²⁶ | L_{A2151} | R¹⁶ | G²⁷ | L_{A2152} | R¹⁶ | G²⁸ |
| L_{A2153} | R¹⁷ | G²⁵ | L_{A2154} | R¹⁷ | G²⁶ | L_{A2155} | R¹⁷ | G²⁷ | L_{A2156} | R¹⁷ | G²⁸ |
| L_{A2157} | R¹⁸ | G²⁵ | L_{A2158} | R¹⁸ | G²⁶ | L_{A2159} | R¹⁸ | G²⁷ | L_{A2160} | R¹⁸ | G²⁸ |
| L_{A2161} | R¹⁹ | G²⁵ | L_{A2162} | R¹⁹ | G²⁶ | L_{A2163} | R¹⁹ | G²⁷ | L_{A2164} | R¹⁹ | G²⁸ |
| L_{A2165} | R²⁰ | G²⁵ | L_{A2166} | R²⁰ | G²⁶ | L_{A2167} | R²⁰ | G²⁷ | L_{A2168} | R²⁰ | G²⁸ |
| L_{A2169} | R²¹ | G²⁵ | L_{A2170} | R²¹ | G²⁶ | L_{A2171} | R²¹ | G²⁷ | L_{A2172} | R²¹ | G²⁸ |
| L_{A2173} | R²² | G²⁵ | L_{A2174} | R²² | G²⁶ | L_{A2175} | R²² | G²⁷ | L_{A2176} | R²² | G²⁸ |
| L_{A2177} | R²³ | G²⁵ | L_{A2178} | R²³ | G²⁶ | L_{A2179} | R²³ | G²⁷ | L_{A2180} | R²³ | G²⁸ |
| L_{A2181} | R²⁴ | G²⁵ | L_{A2182} | R²⁴ | G²⁶ | L_{A2183} | R²⁴ | G²⁷ | L_{A2184} | R²⁴ | G²⁸ |
| L_{A2185} | R²⁵ | G²⁵ | L_{A2186} | R²⁵ | G²⁶ | L_{A2187} | R²⁵ | G²⁷ | L_{A2188} | R²⁵ | G²⁸ |
| L_{A2189} | R²⁶ | G²⁵ | L_{A2190} | R²⁶ | G²⁶ | L_{A2191} | R²⁶ | G²⁷ | L_{A2192} | R²⁶ | G²⁸ |
| L_{A2193} | R²⁷ | G²⁵ | L_{A2194} | R²⁷ | G²⁶ | L_{A2195} | R²⁷ | G²⁷ | L_{A2196} | R²⁷ | G²⁸ |
| L_{A2197} | R²⁸ | G²⁵ | L_{A2198} | R²⁸ | G²⁶ | L_{A2199} | R²⁸ | G²⁷ | L_{A2200} | R²⁸ | G²⁸ |
| L_{A2201} | R²⁹ | G²⁵ | L_{A2202} | R²⁹ | G²⁶ | L_{A2203} | R²⁹ | G²⁷ | L_{A2204} | R²⁹ | G²⁸ |
| L_{A2205} | R³⁰ | G²⁵ | L_{A2206} | R³⁰ | G²⁶ | L_{A2207} | R³⁰ | G²⁷ | L_{A2208} | R³⁰ | G²⁸ |
| L_{A2209} | R³¹ | G²⁵ | L_{A2210} | R³¹ | G²⁶ | L_{A2211} | R³¹ | G²⁷ | L_{A2212} | R³¹ | G²⁸ |
| L_{A2213} | R³² | G²⁵ | L_{A2214} | R³² | G²⁶ | L_{A2215} | R³² | G²⁷ | L_{A2216} | R³² | G²⁸ |
| L_{A2217} | R³³ | G²⁵ | L_{A2218} | R³³ | G²⁶ | L_{A2219} | R³³ | G²⁷ | L_{A220} | R³³ | G²⁸ |
| L_{A2221} | R³⁴ | G²⁵ | L_{A2222} | R³⁴ | G²⁶ | L_{A2223} | R³⁴ | G²⁷ | L_{A2224} | R³⁴ | G²⁸ |
| L_{A2225} | R³⁵ | G²⁵ | L_{A2226} | R³⁵ | G²⁶ | L_{A2227} | R³⁵ | G²⁷ | L_{A2228} | R³⁵ | G²⁸ |
| L_{A2229} | R³⁶ | G²⁵ | L_{A2230} | R³⁶ | G²⁶ | L_{A2231} | R³⁶ | G²⁷ | L_{A2232} | R³⁶ | G²⁸ |
| L_{A2233} | R³⁷ | G²⁵ | L_{A2234} | R³⁷ | G²⁶ | L_{A2235} | R³⁷ | G²⁷ | L_{A2236} | R³⁷ | G²⁸ |
| L_{A2237} | R³⁸ | G²⁵ | L_{A2238} | R³⁸ | G²⁶ | L_{A2239} | R³⁸ | G²⁷ | L_{A2240} | R³⁸ | G²⁸ |
| L_{A2241} | R³⁹ | G²⁵ | L_{A2242} | R³⁹ | G²⁶ | L_{A2243} | R³⁹ | G²⁷ | L_{A2244} | R³⁹ | G²⁸ |
| L_{A2245} | R⁴⁰ | G²⁵ | L_{A2246} | R⁴⁰ | G²⁶ | L_{A2247} | R⁴⁰ | G²⁷ | L_{A2248} | R⁴⁰ | G²⁸ |
| L_{A2249} | R⁴¹ | G²⁵ | L_{A2250} | R⁴¹ | G²⁶ | L_{A2251} | R⁴¹ | G²⁷ | L_{A2252} | R⁴¹ | G²⁸ |
| L_{A2253} | R⁴² | G²⁵ | L_{A2254} | R⁴² | G²⁶ | L_{A2255} | R⁴² | G²⁷ | L_{A2256} | R⁴² | G²⁸ |
| L_{A2257} | R⁴³ | G²⁵ | L_{A2258} | R⁴³ | G²⁶ | L_{A2259} | R⁴³ | G²⁷ | L_{A2260} | R⁴³ | G²⁸ |
| L_{A2261} | R⁴⁴ | G²⁵ | L_{A2262} | R⁴⁴ | G²⁶ | L_{A2263} | R⁴⁴ | G²⁷ | L_{A2264} | R⁴⁴ | G²⁸ |
| L_{A2265} | R⁴⁵ | G²⁵ | L_{A2266} | R⁴⁵ | G²⁶ | L_{A2267} | R⁴⁵ | G²⁷ | L_{A2268} | R⁴⁵ | G²⁸ |
| L_{A2269} | R⁴⁶ | G²⁵ | L_{A2270} | R⁴⁶ | G²⁶ | L_{A2271} | R⁴⁶ | G²⁷ | L_{A2272} | R⁴⁶ | G²⁸ |
| L_{A2273} | R⁴⁷ | G²⁵ | L_{A2274} | R⁴⁷ | G²⁶ | L_{A2275} | R⁴⁷ | G²⁷ | L_{A2276} | R⁴⁷ | G²⁸ |
| L_{A2277} | R⁴⁸ | G²⁵ | L_{A2278} | R⁴⁸ | G²⁶ | L_{A2279} | R⁴⁸ | G²⁷ | L_{A2280} | R⁴⁸ | G²⁸ |
| L_{A2281} | R⁴⁹ | G²⁵ | L_{A2282} | R⁴⁹ | G²⁶ | L_{A2283} | R⁴⁹ | G²⁷ | L_{A2284} | R⁴⁹ | G²⁸ |
| L_{A2285} | R⁵⁰ | G²⁵ | L_{A2286} | R⁵⁰ | G²⁶ | L_{A2287} | R⁵⁰ | G²⁷ | L_{A2288} | R⁵⁰ | G²⁸ |
| L_{A2289} | R⁵¹ | G²⁵ | L_{A2290} | R⁵¹ | G²⁶ | L_{A2291} | R⁵¹ | G²⁷ | L_{A2292} | R⁵¹ | G²⁸ |
| L_{A2293} | R⁵² | G²⁵ | L_{A2294} | R⁵² | G²⁶ | L_{A2295} | R⁵² | G²⁷ | L_{A2296} | R⁵² | G²⁸ |
| L_{A2297} | R⁵³ | G²⁵ | L_{A2298} | R⁵³ | G²⁶ | L_{A2299} | R⁵³ | G²⁷ | L_{A2300} | R⁵³ | G²⁸ |
| L_{A2301} | R⁵⁴ | G²⁵ | L_{A2302} | R⁵⁴ | G²⁶ | L_{A2303} | R⁵⁴ | G²⁷ | L_{A2304} | R⁵⁴ | G²⁸ |
| L_{A2305} | R⁵⁵ | G²⁵ | L_{A2306} | R⁵⁵ | G²⁶ | L_{A2307} | R⁵⁵ | G²⁷ | L_{A2308} | R⁵⁵ | G²⁸ |
| L_{A2309} | R⁵⁶ | G²⁵ | L_{A2310} | R⁵⁶ | G²⁶ | L_{A2311} | R⁵⁶ | G²⁷ | L_{A2312} | R⁵⁶ | G²⁸ |
| L_{A2313} | R⁵⁷ | G²⁵ | L_{A2314} | R⁵⁷ | G²⁶ | L_{A2315} | R⁵⁷ | G²⁷ | L_{A2316} | R⁵⁷ | G²⁸ |
| L_{A2317} | R⁵⁸ | G²⁵ | L_{A2318} | R⁵⁸ | G²⁶ | L_{A2319} | R⁵⁸ | G²⁷ | L_{A2320} | R⁵⁸ | G²⁸ |
| L_{A2321} | R⁵⁹ | G²⁵ | L_{A2322} | R⁵⁹ | G²⁶ | L_{A2323} | R⁵⁹ | G²⁷ | L_{A2324} | R⁵⁹ | G²⁸ |
| L_{A2325} | R⁶⁰ | G²⁵ | L_{A2326} | R⁶⁰ | G²⁶ | L_{A2327} | R⁶⁰ | G²⁷ | L_{A2328} | R⁶⁰ | G²⁸ |
| L_{A2329} | R⁶¹ | G²⁵ | L_{A2330} | R⁶¹ | G²⁶ | L_{A2331} | R⁶¹ | G²⁷ | L_{A2332} | R⁶¹ | G²⁸ |
| L_{A2333} | R⁶² | G²⁵ | L_{A2334} | R⁶² | G²⁶ | L_{A2335} | R⁶² | G²⁷ | L_{A2336} | R⁶² | G²⁸ |
| L_{A2337} | R⁶³ | G²⁵ | L_{A2338} | R⁶³ | G²⁶ | L_{A2339} | R⁶³ | G²⁷ | L_{A2340} | R⁶³ | G²⁸ |
| L_{A2341} | R⁶⁴ | G²⁵ | L_{A2342} | R⁶⁴ | G²⁶ | L_{A2343} | R⁶⁴ | G²⁷ | L_{A2344} | R⁶⁴ | G²⁸ |
| L_{A2345} | R⁶⁵ | G²⁵ | L_{A2346} | R⁶⁵ | G²⁶ | L_{A2347} | R⁶⁵ | G²⁷ | L_{A2348} | R⁶⁵ | G²⁸ |
| L_{A2349} | R⁶⁶ | G²⁵ | L_{A2350} | R⁶⁶ | G²⁶ | L_{A2351} | R⁶⁶ | G²⁷ | L_{A2352} | R⁶⁶ | G²⁸ |
| L_{A2353} | R⁶⁷ | G²⁵ | L_{A2354} | R⁶⁷ | G²⁶ | L_{A2355} | R⁶⁷ | G²⁷ | L_{A2356} | R⁶⁷ | G²⁸ |
| L_{A2357} | R⁶⁸ | G²⁵ | L_{A2358} | R⁶⁸ | G²⁶ | L_{A2359} | R⁶⁸ | G²⁷ | L_{A2360} | R⁶⁸ | G²⁸ |
| L_{A2361} | R⁶⁹ | G²⁵ | L_{A2362} | R⁶⁹ | G²⁶ | L_{A2363} | R⁶⁹ | G²⁷ | L_{A2364} | R⁶⁹ | G²⁸ |
| L_{A2365} | R⁷ | G²⁵ | L_{A2366} | R⁷⁰ | G²⁶ | L_{A2367} | R⁷⁰ | G²⁷ | L_{A2368} | R⁷⁰ | G²⁸ |
| L_{A2369} | R⁷¹ | G²⁵ | L_{A2370} | R⁷¹ | G²⁶ | L_{A2371} | R⁷¹ | G²⁷ | L_{A2372} | R⁷¹ | G²⁸ |
| L_{A2373} | R⁷² | G²⁵ | L_{A2374} | R⁷² | G²⁶ | L_{A2375} | R⁷² | G²⁷ | L_{A2376} | R⁷² | G²⁸ |
| L_{A2377} | R⁷³ | G²⁵ | L_{A2378} | R⁷³ | G²⁶ | L_{A2379} | R⁷³ | G²⁷ | L_{A2380} | R⁷³ | G²⁸ |
| L_{A2381} | R⁷⁴ | G²⁵ | L_{A2382} | R⁷⁴ | G²⁶ | L_{A2383} | R⁷⁴ | G²⁷ | L_{A2384} | R⁷⁴ | G²⁸ |
| L_{A2385} | R⁷⁵ | G²⁵ | L_{A2386} | R⁷⁵ | G²⁶ | L_{A2387} | R⁷⁵ | G²⁷ | L_{A2388} | R⁷⁵ | G²⁸ |
| L_{A2389} | R⁷⁶ | G²⁵ | L_{A2390} | R⁷⁶ | G²⁶ | L_{A2391} | R⁷⁶ | G²⁷ | L_{A2392} | R⁷⁶ | G²⁸ |
| L_{A2393} | R⁷⁷ | G²⁵ | L_{A2394} | R⁷⁷ | G²⁶ | L_{A2395} | R⁷⁷ | G²⁷ | L_{A2396} | R⁷⁷ | G²⁸ |
| L_{A2397} | R⁷⁸ | G²⁵ | L_{A2398} | R⁷⁸ | G²⁶ | L_{A2399} | R⁷⁸ | G²⁷ | L_{A2400} | R⁷⁸ | G²⁸ |
| L_{A2401} | R⁷⁹ | G²⁵ | L_{A2402} | R⁷⁹ | G²⁶ | L_{A2403} | R⁷⁹ | G²⁷ | L_{A2404} | R⁷⁹ | G²⁸ |
| L_{A2405} | R⁸⁰ | G²⁵ | L_{A2406} | R⁸⁰ | G²⁶ | L_{A2407} | R⁸⁰ | G²⁷ | L_{A2408} | R⁸⁰ | G²⁸ |
| L_{A2409} | R⁸¹ | G²⁵ | L_{A2410} | R⁸¹ | G²⁶ | L_{A2411} | R⁸¹ | G²⁷ | L_{A2412} | R⁸¹ | G²⁸ |
| L_{A2413} | R⁸² | G²⁵ | L_{A2414} | R⁸² | G²⁶ | L_{A2415} | R⁸² | G²⁷ | L_{A2416} | R⁸² | G²⁸ |
| L_{A2417} | R⁸³ | G²⁵ | L_{A2418} | R⁸³ | G²⁶ | L_{A2419} | R⁸³ | G²⁷ | L_{A2420} | R⁸³ | G²⁸ |
| L_{A2421} | R⁸⁴ | G²⁵ | L_{A2422} | R⁸⁴ | G²⁶ | L_{A2423} | R⁸⁴ | G²⁷ | L_{A2424} | R⁸⁴ | G²⁸ |
| L_{A2425} | R⁸⁵ | G²⁵ | L_{A2426} | R⁸⁵ | G²⁶ | L_{A2427} | R⁸⁵ | G²⁷ | L_{A2428} | R⁸⁵ | G²⁸ |
| L_{A2429} | R⁸⁶ | G²⁵ | L_{A2430} | R⁸⁶ | G²⁶ | L_{A2431} | R⁸⁶ | G²⁷ | L_{A2432} | R⁸⁶ | G²⁸ |
| L_{A2433} | R⁸⁷ | G²⁵ | L_{A2434} | R⁸⁷ | G²⁶ | L_{A2435} | R⁸⁷ | G²⁷ | L_{A2436} | R⁸⁷ | G²⁸ |
| L_{A2437} | R¹ | G²⁹ | L_{A2438} | R¹ | G³⁰ | L_{A2439} | R¹ | G³¹ | L_{A2440} | R¹ | G³² |
| L_{A2441} | R² | G²⁹ | L_{A2442} | R² | G³⁰ | L_{A2443} | R² | G³¹ | L_{A2444} | R² | G³² |
| L_{A2445} | R³ | G²⁹ | L_{A2446} | R³ | G³⁰ | L_{A2447} | R³ | G³¹ | L_{A2448} | R³ | G³² |
| L_{A2449} | R⁴ | G²⁹ | L_{A2450} | R⁴ | G³⁰ | L_{A2451} | R⁴ | G³¹ | L_{A2452} | R⁴ | G³² |
| L_{A2453} | R⁵ | G²⁹ | L_{A2454} | R⁵ | G³⁰ | L_{A2455} | R⁵ | G³¹ | L_{A2456} | R⁵ | G³² |
| L_{A2457} | R⁶ | G²⁹ | L_{A2458} | R⁶ | G³⁰ | L_{A2459} | R⁶ | G³¹ | L_{A2460} | R⁶ | G³² |
| L_{A2461} | R⁷ | G²⁹ | L_{A2462} | R⁷ | G³⁰ | L_{A2463} | R⁷ | G³¹ | L_{A2464} | R⁷ | G³² |
| L_{A2465} | R⁸ | G²⁹ | L_{A2466} | R⁸ | G³⁰ | L_{A2467} | R⁸ | G³¹ | L_{A2468} | R⁸ | G³² |
| L_{A2469} | R⁹ | G²⁹ | L_{A2470} | R⁹ | G³⁰ | L_{A2473} | R⁹ | G³¹ | L_{A2472} | R⁹ | G³² |
| L_{A2473} | R¹⁰ | G²⁹ | L_{A2474} | R¹⁰ | G³⁰ | L_{A2475} | R¹⁰ | G³¹ | L_{A2476} | R¹⁰ | G³² |
| L_{A2477} | R¹¹ | G²⁹ | L_{A2478} | R¹¹ | G³⁰ | L_{A2479} | R¹¹ | G³¹ | L_{A2480} | R¹¹ | G³² |
| L_{A2481} | R¹² | G²⁹ | L_{A2482} | R¹² | G³⁰ | L_{A2483} | R¹² | G³¹ | L_{A2484} | R¹² | G³² |
| L_{A2485} | R¹³ | G²⁹ | L_{A2486} | R¹³ | G³⁰ | L_{A2487} | R¹³ | G³¹ | L_{A2488} | R¹³ | G³² |
| L_{A2489} | R¹⁴ | G²⁹ | L_{A2490} | R¹⁴ | G³⁰ | L_{A2491} | R¹⁴ | G³¹ | L_{A2492} | R¹⁴ | G³² |
| L_{A2493} | R¹⁵ | G²⁹ | L_{A2494} | R¹⁵ | G³⁰ | L_{A2495} | R¹⁵ | G³¹ | L_{A2496} | R¹⁵ | G³² |
| L_{A2497} | R¹⁶ | G²⁹ | L_{A2498} | R¹⁶ | G³⁰ | L_{A2499} | R¹⁶ | G³¹ | L_{A2500} | R¹⁶ | G³² |
| L_{A2501} | R¹⁷ | G²⁹ | L_{A2502} | R¹⁷ | G³⁰ | L_{A2503} | R¹⁷ | G³¹ | L_{A2504} | R¹⁷ | G³² |
| L_{A2505} | R¹⁸ | G²⁹ | L_{A2506} | R¹⁸ | G³⁰ | L_{A2507} | R¹⁸ | G³¹ | L_{A2508} | R¹⁸ | G³² |
| L_{A2509} | R¹⁹ | G²⁹ | L_{A2510} | R¹⁹ | G³⁰ | L_{A2511} | R¹⁹ | G³¹ | L_{A2512} | R¹⁹ | G³² |
| L_{A2513} | R²⁰ | G²⁹ | L_{A2514} | R²⁰ | G³⁰ | L_{A2515} | R²⁰ | G³¹ | L_{A2516} | R²⁰ | G³² |
| L_{A2517} | R²¹ | G²⁹ | L_{A2518} | R²¹ | G³⁰ | L_{A2519} | R²¹ | G³¹ | L_{A2520} | R²¹ | G³² |
| L_{A2521} | R²² | G²⁹ | L_{A2522} | R²² | G³⁰ | L_{A2523} | R²² | G³¹ | L_{A2524} | R²² | G³² |
| L_{A2525} | R²³ | G²⁹ | L_{A2526} | R²³ | G³⁰ | L_{A2527} | R²³ | G³¹ | L_{A2528} | R²³ | G³² |
| L_{A2529} | R²⁴ | G²⁹ | L_{A2530} | R²⁴ | G³⁰ | L_{A2531} | R²⁴ | G³¹ | L_{A2532} | R²⁴ | G³² |
| L_{A2533} | R²⁵ | G²⁹ | L_{A2534} | R²⁵ | G³⁰ | L_{A2535} | R²⁵ | G³¹ | L_{A2536} | R²⁵ | G³² |
| L_{A2537} | R²⁶ | G²⁹ | L_{A2538} | R²⁶ | G³⁰ | L_{A2539} | R²⁶ | G³¹ | L_{A2540} | R²⁶ | G³² |
| L_{A2541} | R²⁷ | G²⁹ | L_{A2542} | R²⁷ | G³⁰ | L_{A2543} | R²⁷ | G³¹ | L_{A2544} | R²⁷ | G³² |
| L_{A2545} | R²⁸ | G²⁹ | L_{A2546} | R²⁸ | G³⁰ | L_{A2547} | R²⁸ | G³¹ | L_{A2548} | R²⁸ | G³² |
| L_{A2549} | R²⁹ | G²⁹ | L_{A2550} | R²⁹ | G³⁰ | L_{A2551} | R²⁹ | G³¹ | L_{A2552} | R²⁹ | G³² |
| L_{A2553} | R³⁰ | G²⁹ | L_{A2554} | R³⁰ | G³⁰ | L_{A2555} | R³⁰ | G³¹ | L_{A2556} | R³⁰ | G³² |
| L_{A2557} | R³¹ | G²⁹ | L_{A2558} | R³¹ | G³⁰ | L_{A2559} | R³¹ | G³¹ | L_{A2560} | R³¹ | G³² |
| L_{A2561} | R³² | G²⁹ | L_{A2562} | R³² | G³⁰ | L_{A2563} | R³² | G³¹ | L_{A2564} | R³² | G³² |
| L_{A2565} | R³³ | G²⁹ | L_{A2566} | R³³ | G³⁰ | L_{A2567} | R³³ | G³¹ | L_{A2568} | R³³ | G³² |
| L_{A2569} | R³⁴ | G²⁹ | L_{A2570} | R³⁴ | G³⁰ | L_{A2571} | R³⁴ | G³¹ | L_{A2572} | R³⁴ | G³² |
| L_{A2573} | R³⁵ | G²⁹ | L_{A2574} | R³⁵ | G³⁰ | L_{A2575} | R³⁵ | G³¹ | L_{A2576} | R³⁵ | G³² |
| L_{A2577} | R³⁶ | G²⁹ | L_{A2578} | R³⁶ | G³⁰ | L_{A2579} | R³⁶ | G³¹ | L_{A2580} | R³⁶ | G³² |
| L_{A2581} | R³⁷ | G²⁹ | L_{A2582} | R³⁷ | G³⁰ | L_{A2583} | R³⁷ | G³¹ | L_{A2584} | R³⁷ | G³² |
| L_{A2585} | R³⁸ | G²⁹ | L_{A2586} | R³⁸ | G³⁰ | L_{A2587} | R³⁸ | G³¹ | L_{A2588} | R³⁸ | G³² |
| L_{A2589} | R³⁹ | G²⁹ | L_{A2590} | R³⁹ | G³⁰ | L_{A2591} | R³⁹ | G³¹ | L_{A2592} | R³⁹ | G³² |
| L_{A2593} | R⁴⁰ | G²⁹ | L_{A2594} | R⁴⁰ | G³⁰ | L_{A2595} | R⁴⁰ | G³¹ | L_{A2596} | R⁴⁰ | G³² |
| L_{A2597} | R⁴¹ | G²⁹ | L_{A2598} | R⁴¹ | G³⁰ | L_{A2599} | R⁴¹ | G³¹ | L_{A2600} | R⁴¹ | G³² |
| L_{A2601} | R⁴² | G²⁹ | L_{A2602} | R⁴² | G³⁰ | L_{A2603} | R⁴² | G³¹ | L_{A2604} | R⁴² | G³² |
| L_{A2605} | R⁴³ | G²⁹ | L_{A2606} | R⁴³ | G³⁰ | L_{A2607} | R⁴³ | G³¹ | L_{A2608} | R⁴³ | G³² |
| L_{A2609} | R⁴⁴ | G²⁹ | L_{A2610} | R⁴⁴ | G³⁰ | L_{A2611} | R⁴⁴ | G³¹ | L_{A2612} | R⁴⁴ | G³² |
| L_{A2613} | R⁴⁵ | G²⁹ | L_{A2614} | R⁴⁵ | G³⁰ | L_{A2615} | R⁴⁵ | G³¹ | L_{A2616} | R⁴⁵ | G³² |
| L_{A2617} | R⁴⁶ | G²⁹ | L_{A2618} | R⁴⁶ | G³⁰ | L_{A2619} | R⁴⁶ | G³¹ | L_{A2620} | R⁴⁶ | G³² |
| L_{A2621} | R⁴⁷ | G²⁹ | L_{A2622} | R⁴⁷ | G³⁰ | L_{A2623} | R⁴⁷ | G³¹ | L_{A2624} | R⁴⁷ | G³² |
| L_{A2625} | R⁴⁸ | G²⁹ | L_{A2626} | R⁴⁸ | G³⁰ | L_{A2627} | R⁴⁸ | G³¹ | L_{A2628} | R⁴⁸ | G³² |
| L_{A2629} | R⁴⁹ | G²⁹ | L_{A2630} | R⁴⁹ | G³⁰ | L_{A2631} | R⁴⁹ | G³¹ | L_{A2632} | R⁴⁹ | G³² |
| L_{A2633} | R⁵⁰ | G²⁹ | L_{A2634} | R⁵⁰ | G³⁰ | L_{A2635} | R⁵⁰ | G³¹ | L_{A2636} | R⁵⁰ | G³² |
| L_{A2637} | R⁵¹ | G²⁹ | L_{A2638} | R⁵¹ | G³⁰ | L_{A2639} | R⁵¹ | G³¹ | L_{A2640} | R⁵¹ | G³² |
| L_{A2641} | R⁵² | G²⁹ | L_{A2642} | R⁵² | G³⁰ | L_{A2643} | R⁵² | G³¹ | L_{A2644} | R⁵² | G³² |
| L_{A2645} | R⁵³ | G²⁹ | L_{A2646} | R⁵³ | G³⁰ | L_{A2647} | R⁵³ | G³¹ | L_{A2648} | R⁵³ | G³² |
| L_{A2649} | R⁵⁴ | G²⁹ | L_{A2650} | R⁵⁴ | G³⁰ | L_{A2651} | R⁵⁴ | G³¹ | L_{A2652} | R⁵⁴ | G³² |
| L_{A2653} | R⁵⁵ | G²⁹ | L_{A2654} | R⁵⁵ | G³⁰ | L_{A2655} | R⁵⁵ | G³¹ | L_{A2656} | R⁵⁵ | G³² |
| L_{A2657} | R⁵⁶ | G²⁹ | L_{A2658} | R⁵⁶ | G³⁰ | L_{A2659} | R⁵⁶ | G³¹ | L_{A2660} | R⁵⁶ | G³² |
| L_{A2661} | R⁵⁷ | G²⁹ | L_{A2662} | R⁵⁷ | G³⁰ | L_{A2663} | R⁵⁷ | G³¹ | L_{A2664} | R⁵⁷ | G³² |
| L_{A2665} | R⁵⁸ | G²⁹ | L_{A2666} | R⁵⁸ | G³⁰ | L_{A2667} | R⁵⁸ | G³¹ | L_{A2668} | R⁵⁸ | G³² |
| L_{A2669} | R⁵⁹ | G²⁹ | L_{A2670} | R⁵⁹ | G³⁰ | L_{A2671} | R⁵⁹ | G³¹ | L_{A2672} | R⁵⁹ | G³² |
| L_{A2673} | R⁶⁰ | G²⁹ | L_{A2674} | R⁶⁰ | G³⁰ | L_{A2675} | R⁶⁰ | G³¹ | L_{A2676} | R⁶⁰ | G³² |
| L_{A2677} | R⁶¹ | G²⁹ | L_{A2678} | R⁶¹ | G³⁰ | L_{A2679} | R⁶¹ | G³¹ | L_{A2680} | R⁶¹ | G³² |
| L_{A2681} | R⁶² | G²⁹ | L_{A2682} | R⁶² | G³⁰ | L_{A2683} | R⁶² | G³¹ | L_{A2684} | R⁶² | G³² |
| L_{A2685} | R⁶³ | G²⁹ | L_{A2686} | R⁶³ | G³⁰ | L_{A2687} | R⁶³ | G³¹ | L_{A2688} | R⁶³ | G³² |
| L_{A2689} | R⁶⁴ | G²⁹ | L_{A2690} | R⁶⁴ | G³⁰ | L_{A2691} | R⁶⁴ | G³¹ | L_{A2692} | R⁶⁴ | G³² |
| L_{A2693} | R⁶⁵ | G²⁹ | L_{A2694} | R⁶⁵ | G³⁰ | L_{A2695} | R⁶⁵ | G³¹ | L_{A2696} | R⁶⁵ | G³² |
| L_{A2697} | R⁶⁶ | G²⁹ | L_{A2698} | R⁶⁶ | G³⁰ | L_{A2699} | R⁶⁶ | G³¹ | L_{A2700} | R⁶⁶ | G³² |
| L_{A2701} | R⁶⁷ | G²⁹ | L_{A2702} | R⁶⁷ | G³⁰ | L_{A2703} | R⁶⁷ | G³¹ | L_{A2704} | R⁶⁷ | G³² |
| L_{A2705} | R⁶⁸ | G²⁹ | L_{A2706} | R⁶⁸ | G³⁰ | L_{A2707} | R⁶⁸ | G³¹ | L_{A2708} | R⁶⁸ | G³² |
| L_{A2709} | R⁶⁹ | G²⁹ | L_{A2710} | R⁶⁹ | G³⁰ | L_{A2711} | R⁶⁹ | G³¹ | L_{A2712} | R⁶⁹ | G³² |
| L_{A2713} | R⁷⁰ | G²⁹ | L_{A2714} | R⁷⁰ | G³⁰ | L_{A2715} | R⁷⁰ | G³¹ | L_{A2716} | R⁷⁰ | G³² |
| L_{A2717} | R⁷¹ | G²⁹ | L_{A2718} | R⁷¹ | G³⁰ | L_{A2719} | R⁷¹ | G³¹ | L_{A2720} | R⁷¹ | G³² |
| L_{A2721} | R⁷² | G²⁹ | L_{A2722} | R⁷² | G³⁰ | L_{A2723} | R⁷² | G³¹ | L_{A2724} | R⁷² | G³² |
| L_{A2725} | R⁷³ | G²⁹ | L_{A2726} | R⁷³ | G³⁰ | L_{A2727} | R⁷³ | G³¹ | L_{A2728} | R⁷³ | G³² |
| L_{A2729} | R⁷⁴ | G²⁹ | L_{A2730} | R⁷⁴ | G³⁰ | L_{A2731} | R⁷⁴ | G³¹ | L_{A2732} | R⁷⁴ | G³² |
| L_{A2733} | R⁷⁵ | G²⁹ | L_{A2734} | R⁷⁵ | G³⁰ | L_{A2735} | R⁷⁵ | G³¹ | L_{A2736} | R⁷⁵ | G³² |
| L_{A2737} | R⁷⁶ | G²⁹ | L_{A2738} | R⁷⁶ | G³⁰ | L_{A2739} | R⁷⁶ | G³¹ | L_{A2740} | R⁷⁶ | G³² |
| L_{A2741} | R⁷⁷ | G²⁹ | L_{A2742} | R⁷⁷ | G³⁰ | L_{A2743} | R⁷⁷ | G³¹ | L_{A2744} | R⁷⁷ | G³² |
| L_{A2745} | R⁷⁸ | G²⁹ | L_{A2746} | R⁷⁸ | G³⁰ | L_{A2747} | R⁷⁸ | G³¹ | L_{A2748} | R⁷⁸ | G³² |
| L_{A2749} | R⁷⁹ | G²⁹ | L_{A2750} | R⁷⁹ | G³⁰ | L_{A2751} | R⁷⁹ | G³¹ | L_{A2752} | R⁷⁹ | G³² |
| L_{A2753} | R⁸⁰ | G²⁹ | L_{A2754} | R⁸⁰ | G³⁰ | L_{A2755} | R⁸⁰ | G³¹ | L_{A2756} | R⁸⁰ | G³² |
| L_{A2757} | R⁸¹ | G²⁹ | L_{A2758} | R⁸¹ | G³⁰ | L_{A2759} | R⁸¹ | G³¹ | L_{A2760} | R⁸¹ | G³² |
| L_{A2763} | R⁸² | G²⁹ | L_{A2762} | R⁸² | G³⁰ | L_{A2763} | R⁸² | G³¹ | L_{A2764} | R⁸² | G³² |
| L_{A2765} | R⁸³ | G²⁹ | L_{A2766} | R⁸³ | G³⁰ | L_{A2767} | R⁸³ | G³¹ | L_{A2768} | R⁸³ | G³² |
| L_{A2769} | R⁸⁴ | G²⁹ | L_{A2770} | R⁸⁴ | G³⁰ | L_{A2771} | R⁸⁴ | G³¹ | L_{A2772} | R⁸⁴ | G³² |
| L_{A2773} | R⁸⁵ | G²⁹ | L_{A2774} | R⁸⁵ | G³⁰ | L_{A2775} | R⁸⁵ | G³¹ | L_{A2776} | R⁸⁵ | G³² |
| L_{A2777} | R⁸⁶ | G²⁹ | L_{A2778} | R⁸⁶ | G³⁰ | L_{A2779} | R⁸⁶ | G³¹ | L_{A2780} | R⁸⁶ | G³² |
| L_{A2781} | R⁸⁷ | G²⁹ | L_{A2782} | R⁸⁷ | G³⁰ | L_{A2783} | R⁸⁷ | G³¹ | L_{A2784} | R⁸⁷ | G³² |
| L_{A2785} | R¹ | G³³ | L_{A2786} | R¹ | G³⁴ | L_{A2787} | R¹ | G³⁵ | L_{A2788} | R¹ | G³⁶ |
| L_{A2789} | R² | G³³ | L_{A2790} | R² | G³⁴ | L_{A2791} | R² | G³⁵ | L_{A2792} | R² | G³⁶ |
| L_{A2793} | R³ | G³³ | L_{A2794} | R³ | G³⁴ | L_{A2795} | R³ | G³⁵ | L_{A2796} | R³ | G³⁶ |
| L_{A2797} | R⁴ | G³³ | L_{A2798} | R⁴ | G³⁴ | L_{A2799} | R⁴ | G³⁵ | L_{A2800} | R⁴ | G³⁶ |
| L_{A2801} | R⁵ | G³³ | L_{A2802} | R⁵ | G³⁴ | L_{A2803} | R⁵ | G³⁵ | L_{A2804} | R⁵ | G³⁶ |
| L_{A2805} | R⁶ | G³³ | L_{A2806} | R⁶ | G³⁴ | L_{A2807} | R⁶ | G³⁵ | L_{A2808} | R⁶ | G³⁶ |
| L_{A2809} | R⁷ | G³³ | L_{A2810} | R⁷ | G³⁴ | L_{A2811} | R⁷ | G³⁵ | L_{A2812} | R⁷ | G³⁶ |
| L_{A2813} | R⁸ | G³³ | L_{A2814} | R⁸ | G³⁴ | L_{A2815} | R⁸ | G³⁵ | L_{A2816} | R⁸ | G³⁶ |
| L_{A2817} | R⁹ | G³³ | L_{A2818} | R⁹ | G³⁴ | L_{A2819} | R⁹ | G³⁵ | L_{A282}o | R⁹ | G³⁶ |
| L_{A2821} | R¹⁰ | G³³ | L_{A2822} | R¹⁰ | G³⁴ | L_{A2823} | R¹⁰ | G³⁵ | L_{A2824} | R¹⁰ | G³⁶ |
| L_{A2825} | R¹¹ | G³³ | L_{A2826} | R¹¹ | G³⁴ | L_{A2827} | R¹¹ | G³⁵ | L_{A2828} | R¹¹ | G³⁶ |
| L_{A2829} | R¹² | G³³ | L_{A2830} | R¹² | G³⁴ | L_{A2831} | R¹² | G³⁵ | L_{A2832} | R¹² | G³⁶ |
| L_{A2833} | R¹³ | G³³ | L_{A2834} | R¹³ | G³⁴ | L_{A2835} | R¹³ | G³⁵ | L_{A2836} | R¹³ | G³⁶ |
| L_{A2837} | R¹⁴ | G³³ | L_{A2838} | R¹⁴ | G³⁴ | L_{A2839} | R¹⁴ | G³⁵ | L_{A2840} | R¹⁴ | G³⁶ |
| L_{A2841} | R¹⁵ | G³³ | L_{A2842} | R¹⁵ | G³⁴ | L_{A2843} | R¹⁵ | G³⁵ | L_{A2844} | R¹⁵ | G³⁶ |
| L_{A2845} | R¹⁶ | G³³ | L_{A2846} | R¹⁶ | G³⁴ | L_{A2847} | R¹⁶ | G³⁵ | L_{A2848} | R¹⁶ | G³⁶ |
| L_{A2849} | R¹⁷ | G³³ | L_{A2850} | R¹⁷ | G³⁴ | L_{A2851} | R¹⁷ | G³⁵ | L_{A2852} | R¹⁷ | G³⁶ |
| L_{A2853} | R¹⁸ | G³³ | L_{A2854} | R¹⁸ | G³⁴ | L_{A2855} | R¹⁸ | G³⁵ | L_{A2856} | R¹⁸ | G³⁶ |
| L_{A2857} | R¹⁹ | G³³ | L_{A2858} | R¹⁹ | G³⁴ | L_{A2859} | R¹⁹ | G³⁵ | L_{A2860} | R¹⁹ | G³⁶ |
| L_{A2861} | R²⁰ | G³³ | L_{A2862} | R²⁰ | G³⁴ | L_{A2863} | R²⁰ | G³⁵ | L_{A2864} | R²⁰ | G³⁶ |
| L_{A2865} | R²¹ | G³³ | L_{A2866} | R²¹ | G³⁴ | L_{A2867} | R²¹ | G³⁵ | L_{A2868} | R²¹ | G³⁶ |
| L_{A2869} | R²² | G³³ | L_{A2870} | R²² | G³⁴ | L_{A2871} | R²² | G³⁵ | L_{A2872} | R²² | G³⁶ |
| L_{A2873} | R²³ | G³³ | L_{A2874} | R²³ | G³⁴ | L_{A2875} | R²³ | G³⁵ | L_{A2876} | R²³ | G³⁶ |
| L_{A2877} | R²⁴ | G³³ | L_{A2878} | R²⁴ | G³⁴ | L_{A2879} | R²⁴ | G³⁵ | L_{A2880} | R²⁴ | G³⁶ |
| L_{A2881} | R²⁵ | G³³ | L_{A2882} | R²⁵ | G³⁴ | L_{A2883} | R²⁵ | G³⁵ | L_{A2884} | R²⁵ | G³⁶ |
| L_{A2885} | R²⁶ | G³³ | L_{A2886} | R²⁶ | G³⁴ | L_{A2887} | R²⁶ | G³⁵ | L_{A2888} | R²⁶ | G³⁶ |
| L_{A2889} | R²⁷ | G³³ | L_{A2890} | R²⁷ | G³⁴ | L_{A2891} | R²⁷ | G³⁵ | L_{A2892} | R²⁷ | G³⁶ |
| L_{A2893} | R²⁸ | G³³ | L_{A2894} | R²⁸ | G³⁴ | L_{A2895} | R²⁸ | G³⁵ | L_{A2896} | R²⁸ | G³⁶ |
| L_{A2897} | R²⁹ | G³³ | L_{A2898} | R²⁹ | G³⁴ | L_{A2899} | R²⁹ | G³⁵ | L_{A2900} | R²⁹ | G³⁶ |
| L_{A2901} | R³⁰ | G³³ | L_{A2902} | R³⁰ | G³⁴ | L_{A2903} | R³⁰ | G³⁵ | L_{A2904} | R³⁰ | G³⁶ |
| L_{A2905} | R³¹ | G³³ | L_{A2906} | R³¹ | G³⁴ | L_{A2907} | R³¹ | G³⁵ | L_{A2908} | R³¹ | G³⁶ |
| L_{A2909} | R³² | G³³ | L_{A2910} | R³² | G³⁴ | L_{A2911} | R³² | G³⁵ | L_{A2912} | R³² | G³⁶ |
| L_{A2913} | R³³ | G³³ | L_{A2914} | R³³ | G³⁴ | L_{A2915} | R³³ | G³⁵ | L_{A2916} | R³³ | G³⁶ |
| L_{A2917} | R³⁴ | G³³ | L_{A2918} | R³⁴ | G³⁴ | L_{A2919} | R³⁴ | G³⁵ | L_{A2920} | R³⁴ | G³⁶ |
| L_{A2921} | R³⁵ | G³³ | L_{A2922} | R³⁵ | G³⁴ | L_{A2923} | R³⁵ | G³⁵ | L_{A2924} | R³⁵ | G³⁶ |
| L_{A2925} | R³⁶ | G³³ | L_{A2926} | R³⁶ | G³⁴ | L_{A2927} | R³⁶ | G³⁵ | L_{A2928} | R³⁶ | G³⁶ |
| L_{A2929} | R³⁷ | G³³ | L_{A2930} | R³⁷ | G³⁴ | L_{A2931} | R³⁷ | G³⁵ | L_{A2932} | R³⁷ | G³⁶ |
| L_{A2933} | R³⁸ | G³³ | L_{A2934} | R³⁸ | G³⁴ | L_{A2935} | R³⁸ | G³⁵ | L_{A2936} | R³⁸ | G³⁶ |
| L_{A2937} | R³⁹ | G³³ | L_{A2938} | R³⁹ | G³⁴ | L_{A2939} | R³⁹ | G³⁵ | L_{A2940} | R³⁹ | G³⁶ |
| L_{A2941} | R⁴⁰ | G³³ | L_{A2942} | R⁴⁰ | G³⁴ | L_{A2943} | R⁴⁰ | G³⁵ | L_{A2944} | R⁴⁰ | G³⁶ |
| L_{A2945} | R⁴¹ | G³³ | L_{A2946} | R⁴¹ | G³⁴ | L_{A2947} | R⁴¹ | G³⁵ | L_{A2948} | R⁴¹ | G³⁶ |
| L_{A2949} | R⁴² | G³³ | L_{A2950} | R⁴² | G³⁴ | L_{A2951} | R⁴² | G³⁵ | L_{A2952} | R⁴² | G³⁶ |
| L_{A2953} | R⁴³ | G³³ | L_{A2954} | R⁴³ | G³⁴ | L_{A2955} | R⁴³ | G³⁵ | L_{A2956} | R⁴³ | G³⁶ |
| L_{A2957} | R⁴⁴ | G³³ | L_{A2958} | R⁴⁴ | G³⁴ | L_{A2959} | R⁴⁴ | G³⁵ | L_{A2960} | R⁴⁴ | G³⁶ |
| L_{A2961} | R⁴⁵ | G³³ | L_{A2962} | R⁴⁵ | G³⁴ | L_{A2963} | R⁴⁵ | G³⁵ | L_{A2964} | R⁴⁵ | G³⁶ |
| L_{A2965} | R⁴⁶ | G³³ | L_{A2966} | R⁴⁶ | G³⁴ | L_{A2967} | R⁴⁶ | G³⁵ | L_{A2968} | R⁴⁶ | G³⁶ |
| L_{A2969} | R⁴⁷ | G³³ | L_{A2970} | R⁴⁷ | G³⁴ | L_{A2971} | R⁴⁷ | G³⁵ | L_{A2972} | R⁴⁷ | G³⁶ |
| L_{A2973} | R⁴⁸ | G³³ | L_{A2974} | R⁴⁸ | G³⁴ | L_{A2975} | R⁴⁸ | G³⁵ | L_{A2976} | R⁴⁸ | G³⁶ |
| L_{A2977} | R⁴⁹ | G³³ | L_{A2978} | R⁴⁹ | G³⁴ | L_{A2979} | R⁴⁹ | G³⁵ | L_{A2980} | R⁴⁹ | G³⁶ |
| L_{A2981} | R⁵⁰ | G³³ | L_{A2982} | R⁵⁰ | G³⁴ | L_{A2983} | R⁵⁰ | G³⁵ | L_{A2984} | R⁵⁰ | G³⁶ |
| L_{A2985} | R⁵¹ | G³³ | L_{A2986} | R⁵¹ | G³⁴ | L_{A2987} | R⁵¹ | G³⁵ | L_{A2988} | R⁵¹ | G³⁶ |
| L_{A2989} | R⁵² | G³³ | L_{A2990} | R⁵² | G³⁴ | L_{A2991} | R⁵² | G³⁵ | L_{A2992} | R⁵² | G³⁶ |
| L_{A2993} | R⁵³ | G³³ | L_{A2994} | R⁵³ | G³⁴ | L_{A2995} | R⁵³ | G³⁵ | L_{A2996} | R⁵³ | G³⁶ |
| L_{A2997} | R⁵⁴ | G³³ | L_{A2998} | R⁵⁴ | G³⁴ | L_{A2999} | R⁵⁴ | G³⁵ | L_{A3000} | R⁵⁴ | G³⁶ |
| L_{A3001} | R⁵⁵ | G³³ | L_{A3002} | R⁵⁵ | G³⁴ | L_{A3003} | R⁵⁵ | G³⁵ | L_{A3004} | R⁵⁵ | G³⁶ |
| L_{A3005} | R⁵⁶ | G³³ | L_{A3006} | R⁵⁶ | G³⁴ | L_{A3007} | R⁵⁶ | G³⁵ | L_{A3008} | R⁵⁶ | G³⁶ |
| L_{A3009} | R⁵⁷ | G³³ | L_{A3010} | R⁵⁷ | G³⁴ | L_{A3011} | R⁵⁷ | G³⁵ | L_{A3012} | R⁵⁷ | G³⁶ |
| L_{A3013} | R⁵⁸ | G³³ | L_{A3014} | R⁵⁸ | G³⁴ | L_{A3015} | R⁵⁸ | G³⁵ | L_{A3016} | R⁵⁸ | G³⁶ |
| L_{A3017} | R⁵⁹ | G³³ | L_{A3018} | R⁵⁹ | G³⁴ | L_{A3019} | R⁵⁹ | G³⁵ | L_{A3020} | R⁵⁹ | G³⁶ |
| L_{A3021} | R⁶⁰ | G³³ | L_{A3022} | R⁶⁰ | G³⁴ | L_{A3023} | R⁶⁰ | G³⁵ | L_{A3024} | R⁶⁰ | G³⁶ |
| L_{A3025} | R⁶¹ | G³³ | L_{A3026} | R⁶¹ | G³⁴ | L_{A3027} | R⁶¹ | G³⁵ | L_{A3028} | R⁶¹ | G³⁶ |
| L_{A3029} | R⁶² | G³³ | L_{A3030} | R⁶² | G³⁴ | L_{A3031} | R⁶² | G³⁵ | L_{A3032} | R⁶² | G³⁶ |
| L_{A3033} | R⁶³ | G³³ | L_{A3034} | R⁶³ | G³⁴ | L_{A3035} | R⁶³ | G³⁵ | L_{A3036} | R⁶³ | G³⁶ |
| L_{A3037} | R⁶⁴ | G³³ | L_{A3038} | R⁶⁴ | G³⁴ | L_{A3039} | R⁶⁴ | G³⁵ | L_{A3040} | R⁶⁴ | G³⁶ |
| L_{A3041} | R⁶⁵ | G³³ | L_{A3042} | R⁶⁵ | G³⁴ | L_{A3043} | R⁶⁵ | G³⁵ | L_{A3044} | R⁶⁵ | G³⁶ |
| L_{A3045} | R⁶⁶ | G³³ | L_{A3046} | R⁶⁶ | G³⁴ | L_{A3047} | R⁶⁶ | G³⁵ | L_{A3048} | R⁶⁶ | G³⁶ |
| L_{A3049} | R⁶⁷ | G³³ | L_{A3050} | R⁶⁷ | G³⁴ | L_{A3051} | R⁶⁷ | G³⁵ | L_{A3052} | R⁶⁷ | G³⁶ |
| L_{A3053} | R⁶⁸ | G³³ | L_{A3054} | R⁶⁸ | G³⁴ | L_{A3055} | R⁶⁸ | G³⁵ | L_{A3056} | R⁶⁸ | G³⁶ |
| L_{A3057} | R⁶⁹ | G³³ | L_{A3058} | R⁶⁹ | G³⁴ | L_{A3059} | R⁶⁹ | G³⁵ | L_{A3060} | R⁶⁹ | G³⁶ |
| L_{A3061} | R⁷⁰ | G³³ | L_{A3062} | R⁷⁰ | G³⁴ | L_{A3063} | R⁷⁰ | G³⁵ | L_{A3064} | R⁷⁰ | G³⁶ |
| L_{A3065} | R⁷¹ | G³³ | L_{A3066} | R⁷¹ | G³⁴ | L_{A3067} | R⁷¹ | G³⁵ | L_{A3068} | R⁷¹ | G³⁶ |
| L_{A3069} | R⁷² | G³³ | L_{A3070} | R⁷² | G³⁴ | L_{A3071} | R⁷² | G³⁵ | L_{A3072} | R⁷² | G³⁶ |
| L_{A3073} | R⁷³ | G³³ | L_{A3074} | R⁷³ | G³⁴ | L_{A3075} | R⁷³ | G³⁵ | L_{A3076} | R⁷³ | G³⁶ |
| L_{A3077} | R⁷⁴ | G³³ | L_{A3078} | R⁷⁴ | G³⁴ | L_{A3079} | R⁷⁴ | G³⁵ | L_{A3080} | R⁷⁴ | G³⁶ |
| L_{A3081} | R⁷⁵ | G³³ | L_{A3082} | R⁷⁵ | G³⁴ | L_{A3083} | R⁷⁵ | G³⁵ | L_{A3084} | R⁷⁵ | G³⁶ |
| L_{A3085} | R⁷⁶ | G³³ | L_{A3086} | R⁷⁶ | G³⁴ | L_{A3087} | R⁷⁶ | G³⁵ | L_{A3088} | R⁷⁶ | G³⁶ |
| L_{A3089} | R⁷⁷ | G³³ | L_{A3090} | R⁷⁷ | G³⁴ | L_{A3091} | R⁷⁷ | G³⁵ | L_{A3092} | R⁷⁷ | G³⁶ |
| L_{A3093} | R⁷⁸ | G³³ | L_{A3094} | R⁷⁸ | G³⁴ | L_{A3095} | R⁷⁸ | G³⁵ | L_{A3096} | R⁷⁸ | G³⁶ |
| L_{A3097} | R⁷⁹ | G³³ | L_{A3098} | R⁷⁹ | G³⁴ | L_{A3099} | R⁷⁹ | G³⁵ | L_{A3100} | R⁷⁹ | G³⁶ |
| L_{A3101} | R⁸⁰ | G³³ | L_{A3102} | R⁸⁰ | G³⁴ | L_{A3103} | R⁸⁰ | G³⁵ | L_{A3104} | R⁸⁰ | G³⁶ |
| L_{A3105} | R⁸¹ | G³³ | L_{A3106} | R⁸¹ | G³⁴ | L_{A3107} | R⁸¹ | G³⁵ | L_{A3108} | R⁸¹ | G³⁶ |
| L_{A3109} | R⁸² | G³³ | L_{A3110} | R⁸² | G³⁴ | L_{A3111} | R⁸² | G³⁵ | L_{A3112} | R⁸² | G³⁶ |
| L_{A3113} | R⁸³ | G³³ | L_{A3114} | R⁸³ | G³⁴ | L_{A3115} | R⁸³ | G³⁵ | L_{A3116} | R⁸³ | G³⁶ |
| L_{A3117} | R⁸⁴ | G³³ | L_{A3118} | R⁸⁴ | G³⁴ | L_{A3119} | R⁸⁴ | G³⁵ | L_{A3120} | R⁸⁴ | G³⁶ |
| L_{A3121} | R⁸⁵ | G³³ | L_{A3122} | R⁸⁵ | G³⁴ | L_{A3123} | R⁸⁵ | G³⁵ | L_{A3124} | R⁸⁵ | G³⁶ |
| L_{A3125} | R⁸⁶ | G³³ | L_{A3126} | R⁸⁶ | G³⁴ | L_{A3127} | R⁸⁶ | G³⁵ | L_{A3128} | R⁸⁶ | G³⁶ |
| L_{A3129} | R⁸⁷ | G³³ | L_{A3130} | R⁸⁷ | G³⁴ | L_{A3131} | R⁸⁷ | G³⁵ | L_{A3132} | R⁸⁷ | G³⁶ |
| L_{A3133} | R¹ | G³⁷ | L_{A3134} | R¹ | G³⁸ | L_{A3135} | R¹ | G³⁹ | L_{A3136} | R¹ | G⁴⁰ |
| L_{A3137} | R² | G³⁷ | L_{A3138} | R² | G³⁸ | L_{A3139} | R² | G³⁹ | L_{A3140} | R² | G⁴⁰ |
| L_{A3141} | R³ | G³⁷ | L_{A3142} | R³ | G³⁸ | L_{A3143} | R³ | G³⁹ | L_{A3144} | R³ | G⁴⁰ |
| L_{A3145} | R⁴ | G³⁷ | L_{A3146} | R⁴ | G³⁸ | L_{A3147} | R⁴ | G³⁹ | L_{A3148} | R⁴ | G⁴⁰ |
| L_{A3149} | R⁵ | G³⁷ | L_{A3150} | R⁵ | G³⁸ | L_{A3151} | R⁵ | G³⁹ | L_{A3152} | R⁵ | G⁴⁰ |
| L_{A3153} | R⁶ | G³⁷ | L_{A3154} | R⁶ | G³⁸ | L_{A3155} | R⁶ | G³⁹ | L_{A3156} | R⁶ | G⁴⁰ |
| L_{A3157} | R⁷ | G³⁷ | L_{A3158} | R⁷ | G³⁸ | L_{A3159} | R⁷ | G³⁹ | L_{A3160} | R⁷ | G⁴⁰ |
| L_{A3161} | R⁸ | G³⁷ | L_{A3162} | R⁸ | G³⁸ | L_{A3163} | R⁸ | G³⁹ | L_{A3164} | R⁸ | G⁴⁰ |
| L_{A3165} | R⁹ | G³⁷ | L_{A3166} | R⁹ | G³⁸ | L_{A3167} | R⁹ | G³⁹ | L_{A3168} | R⁹ | G⁴⁰ |
| L_{A3169} | R¹⁰ | G³⁷ | L_{A3170} | R¹⁰ | G³⁸ | L_{A3171} | R¹⁰ | G³⁹ | L_{A3172} | R¹⁰ | G⁴⁰ |
| L_{A3173} | R¹¹ | G³⁷ | L_{A3174} | R¹¹ | G³⁸ | L_{A3175} | R¹¹ | G³⁹ | L_{A3176} | R¹¹ | G⁴⁰ |
| L_{A3177} | R¹² | G³⁷ | L_{A3178} | R¹² | G³⁸ | L_{A3179} | R¹² | G³⁹ | L_{A3180} | R¹² | G⁴⁰ |
| L_{A3181} | R¹³ | G³⁷ | L_{A3182} | R¹³ | G³⁸ | L_{A3183} | R¹³ | G³⁹ | L_{A3184} | R¹³ | G⁴⁰ |
| L_{A3185} | R¹⁴ | G³⁷ | L_{A3186} | R¹⁴ | G³⁸ | L_{A3187} | R¹⁴ | G³⁹ | L_{A3188} | R¹⁴ | G⁴⁰ |
| L_{A3189} | R¹⁵ | G³⁷ | L_{A3190} | R¹⁵ | G³⁸ | L_{A3191} | R¹⁵ | G³⁹ | L_{A3192} | R¹⁵ | G⁴⁰ |
| L_{A3193} | R¹⁶ | G³⁷ | L_{A3194} | R¹⁶ | G³⁸ | L_{A3195} | R¹⁶ | G³⁹ | L_{A3196} | R¹⁶ | G⁴⁰ |
| L_{A3197} | R¹⁷ | G³⁷ | L_{A3198} | R¹⁷ | G³⁸ | L_{A3199} | R¹⁷ | G³⁹ | L_{A3200} | R¹⁷ | G⁴⁰ |
| L_{A3201} | R¹⁸ | G³⁷ | L_{A3202} | R¹⁸ | G³⁸ | L_{A3203} | R¹⁸ | G³⁹ | L_{A3204} | R¹⁸ | G⁴⁰ |
| L_{A3205} | R¹⁹ | G³⁷ | L_{A3206} | R¹⁹ | G³⁸ | L_{A3207} | R¹⁹ | G³⁹ | L_{A3208} | R¹⁹ | G⁴⁰ |
| L_{A3209} | R²⁰ | G³⁷ | L_{A3210} | R²⁰ | G³⁸ | L_{A3211} | R²⁰ | G³⁹ | L_{A3212} | R²⁰ | G⁴⁰ |
| L_{A3213} | R²¹ | G³⁷ | L_{A3214} | R²¹ | G³⁸ | L_{A3215} | R²¹ | G³⁹ | L_{A3216} | R²¹ | G⁴⁰ |
| L_{A3217} | R²² | G³⁷ | L_{A3218} | R²² | G³⁸ | L_{A3219} | R²² | G³⁹ | L_{A3220} | R²² | G⁴⁰ |
| L_{A3221} | R²³ | G³⁷ | L_{A3222} | R²³ | G³⁸ | L_{A3223} | R²³ | G³⁹ | L_{A3224} | R²³ | G⁴⁰ |
| L_{A3225} | R²⁴ | G³⁷ | L_{A3226} | R²⁴ | G³⁸ | L_{A3227} | R²⁴ | G³⁹ | L_{A3228} | R²⁴ | G⁴⁰ |
| L_{A3229} | R²⁵ | G³⁷ | L_{A3230} | R²⁵ | G³⁸ | L_{A3231} | R²⁵ | G³⁹ | L_{A3232} | R²⁵ | G⁴⁰ |
| L_{A3233} | R²⁶ | G³⁷ | L_{A3234} | R²⁶ | G³⁸ | L_{A3235} | R²⁶ | G³⁹ | L_{A3236} | R²⁶ | G⁴⁰ |
| L_{A3237} | R²⁷ | G³⁷ | L_{A3238} | R²⁷ | G³⁸ | L_{A3239} | R²⁷ | G³⁹ | L_{A3240} | R²⁷ | G⁴⁰ |
| L_{A3241} | R²⁸ | G³⁷ | L_{A3242} | R²⁸ | G³⁸ | L_{A3243} | R²⁸ | G³⁹ | L_{A3244} | R²⁸ | G⁴⁰ |
| L_{A3245} | R²⁹ | G³⁷ | L_{A3246} | R²⁹ | G³⁸ | L_{A3247} | R²⁹ | G³⁹ | L_{A3248} | R²⁹ | G⁴⁰ |
| L_{A3249} | R³⁰ | G³⁷ | L_{A3250} | R³⁰ | G³⁸ | L_{A3251} | R³⁰ | G³⁹ | L_{A3252} | R³⁰ | G⁴⁰ |
| L_{A3253} | R³¹ | G³⁷ | L_{A3254} | R³¹ | G³⁸ | L_{A3255} | R³¹ | G³⁹ | L_{A3256} | R³¹ | G⁴⁰ |
| L_{A3257} | R³² | G³⁷ | L_{A3258} | R³² | G³⁸ | L_{A3259} | R³² | G³⁹ | L_{A3260} | R³² | G⁴⁰ |
| L_{A3261} | R³³ | G³⁷ | L_{A3262} | R³³ | G³⁸ | L_{A3263} | R³³ | G³⁹ | L_{A3264} | R³³ | G⁴⁰ |
| L_{A3265} | R³⁴ | G³⁷ | L_{A3266} | R³⁴ | G³⁸ | L_{A3267} | R³⁴ | G³⁹ | L_{A3268} | R³⁴ | G⁴⁰ |
| L_{A3269} | R³⁵ | G³⁷ | L_{A3270} | R³⁵ | G³⁸ | L_{A3271} | R³⁵ | G³⁹ | L_{A3272} | R³⁵ | G⁴⁰ |
| L_{A3273} | R³⁶ | G³⁷ | L_{A3274} | R³⁶ | G³⁸ | L_{A3275} | R³⁶ | G³⁹ | L_{A3276} | R³⁶ | G⁴⁰ |
| L_{A3277} | R³⁷ | G³⁷ | L_{A3278} | R³⁷ | G³⁸ | L_{A3279} | R³⁷ | G³⁹ | L_{A3280} | R³⁷ | G⁴⁰ |
| L_{A3281} | R³⁸ | G³⁷ | L_{A3282} | R³⁸ | G³⁸ | L_{A3283} | R³⁸ | G³⁹ | L_{A3284} | R³⁸ | G⁴⁰ |
| L_{A3285} | R³⁹ | G³⁷ | L_{A3286} | R³⁹ | G³⁸ | L_{A3287} | R³⁹ | G³⁹ | L_{A3288} | R³⁹ | G⁴⁰ |
| L_{A3289} | R⁴⁰ | G³⁷ | L_{A3290} | R⁴⁰ | G³⁸ | L_{A3291} | R⁴⁰ | G³⁹ | L_{A3292} | R⁴⁰ | G⁴⁰ |
| L_{A3293} | R⁴¹ | G³⁷ | L_{A3294} | R⁴¹ | G³⁸ | L_{A3295} | R⁴¹ | G³⁹ | L_{A3296} | R⁴¹ | G⁴⁰ |
| L_{A3297} | R⁴² | G³⁷ | L_{A3298} | R⁴² | G³⁸ | L_{A3299} | R⁴² | G³⁹ | L_{A3300} | R⁴² | G⁴⁰ |
| L_{A3301} | R⁴³ | G³⁷ | L_{A3302} | R⁴³ | G³⁸ | L_{A3303} | R⁴³ | G³⁹ | L_{A3304} | R⁴³ | G⁴⁰ |
| L_{A3305} | R⁴⁴ | G³⁷ | L_{A3306} | R⁴⁴ | G³⁸ | L_{A3307} | R⁴⁴ | G³⁹ | L_{A3308} | R⁴⁴ | G⁴⁰ |
| L_{A3309} | R⁴⁵ | G³⁷ | L_{A3310} | R⁴⁵ | G³⁸ | L_{A3311} | R⁴⁵ | G³⁹ | L_{A3312} | R⁴⁵ | G⁴⁰ |
| L_{A3313} | R⁴⁶ | G³⁷ | L_{A3314} | R⁴⁶ | G³⁸ | L_{A3315} | R⁴⁶ | G³⁹ | L_{A3316} | R⁴⁶ | G⁴⁰ |
| L_{A3317} | R⁴⁷ | G³⁷ | L_{A3318} | R⁴⁷ | G³⁸ | L_{A3319} | R⁴⁷ | G³⁹ | L_{A3320} | R⁴⁷ | G⁴⁰ |
| L_{A3321} | R⁴⁸ | G³⁷ | L_{A3322} | R⁴⁸ | G³⁸ | L_{A3323} | R⁴⁸ | G³⁹ | L_{A3324} | R⁴⁸ | G⁴⁰ |
| L_{A3325} | R⁴⁹ | G³⁷ | L_{A3326} | R⁴⁹ | G³⁸ | L_{A3327} | R⁴⁹ | G³⁹ | L_{A3328} | R⁴⁹ | G⁴⁰ |
| L_{A3329} | R⁵⁰ | G³⁷ | L_{A3330} | R⁵⁰ | G³⁸ | L_{A3331} | R⁵⁰ | G³⁹ | L_{A3332} | R⁵⁰ | G⁴⁰ |
| L_{A3333} | R⁵¹ | G³⁷ | L_{A3334} | R⁵¹ | G³⁸ | L_{A3335} | R⁵¹ | G³⁹ | L_{A3336} | R⁵¹ | G⁴⁰ |
| L_{A3337} | R⁵² | G³⁷ | L_{A3338} | R⁵² | G³⁸ | L_{A3339} | R⁵² | G³⁹ | L_{A3340} | R⁵² | G⁴⁰ |
| L_{A3341} | R⁵³ | G³⁷ | L_{A3342} | R⁵³ | G³⁸ | L_{A3343} | R⁵³ | G³⁹ | L_{A3344} | R⁵³ | G⁴⁰ |
| L_{A3345} | R⁵⁴ | G³⁷ | L_{A3346} | R⁵⁴ | G³⁸ | L_{A3347} | R⁵⁴ | G³⁹ | L_{A3348} | R⁵⁴ | G⁴⁰ |
| L_{A3349} | R⁵⁵ | G³⁷ | L_{A3350} | R⁵⁵ | G³⁸ | L_{A3351} | R⁵⁵ | G³⁹ | L_{A3352} | R⁵⁵ | G⁴⁰ |
| L_{A3353} | R⁵⁶ | G³⁷ | L_{A3354} | R⁵⁶ | G³⁸ | L_{A3355} | R⁵⁶ | G³⁹ | L_{A3356} | R⁵⁶ | G⁴⁰ |
| L_{A3357} | R⁵⁷ | G³⁷ | L_{A3358} | R⁵⁷ | G³⁸ | L_{A3359} | R⁵⁷ | G³⁹ | L_{A3360} | R⁵⁷ | G⁴⁰ |
| L_{A3361} | R⁵⁸ | G³⁷ | L_{A3362} | R⁵⁸ | G³⁸ | L_{A3363} | R⁵⁸ | G³⁹ | L_{A3364} | R⁵⁸ | G⁴⁰ |
| L_{A3365} | R⁵⁹ | G³⁷ | L_{A3366} | R⁵⁹ | G³⁸ | L_{A3367} | R⁵⁹ | G³⁹ | L_{A3368} | R⁵⁹ | G⁴⁰ |
| L_{A3369} | R⁶⁰ | G³⁷ | L_{A3370} | R⁶⁰ | G³⁸ | L_{A3371} | R⁶⁰ | G³⁹ | L_{A3372} | R⁶⁰ | G⁴⁰ |
| L_{A3373} | R⁶¹ | G³⁷ | L_{A3374} | R⁶¹ | G³⁸ | L_{A3375} | R⁶¹ | G³⁹ | L_{A3376} | R⁶¹ | G⁴⁰ |
| L_{A3377} | R⁶² | G³⁷ | L_{A3378} | R⁶² | G³⁸ | L_{A3379} | R⁶² | G³⁹ | L_{A3380} | R⁶² | G⁴⁰ |
| L_{A3381} | R⁶³ | G³⁷ | L_{A3382} | R⁶³ | G³⁸ | L_{A3383} | R⁶³ | G³⁹ | L_{A3384} | R⁶³ | G⁴⁰ |
| L_{A3385} | R⁶⁴ | G³⁷ | L_{A3386} | R⁶⁴ | G³⁸ | L_{A3387} | R⁶⁴ | G³⁹ | L_{A3388} | R⁶⁴ | G⁴⁰ |
| L_{A3389} | R⁶⁵ | G³⁷ | L_{A3390} | R⁶⁵ | G³⁸ | L_{A3391} | R⁶⁵ | G³⁹ | L_{A3392} | R⁶⁵ | G⁴⁰ |
| L_{A3393} | R⁶⁶ | G³⁷ | L_{A3394} | R⁶⁶ | G³⁸ | L_{A3395} | R⁶⁶ | G³⁹ | L_{A3396} | R⁶⁶ | G⁴⁰ |
| L_{A3397} | R⁶⁷ | G³⁷ | L_{A3398} | R⁶⁷ | G³⁸ | L_{A3399} | R⁶⁷ | G³⁹ | L_{A3400} | R⁶⁷ | G⁴⁰ |
| L_{A3401} | R⁶⁸ | G³⁷ | L_{A3402} | R⁶⁸ | G³⁸ | L_{A3403} | R⁶⁸ | G³⁹ | L_{A3404} | R⁶⁸ | G⁴⁰ |
| L_{A3405} | R⁶⁹ | G³⁷ | L_{A3406} | R⁶⁹ | G³⁸ | L_{A3407} | R⁶⁹ | G³⁹ | L_{A3408} | R⁶⁹ | G⁴⁰ |
| L_{A3409} | R⁷⁰ | G³⁷ | L_{A3410} | R⁷⁰ | G³⁸ | L_{A3411} | R⁷⁰ | G³⁹ | L_{A3412} | R⁷⁰ | G⁴⁰ |
| L_{A3413} | R⁷¹ | G³⁷ | L_{A3414} | R⁷¹ | G³⁸ | L_{A3415} | R⁷¹ | G³⁹ | L_{A3416} | R⁷¹ | G⁴⁰ |
| L_{A3417} | R⁷² | G³⁷ | L_{A3418} | R⁷² | G³⁸ | L_{A3419} | R⁷² | G³⁹ | L_{A3420} | R⁷² | G⁴⁰ |
| L_{A3421} | R⁷³ | G³⁷ | L_{A3422} | R⁷³ | G³⁸ | L_{A3423} | R⁷³ | G³⁹ | L_{A3424} | R⁷³ | G⁴⁰ |
| L_{A3425} | R⁷⁴ | G³⁷ | L_{A3426} | R⁷⁴ | G³⁸ | L_{A3427} | R⁷⁴ | G³⁹ | L_{A3428} | R⁷⁴ | G⁴⁰ |
| L_{A3429} | R⁷⁵ | G³⁷ | L_{A3430} | R⁷⁵ | G³⁸ | L_{A3431} | R⁷⁵ | G³⁹ | L_{A3432} | R⁷⁵ | G⁴⁰ |
| L_{A3433} | R⁷⁶ | G³⁷ | L_{A3434} | R⁷⁶ | G³⁸ | L_{A3435} | R⁷⁶ | G³⁹ | L_{A3436} | R⁷⁶ | G⁴⁰ |
| L_{A3437} | R⁷⁷ | G³⁷ | L_{A3438} | R⁷⁷ | G³⁸ | L_{A3439} | R⁷⁷ | G³⁹ | L_{A3440} | R⁷⁷ | G⁴⁰ |
| L_{A3441} | R⁷⁸ | G³⁷ | L_{A3442} | R⁷⁸ | G³⁸ | L_{A3443} | R⁷⁸ | G³⁹ | L_{A3444} | R⁷⁸ | G⁴⁰ |
| L_{A3445} | R⁷⁹ | G³⁷ | L_{A3446} | R⁷⁹ | G³⁸ | L_{A3447} | R⁷⁹ | G³⁹ | L_{A3448} | R⁷⁹ | G⁴⁰ |
| L_{A3449} | R⁸⁰ | G³⁷ | L_{A3450} | R⁸⁰ | G³⁸ | L_{A3451} | R⁸⁰ | G³⁹ | L_{A3452} | R⁸⁰ | G⁴⁰ |
| L_{A3453} | R⁸¹ | G³⁷ | L_{A3454} | R⁸¹ | G³⁸ | L_{A3455} | R⁸¹ | G³⁹ | L_{A3456} | R⁸¹ | G⁴⁰ |
| L_{A3457} | R⁸² | G³⁷ | L_{A3458} | R⁸² | G³⁸ | L_{A3459} | R⁸² | G³⁹ | L_{A3460} | R⁸² | G⁴⁰ |
| L_{A3461} | R⁸³ | G³⁷ | L_{A3462} | R⁸³ | G³⁸ | L_{A3463} | R⁸³ | G³⁹ | L_{A3464} | R⁸³ | G⁴⁰ |
| L_{A3465} | R⁸⁴ | G³⁷ | L_{A3466} | R⁸⁴ | G³⁸ | L_{A3467} | R⁸⁴ | G³⁹ | L_{A3468} | R⁸⁴ | G⁴⁰ |
| L_{A3469} | R⁸⁵ | G³⁷ | L_{A3470} | R⁸⁵ | G³⁸ | L_{A3471} | R⁸⁵ | G³⁹ | L_{A3472} | R⁸⁵ | G⁴⁰ |
| L_{A3473} | R⁸⁶ | G³⁷ | L_{A3474} | R⁸⁶ | G³⁸ | L_{A3475} | R⁸⁶ | G³⁹ | L_{A3476} | R⁸⁶ | G⁴⁰ |
| L_{A3477} | R⁸⁷ | G³⁷ | L_{A3478} | R⁸⁷ | G³⁸ | L_{A3479} | R⁸⁷ | G³⁹ | L_{A3480} | R⁸⁷ | G⁴⁰ |
| L_{A3481} | R¹ | G⁴¹ | L_{A3482} | R¹ | G⁴² | L_{A3483} | R¹ | G⁴³ | L_{A3484} | R¹ | G⁴⁴ |
| L_{A3485} | R² | G⁴¹ | L_{A3486} | R² | G⁴² | L_{A3487} | R² | G⁴³ | L_{A3488} | R² | G⁴⁴ |
| L_{A3489} | R³ | G⁴¹ | L_{A3490} | R³ | G⁴² | L_{A3491} | R³ | G⁴³ | L_{A3492} | R³ | G⁴⁴ |
| L_{A3493} | R⁴ | G⁴¹ | L_{A3494} | R⁴ | G⁴² | L_{A3495} | R⁴ | G⁴³ | L_{A3496} | R⁴ | G⁴⁴ |
| L_{A3497} | R⁵ | G⁴¹ | L_{A3498} | R⁵ | G⁴² | L_{A3499} | R⁵ | G⁴³ | L_{A3500} | R⁵ | G⁴⁴ |
| L_{A3501} | R⁶ | G⁴¹ | L_{A3502} | R⁶ | G⁴² | L_{A3503} | R⁶ | G⁴³ | L_{A3504} | R⁶ | G⁴⁴ |
| L_{A3505} | R⁷ | G⁴¹ | L_{A3506} | R⁷ | G⁴² | L_{A3507} | R⁷ | G⁴³ | L_{A3508} | R⁷ | G⁴⁴ |
| L_{A3509} | R⁸ | G⁴¹ | L_{A3510} | R⁸ | G⁴² | L_{A3511} | R⁸ | G⁴³ | L_{A3512} | R⁸ | G⁴⁴ |
| L_{A3513} | R⁹ | G⁴¹ | L_{A3514} | R⁹ | G⁴² | L_{A3515} | R⁹ | G⁴³ | L_{A3516} | R⁹ | G⁴⁴ |
| L_{A3517} | R¹⁰ | G⁴¹ | L_{A3518} | R¹⁰ | G⁴² | L_{A3519} | R¹⁰ | G⁴³ | L_{A3520} | R¹⁰ | G⁴⁴ |
| L_{A3521} | R¹¹ | G⁴¹ | L_{A3522} | R¹¹ | G⁴² | L_{A3523} | R¹¹ | G⁴³ | L_{A3524} | R¹¹ | G⁴⁴ |
| L_{A3525} | R¹² | G⁴¹ | L_{A3526} | R¹² | G⁴² | L_{A3527} | R¹² | G⁴³ | L_{A3528} | R¹² | G⁴⁴ |
| L_{A3529} | R¹³ | G⁴¹ | L_{A3530} | R¹³ | G⁴² | L_{A3531} | R¹³ | G⁴³ | L_{A3532} | R¹³ | G⁴⁴ |
| L_{A3533} | R¹⁴ | G⁴¹ | L_{A3534} | R¹⁴ | G⁴² | L_{A3535} | R¹⁴ | G⁴³ | L_{A3536} | R¹⁴ | G⁴⁴ |
| L_{A3537} | R¹⁵ | G⁴¹ | L_{A3538} | R¹⁵ | G⁴² | L_{A3539} | R¹⁵ | G⁴³ | L_{A3540} | R¹⁵ | G⁴⁴ |
| L_{A3541} | R¹⁶ | G⁴¹ | L_{A3542} | R¹⁶ | G⁴² | L_{A3543} | R¹⁶ | G⁴³ | L_{A3544} | R¹⁶ | G⁴⁴ |
| L_{A3545} | R¹⁷ | G⁴¹ | L_{A3546} | R¹⁷ | G⁴² | L_{A3547} | R¹⁷ | G⁴³ | L_{A3548} | R¹⁷ | G⁴⁴ |
| L_{A3549} | R¹⁸ | G⁴¹ | L_{A3550} | R¹⁸ | G⁴² | L_{A3551} | R¹⁸ | G⁴³ | L_{A3552} | R¹⁸ | G⁴⁴ |
| L_{A3553} | R¹⁹ | G⁴¹ | L_{A3554} | R¹⁹ | G⁴² | L_{A3555} | R¹⁹ | G⁴³ | L_{A3556} | R¹⁹ | G⁴⁴ |
| L_{A3557} | R²⁰ | G⁴¹ | L_{A3558} | R²⁰ | G⁴² | L_{A3559} | R²⁰ | G⁴³ | L_{A3560} | R²⁰ | G⁴⁴ |
| L_{A3561} | R²¹ | G⁴¹ | L_{A3562} | R²¹ | G⁴² | L_{A3563} | R²¹ | G⁴³ | L_{A3564} | R²¹ | G⁴⁴ |
| L_{A3565} | R²² | G⁴¹ | L_{A3566} | R²² | G⁴² | L_{A3567} | R²² | G⁴³ | L_{A3568} | R²² | G⁴⁴ |
| L_{A3569} | R²³ | G⁴¹ | L_{A3570} | R²³ | G⁴² | L_{A3571} | R²³ | G⁴³ | L_{A3572} | R²³ | G⁴⁴ |
| L_{A3573} | R²⁴ | G⁴¹ | L_{A3574} | R²⁴ | G⁴² | L_{A3575} | R²⁴ | G⁴³ | L_{A3576} | R²⁴ | G⁴⁴ |
| L_{A3577} | R²⁵ | G⁴¹ | L_{A3578} | R²⁵ | G⁴² | L_{A3579} | R²⁵ | G⁴³ | L_{A3580} | R²⁵ | G⁴⁴ |
| L_{A3581} | R²⁶ | G⁴¹ | L_{A3582} | R²⁶ | G⁴² | L_{A3583} | R²⁶ | G⁴³ | L_{A3584} | R²⁶ | G⁴⁴ |
| L_{A3585} | R²⁷ | G⁴¹ | L_{A3586} | R²⁷ | G⁴² | L_{A3587} | R²⁷ | G⁴³ | L_{A3588} | R²⁷ | G⁴⁴ |
| L_{A3589} | R²⁸ | G⁴¹ | L_{A3590} | R²⁸ | G⁴² | L_{A3591} | R²⁸ | G⁴³ | L_{A3592} | R²⁸ | G⁴⁴ |
| L_{A3593} | R²⁹ | G⁴¹ | L_{A3594} | R²⁹ | G⁴² | L_{A3595} | R²⁹ | G⁴³ | L_{A3596} | R²⁹ | G⁴⁴ |
| L_{A3597} | R³⁰ | G⁴¹ | L_{A3598} | R³⁰ | G⁴² | L_{A3599} | R³⁰ | G⁴³ | L_{A3600} | R³⁰ | G⁴⁴ |
| L_{A3601} | R³¹ | G⁴¹ | L_{A3602} | R³¹ | G⁴² | L_{A3603} | R³¹ | G⁴³ | L_{A3604} | R³¹ | G⁴⁴ |
| L_{A3605} | R³² | G⁴¹ | L_{A3606} | R³² | G⁴² | L_{A3607} | R³² | G⁴³ | L_{A3608} | R³² | G⁴⁴ |
| L_{A3609} | R³³ | G⁴¹ | L_{A3610} | R³³ | G⁴² | L_{A3611} | R³³ | G⁴³ | L_{A3612} | R³³ | G⁴⁴ |
| L_{A3613} | R³⁴ | G⁴¹ | L_{A3614} | R³⁴ | G⁴² | L_{A3615} | R³⁴ | G⁴³ | L_{A3616} | R³⁴ | G⁴⁴ |
| L_{A3617} | R³⁵ | G⁴¹ | L_{A3618} | R³⁵ | G⁴² | L_{A3619} | R³⁵ | G⁴³ | L_{A3620} | R³⁵ | G⁴⁴ |
| L_{A3621} | R³⁶ | G⁴¹ | L_{A3622} | R³⁶ | G⁴² | L_{A3623} | R³⁶ | G⁴³ | L_{A3624} | R³⁶ | G⁴⁴ |
| L_{A3625} | R³⁷ | G⁴¹ | L_{A3626} | R³⁷ | G⁴² | L_{A3627} | R³⁷ | G⁴³ | L_{A3628} | R³⁷ | G⁴⁴ |
| L_{A3629} | R³⁸ | G⁴¹ | L_{A3620} | R³⁸ | G⁴² | L_{A3631} | R³⁸ | G⁴³ | L_{A3632} | R³⁸ | G⁴⁴ |
| L_{A3633} | R³⁹ | G⁴¹ | L_{A3634} | R³⁹ | G⁴² | L_{A3635} | R³⁹ | G⁴³ | L_{A3636} | R³⁹ | G⁴⁴ |
| L_{A3637} | R⁴⁰ | G⁴¹ | L_{A3638} | R⁴⁰ | G⁴² | L_{A3639} | R⁴⁰ | G⁴³ | L_{A3640} | R⁴⁰ | G⁴⁴ |
| L_{A3641} | R⁴¹ | G⁴¹ | L_{A3642} | R⁴¹ | G⁴² | L_{A3643} | R⁴¹ | G⁴³ | L_{A3644} | R⁴¹ | G⁴⁴ |
| L_{A3645} | R⁴² | G⁴¹ | L_{A3646} | R⁴² | G⁴² | L_{A3647} | R⁴² | G⁴³ | L_{A3648} | R⁴² | G⁴⁴ |
| L_{A3649} | R⁴³ | G⁴¹ | L_{A3650} | R⁴³ | G⁴² | L_{A3651} | R⁴³ | G⁴³ | L_{A3652} | R⁴³ | G⁴⁴ |
| L_{A3653} | R⁴⁴ | G⁴¹ | L_{A3654} | R⁴⁴ | G⁴² | L_{A3655} | R⁴⁴ | G⁴³ | L_{A3656} | R⁴⁴ | G⁴⁴ |
| L_{A3657} | R⁴⁵ | G⁴¹ | L_{A3658} | R⁴⁵ | G⁴² | L_{A3659} | R⁴⁵ | G⁴³ | L_{A3660} | R⁴⁵ | G⁴⁴ |
| L_{A3661} | R⁴⁶ | G⁴¹ | L_{A3662} | R⁴⁶ | G⁴² | L_{A3663} | R⁴⁶ | G⁴³ | L_{A3664} | R⁴⁶ | G⁴⁴ |
| L_{A3665} | R⁴⁷ | G⁴¹ | L_{A3666} | R⁴⁷ | G⁴² | L_{A3667} | R⁴⁷ | G⁴³ | L_{A3668} | R⁴⁷ | G⁴⁴ |
| L_{A3669} | R⁴⁸ | G⁴¹ | L_{A3670} | R⁴⁸ | G⁴² | L_{A3671} | R⁴⁸ | G⁴³ | L_{A3672} | R⁴⁸ | G⁴⁴ |
| L_{A3673} | R⁴⁹ | G⁴¹ | L_{A3674} | R⁴⁹ | G⁴² | L_{A3675} | R⁴⁹ | G⁴³ | L_{A3676} | R⁴⁹ | G⁴⁴ |
| L_{A3677} | R⁵⁰ | G⁴¹ | L_{A3678} | R⁵⁰ | G⁴² | L_{A3679} | R⁵⁰ | G⁴³ | L_{A3680} | R⁵⁰ | G⁴⁴ |
| L_{A3681} | R⁵¹ | G⁴¹ | L_{A3682} | R⁵¹ | G⁴² | L_{A3683} | R⁵¹ | G⁴³ | L_{A3684} | R⁵¹ | G⁴⁴ |
| L_{A3685} | R⁵² | G⁴¹ | L_{A3686} | R⁵² | G⁴² | L_{A3687} | R⁵² | G⁴³ | L_{A3688} | R⁵² | G⁴⁴ |
| L_{A3689} | R⁵³ | G⁴¹ | L_{A3690} | R⁵³ | G⁴² | L_{A3691} | R⁵³ | G⁴³ | L_{A3692} | R⁵³ | G⁴⁴ |
| L_{A3693} | R⁵⁴ | G⁴¹ | L_{A3694} | R⁵⁴ | G⁴² | L_{A3695} | R⁵⁴ | G⁴³ | L_{A3696} | R⁵⁴ | G⁴⁴ |
| L_{A3697} | R⁵⁵ | G⁴¹ | L_{A3698} | R⁵⁵ | G⁴² | L_{A3699} | R⁵⁵ | G⁴³ | L_{A3700} | R⁵⁵ | G⁴⁴ |
| L_{A3701} | R⁵⁶ | G⁴¹ | L_{A3702} | R⁵⁶ | G⁴² | L_{A3703} | R⁵⁶ | G⁴³ | L_{A3704} | R⁵⁶ | G⁴⁴ |
| L_{A3705} | R⁵⁷ | G⁴¹ | L_{A3706} | R⁵⁷ | G⁴² | L_{A3707} | R⁵⁷ | G⁴³ | L_{A3708} | R⁵⁷ | G⁴⁴ |
| L_{A3709} | R⁵⁸ | G⁴¹ | L_{A3710} | R⁵⁸ | G⁴² | L_{A3711} | R⁵⁸ | G⁴³ | L_{A3712} | R⁵⁸ | G⁴⁴ |
| L_{A3713} | R⁵⁹ | G⁴¹ | L_{A3714} | R⁵⁹ | G⁴² | L_{A3715} | R⁵⁹ | G⁴³ | L_{A3716} | R⁵⁹ | G⁴⁴ |
| L_{A3717} | R⁶⁰ | G⁴¹ | L_{A3718} | R⁶⁰ | G⁴² | L_{A3719} | R⁶⁰ | G⁴³ | L_{A3720} | R⁶⁰ | G⁴⁴ |
| L_{A3721} | R⁶¹ | G⁴¹ | L_{A3722} | R⁶¹ | G⁴² | L_{A3723} | R⁶¹ | G⁴³ | L_{A3724} | R⁶¹ | G⁴⁴ |
| L_{A3725} | R⁶² | G⁴¹ | L_{A3726} | R⁶² | G⁴² | L_{A3727} | R⁶² | G⁴³ | L_{A3728} | R⁶² | G⁴⁴ |
| L_{A3729} | R⁶³ | G⁴¹ | L_{A3730} | R⁶³ | G⁴² | L_{A3731} | R⁶³ | G⁴³ | L_{A3732} | R⁶³ | G⁴⁴ |
| L_{A3733} | R⁶⁴ | G⁴¹ | L_{A3734} | R⁶⁴ | G⁴² | L_{A3735} | R⁶⁴ | G⁴³ | L_{A3736} | R⁶⁴ | G⁴⁴ |
| L_{A3737} | R⁶⁵ | G⁴¹ | L_{A3738} | R⁶⁵ | G⁴² | L_{A3739} | R⁶⁵ | G⁴³ | L_{A3740} | R⁶⁵ | G⁴⁴ |
| L_{A3741} | R⁶⁶ | G⁴¹ | L_{A3742} | R⁶⁶ | G⁴² | L_{A3743} | R⁶⁶ | G⁴³ | L_{A3744} | R⁶⁶ | G⁴⁴ |
| L_{A3745} | R⁶⁷ | G⁴¹ | L_{A3746} | R⁶⁷ | G⁴² | L_{A3747} | R⁶⁷ | G⁴³ | L_{A3748} | R⁶⁷ | G⁴⁴ |
| L_{A3749} | R⁶⁸ | G⁴¹ | L_{A3750} | R⁶⁸ | G⁴² | L_{A3751} | R⁶⁸ | G⁴³ | L_{A3752} | R⁶⁸ | G⁴⁴ |
| L_{A3753} | R⁶⁹ | G⁴¹ | L_{A3754} | R⁶⁹ | G⁴² | L_{A3755} | R⁶⁹ | G⁴³ | L_{A3756} | R⁶⁹ | G⁴⁴ |
| L_{A3757} | R⁷⁰ | G⁴¹ | L_{A3758} | R⁷⁰ | G⁴² | L_{A3759} | R⁷⁰ | G⁴³ | L_{A3760} | R⁷⁰ | G⁴⁴ |
| L_{A3761} | R⁷¹ | G⁴¹ | L_{A3762} | R⁷¹ | G⁴² | L_{A3763} | R⁷¹ | G⁴³ | L_{A3764} | R⁷¹ | G⁴⁴ |
| L_{A3765} | R⁷² | G⁴¹ | L_{A3766} | R⁷² | G⁴² | L_{A3767} | R⁷² | G⁴³ | L_{A3768} | R⁷² | G⁴⁴ |
| L_{A3769} | R⁷³ | G⁴¹ | L_{A3770} | R⁷³ | G⁴² | L_{A3771} | R⁷³ | G⁴³ | L_{A3772} | R⁷³ | G⁴⁴ |
| L_{A3773} | R⁷⁴ | G⁴¹ | L_{A3774} | R⁷⁴ | G⁴² | L_{A3775} | R⁷⁴ | G⁴³ | L_{A3776} | R⁷⁴ | G⁴⁴ |
| L_{A3777} | R⁷⁵ | G⁴¹ | L_{A3778} | R⁷⁵ | G⁴² | L_{A3779} | R⁷⁵ | G⁴³ | L_{A3780} | R⁷⁵ | G⁴⁴ |
| L_{A3781} | R⁷⁶ | G⁴¹ | L_{A3782} | R⁷⁶ | G⁴² | L_{A3783} | R⁷⁶ | G⁴³ | L_{A3784} | R⁷⁶ | G⁴⁴ |
| L_{A3785} | R⁷⁷ | G⁴¹ | L_{A3786} | R⁷⁷ | G⁴² | L_{A3787} | R⁷⁷ | G⁴³ | L_{A3788} | R⁷⁷ | G⁴⁴ |
| L_{A3789} | R⁷⁸ | G⁴¹ | L_{A3790} | R⁷⁸ | G⁴² | L_{A3791} | R⁷⁸ | G⁴³ | L_{A3792} | R⁷⁸ | G⁴⁴ |
| L_{A3793} | R⁷⁹ | G⁴¹ | L_{A3794} | R⁷⁹ | G⁴² | L_{A3795} | R⁷⁹ | G⁴³ | L_{A3796} | R⁷⁹ | G⁴⁴ |
| L_{A3797} | R⁸⁰ | G⁴¹ | L_{A3798} | R⁸⁰ | G⁴² | L_{A3799} | R⁸⁰ | G⁴³ | L_{A3800} | R⁸⁰ | G⁴⁴ |
| L_{A3801} | R⁸¹ | G⁴¹ | L_{A3802} | R⁸¹ | G⁴² | L_{A3803} | R⁸¹ | G⁴³ | L_{A3804} | R⁸¹ | G⁴⁴ |
| L_{A3805} | R⁸² | G⁴¹ | L_{A3806} | R⁸² | G⁴² | L_{A3807} | R⁸² | G⁴³ | L_{A3808} | R⁸² | G⁴⁴ |
| L_{A3809} | R⁸³ | G⁴¹ | L_{A3810} | R⁸³ | G⁴² | L_{A3811} | R⁸³ | G⁴³ | L_{A3812} | R⁸³ | G⁴⁴ |
| L_{A3813} | R⁸⁴ | G⁴¹ | L_{A3814} | R⁸⁴ | G⁴² | L_{A3815} | R⁸⁴ | G⁴³ | L_{A3816} | R⁸⁴ | G⁴⁴ |
| L_{A3817} | R⁸⁵ | G⁴¹ | L_{A3818} | R⁸⁵ | G⁴² | L_{A3819} | R⁸⁵ | G⁴³ | L_{A3820} | R⁸⁵ | G⁴⁴ |
| L_{A3821} | R⁸⁶ | G⁴¹ | L_{A3822} | R⁸⁶ | G⁴² | L_{A3823} | R⁸⁶ | G⁴³ | L_{A3824} | R⁸⁶ | G⁴⁴ |
| L_{A3825} | R⁸⁷ | G⁴¹ | L_{A3826} | R⁸⁷ | G⁴² | L_{A3827} | R⁸⁷ | G⁴³ | L_{A3828} | R⁸⁷ | G⁴⁴ |
| L_{A3829} | R¹ | G⁴⁵ | L_{A3830} | R¹ | G⁴⁶ | L_{A3831} | R¹ | G⁴⁷ | L_{A3832} | R¹ | G⁴⁸ |
| L_{A3833} | R² | G⁴⁵ | L_{A3834} | R² | G⁴⁶ | L_{A3835} | R² | G⁴⁷ | L_{A3836} | R² | G⁴⁸ |
| L_{A3837} | R³ | G⁴⁵ | L_{A3838} | R³ | G⁴⁶ | L_{A3839} | R³ | G⁴⁷ | L_{A3840} | R³ | G⁴⁸ |
| L_{A3841} | R⁴ | G⁴⁵ | L_{A3842} | R⁴ | G⁴⁶ | L_{A3843} | R⁴ | G⁴⁷ | L_{A3844} | R⁴ | G⁴⁸ |
| L_{A3845} | R⁵ | G⁴⁵ | L_{A3846} | R⁵ | G⁴⁶ | L_{A3847} | R⁵ | G⁴⁷ | L_{A3848} | R⁵ | G⁴⁸ |
| L_{A3849} | R⁶ | G⁴⁵ | L_{A3850} | R⁶ | G⁴⁶ | L_{A3851} | R⁶ | G⁴⁷ | L_{A3852} | R⁶ | G⁴⁸ |
| L_{A3853} | R⁷ | G⁴⁵ | L_{A3854} | R⁷ | G⁴⁶ | L_{A3855} | R⁷ | G⁴⁷ | L_{A3856} | R⁷ | G⁴⁸ |
| L_{A3857} | R⁸ | G⁴⁵ | L_{A3858} | R⁸ | G⁴⁶ | L_{A3859} | R⁸ | G⁴⁷ | L_{A3860} | R⁸ | G⁴⁸ |
| L_{A3861} | R⁹ | G⁴⁵ | L_{A3862} | R⁹ | G⁴⁶ | L_{A3863} | R⁹ | G⁴⁷ | L_{A3864} | R⁹ | G⁴⁸ |
| L_{A3865} | R¹⁰ | G⁴⁵ | L_{A3866} | R¹⁰ | G⁴⁶ | L_{A3867} | R¹⁰ | G⁴⁷ | L_{A3868} | R¹⁰ | G⁴⁸ |
| L_{A3869} | R¹¹ | G⁴⁵ | L_{A3870} | R¹¹ | G⁴⁶ | L_{A3871} | R¹¹ | G⁴⁷ | L_{A3872} | R¹¹ | G⁴⁸ |
| L_{A3873} | R¹² | G⁴⁵ | L_{A3874} | R¹² | G⁴⁶ | L_{A3875} | R¹² | G⁴⁷ | L_{A3876} | R¹² | G⁴⁸ |
| L_{A3877} | R¹³ | G⁴⁵ | L_{A3878} | R¹³ | G⁴⁶ | L_{A3879} | R¹³ | G⁴⁷ | L_{A3880} | R¹³ | G⁴⁸ |
| L_{A3881} | R¹⁴ | G⁴⁵ | L_{A3882} | R¹⁴ | G⁴⁶ | L_{A3883} | R¹⁴ | G⁴⁷ | L_{A3884} | R¹⁴ | G⁴⁸ |
| L_{A3885} | R¹⁵ | G⁴⁵ | L_{A3886} | R¹⁵ | G⁴⁶ | L_{A3887} | R¹⁵ | G⁴⁷ | L_{A3888} | R¹⁵ | G⁴⁸ |
| L_{A3889} | R¹⁶ | G⁴⁵ | L_{A3890} | R¹⁶ | G⁴⁶ | L_{A3891} | R¹⁶ | G⁴⁷ | L_{A3892} | R¹⁶ | G⁴⁸ |
| L_{A3893} | R¹⁷ | G⁴⁵ | L_{A3894} | R¹⁷ | G⁴⁶ | L_{A3895} | R¹⁷ | G⁴⁷ | L_{A3896} | R¹⁷ | G⁴⁸ |
| L_{A3897} | R¹⁸ | G⁴⁵ | L_{A3898} | R¹⁸ | G⁴⁶ | L_{A3899} | R¹⁸ | G⁴⁷ | L_{A3900} | R¹⁸ | G⁴⁸ |
| L_{A3901} | R¹⁹ | G⁴⁵ | L_{A3902} | R¹⁹ | G⁴⁶ | L_{A3903} | R¹⁹ | G⁴⁷ | L_{A3904} | R¹⁹ | G⁴⁸ |
| L_{A3905} | R²⁰ | G⁴⁵ | L_{A3906} | R²⁰ | G⁴⁶ | L_{A3907} | R²⁰ | G⁴⁷ | L_{A3908} | R²⁰ | G⁴⁸ |
| L_{A3909} | R²¹ | G⁴⁵ | L_{A3910} | R²¹ | G⁴⁶ | L_{A3911} | R²¹ | G⁴⁷ | L_{A3912} | R²¹ | G⁴⁸ |
| L_{A3913} | R²² | G⁴⁵ | L_{A3914} | R²² | G⁴⁶ | L_{A3915} | R²² | G⁴⁷ | L_{A3916} | R²² | G⁴⁸ |
| L_{A3917} | R²³ | G⁴⁵ | L_{A3918} | R²³ | G⁴⁶ | L_{A3919} | R²³ | G⁴⁷ | L_{A3920} | R²³ | G⁴⁸ |
| L_{A3921} | R²⁴ | G⁴⁵ | L_{A3922} | R²⁴ | G⁴⁶ | L_{A3923} | R²⁴ | G⁴⁷ | L_{A3924} | R²⁴ | G⁴⁸ |
| L_{A3925} | R²⁵ | G⁴⁵ | L_{A3926} | R²⁵ | G⁴⁶ | L_{A3927} | R²⁵ | G⁴⁷ | L_{A3928} | R²⁵ | G⁴⁸ |
| L_{A3929} | R²⁶ | G⁴⁵ | L_{A3930} | R²⁶ | G⁴⁶ | L_{A3931} | R²⁶ | G⁴⁷ | L_{A3932} | R²⁶ | G⁴⁸ |
| L_{A3933} | R²⁷ | G⁴⁵ | L_{A3934} | R²⁷ | G⁴⁶ | L_{A3935} | R²⁷ | G⁴⁷ | L_{A3936} | R²⁷ | G⁴⁸ |
| L_{A3937} | R²⁸ | G⁴⁵ | L_{A3938} | R²⁸ | G⁴⁶ | L_{A3939} | R²⁸ | G⁴⁷ | L_{A3940} | R²⁸ | G⁴⁸ |
| L_{A3941} | R²⁹ | G⁴⁵ | L_{A3942} | R²⁹ | G⁴⁶ | L_{A3943} | R²⁹ | G⁴⁷ | L_{A3944} | R²⁹ | G⁴⁸ |
| L_{A3945} | R³⁰ | G⁴⁵ | L_{A3946} | R³⁰ | G⁴⁶ | L_{A3947} | R³⁰ | G⁴⁷ | L_{A3948} | R³⁰ | G⁴⁸ |
| L_{A3949} | R³¹ | G⁴⁵ | L_{A3950} | R³¹ | G⁴⁶ | L_{A3951} | R³¹ | G⁴⁷ | L_{A3952} | R³¹ | G⁴⁸ |
| L_{A3953} | R³² | G⁴⁵ | L_{A3954} | R³² | G⁴⁶ | L_{A3955} | R³² | G⁴⁷ | L_{A3956} | R³² | G⁴⁸ |
| L_{A3957} | R³³ | G⁴⁵ | L_{A3958} | R³³ | G⁴⁶ | L_{A3959} | R³³ | G⁴⁷ | L_{A3960} | R³³ | G⁴⁸ |
| L_{A3961} | R³⁴ | G⁴⁵ | L_{A3962} | R³⁴ | G⁴⁶ | L_{A3963} | R³⁴ | G⁴⁷ | L_{A3964} | R³⁴ | G⁴⁸ |
| L_{A3965} | R³⁵ | G⁴⁵ | L_{A3966} | R³⁵ | G⁴⁶ | L_{A3967} | R³⁵ | G⁴⁷ | L_{A3968} | R³⁵ | G⁴⁸ |
| L_{A3969} | R³⁶ | G⁴⁵ | L_{A3970} | R³⁶ | G⁴⁶ | L_{A3971} | R³⁶ | G⁴⁷ | L_{A3972} | R³⁶ | G⁴⁸ |
| L_{A3973} | R³⁷ | G⁴⁵ | L_{A3974} | R³⁷ | G⁴⁶ | L_{A3975} | R³⁷ | G⁴⁷ | L_{A3976} | R³⁷ | G⁴⁸ |
| L_{A3977} | R³⁸ | G⁴⁵ | L_{A3978} | R³⁸ | G⁴⁶ | L_{A3979} | R³⁸ | G⁴⁷ | L_{A3980} | R³⁸ | G⁴⁸ |
| L_{A3981} | R³⁹ | G⁴⁵ | L_{A3982} | R³⁹ | G⁴⁶ | L_{A3983} | R³⁹ | G⁴⁷ | L_{A3984} | R³⁹ | G⁴⁸ |
| L_{A3985} | R⁴⁰ | G⁴⁵ | L_{A3986} | R⁴⁰ | G⁴⁶ | L_{A3987} | R⁴⁰ | G⁴⁷ | L_{A3988} | R⁴⁰ | G⁴⁸ |
| L_{A3989} | R⁴¹ | G⁴⁵ | L_{A3990} | R⁴¹ | G⁴⁶ | L_{A3991} | R⁴¹ | G⁴⁷ | L_{A3992} | R⁴¹ | G⁴⁸ |
| L_{A3993} | R⁴² | G⁴⁵ | L_{A3994} | R⁴² | G⁴⁶ | L_{A3995} | R⁴² | G⁴⁷ | L_{A3996} | R⁴² | G⁴⁸ |
| L_{A3997} | R⁴³ | G⁴⁵ | L_{A3998} | R⁴³ | G⁴⁶ | L_{A3999} | R⁴³ | G⁴⁷ | L_{A4000} | R⁴³ | G⁴⁸ |
| L_{A4001} | R⁴⁴ | G⁴⁵ | L_{A4002} | R⁴⁴ | G⁴⁶ | L_{A4003} | R⁴⁴ | G⁴⁷ | L_{A4004} | R⁴⁴ | G⁴⁸ |
| L_{A4005} | R⁴⁵ | G⁴⁵ | L_{A4006} | R⁴⁵ | G⁴⁶ | L_{A4007} | R⁴⁵ | G⁴⁷ | L_{A4008} | R⁴⁵ | G⁴⁸ |
| L_{A4009} | R⁴⁶ | G⁴⁵ | L_{A4010} | R⁴⁶ | G⁴⁶ | L_{A4011} | R⁴⁶ | G⁴⁷ | L_{A4012} | R⁴⁶ | G⁴⁸ |
| L_{A4013} | R⁴⁷ | G⁴⁵ | L_{A4014} | R⁴⁷ | G⁴⁶ | L_{A4015} | R⁴⁷ | G⁴⁷ | L_{A4016} | R⁴⁷ | G⁴⁸ |
| L_{A4017} | R⁴⁸ | G⁴⁵ | L_{A4018} | R⁴⁸ | G⁴⁶ | L_{A4019} | R⁴⁸ | G⁴⁷ | L_{A4020} | R⁴⁸ | G⁴⁸ |
| L_{A4021} | R⁴⁹ | G⁴⁵ | L_{A4022} | R⁴⁹ | G⁴⁶ | L_{A4023} | R⁴⁹ | G⁴⁷ | L_{A4024} | R⁴⁹ | G⁴⁸ |
| L_{A4025} | R⁵⁰ | G⁴⁵ | L_{A4026} | R⁵⁰ | G⁴⁶ | L_{A4027} | R⁵⁰ | G⁴⁷ | L_{A4028} | R⁵⁰ | G⁴⁸ |
| L_{A4029} | R⁵¹ | G⁴⁵ | L_{A4030} | R⁵¹ | G⁴⁶ | L_{A4031} | R⁵¹ | G⁴⁷ | L_{A4032} | R⁵¹ | G⁴⁸ |
| L_{A4033} | R⁵² | G⁴⁵ | L_{A4034} | R⁵² | G⁴⁶ | L_{A4035} | R⁵² | G⁴⁷ | L_{A4036} | R⁵² | G⁴⁸ |
| L_{A4037} | R⁵³ | G⁴⁵ | L_{A4038} | R⁵³ | G⁴⁶ | L_{A4039} | R⁵³ | G⁴⁷ | L_{A4040} | R⁵³ | G⁴⁸ |
| L_{A4041} | R⁵⁴ | G⁴⁵ | L_{A4042} | R⁵⁴ | G⁴⁶ | L_{A4043} | R⁵⁴ | G⁴⁷ | L_{A4044} | R⁵⁴ | G⁴⁸ |
| L_{A4045} | R⁵⁵ | G⁴⁵ | L_{A4046} | R⁵⁵ | G⁴⁶ | L_{A4047} | R⁵⁵ | G⁴⁷ | L_{A4048} | R⁵⁵ | G⁴⁸ |
| L_{A4049} | R⁵⁶ | G⁴⁵ | L_{A4050} | R⁵⁶ | G⁴⁶ | L_{A4051} | R⁵⁶ | G⁴⁷ | L_{A4052} | R⁵⁶ | G⁴⁸ |
| L_{A4053} | R⁵⁷ | G⁴⁵ | L_{A4054} | R⁵⁷ | G⁴⁶ | L_{A4055} | R⁵⁷ | G⁴⁷ | L_{A4056} | R⁵⁷ | G⁴⁸ |
| L_{A4057} | R⁵⁸ | G⁴⁵ | L_{A4058} | R⁵⁸ | G⁴⁶ | L_{A4059} | R⁵⁸ | G⁴⁷ | L_{A4060} | R⁵⁸ | G⁴⁸ |
| L_{A4061} | R⁵⁹ | G⁴⁵ | L_{A4062} | R⁵⁹ | G⁴⁶ | L_{A4063} | R⁵⁹ | G⁴⁷ | L_{A4064} | R⁵⁹ | G⁴⁸ |
| L_{A4065} | R⁶⁰ | G⁴⁵ | L_{A4066} | R⁶⁰ | G⁴⁶ | L_{A4067} | R⁶⁰ | G⁴⁷ | L_{A4068} | R⁶⁰ | G⁴⁸ |
| L_{A4069} | R⁶¹ | G⁴⁵ | L_{A4070} | R⁶¹ | G⁴⁶ | L_{A4071} | R⁶¹ | G⁴⁷ | L_{A4072} | R⁶¹ | G⁴⁸ |
| L_{A4073} | R⁶² | G⁴⁵ | L_{A4074} | R⁶² | G⁴⁶ | L_{A4075} | R⁶² | G⁴⁷ | L_{A4076} | R⁶² | G⁴⁸ |
| L_{A4077} | R⁶³ | G⁴⁵ | L_{A4078} | R⁶³ | G⁴⁶ | L_{A4079} | R⁶³ | G⁴⁷ | L_{A4080} | R⁶³ | G⁴⁸ |
| L_{A4081} | R⁶⁴ | G⁴⁵ | L_{A4082} | R⁶⁴ | G⁴⁶ | L_{A4083} | R⁶⁴ | G⁴⁷ | L_{A4084} | R⁶⁴ | G⁴⁸ |
| L_{A4085} | R⁶⁵ | G⁴⁵ | L_{A4086} | R⁶⁵ | G⁴⁶ | L_{A4087} | R⁶⁵ | G⁴⁷ | L_{A4088} | R⁶⁵ | G⁴⁸ |
| L_{A4089} | R⁶⁶ | G⁴⁵ | L_{A4090} | R⁶⁶ | G⁴⁶ | L_{A4091} | R⁶⁶ | G⁴⁷ | L_{A4092} | R⁶⁶ | G⁴⁸ |
| L_{A4093} | R⁶⁷ | G⁴⁵ | L_{A4094} | R⁶⁷ | G⁴⁶ | L_{A4095} | R⁶⁷ | G⁴⁷ | L_{A4096} | R⁶⁷ | G⁴⁸ |
| L_{A4097} | R⁶⁸ | G⁴⁵ | L_{A4098} | R⁶⁸ | G⁴⁶ | L_{A4099} | R⁶⁸ | G⁴⁷ | L_{A4100} | R⁶⁸ | G⁴⁸ |
| L_{A4101} | R⁶⁹ | G⁴⁵ | L_{A4102} | R⁶⁹ | G⁴⁶ | L_{A4103} | R⁶⁹ | G⁴⁷ | L_{A4104} | R⁶⁹ | G⁴⁸ |
| L_{A4105} | R⁷⁰ | G⁴⁵ | L_{A4106} | R⁷⁰ | G⁴⁶ | L_{A4107} | R⁷⁰ | G⁴⁷ | L_{A4108} | R⁷⁰ | G⁴⁸ |
| L_{A4109} | R⁷¹ | G⁴⁵ | L_{A4110} | R⁷¹ | G⁴⁶ | L_{A4111} | R⁷¹ | G⁴⁷ | L_{A4112} | R⁷¹ | G⁴⁸ |
| L_{A4113} | R⁷² | G⁴⁵ | L_{A4114} | R⁷² | G⁴⁶ | L_{A4115} | R⁷² | G⁴⁷ | L_{A4116} | R⁷² | G⁴⁸ |
| L_{A4117} | R⁷³ | G⁴⁵ | L_{A4118} | R⁷³ | G⁴⁶ | L_{A4119} | R⁷³ | G⁴⁷ | L_{A4120} | R⁷³ | G⁴⁸ |
| L_{A4121} | R⁷⁴ | G⁴⁵ | L_{A4122} | R⁷⁴ | G⁴⁶ | L_{A4123} | R⁷⁴ | G⁴⁷ | L_{A4124} | R⁷⁴ | G⁴⁸ |
| L_{A4125} | R⁷⁵ | G⁴⁵ | L_{A4126} | R⁷⁵ | G⁴⁶ | L_{A4127} | R⁷⁵ | G⁴⁷ | L_{A4128} | R⁷⁵ | G⁴⁸ |
| L_{A4129} | R⁷⁶ | G⁴⁵ | L_{A4130} | R⁷⁶ | G⁴⁶ | L_{A4131} | R⁷⁶ | G⁴⁷ | L_{A4132} | R⁷⁶ | G⁴⁸ |
| L_{A4133} | R⁷⁷ | G⁴⁵ | L_{A4134} | R⁷⁷ | G⁴⁶ | L_{A4135} | R⁷⁷ | G⁴⁷ | L_{A4136} | R⁷⁷ | G⁴⁸ |
| L_{A4137} | R⁷⁸ | G⁴⁵ | L_{A4138} | R⁷⁸ | G⁴⁶ | L_{A4139} | R⁷⁸ | G⁴⁷ | L_{A4140} | R⁷⁸ | G⁴⁸ |
| L_{A4141} | R⁷⁹ | G⁴⁵ | L_{A4142} | R⁷⁹ | G⁴⁶ | L_{A4143} | R⁷⁹ | G⁴⁷ | L_{A4144} | R⁷⁹ | G⁴⁸ |
| L_{A4145} | R⁸⁰ | G⁴⁵ | L_{A4146} | R⁸⁰ | G⁴⁶ | L_{A4147} | R⁸⁰ | G⁴⁷ | L_{A4148} | R⁸⁰ | G⁴⁸ |
| L_{A4149} | R⁸¹ | G⁴⁵ | L_{A4150} | R⁸¹ | G⁴⁶ | L_{A4151} | R⁸¹ | G⁴⁷ | L_{A4152} | R⁸¹ | G⁴⁸ |
| L_{A4153} | R⁸² | G⁴⁵ | L_{A4154} | R⁸² | G⁴⁶ | L_{A4155} | R⁸² | G⁴⁷ | L_{A4156} | R⁸² | G⁴⁸ |
| L_{A4157} | R⁸³ | G⁴⁵ | L_{A4158} | R⁸³ | G⁴⁶ | L_{A4159} | R⁸³ | G⁴⁷ | L_{A4160} | R⁸³ | G⁴⁸ |
| L_{A4161} | R⁸⁴ | G⁴⁵ | L_{A4162} | R⁸⁴ | G⁴⁶ | L_{A4163} | R⁸⁴ | G⁴⁷ | L_{A4164} | R⁸⁴ | G⁴⁸ |
| L_{A4165} | R⁸⁵ | G⁴⁵ | L_{A4166} | R⁸⁵ | G⁴⁶ | L_{A4167} | R⁸⁵ | G⁴⁷ | L_{A4168} | R⁸⁵ | G⁴⁸ |
| L_{A4169} | R⁸⁶ | G⁴⁵ | L_{A4170} | R⁸⁶ | G⁴⁶ | L_{A4171} | R⁸⁶ | G⁴⁷ | L_{A4172} | R⁸⁶ | G⁴⁸ |
| L_{A4173} | R⁸⁷ | G⁴⁵ | L_{A4174} | R⁸⁷ | G⁴⁶ | L_{A4175} | R⁸⁷ | G⁴⁷ | L_{A4176} | R⁸⁷ | G⁴⁸ |
| L_{A4177} | R¹ | G⁴⁹ | L_{A4178} | R¹ | G⁵⁰ | L_{A4179} | R¹ | G⁵¹ | L_{A4180} | R¹ | G⁵² |
| L_{A4181} | R² | G⁴⁹ | L_{A4182} | R² | G⁵⁰ | L_{A4183} | R² | G⁵¹ | L_{A4184} | R² | G⁵² |
| L_{A4185} | R³ | G⁴⁹ | L_{A4186} | R³ | G⁵⁰ | L_{A4187} | R³ | G⁵¹ | L_{A4188} | R³ | G⁵² |
| L_{A4189} | R⁴ | G⁴⁹ | L_{A4190} | R⁴ | G⁵⁰ | L_{A4191} | R⁴ | G⁵¹ | L_{A4192} | R⁴ | G⁵² |
| L_{A4193} | R⁵ | G⁴⁹ | L_{A4194} | R⁵ | G⁵⁰ | L_{A4195} | R⁵ | G⁵¹ | L_{A4196} | R⁵ | G⁵² |
| L_{A4197} | R⁶ | G⁴⁹ | L_{A4198} | R⁶ | G⁵⁰ | L_{A4199} | R⁶ | G⁵¹ | L_{A4200} | R⁶ | G⁵² |
| L_{A4201} | R⁷ | G⁴⁹ | L_{A4202} | R⁷ | G⁵⁰ | L_{A4203} | R⁷ | G⁵¹ | L_{A4204} | R⁷ | G⁵² |
| L_{A4205} | R⁸ | G⁴⁹ | L_{A4206} | R⁸ | G⁵⁰ | L_{A4207} | R⁸ | G⁵¹ | L_{A4208} | R⁸ | G⁵² |
| L_{A4209} | R⁹ | G⁴⁹ | L_{A4210} | R⁹ | G⁵⁰ | L_{A4211} | R⁹ | G⁵¹ | L_{A4212} | R⁹ | G⁵² |
| L_{A4213} | R¹⁰ | G⁴⁹ | L_{A4214} | R¹⁰ | G⁵⁰ | L_{A4215} | R¹⁰ | G⁵¹ | L_{A4216} | R¹⁰ | G⁵² |
| L_{A4217} | R¹¹ | G⁴⁹ | L_{A4218} | R¹¹ | G⁵⁰ | L_{A4219} | R¹¹ | G⁵¹ | L_{A4220} | R¹¹ | G⁵² |
| L_{A4221} | R¹² | G⁴⁹ | L _{A4222} | R¹² | G⁵⁰ | L_{A4223} | R¹² | G⁵¹ | L_{A4224} | R¹² | G⁵² |
| L_{A4225} | R¹³ | G⁴⁹ | L_{A4226} | R¹³ | G⁵⁰ | L_{A4227} | R¹³ | G⁵¹ | L_{A4228} | R¹³ | G⁵² |
| L_{A4229} | R¹⁴ | G⁴⁹ | L_{A4230} | R¹⁴ | G⁵⁰ | L_{A4231} | R¹⁴ | G⁵¹ | L_{A4232} | R¹⁴ | G⁵² |
| L_{A4233} | R¹⁵ | G⁴⁹ | L_{A4234} | R¹⁵ | G⁵⁰ | L_{A4235} | R¹⁵ | G⁵¹ | L_{A4236} | R¹⁵ | G⁵² |
| L_{A4237} | R¹⁶ | G⁴⁹ | L_{A4238} | R¹⁶ | G⁵⁰ | L_{A4239} | R¹⁶ | G⁵¹ | L_{A4240} | R¹⁶ | G⁵² |
| L_{A4241} | R¹⁷ | G⁴⁹ | L_{A4242} | R¹⁷ | G⁵⁰ | L_{A4243} | R¹⁷ | G⁵¹ | L_{A4244} | R¹⁷ | G⁵² |
| L_{A4245} | R¹⁸ | G⁴⁹ | L_{A4246} | R¹⁸ | G⁵⁰ | L_{A4247} | R¹⁸ | G⁵¹ | L_{A4248} | R¹⁸ | G⁵² |
| L_{A4249} | R¹⁹ | G⁴⁹ | L_{A4250} | R¹⁹ | G⁵⁰ | L_{A4251} | R¹⁹ | G⁵¹ | L_{A4252} | R¹⁹ | G⁵² |
| L_{A4253} | R²⁰ | G⁴⁹ | L_{A4254} | R²⁰ | G⁵⁰ | L_{A4255} | R²⁰ | G⁵¹ | L_{A4256} | R²⁰ | G⁵² |
| L_{A4257} | R²¹ | G⁴⁹ | L_{A4258} | R²¹ | G⁵⁰ | L_{A4259} | R²¹ | G⁵¹ | L_{A4260} | R²¹ | G⁵² |
| L_{A4261} | R²² | G⁴⁹ | L_{A4262} | R²² | G⁵⁰ | L_{A4263} | R²² | G⁵¹ | L_{A4264} | R²² | G⁵² |
| L_{A4265} | R²³ | G⁴⁹ | L_{A4266} | R²³ | G⁵⁰ | L_{A4267} | R²³ | G⁵¹ | L_{A4268} | R²³ | G⁵² |
| L_{A4269} | R²⁴ | G⁴⁹ | L_{A4270} | R²⁴ | G⁵⁰ | L_{A4271} | R²⁴ | G⁵¹ | L_{A4272} | R²⁴ | G⁵² |
| L_{A4273} | R²⁵ | G⁴⁹ | L_{A4274} | R²⁵ | G⁵⁰ | L_{A4275} | R²⁵ | G⁵¹ | L_{A4276} | R²⁵ | G⁵² |
| L_{A4277} | R²⁶ | G⁴⁹ | L_{A4278} | R²⁶ | G⁵⁰ | L_{A4279} | R²⁶ | G⁵¹ | L_{A4280} | R²⁶ | G⁵² |
| L_{A4281} | R²⁷ | G⁴⁹ | L_{A4282} | R²⁷ | G⁵⁰ | L_{A4283} | R²⁷ | G⁵¹ | L_{A4284} | R²⁷ | G⁵² |
| L_{A4285} | R²⁸ | G⁴⁹ | L_{A4286} | R²⁸ | G⁵⁰ | L_{A4287} | R²⁸ | G⁵¹ | L_{A4288} | R²⁸ | G⁵² |
| L_{A4289} | R²⁹ | G⁴⁹ | L_{A4290} | R²⁹ | G⁵⁰ | L_{A4291} | R²⁹ | G⁵¹ | L_{A4292} | R²⁹ | G⁵² |
| L_{A4293} | R³⁰ | G⁴⁹ | L_{A4294} | R³⁰ | G⁵⁰ | L_{A4295} | R³⁰ | G⁵¹ | L_{A4296} | R³⁰ | G⁵² |
| L_{A4297} | R³¹ | G⁴⁹ | L_{A4298} | R³¹ | G⁵⁰ | L_{A4299} | R³¹ | G⁵¹ | L_{A4300} | R³¹ | G⁵² |
| L_{A4301} | R³² | G⁴⁹ | L_{A4302} | R³² | G⁵⁰ | L_{A4303} | R³² | G⁵¹ | L_{A4304} | R³² | G⁵² |
| L_{A4305} | R³³ | G⁴⁹ | L_{A4306} | R³³ | G⁵⁰ | L_{A4307} | R³³ | G⁵¹ | L_{A4308} | R³³ | G⁵² |
| L_{A4309} | R³⁴ | G⁴⁹ | L_{A4310} | R³⁴ | G⁵⁰ | L_{A4311} | R³⁴ | G⁵¹ | L_{A4312} | R³⁴ | G⁵² |
| L_{A4313} | R³⁵ | G⁴⁹ | L_{A4314} | R³⁵ | G⁵⁰ | L_{A4315} | R³⁵ | G⁵¹ | L_{A4316} | R³⁵ | G⁵² |
| L_{A4317} | R³⁶ | G⁴⁹ | L_{A4318} | R³⁶ | G⁵⁰ | L_{A4319} | R³⁶ | G⁵¹ | L_{A4320} | R³⁶ | G⁵² |
| L_{A4321} | R³⁷ | G⁴⁹ | L_{A4322} | R³⁷ | G⁵⁰ | L_{A4323} | R³⁷ | G⁵¹ | L_{A4324} | R³⁷ | G⁵² |
| L_{A4325} | R³⁸ | G⁴⁹ | L_{A4326} | R³⁸ | G⁵⁰ | L_{A4327} | R³⁸ | G⁵¹ | L_{A4328} | R³⁸ | G⁵² |
| L_{A4329} | R³⁹ | G⁴⁹ | L_{A4330} | R³⁹ | G⁵⁰ | L_{A4331} | R³⁹ | G⁵¹ | L_{A4332} | R³⁹ | G⁵² |
| L_{A4333} | R⁴⁰ | G⁴⁹ | L_{A4334} | R⁴⁰ | G⁵⁰ | L_{A4335} | R⁴⁰ | G⁵¹ | L_{A4336} | R⁴⁰ | G⁵² |
| L_{A4337} | R⁴¹ | G⁴⁹ | L_{A4338} | R⁴¹ | G⁵⁰ | L_{A4339} | R⁴⁰ | G⁵¹ | L_{A4340} | R⁴¹ | G⁵² |
| L_{A4343} | R⁴² | G⁴⁹ | L_{A4342} | R⁴² | G⁵⁰ | L_{A4343} | R⁴² | G⁵¹ | L_{A4344} | R⁴² | G⁵² |
| L_{A4345} | R⁴³ | G⁴⁹ | L_{A4346} | R⁴³ | G⁵⁰ | L_{A4347} | R⁴³ | G⁵¹ | L_{A4348} | R⁴³ | G⁵² |
| L_{A4349} | R⁴⁴ | G⁴⁹ | L_{A4350} | R⁴⁴ | G⁵⁰ | L_{A4351} | R⁴⁴ | G⁵¹ | L_{A4352} | R⁴⁴ | G⁵² |
| L_{A4353} | R⁴⁵ | G⁴⁹ | L_{A4354} | R⁴⁵ | G⁵⁰ | L_{A4355} | R⁴⁵ | G⁵¹ | L_{A4356} | R⁴⁵ | G⁵² |
| L_{A4357} | R⁴⁶ | G⁴⁹ | L_{A4358} | R⁴⁶ | G⁵⁰ | L_{A4359} | R⁴⁶ | G⁵¹ | L_{A4360} | R⁴⁶ | G⁵² |
| L_{A4361} | R⁴⁷ | G⁴⁹ | L_{A4362} | R⁴⁷ | G⁵⁰ | L_{A4363} | R⁴⁷ | G⁵¹ | L_{A4364} | R⁴⁷ | G⁵² |
| L_{A4365} | R⁴⁸ | G⁴⁹ | L_{A4366} | R⁴⁸ | G⁵⁰ | L_{A4367} | R⁴⁸ | G⁵¹ | L_{A4368} | R⁴⁸ | G⁵² |
| L_{A4369} | R⁴⁹ | G⁴⁹ | L_{A4370} | R⁴⁹ | G⁵⁰ | L_{A4371} | R⁴⁹ | G⁵¹ | L_{A4372} | R⁴⁹ | G⁵² |
| L_{A4373} | R⁵⁰ | G⁴⁹ | L_{A4374} | R⁵⁰ | G⁵⁰ | L_{A4375} | R⁵⁰ | G⁵¹ | L_{A4376} | R⁵⁰ | G⁵² |
| L_{A4377} | R⁵¹ | G⁴⁹ | L_{A4378} | R⁵¹ | G⁵⁰ | L_{A4379} | R⁵¹ | G⁵¹ | L_{A4380} | R⁵¹ | G⁵² |
| L_{A4381} | R⁵² | G⁴⁹ | L_{A4382} | R⁵² | G⁵⁰ | L_{A4383} | R⁵² | G⁵¹ | L_{A4384} | R⁵² | G⁵² |
| L_{A4385} | R⁵³ | G⁴⁹ | L_{A4386} | R⁵³ | G⁵⁰ | L_{A4387} | R⁵³ | G⁵¹ | L_{A4388} | R⁵³ | G⁵² |
| L_{A4389} | R⁵⁴ | G⁴⁹ | L_{A4390} | R⁵⁴ | G⁵⁰ | L_{A4391} | R⁵⁴ | G⁵¹ | L_{A4392} | R⁵⁴ | G⁵² |
| L_{A4393} | R⁵⁵ | G⁴⁹ | L_{A4394} | R⁵⁵ | G⁵⁰ | L_{A4395} | R⁵⁵ | G⁵¹ | L_{A4396} | R⁵⁵ | G⁵² |
| L_{A4397} | R⁵⁶ | G⁴⁹ | L_{A4398} | R⁵⁶ | G⁵⁰ | L_{A4399} | R⁵⁶ | G⁵¹ | L_{A4400} | R⁵⁶ | G⁵² |
| L_{A4401} | R⁵⁷ | G⁴⁹ | L_{A4402} | R⁵⁷ | G⁵⁰ | L_{A4403} | R⁵⁷ | G⁵¹ | L_{A4404} | R⁵⁷ | G⁵² |
| L_{A4405} | R⁵⁸ | G⁴⁹ | L_{A4406} | R⁵⁸ | G⁵⁰ | L_{A4407} | R⁵⁸ | G⁵¹ | L_{A4408} | R⁵⁸ | G⁵² |
| L_{A4409} | R⁵⁹ | G⁴⁹ | L_{A4410} | R⁵⁹ | G⁵⁰ | L_{A4411} | R⁵⁹ | G⁵¹ | L_{A4412} | R⁵⁹ | G⁵² |
| L_{A4413} | R⁶⁰ | G⁴⁹ | L_{A4414} | R⁶⁰ | G⁵⁰ | L_{A4415} | R⁶⁰ | G⁵¹ | L_{A4416} | R⁶⁰ | G⁵² |
| L_{A4417} | R⁶¹ | G⁴⁹ | L_{A4418} | R⁶¹ | G⁵⁰ | L_{A4419} | R⁶¹ | G⁵¹ | L_{A4420} | R⁶¹ | G⁵² |
| L_{A4421} | R⁶² | G⁴⁹ | L_{A4422} | R⁶² | G⁵⁰ | L_{A4423} | R⁶² | G⁵¹ | L_{A4424} | R⁶² | G⁵² |
| L_{A4425} | R⁶³ | G⁴⁹ | L_{A4426} | R⁶³ | G⁵⁰ | L_{A4427} | R⁶³ | G⁵¹ | L_{A4428} | R⁶³ | G⁵² |
| L_{A4429} | R⁶⁴ | G⁴⁹ | L_{A4430} | R⁶⁴ | G⁵⁰ | L_{A4431} | R⁶⁴ | G⁵¹ | L_{A4432} | R⁶⁴ | G⁵² |
| L_{A4433} | R⁶⁵ | G⁴⁹ | L_{A4434} | R⁶⁵ | G⁵⁰ | L_{A4435} | R⁶⁵ | G⁵¹ | L_{A4436} | R⁶⁵ | G⁵² |
| L_{A4437} | R⁶⁶ | G⁴⁹ | L_{A4438} | R⁶⁶ | G⁵⁰ | L_{A4439} | R⁶⁶ | G⁵¹ | L_{A4440} | R⁶⁶ | G⁵² |
| L_{A4441} | R⁶⁷ | G⁴⁹ | L_{A4442} | R⁶⁷ | G⁵⁰ | L_{A4443} | R⁶⁷ | G⁵¹ | L_{A4444} | R⁶⁷ | G⁵² |
| L_{A4445} | R⁶⁸ | G⁴⁹ | L_{A4446} | R⁶⁸ | G⁵⁰ | L_{A4447} | R⁶⁸ | G⁵¹ | L_{A4448} | R⁶⁸ | G⁵² |
| L_{A4449} | R⁶⁹ | G⁴⁹ | L_{A4450} | R⁶⁹ | G⁵⁰ | L_{A4451} | R⁶⁹ | G⁵¹ | L_{A4452} | R⁶⁹ | G⁵² |
| L_{A4453} | R⁷⁰ | G⁴⁹ | L_{A4454} | R⁷⁰ | G⁵⁰ | L_{A4455} | R⁷⁰ | G⁵¹ | L_{A4456} | R⁷⁰ | G⁵² |
| L_{A4457} | R⁷¹ | G⁴⁹ | L_{A4458} | R⁷¹ | G⁵⁰ | L_{A4459} | R⁷¹ | G⁵¹ | L_{A4460} | R⁷¹ | G⁵² |
| L_{A4461} | R⁷² | G⁴⁹ | L_{A4462} | R⁷² | G⁵⁰ | L_{A4463} | R⁷² | G⁵¹ | L_{A4464} | R⁷² | G⁵² |
| L_{A4465} | R⁷³ | G⁴⁹ | L_{A4466} | R⁷³ | G⁵⁰ | L_{A4467} | R⁷³ | G⁵¹ | L_{A4468} | R⁷³ | G⁵² |
| L_{A4469} | R⁷⁴ | G⁴⁹ | L_{A4470} | R⁷⁴ | G⁵⁰ | L_{A4471} | R⁷⁴ | G⁵¹ | L_{A4472} | R⁷⁴ | G⁵² |
| L_{A4473} | R⁷⁵ | G⁴⁹ | L_{A4474} | R⁷⁵ | G⁵⁰ | L_{A4475} | R⁷⁵ | G⁵¹ | L_{A4476} | R⁷⁵ | G⁵² |
| L_{A4477} | R⁷⁶ | G⁴⁹ | L_{A4478} | R⁷⁶ | G⁵⁰ | L_{A4479} | R⁷⁶ | G⁵¹ | L_{A4480} | R⁷⁶ | G⁵² |
| L_{A4481} | R⁷⁷ | G⁴⁹ | L_{A4482} | R⁷⁷ | G⁵⁰ | L_{A4483} | R⁷⁷ | G⁵¹ | L_{A4484} | R⁷⁷ | G⁵² |
| L_{A4485} | R⁷⁸ | G⁴⁹ | L_{A4486} | R⁷⁸ | G⁵⁰ | L_{A4487} | R⁷⁸ | G⁵¹ | L_{A4488} | R⁷⁸ | G⁵² |
| L_{A4489} | R⁷⁹ | G⁴⁹ | L_{A4490} | R⁷⁹ | G⁵⁰ | L_{A4491} | R⁷⁹ | G⁵¹ | L_{A4492} | R⁷⁹ | G⁵² |
| L_{A4493} | R⁸⁰ | G⁴⁹ | L_{A4494} | R⁸⁰ | G⁵⁰ | L_{A4495} | R⁸⁰ | G⁵¹ | L_{A4496} | R⁸⁰ | G⁵² |
| L_{A4497} | R⁸¹ | G⁴⁹ | L_{A4498} | R⁸¹ | G⁵⁰ | L_{A4499} | R⁸¹ | G⁵¹ | L_{A4500} | R⁸¹ | G⁵² |
| L_{A4501} | R⁸² | G⁴⁹ | L_{A4502} | R⁸² | G⁵⁰ | L_{A4503} | R⁸² | G⁵¹ | L_{A4504} | R⁸² | G⁵² |
| L_{A4505} | R⁸³ | G⁴⁹ | L_{A4506} | R⁸³ | G⁵⁰ | L_{A4507} | R⁸³ | G⁵¹ | L_{A4508} | R⁸³ | G⁵² |
| L_{A4509} | R⁸⁴ | G⁴⁹ | L_{A4510} | R⁸⁴ | G⁵⁰ | L_{A4511} | R⁸⁴ | G⁵¹ | L_{A4512} | R⁸⁴ | G⁵² |
| L_{A4513} | R⁸⁵ | G⁴⁹ | L_{A4514} | R⁸⁵ | G⁵⁰ | L_{A4515} | R⁸⁵ | G⁵¹ | L_{A4516} | R⁸⁵ | G⁵² |
| L_{A4517} | R⁸⁶ | G⁴⁹ | L_{A4518} | R⁸⁶ | G⁵⁰ | L_{A4519} | R⁸⁶ | G⁵¹ | L_{A4520} | R⁸⁶ | G⁵² |
| L_{A4521} | R⁸⁷ | G⁴⁹ | L_{A4522} | R⁸⁷ | G⁵⁰ | L_{A4523} | R⁸⁷ | G⁵¹ | L_{A4524} | R⁸⁷ | G⁵²; |

wherein each of R¹ to R⁸⁷ has the structure defined as follows: 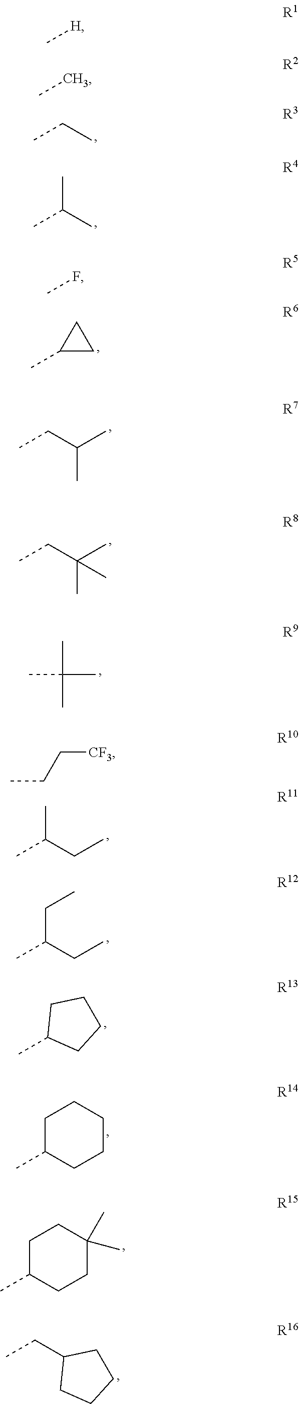 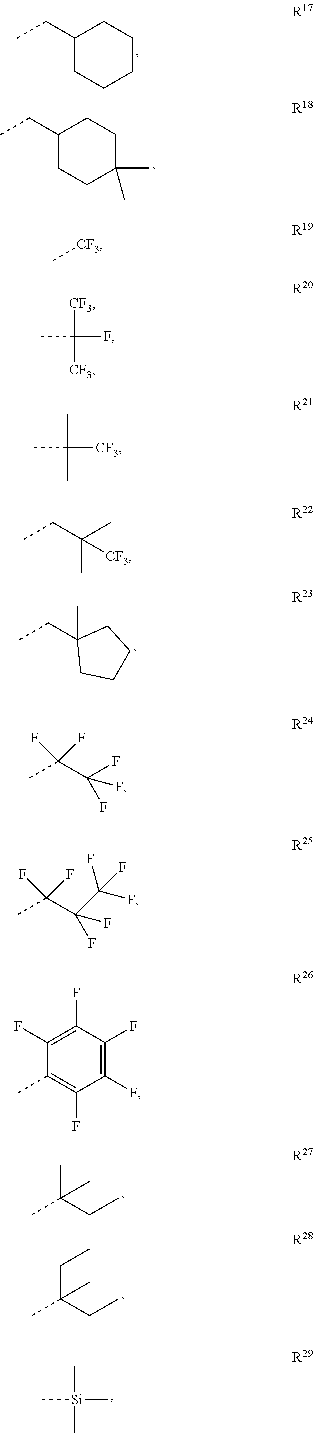 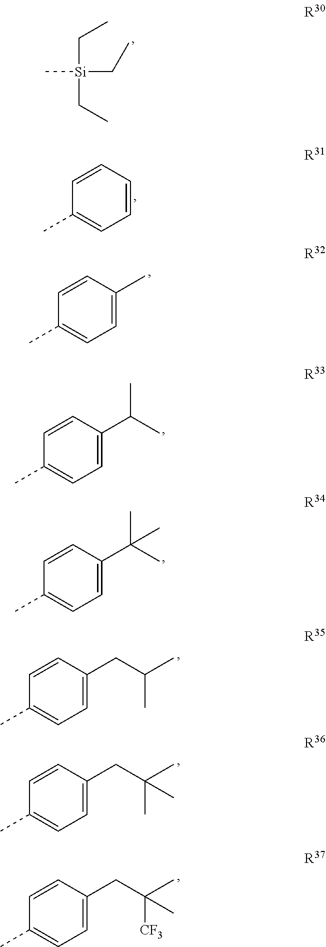 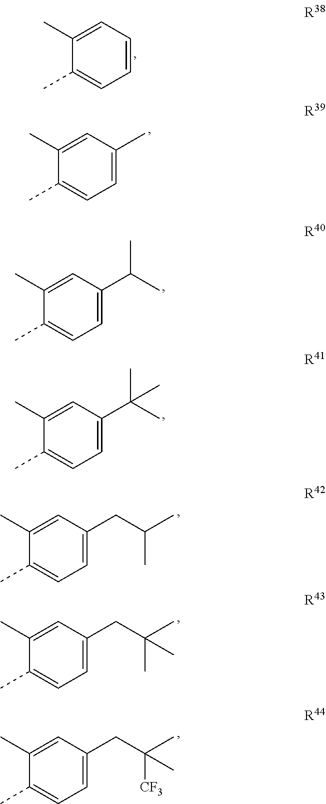 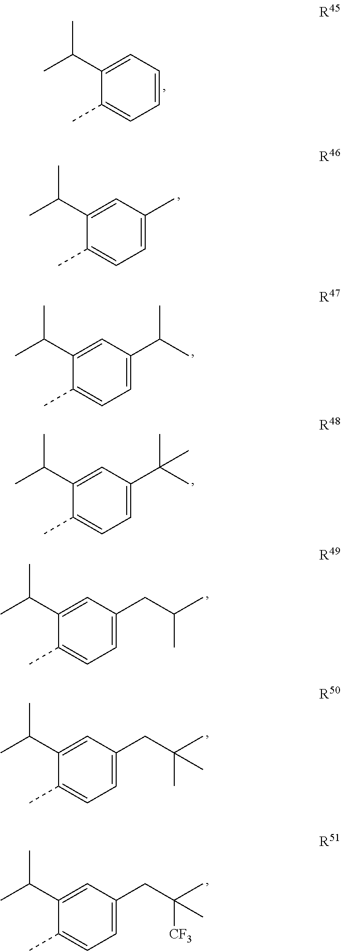 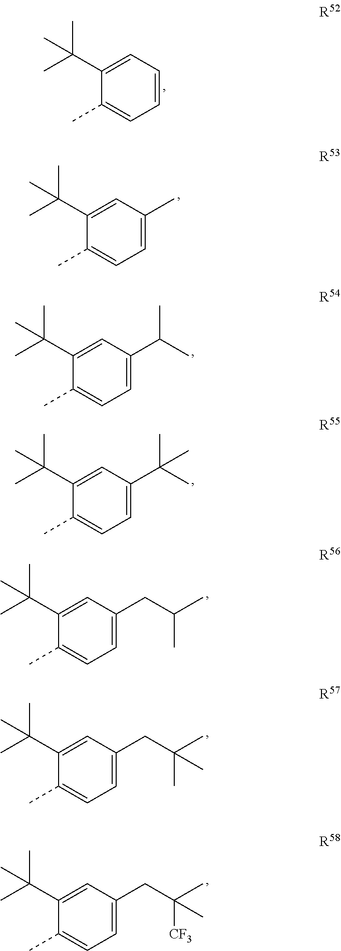 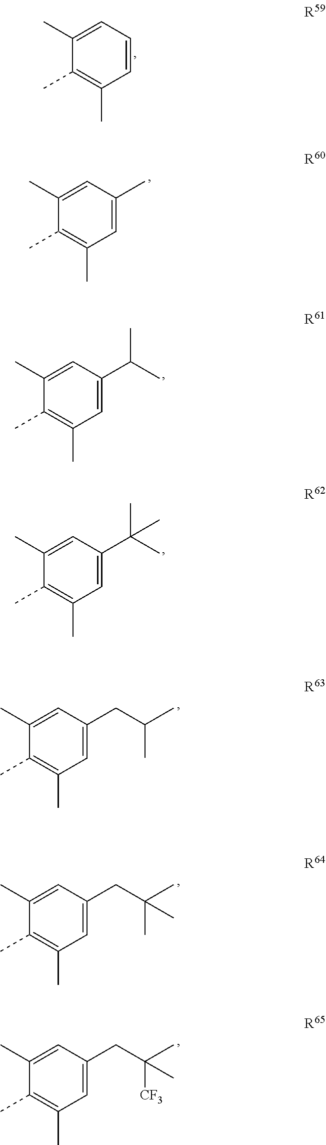 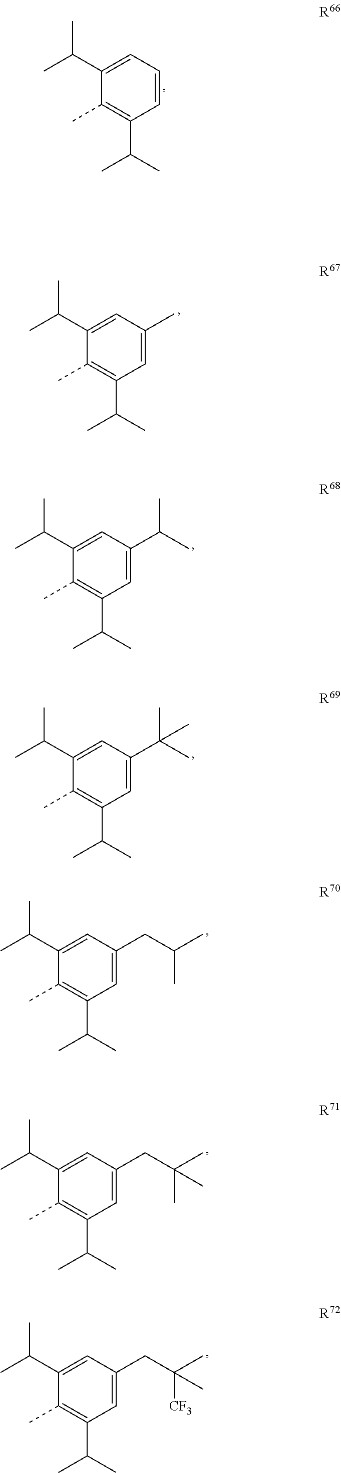 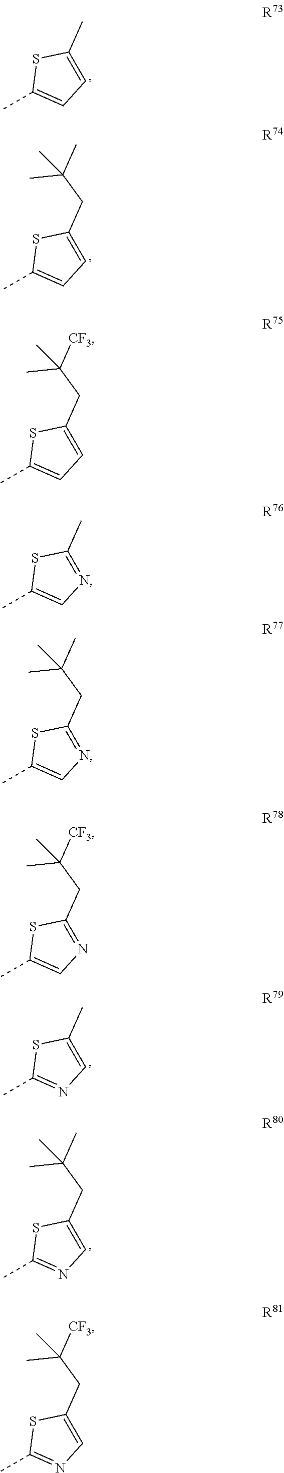 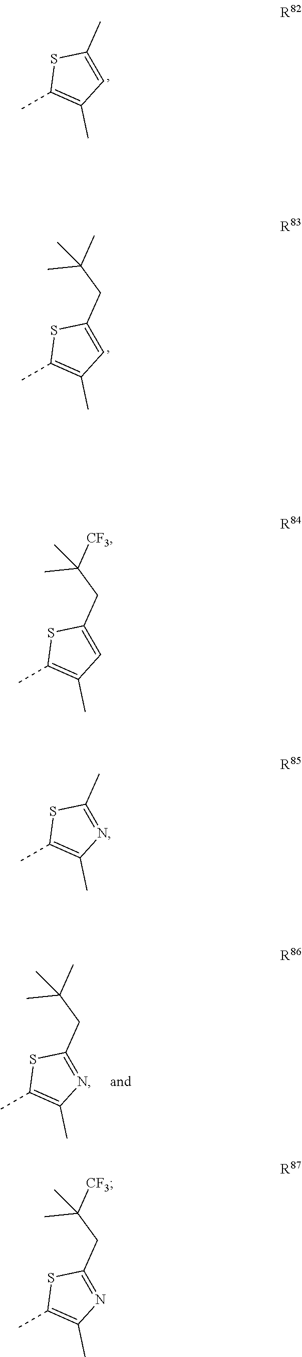
and
wherein each of G¹ to G¹² has the structure defined as follows:

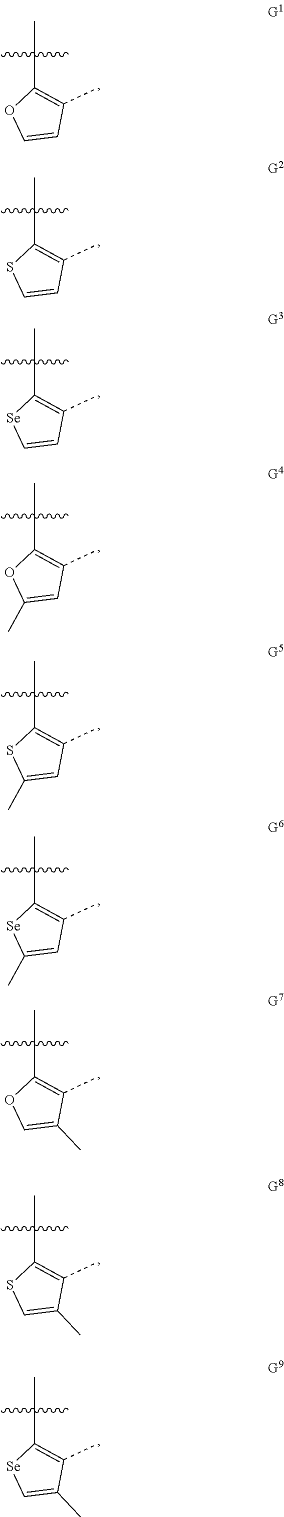

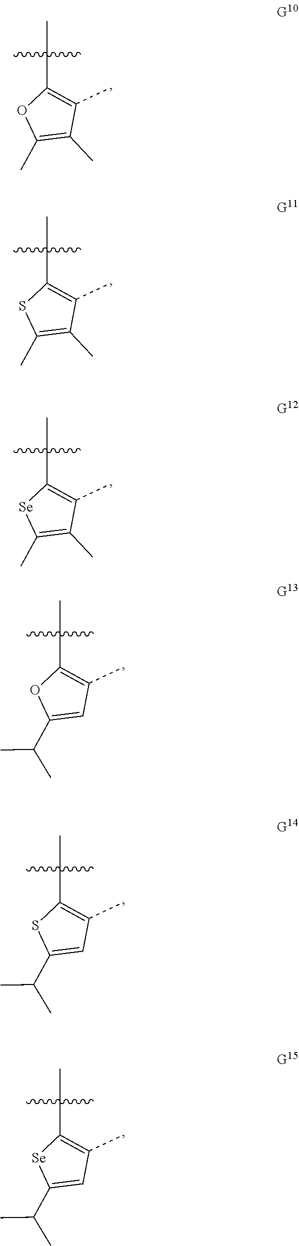

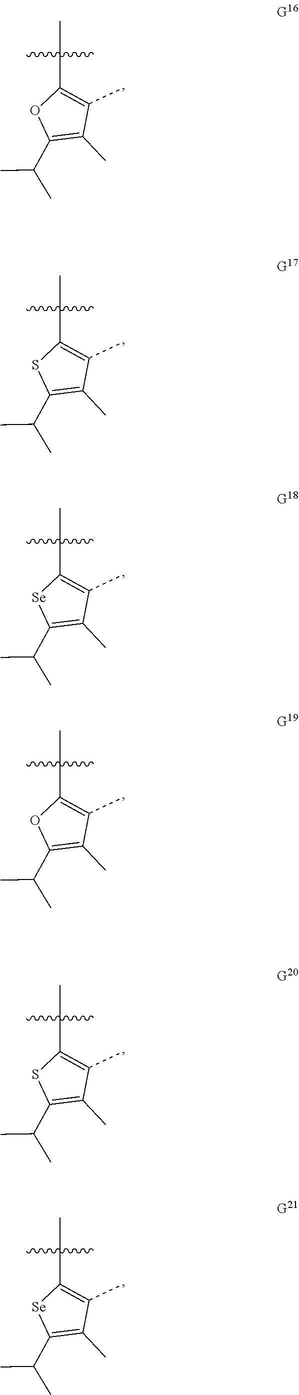

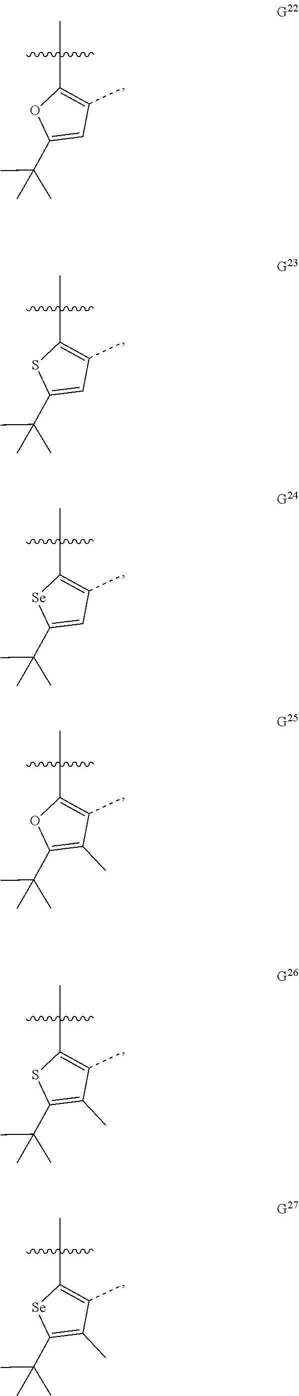

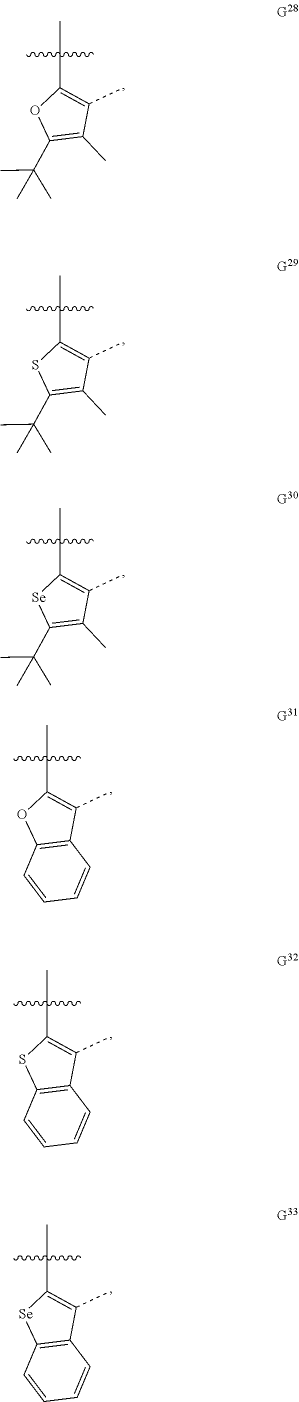

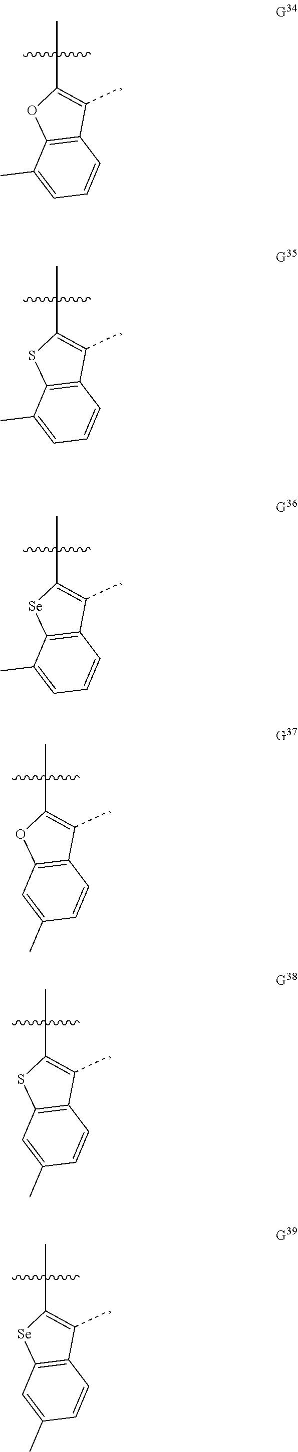

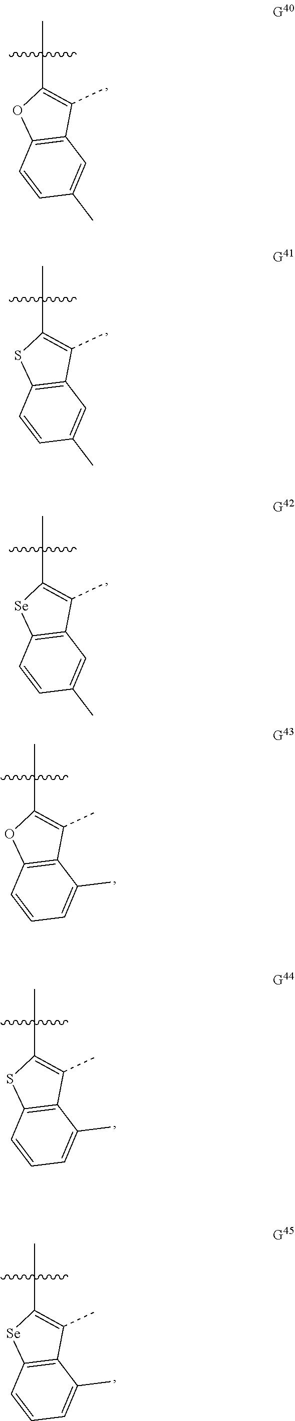

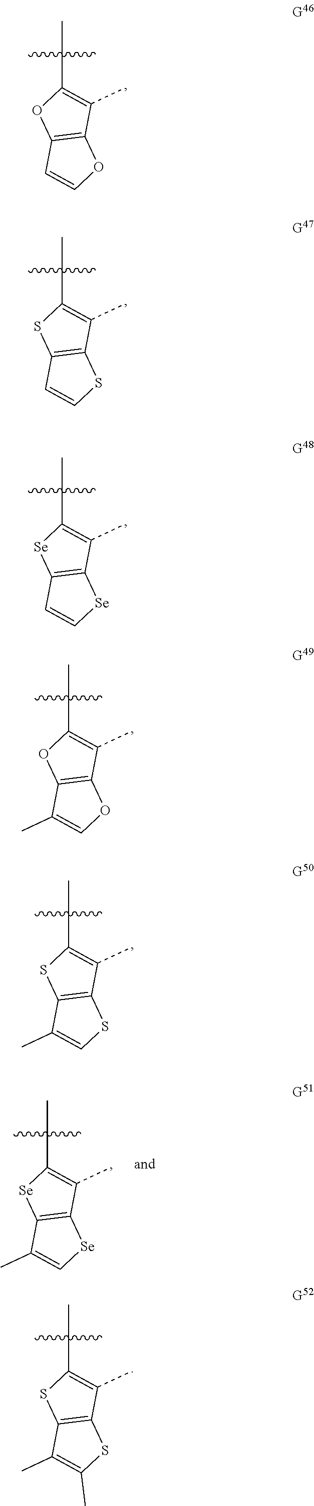

11. The compound of claim 1, wherein the compound has a formula of M(L_{A})ₚ(L_{B})_{q}(L_{C})ᵣ wherein L_{B} and L_{C} are each a bidentate ligand; and wherein p is 1, 2, or 3; q is 0, 1, or 2; r is 0, 1, or 2; and p+q+r is the oxidation state of the metal M.

12. The compound of claim 11, wherein the compound has a formula selected from the group consisting of Ir(L_{A})₃, Ir(L_{A})(L_{B})₂, Ir(L_{A})₂(L_{B}), Ir(L_{A})₂(L_{C}), and Ir(L_{A})(L_{B})(L_{C}); and wherein L_{A}, L_{B}, and L_{C} are different from each other; or a formula of Pt(L_{A})(L_{B}); and wherein L_{A} and L_{B} can be same or different.

13. The compound of claim 11, wherein L_{B} and L_{C} are each independently selected from the group consisting of: 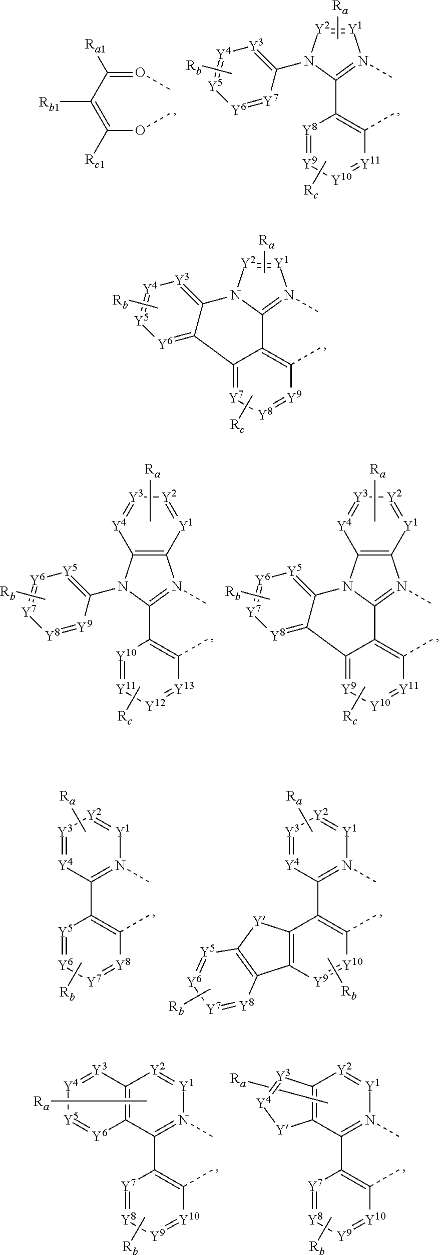 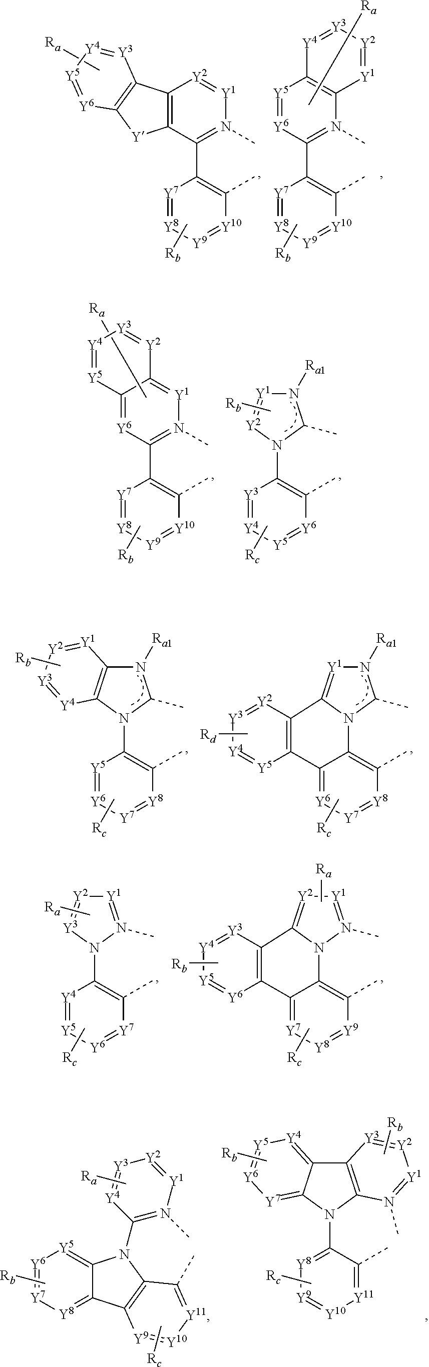 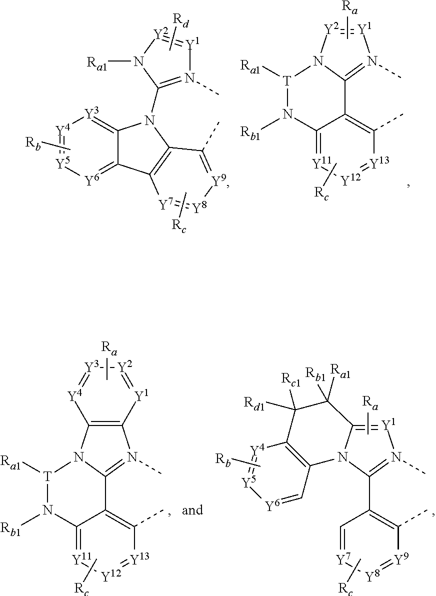
wherein:
T is selected from the group consisting of B, Al, Ga, and In;
each of Y¹ to Y¹³ is independently selected from the group consisting of carbon and nitrogen;
Y′ is selected from the group consisting of BRₑ, NRₑ, PRₑ, O, S, Se, C═O, S═O, SO₂, CRₑR_{f}, SiRₑR_{f}, and GeRₑR_{f};
each Rₐ, R_{b}, R_{c}, and R_{d} independently represent zero, mono, or up to a maximum allowed number of substitutions;
each of Rₐ₁, R_{b1}, R_{c1}, R_{d1}, Rₐ, R_{b}, R_{c}, R_{d}, Rₑ and R_{f} is independently a hydrogen or a substituent selected from the group consisting of the General Substituents defined herein; and
any two adjacent Rₐ, R_{b}, R_{c}, R_{d}, Rₑ and R_{f} can be fused or joined to form a ring or form a multidentate ligand.

14. The compound of claim 10, wherein when the compound has formula Ir(L_{Ai-m-X})₃, i is an integer from 1 to 4524; m is an integer from 1 to 108; and the compound is selected from the group consisting of Ir(L_{A1-1-1})₃ to Ir(L_{A4524-108-4})₃;
when the compound has formula Ir(L_{Ai-m-X})(L_{Bk})₂, i is an integer from 1 to 4542; m is an integer from 1 to 108; k is an integer from 1 to 324; and the compound is selected from the group consisting of Ir(L_{A1-1-1})(L_{B1})₂ to Ir(L_{A4542-108-4})(L_{B270})₂Ir(L_{A4542-108-4})(L_{B324})₂;
when the compound has formula Ir(L_{Ai-m-X})₂(L_{Bk}), i is an integer from 1 to 4542; m is an integer from 1 to 108; k is an integer from 1 to 324; and the compound is selected from the group consisting of Ir(L_{A1-1-1})₂(L_{B1}) to Ir(L_{A4542-108-4})₂(L_{B324});
when the compound has formula Ir(L_{Ai-m-X})₂(L_{Cj-I}), i is an integer from 1 to 4542; m is an integer from 1 to 108;j is an integer from 1 to 1416; and the compound is selected from the group consisting of Ir(L_{A1-1-1})₂(L_{C1-I}) to Ir(L_{A4542-108-4})₂(L_{C1416-I}); and
when the compound has formula Ir(L_{Ai-m-X})₂(L_{Cj-II}), i is an integer from 1 to 4542; m is an integer from 1 to 108;j is an integer from 1 to 1416; and the compound is selected from the group consisting of Ir(L_{A1-1-1})₂(L_{C1-II}) to Ir(L_{A4542-108-4})₂(L_{C1416-II});
wherein each L_{Bk} from L_{B1} to L_{B324} has the structure defined as follows: 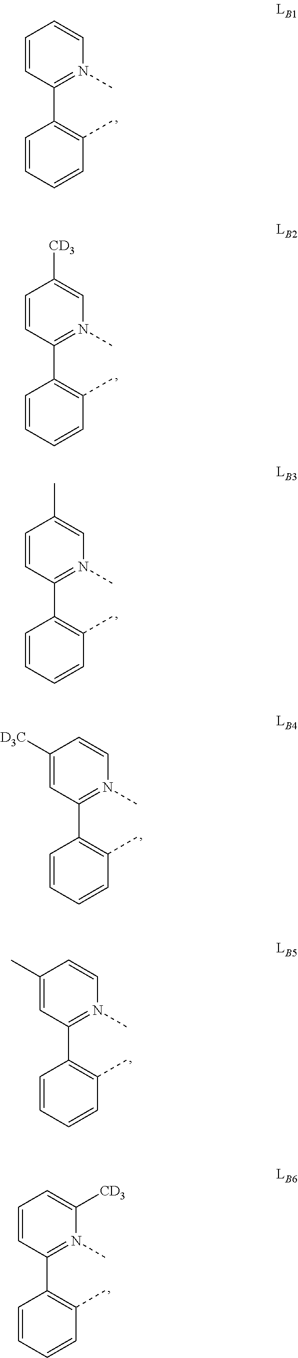 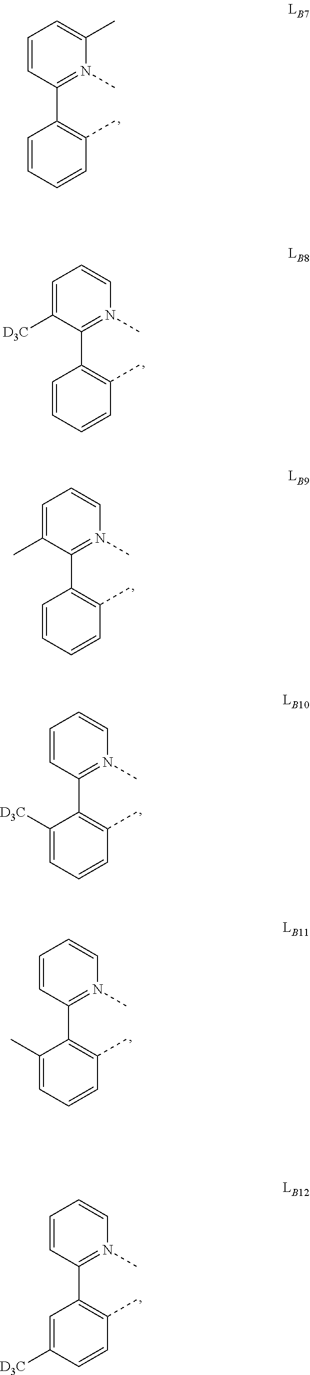 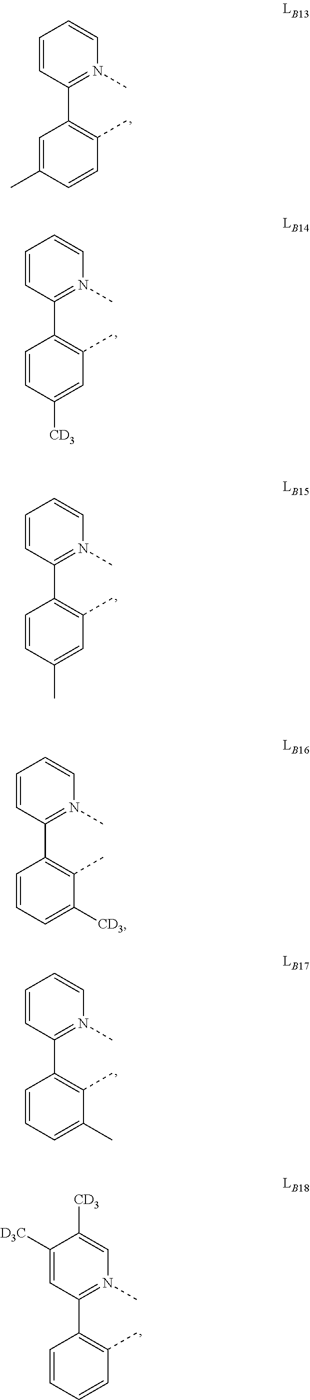 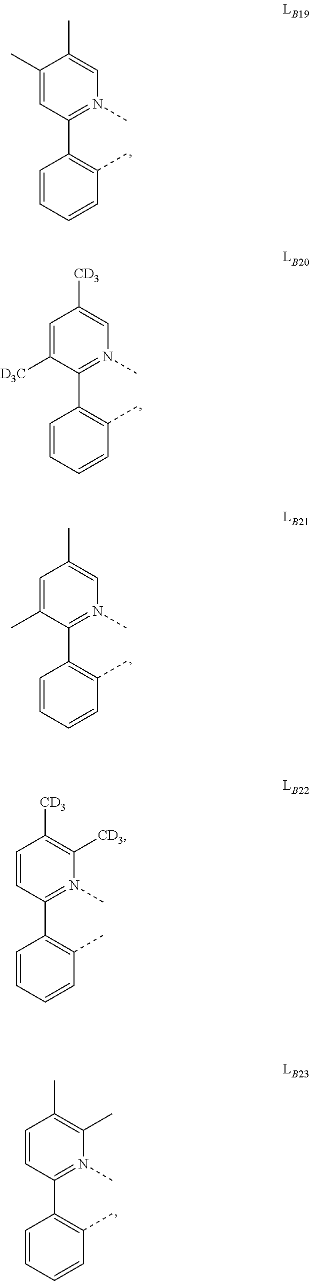 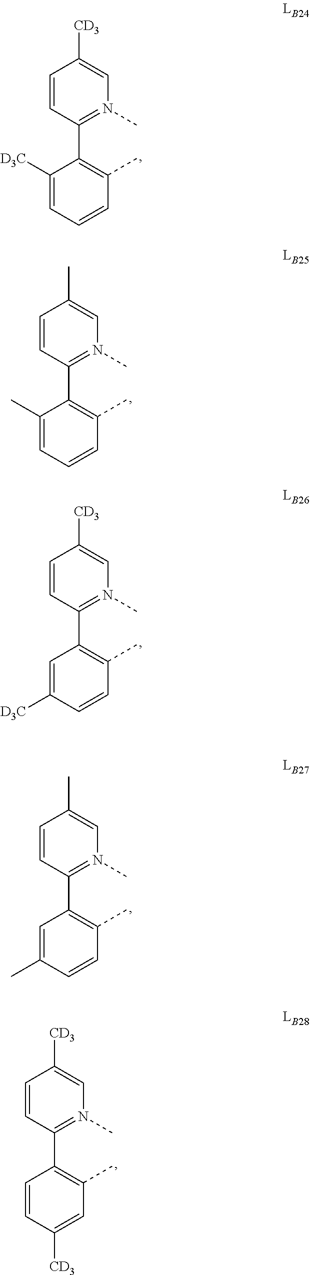 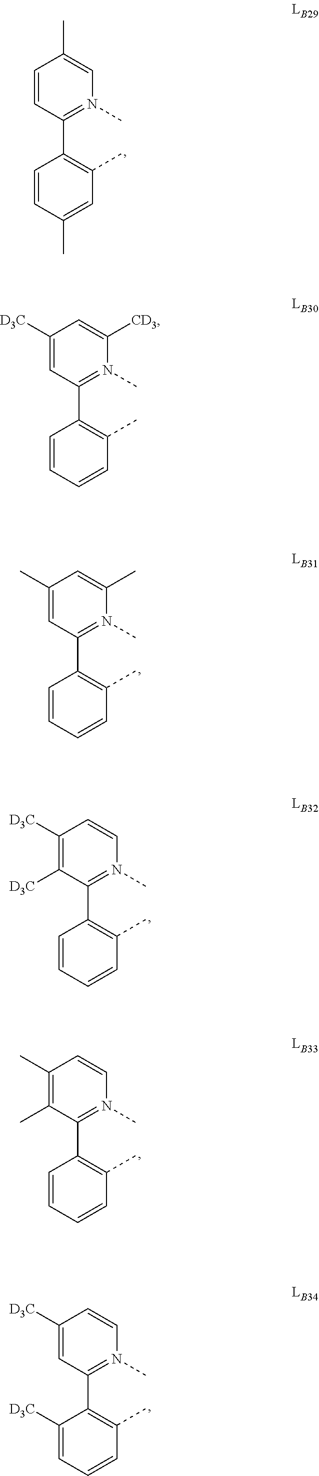 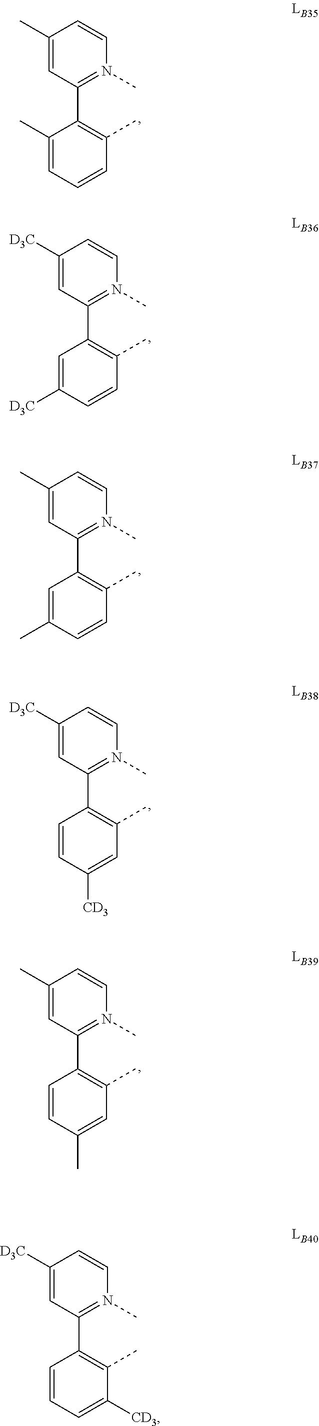 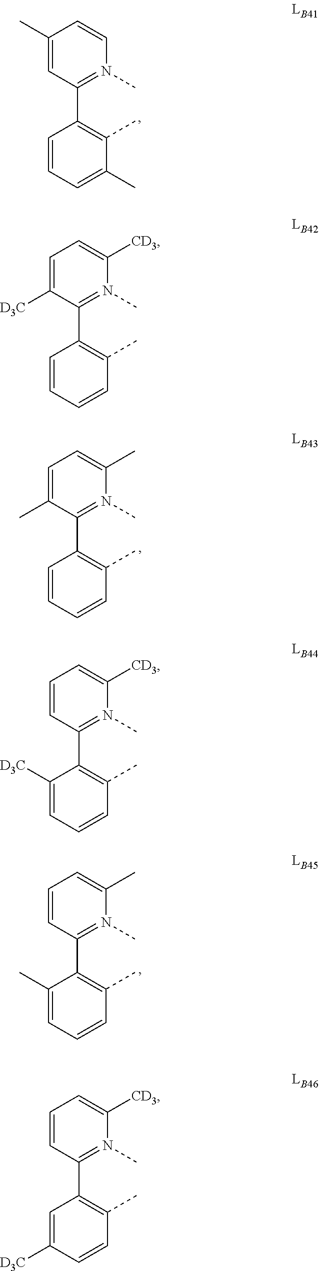 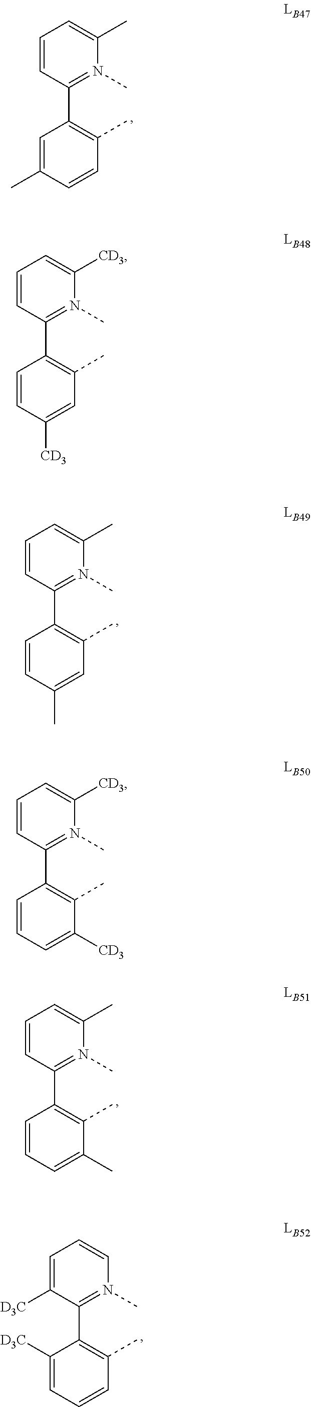 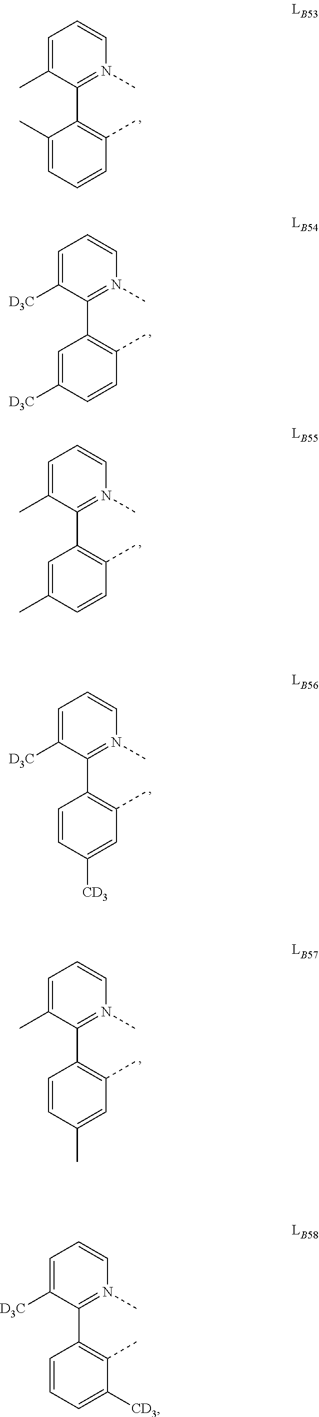 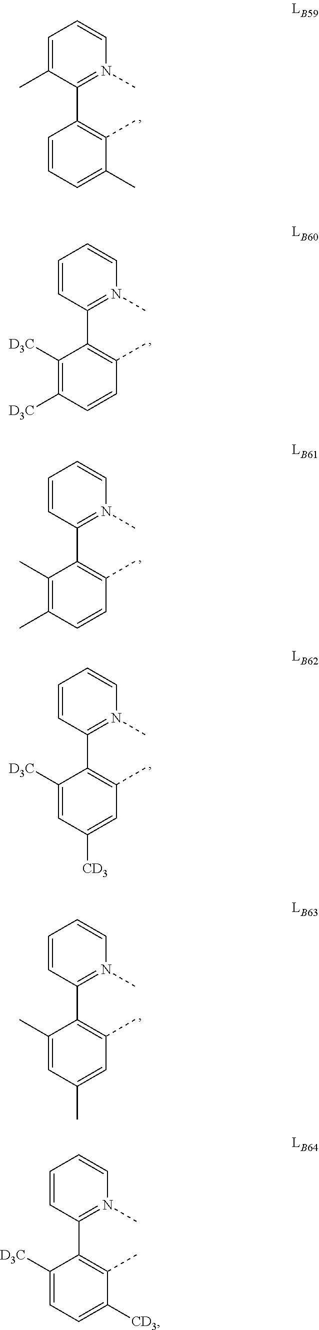 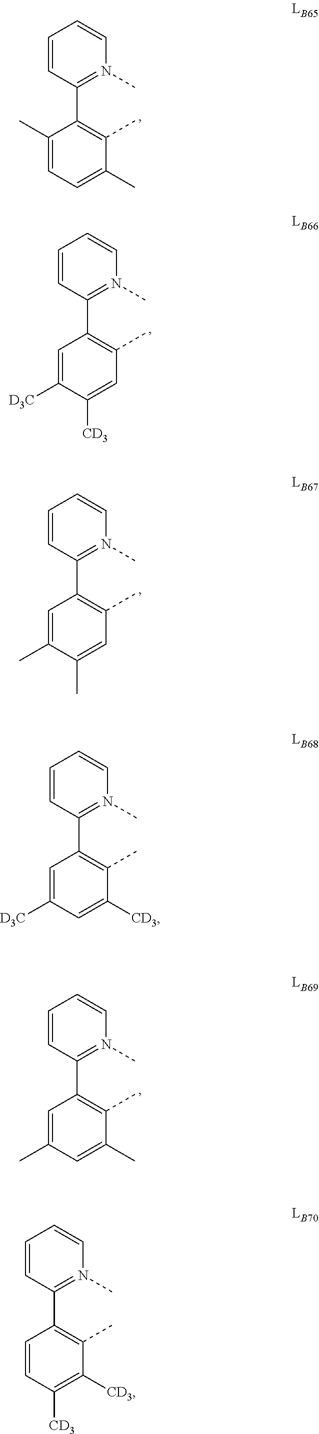 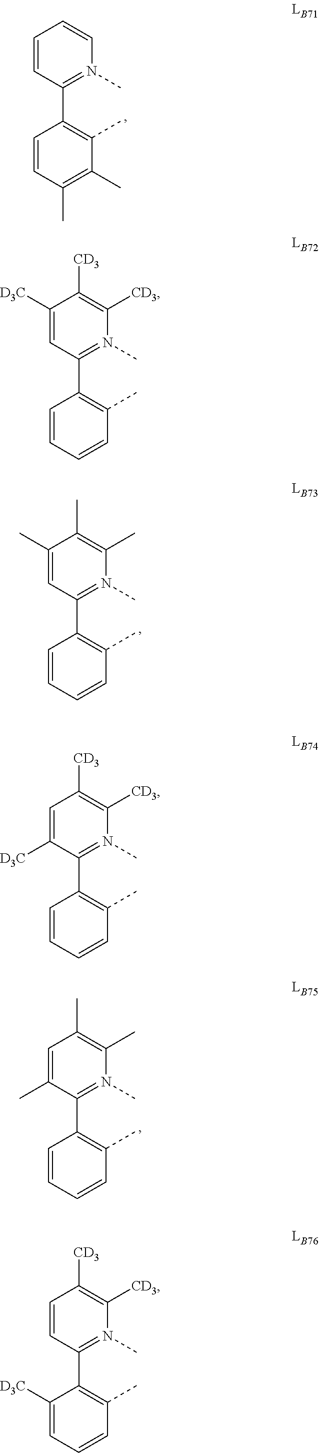 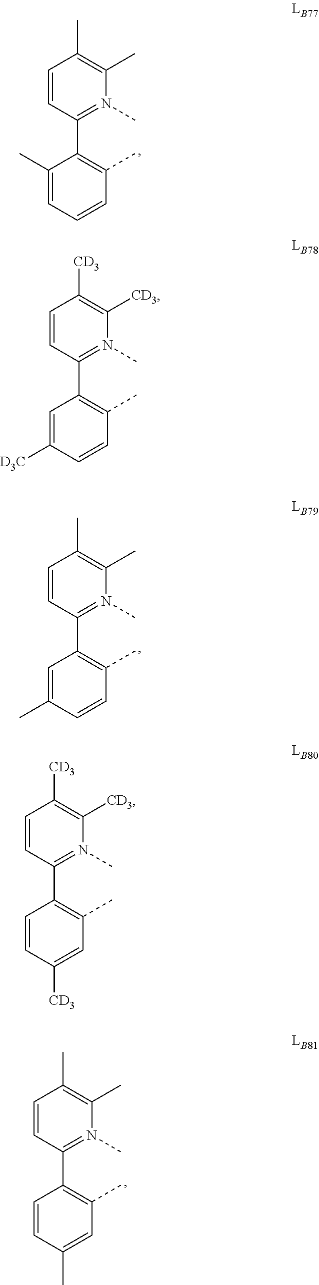 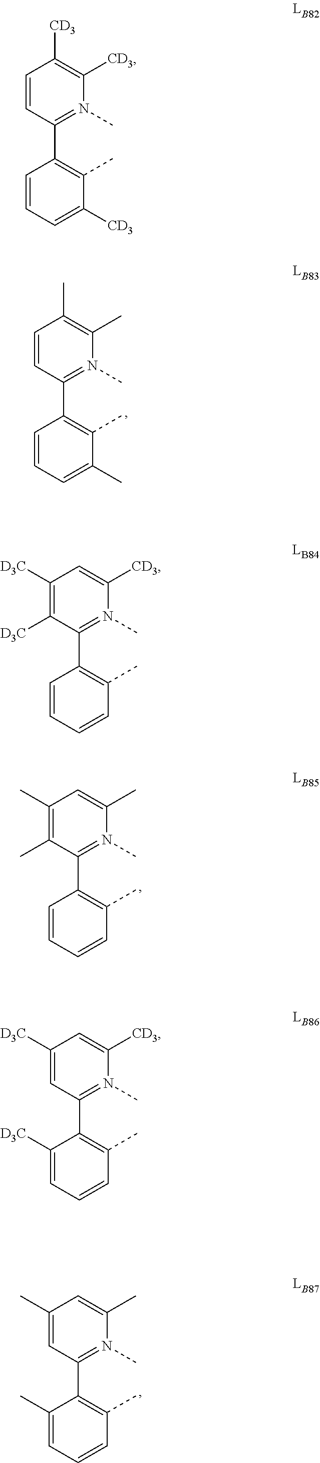 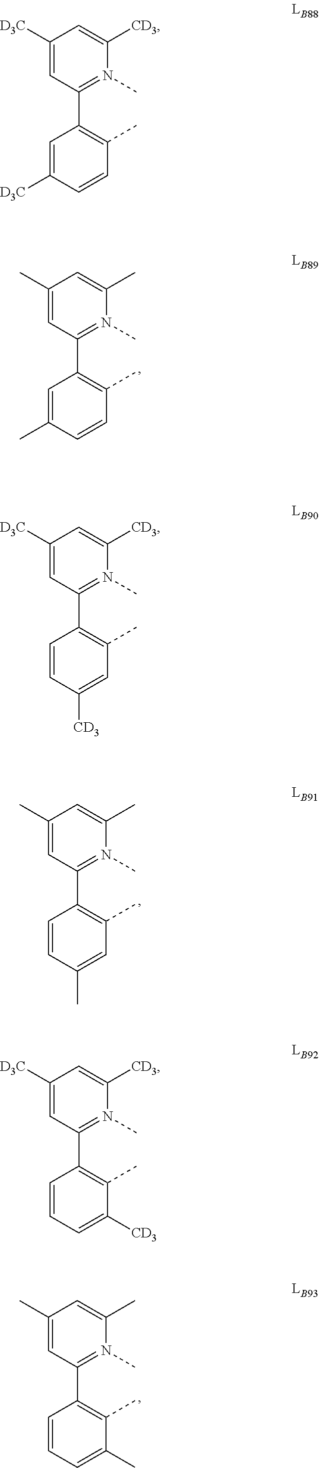 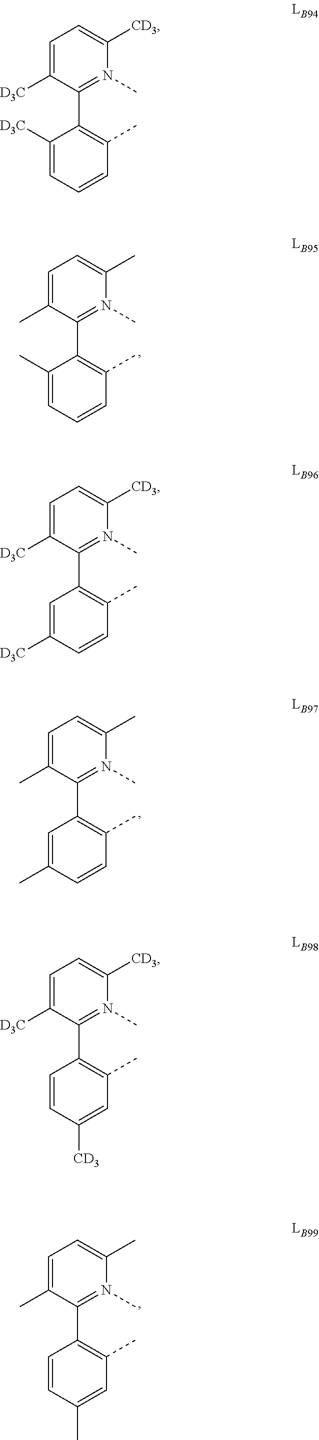 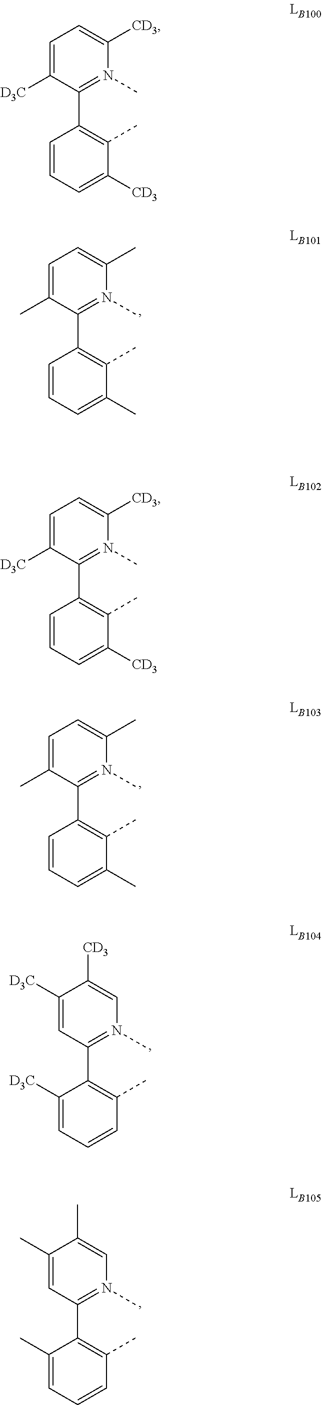 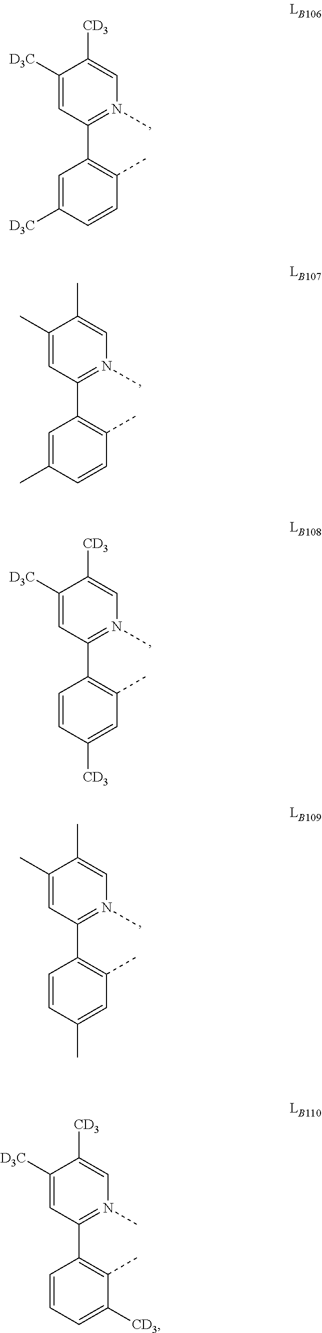 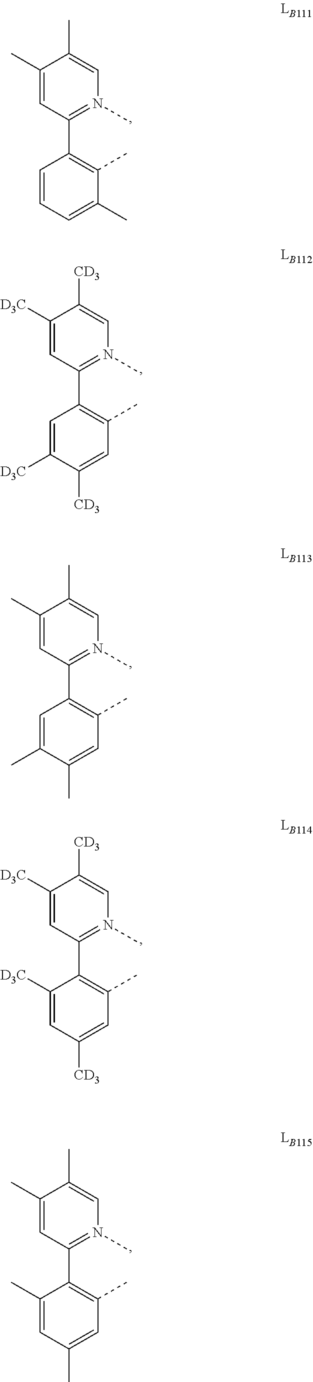 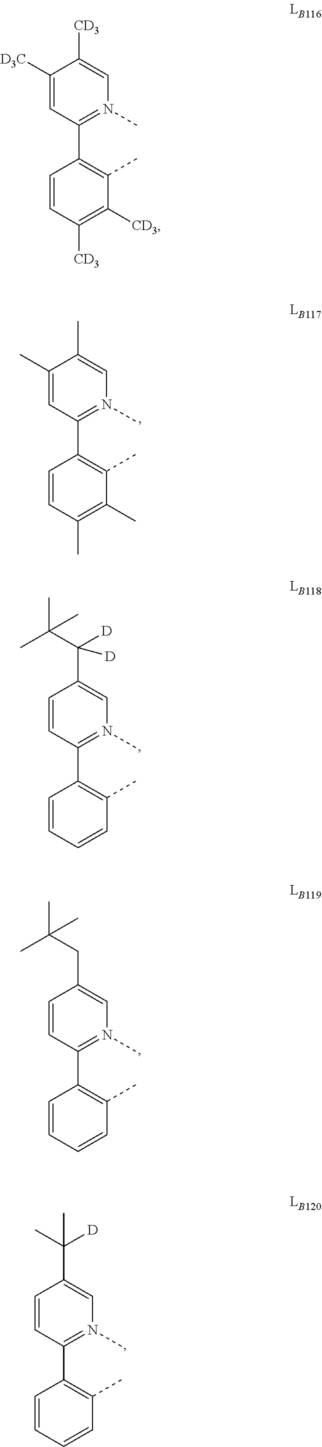 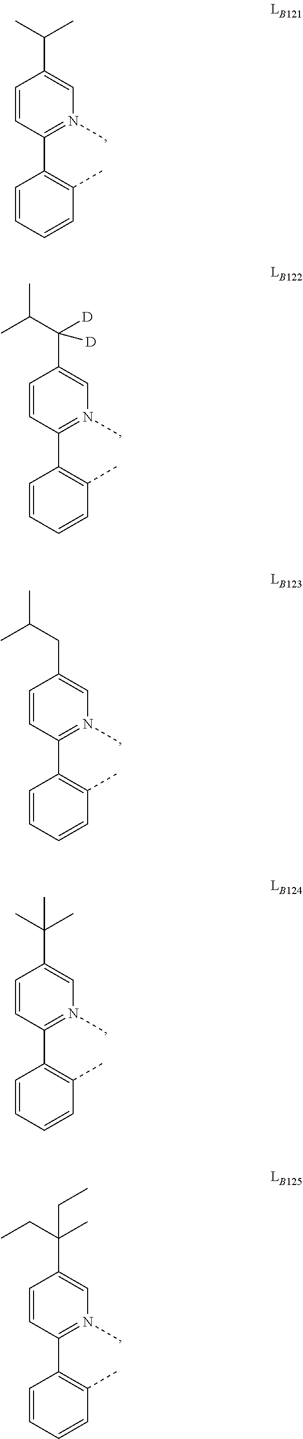 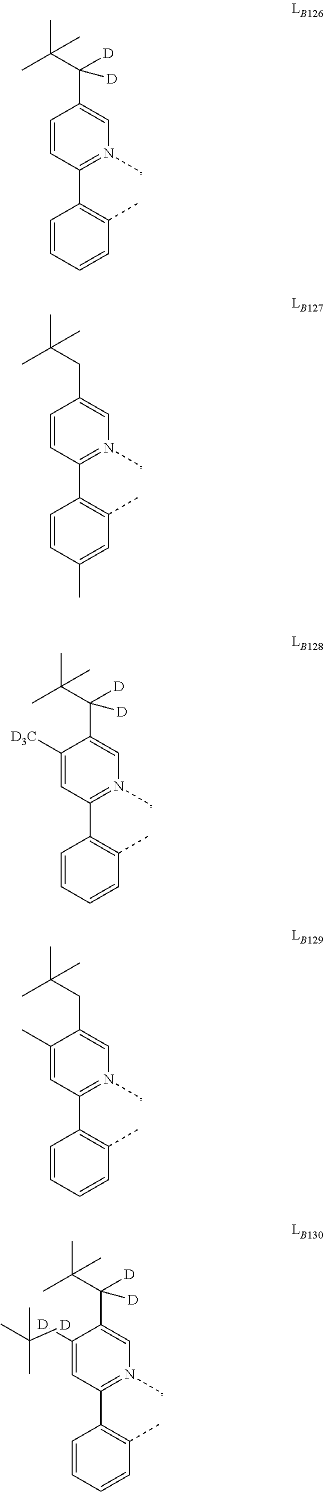 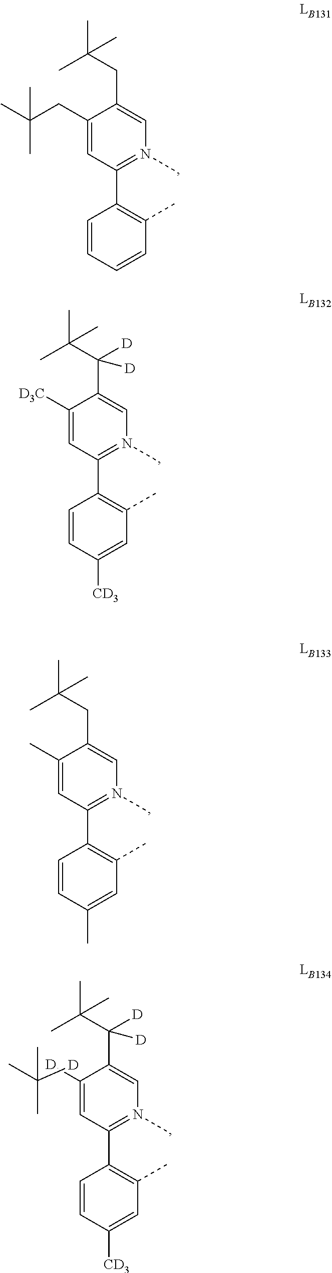 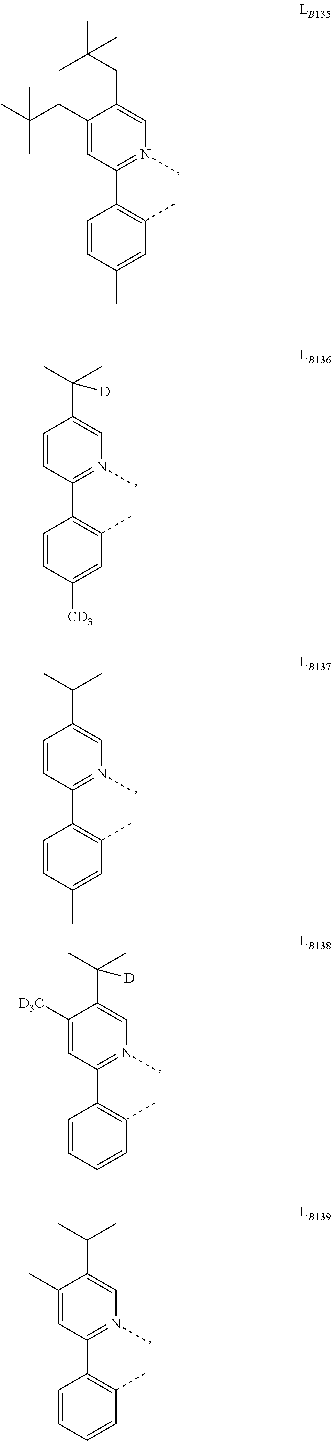 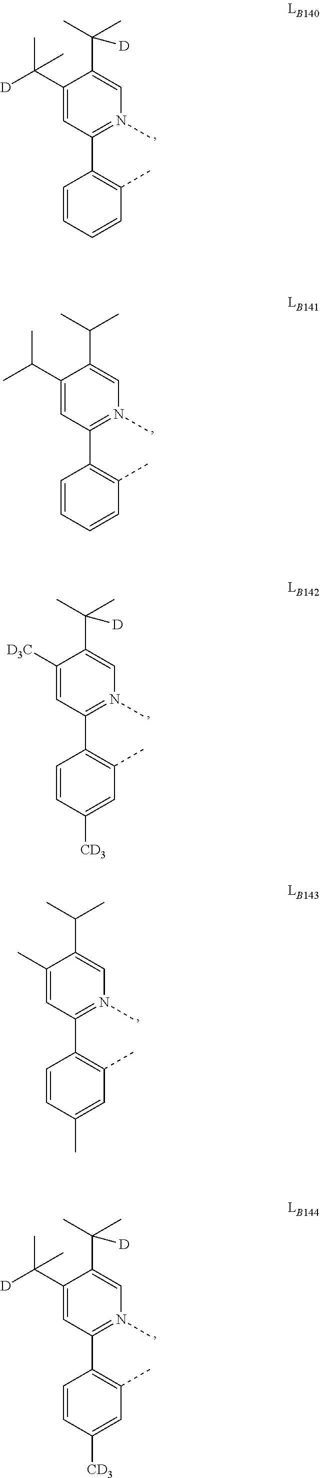 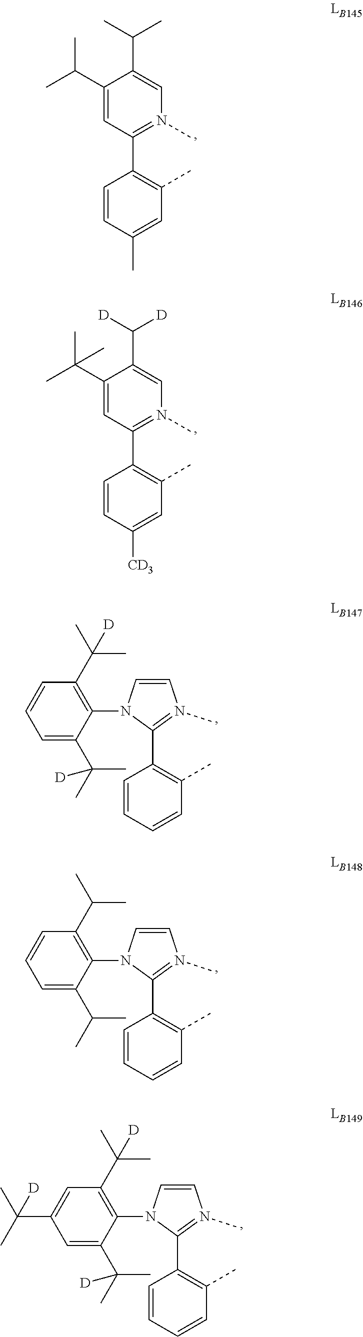 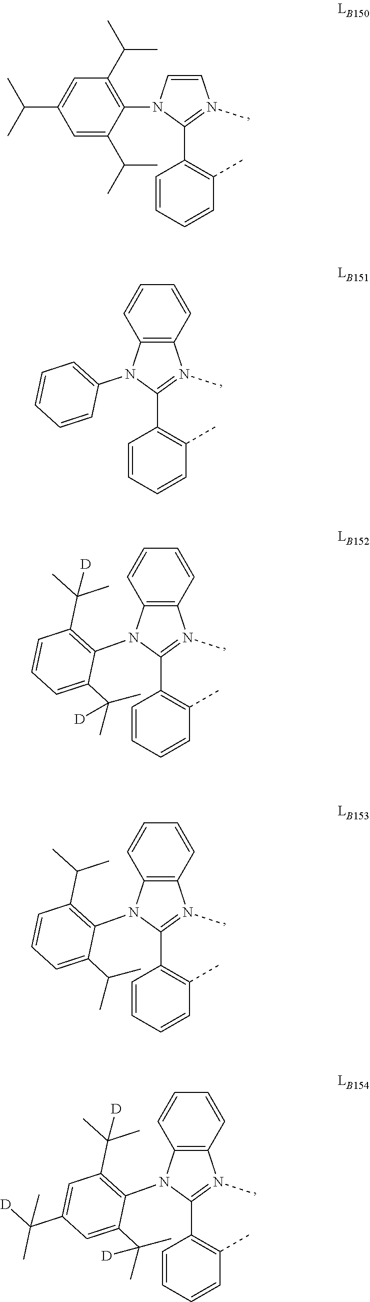 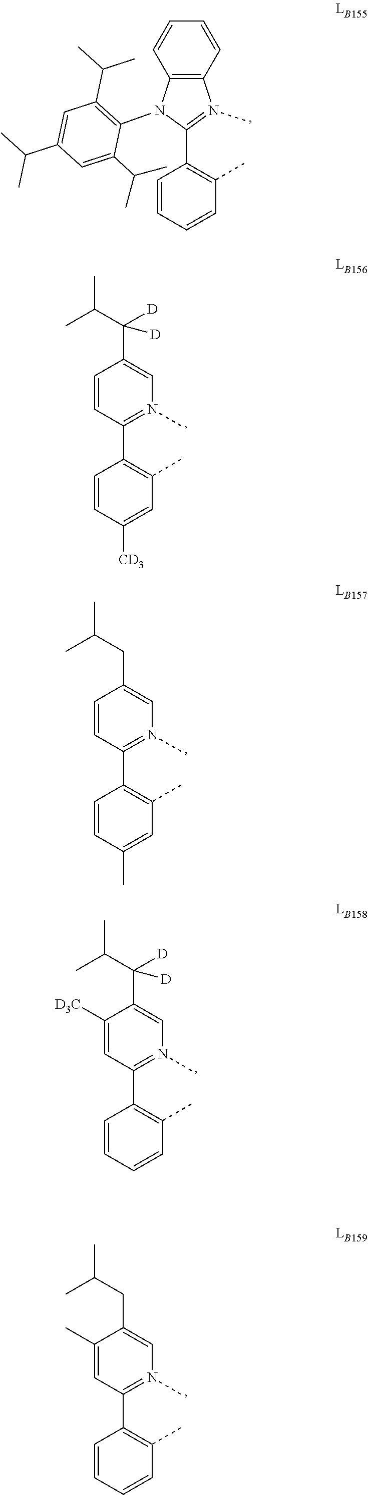 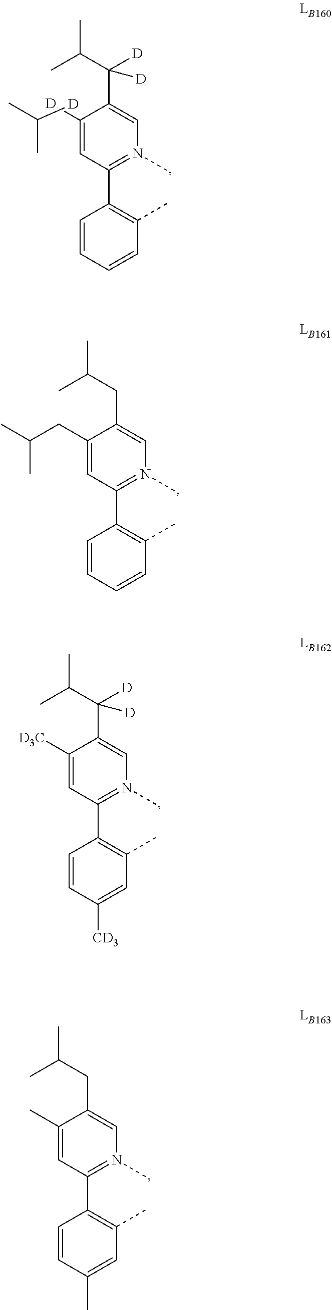 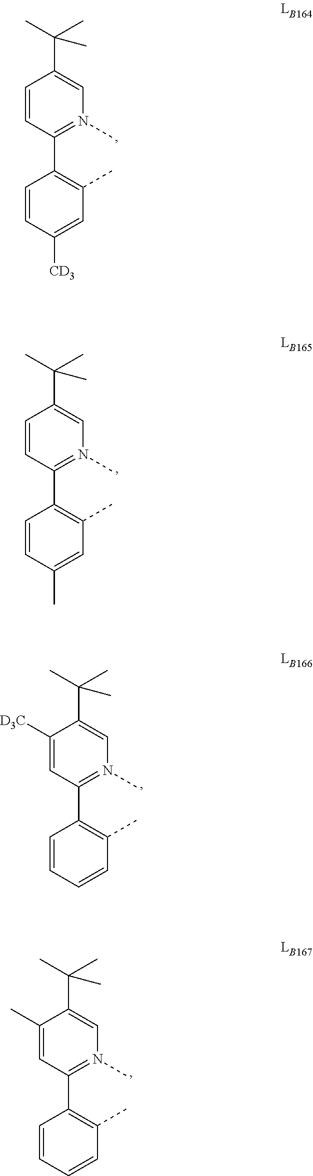 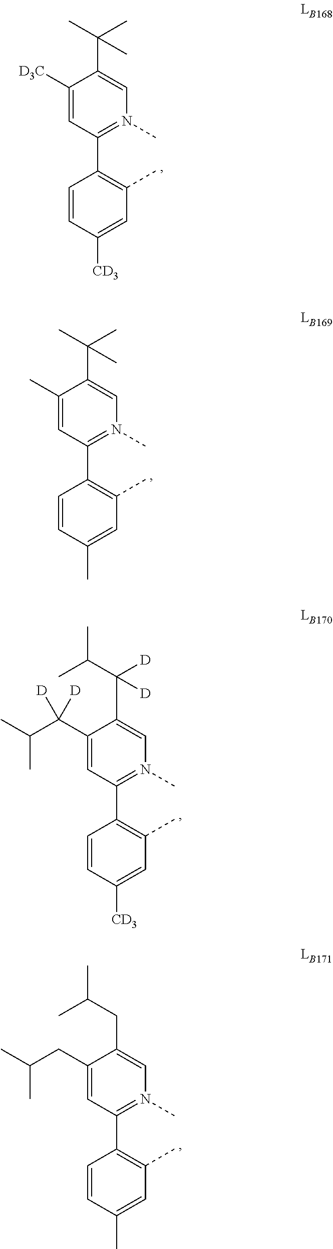 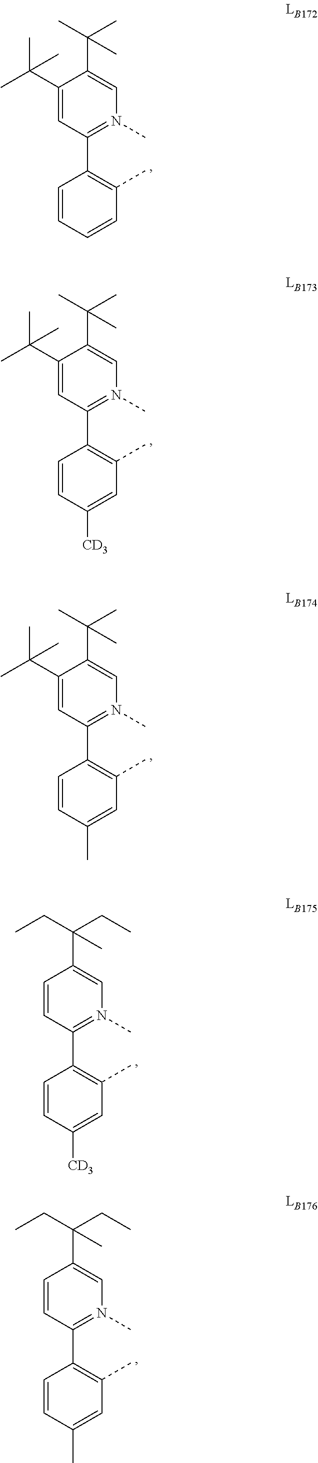 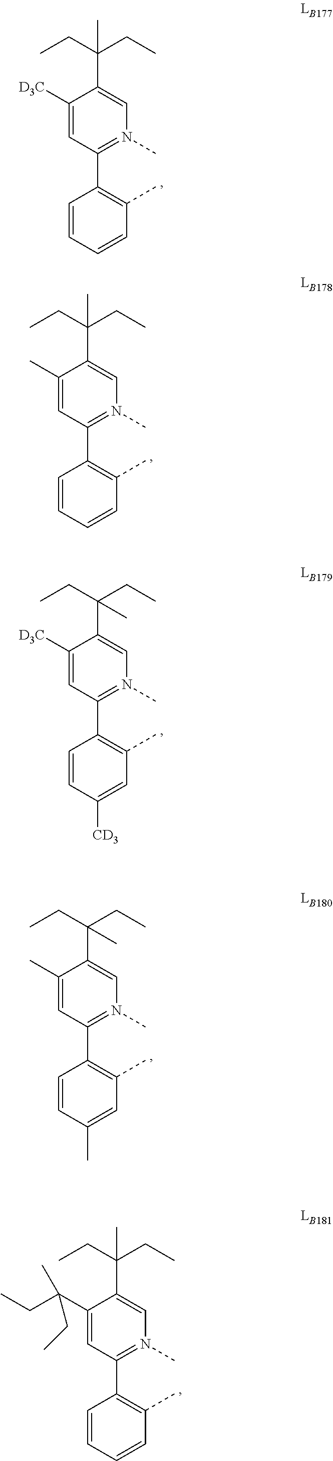 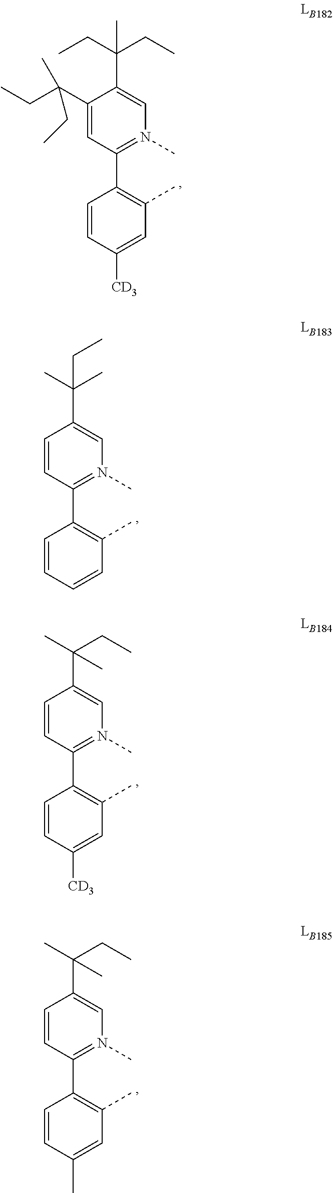 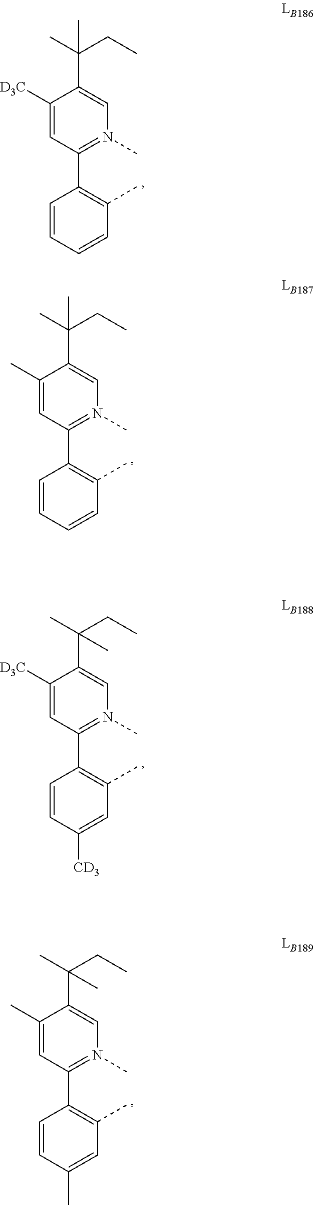 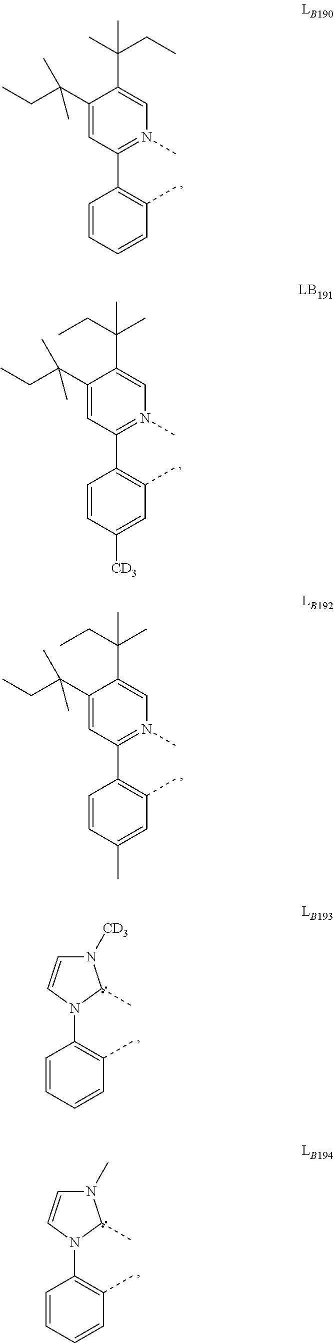 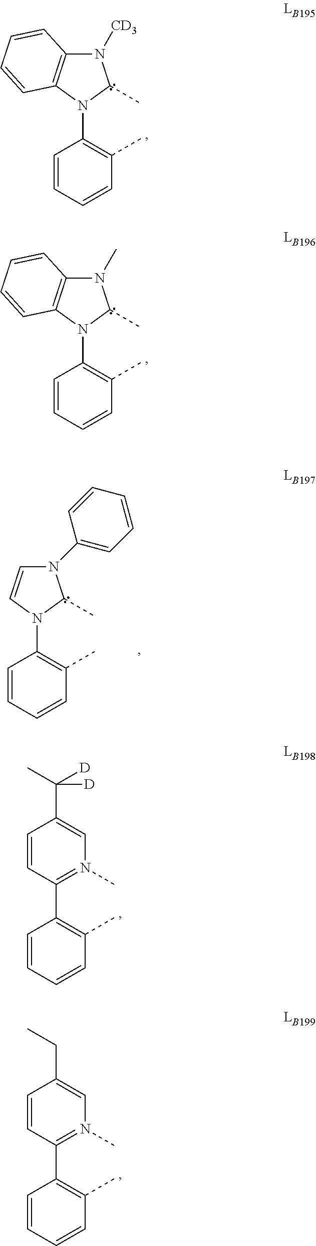 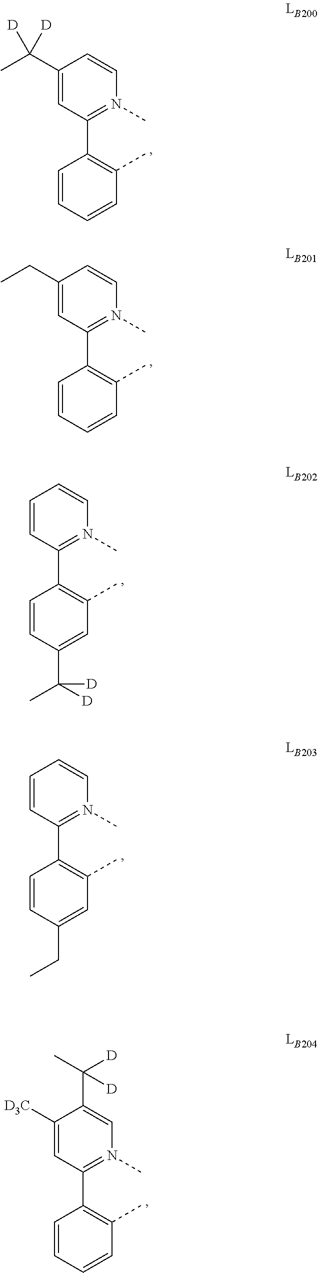 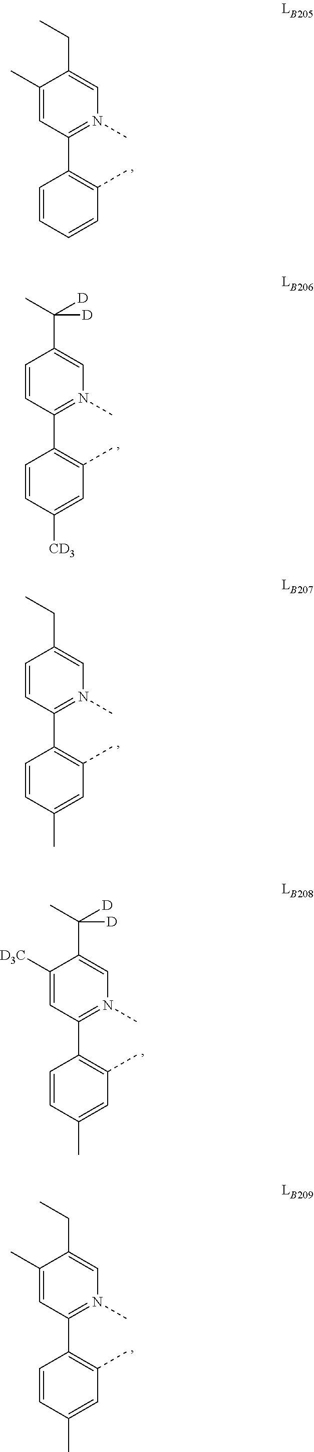 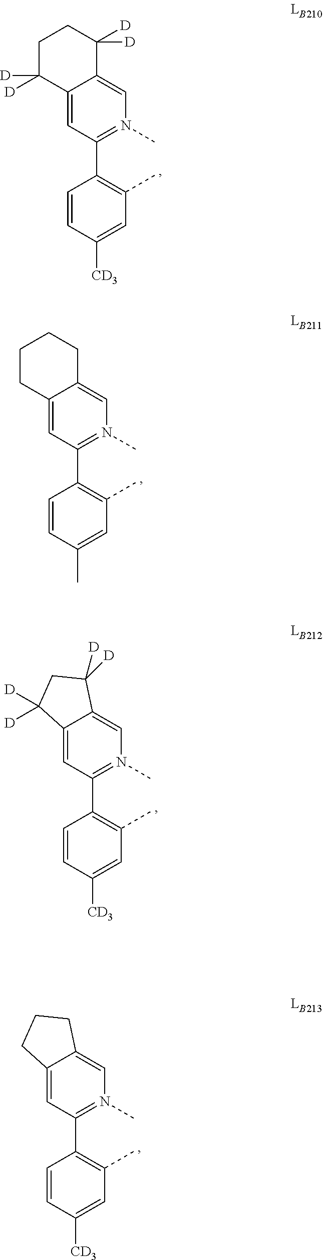 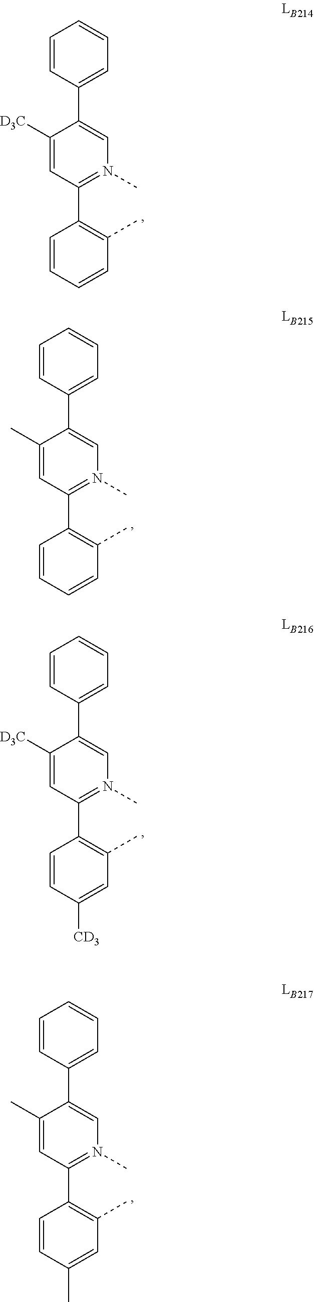 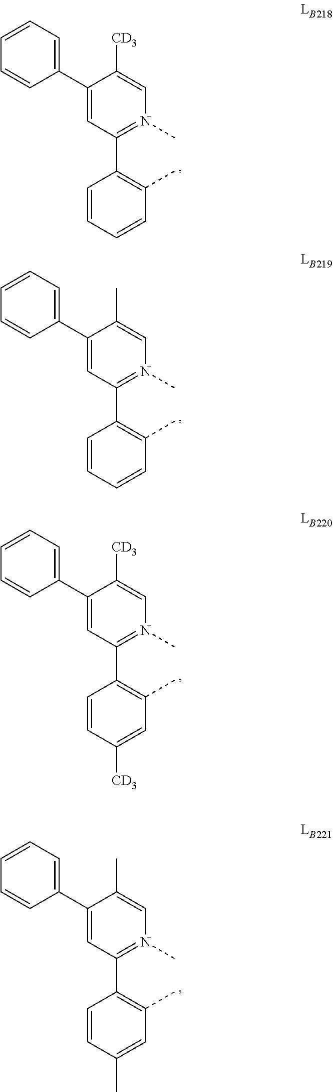 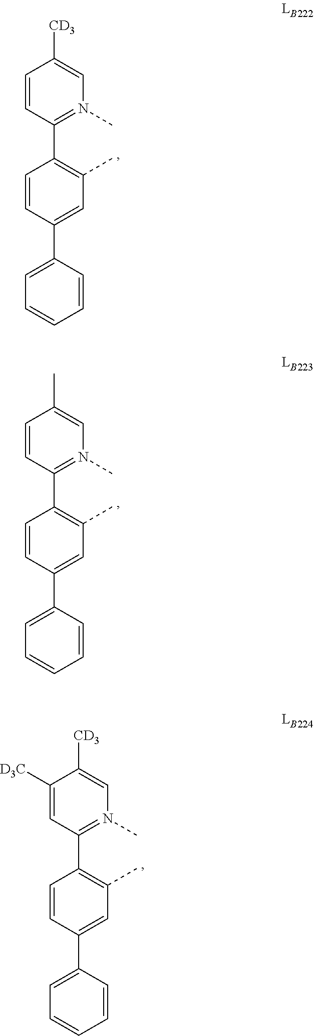 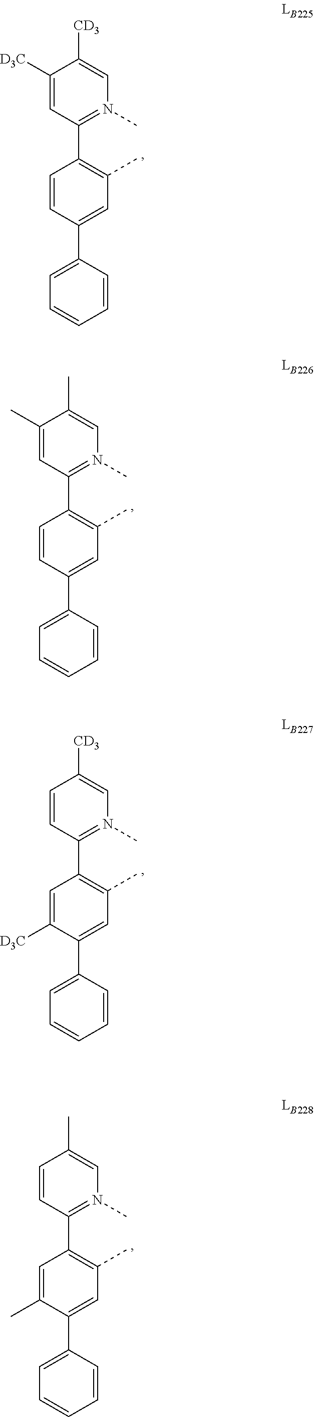 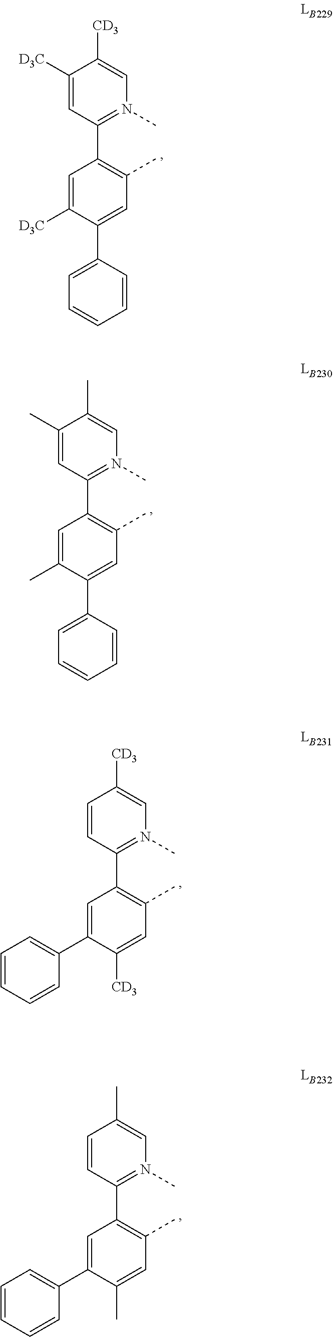 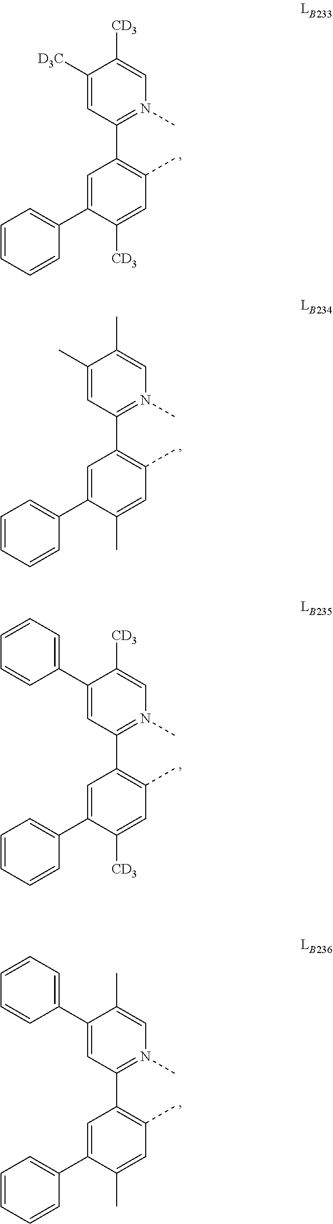 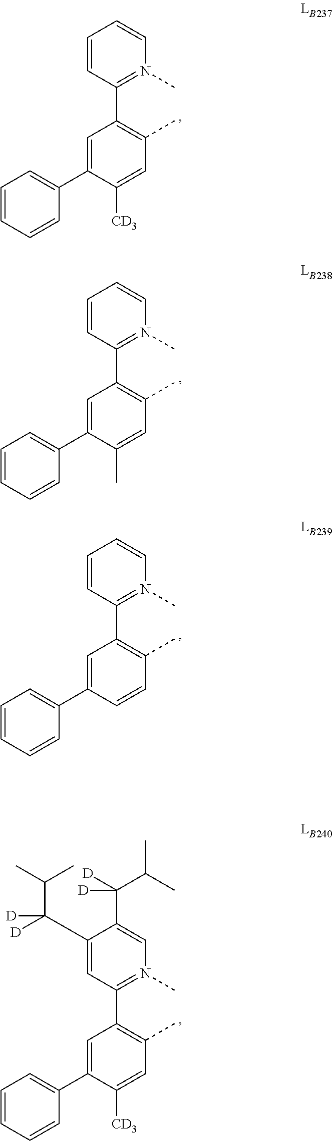 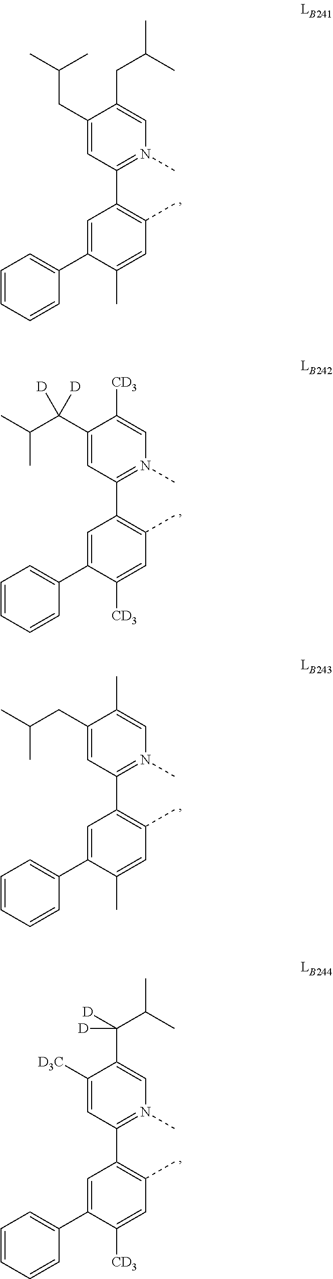 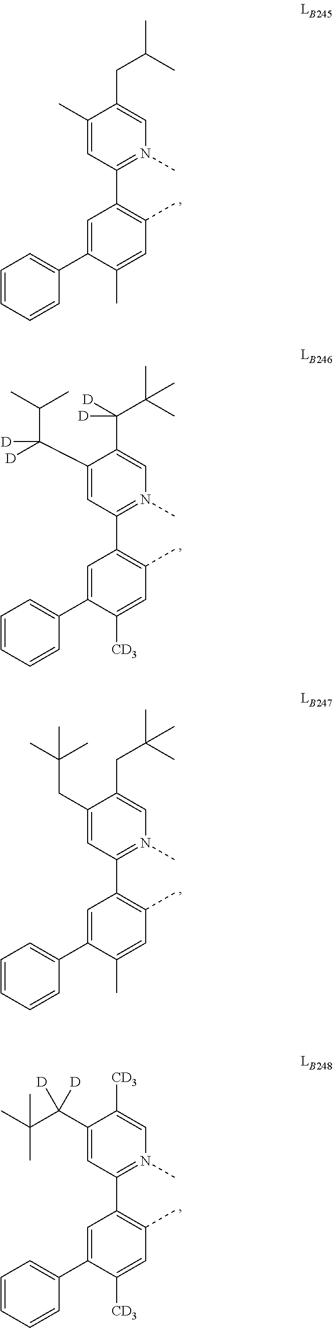 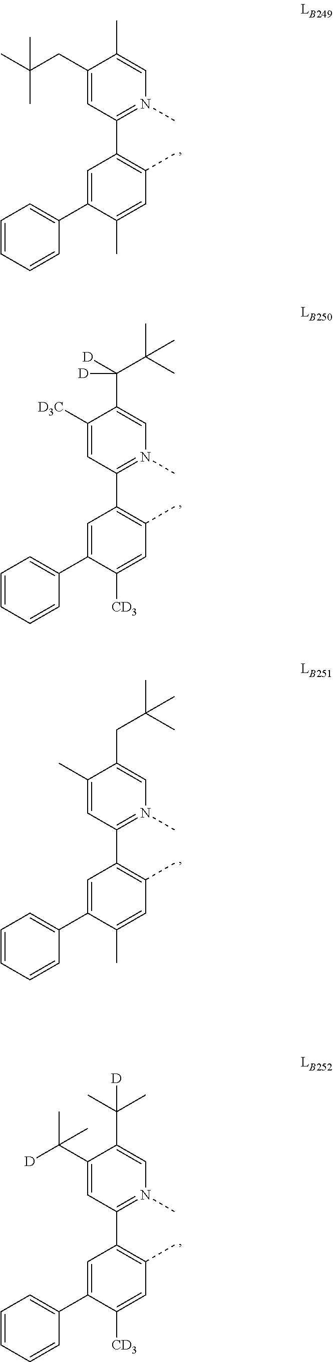 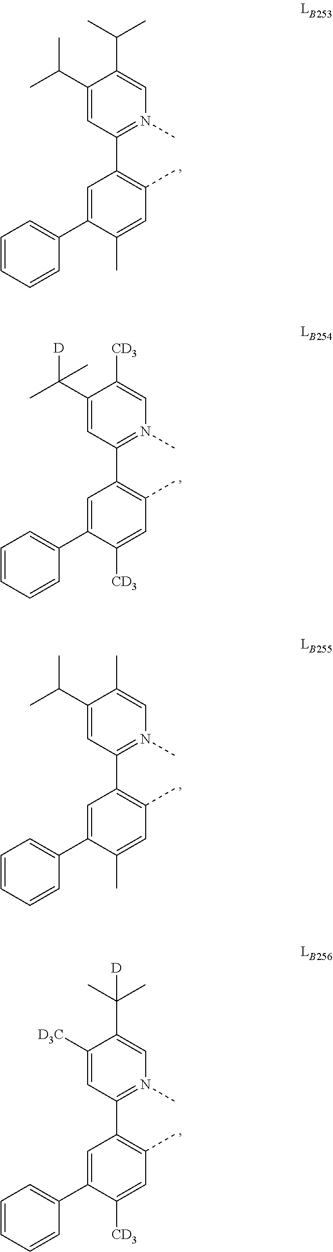 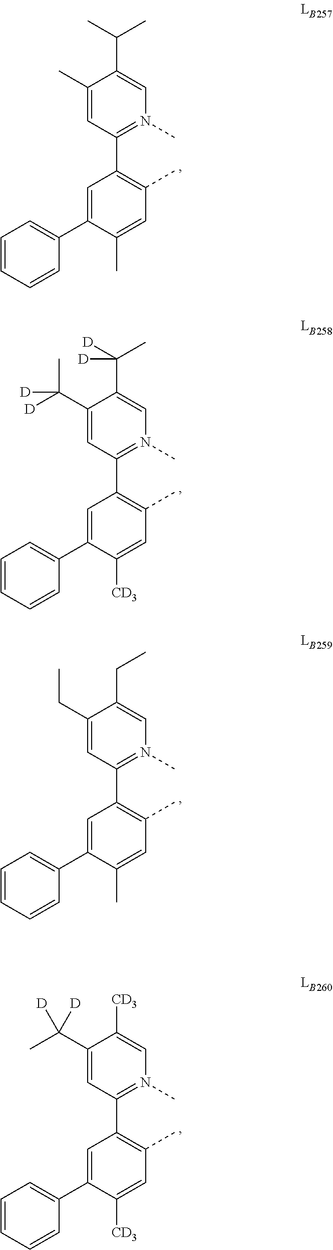 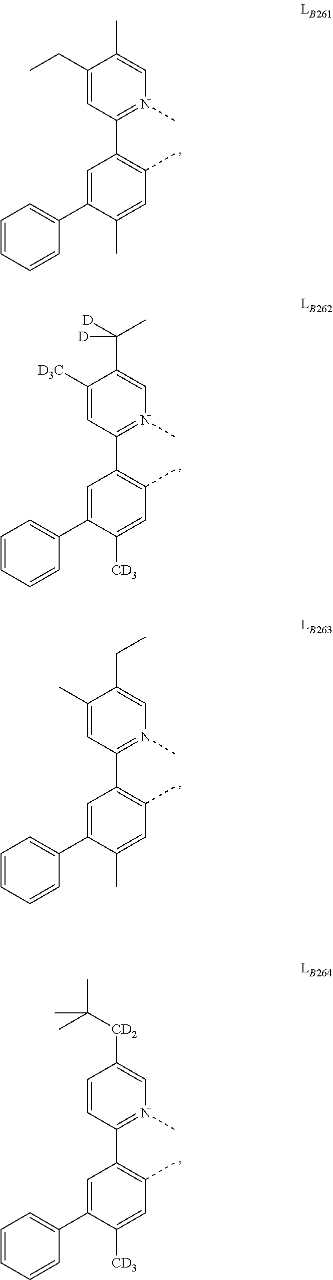 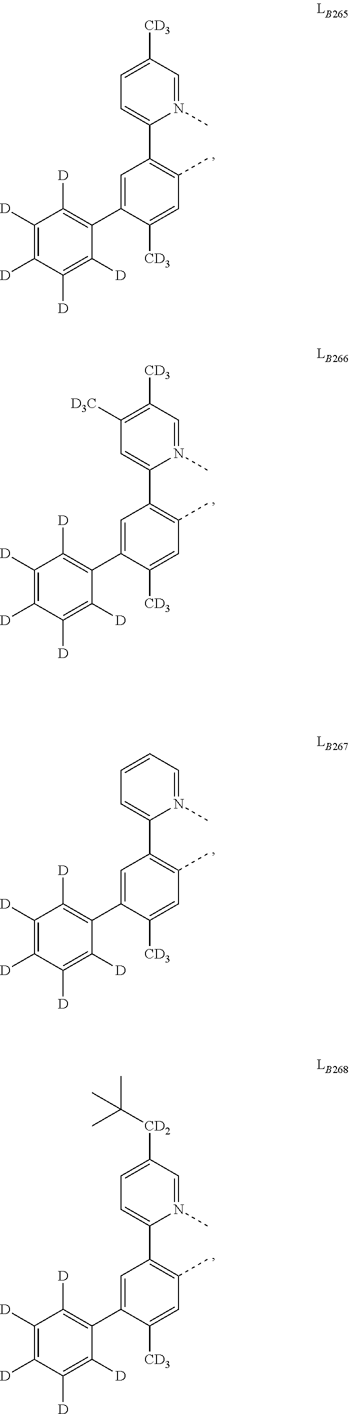 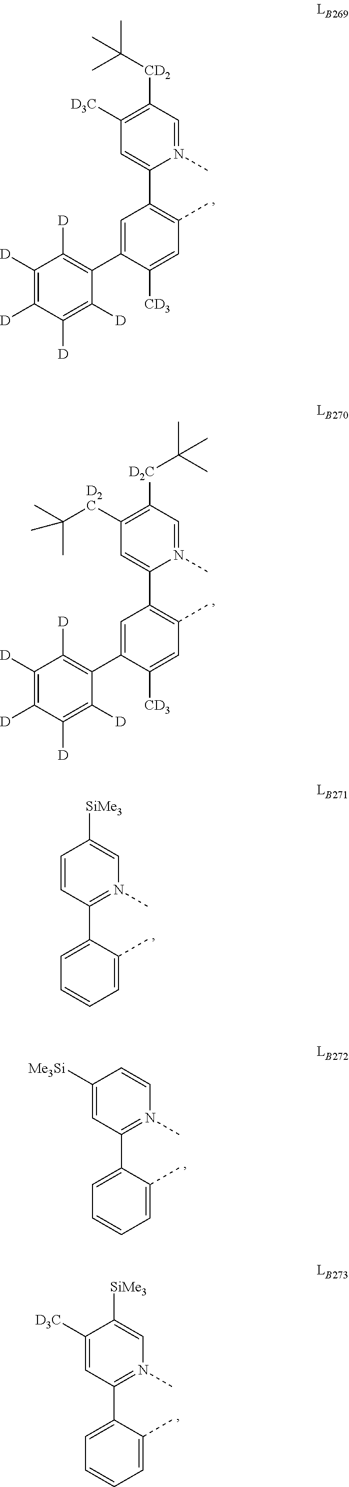 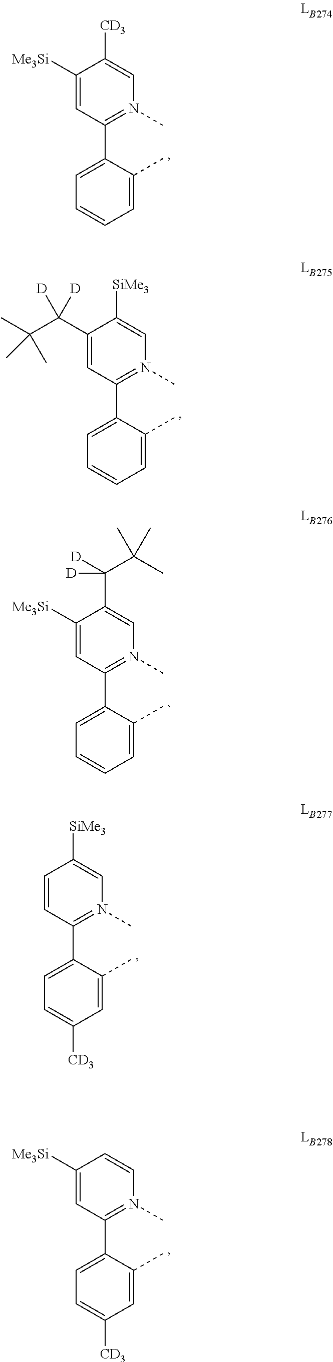 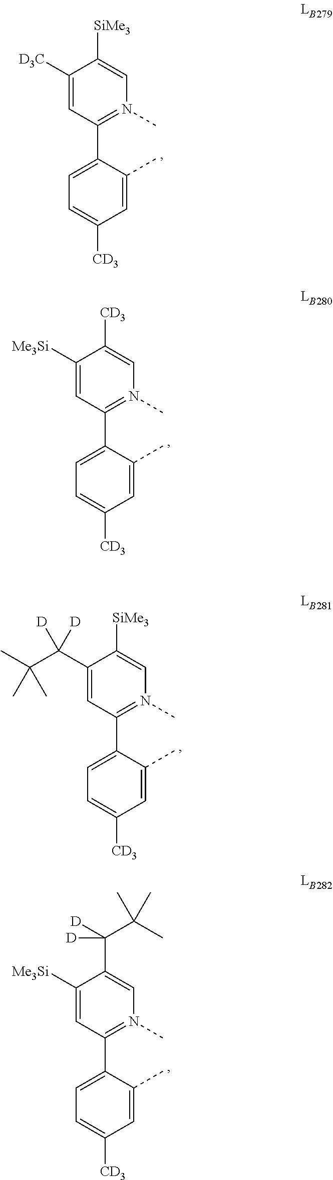 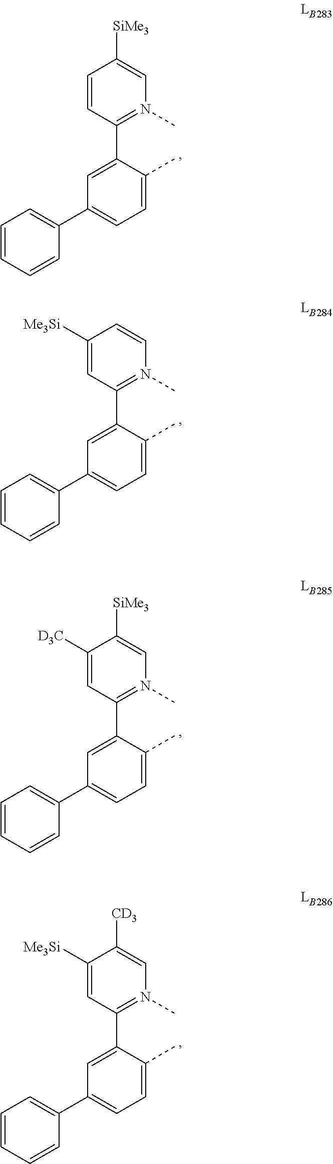 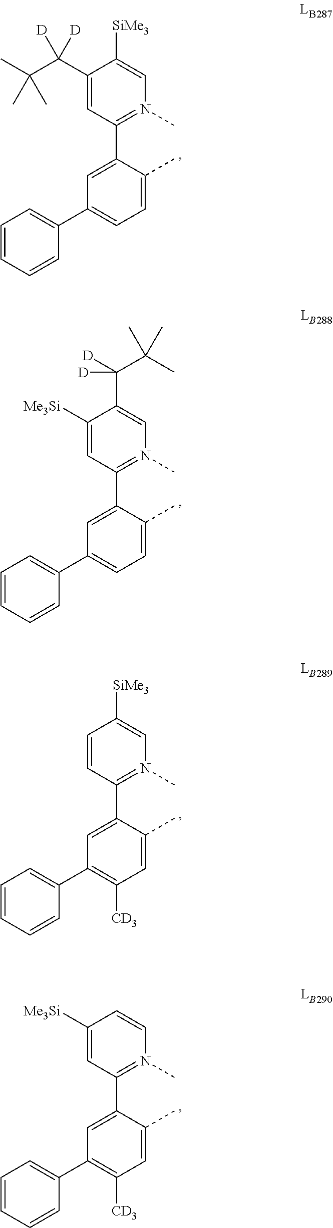 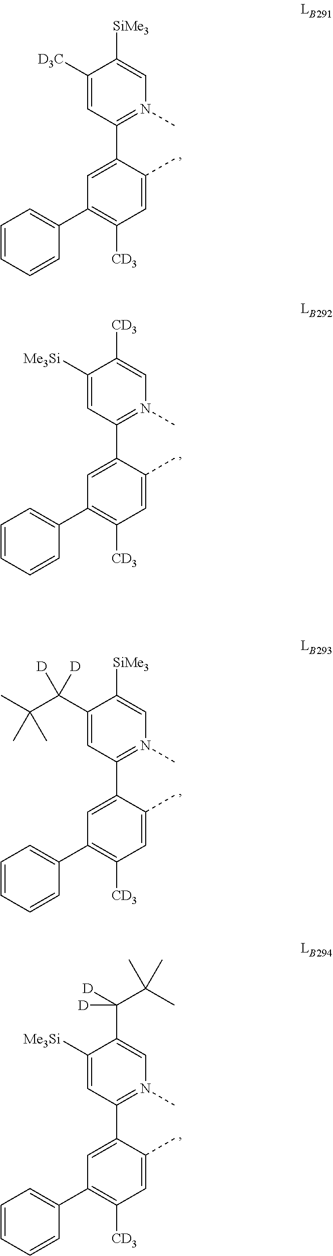 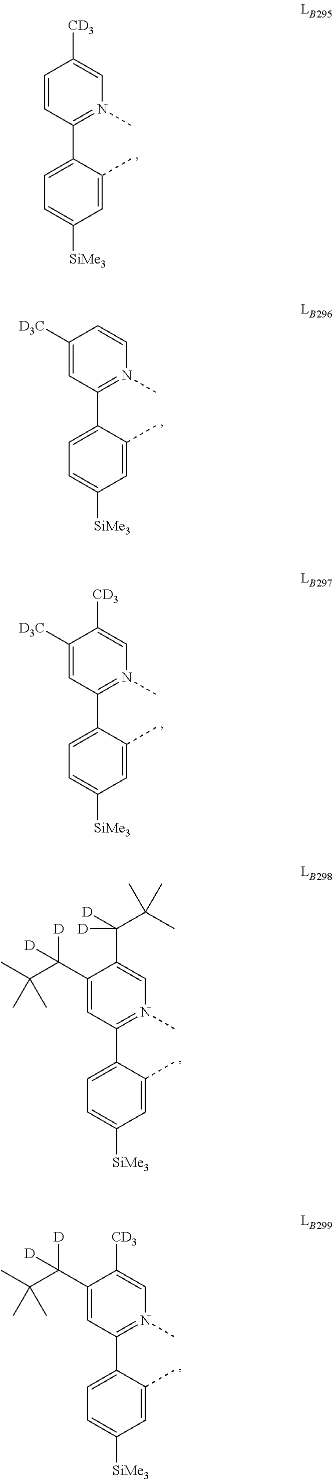 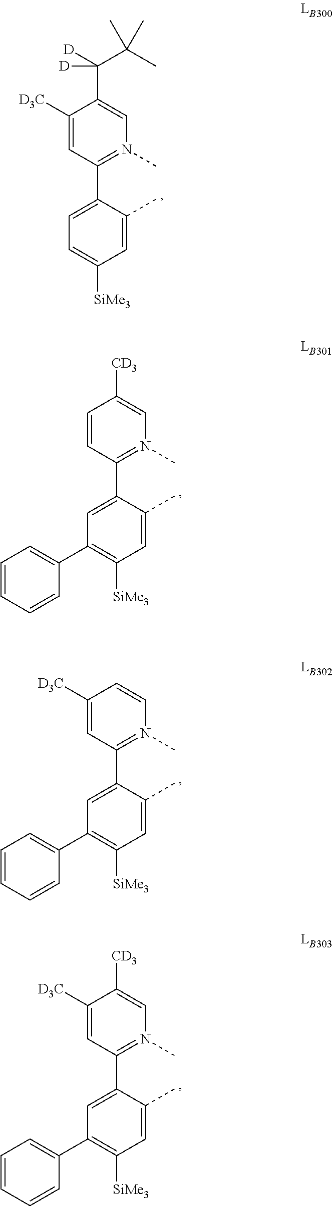 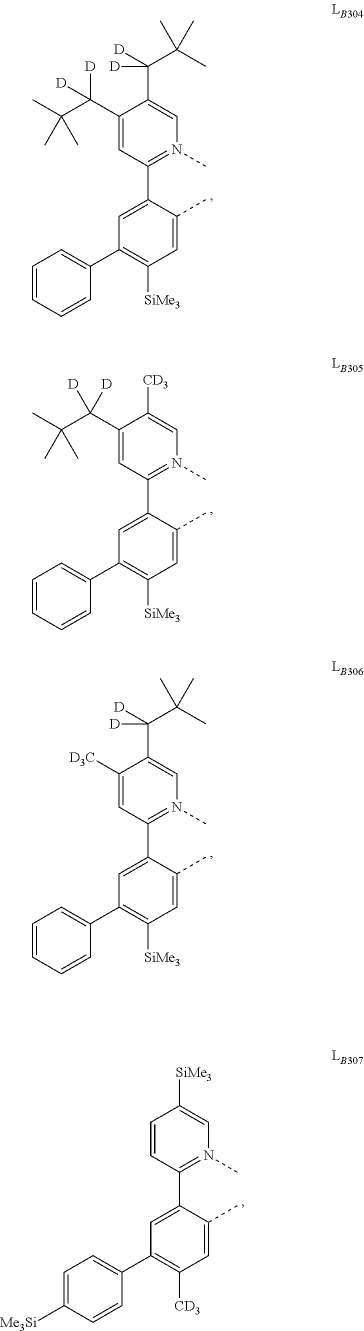 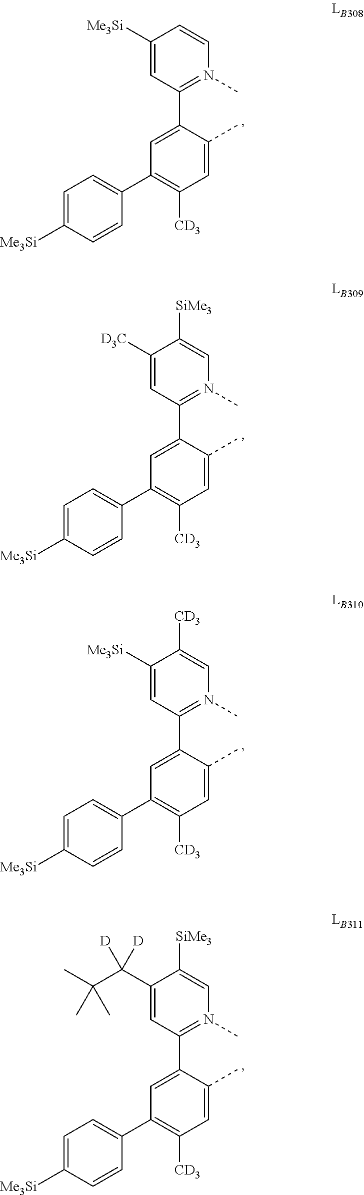 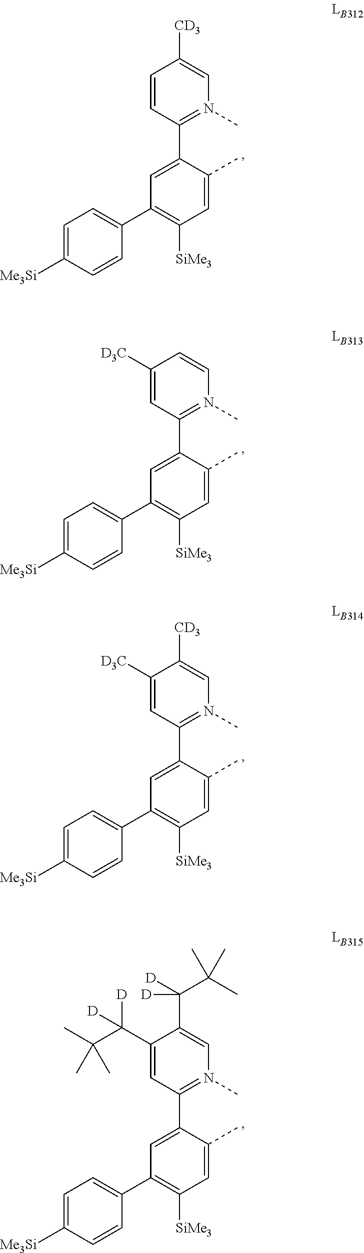 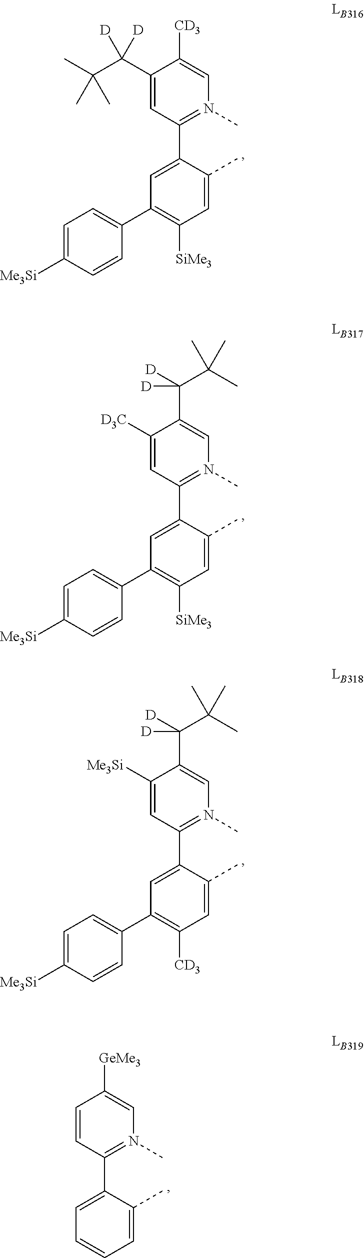 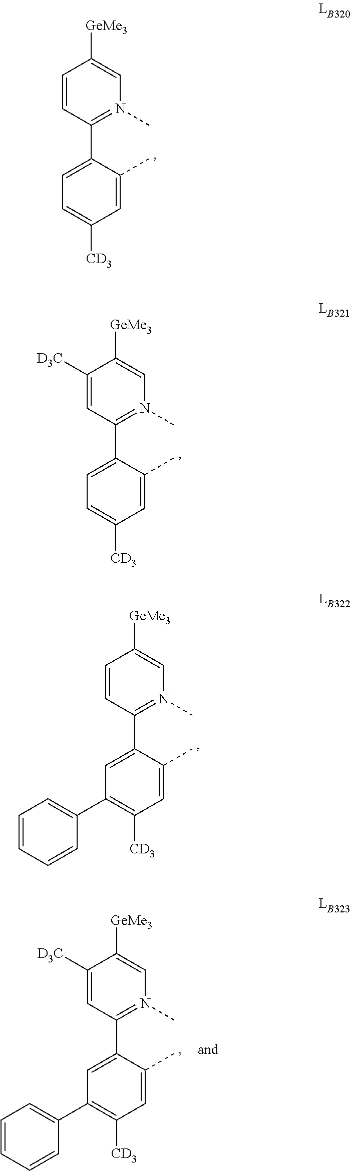 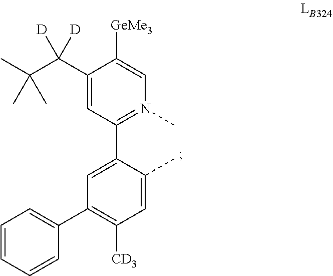
wherein each L_{Cj-I} has a structure based on formula 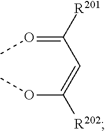
and
each L_{Cj-II} has a structure based on formula 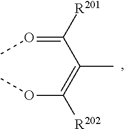
wherein for each L_{Cj} in L_{Cj-I} and L_{Cj-II}, R²⁰¹ and R²⁰² are each independently defined as follows:

| L_{Cj} | R²⁰¹ | R²⁰² | L_{Cj} | R²⁰¹ | R²⁰² | L_{Cj} | R²⁰¹ | R²⁰² | L_{Cj} | R²⁰¹ | R²⁰² |
|---|---|---|---|---|---|---|---|---|---|---|---|
| L_{C1} | R^{D1} | R^{D1} | L_{C193} | R^{D1} | R^{D3} | L_{C385} | R^{D17} | R^{D40} | L_{C577} | R^{D143} | R^{D120} |
| L_{C2} | R^{D2} | R^{D2} | L_{C194} | R^{D1} | R^{D4} | L_{C386} | R^{D17} | R^{D41} | L_{C578} | R^{D143} | R^{D133} |
| L_{C3} | R^{D3} | R^{D3} | L_{C195} | R^{D1} | R^{D5} | L_{C387} | R^{D17} | R^{D42} | L_{C579} | R^{D143} | R^{D134} |
| L_{C4} | R^{D4} | R^{D4} | L_{C196} | R^{D1} | R^{D9} | L_{C388} | R^{D17} | R^{D43} | L_{C580} | R^{D143} | R^{D135} |
| L_{C5} | R^{D5} | R^{D5} | L_{C197} | R^{D1} | R^{D10} | L_{C389} | R^{D17} | R^{D48} | L_{C581} | R^{D143} | R^{D136} |
| L_{C6} | R^{D6} | R^{D6} | L_{C198} | R^{D1} | R^{D17} | L_{C390} | R^{D17} | R^{D49} | L_{C582} | R^{D143} | R^{D144} |
| L_{C7} | R^{D7} | R^{D7} | L_{C199} | R^{D1} | R^{D18} | L_{C391} | R^{D17} | R^{D50} | L_{C583} | R^{D143} | R^{D145} |
| L_{C8} | R^{D8} | R^{D8} | L_{C200} | R^{D1} | R^{D20} | L_{C392} | R^{D17} | R^{D54} | L_{C584} | R^{D143} | R^{D146} |
| L_{C9} | R^{D9} | R^{D9} | L_{C201} | R^{D1} | R^{D22} | L_{C393} | R^{D17} | R^{D55} | L_{C585} | R^{D143} | R^{D147} |
| L_{C10} | R^{D10} | R^{D10} | L_{C202} | R^{D1} | R^{D37} | L_{C394} | R^{D17} | R^{D58} | L_{C586} | R^{D143} | R^{D149} |
| L_{C11} | R^{D11} | R^{D11} | L_{C203} | R^{D1} | R^{D40} | L_{C395} | R^{D17} | R^{D59} | L_{C587} | R^{D143} | R^{D151} |
| L_{C12} | R^{D12} | R^{D12} | L_{C204} | R^{D1} | R^{D41} | L_{C396} | R^{D17} | R^{D78} | L_{C588} | R^{D143} | R^{D154} |
| L_{C13} | R^{D13} | R^{D 13} | L_{C205} | R^{D1} | R^{D42} | L_{C397} | R^{D17} | R^{D79} | L_{C589} | R^{D143} | R^{D155} |
| L_{C14} | R^{D14} | R^{D14} | L_{C206} | R^{D1} | R^{D43} | L_{C398} | R^{D17} | R^{D81} | L_{C590} | R^{D143} | R^{D161} |
| L_{C15} | R^{D15} | R^{D15} | L_{C207} | R^{D1} | R^{D48} | L_{C399} | R^{D17} | R^{D87} | L_{C591} | R^{D143} | R^{D175} |
| L_{C16} | R^{D16} | R^{D16} | L_{C208} | R^{D1} | R^{D49} | L_{C400} | R^{D17} | R^{D88} | L_{C592} | R^{D144} | R^{D3} |
| L_{C17} | R^{D17} | R^{D17} | L_{C209} | R^{D1} | R^{D50} | L_{C401} | R^{D17} | R^{D89} | L_{C593} | R^{D144} | R^{D5} |
| L_{C18} | R^{D18} | R^{D18} | L_{C210} | R^{D1} | R^{D54} | L_{C402} | R^{D17} | R^{D93} | L_{C594} | R^{D144} | R^{D17} |
| L_{C19} | R^{D19} | R^{D19} | L_{C211} | R^{D1} | R^{D55} | L_{C403} | R^{D17} | R^{D116} | L_{C595} | R^{D144} | R^{D18} |
| L_{C20} | R^{D20} | R^{D20} | L_{C212} | R^{D1} | R^{D58} | L_{C404} | R^{D17} | R^{D117} | L_{C596} | R^{D144} | R^{D20} |
| L_{C21} | R^{D21} | R^{D21} | L_{C213} | R^{D1} | R^{D59} | L_{C405} | R^{D17} | R^{D118} | L_{C597} | R^{D144} | R^{D22} |
| L_{C22} | R^{D22} | R^{D22} | L_{C214} | R^{D1} | R^{D78} | L_{C406} | R^{D17} | R^{D119} | L_{C598} | R^{D144} | R^{D37} |
| L_{C23} | R^{D23} | R^{D23} | L_{C215} | R^{D1} | R^{D79} | L_{C407} | R^{D17} | R^{D120} | L_{C599} | R^{D144} | R^{D40} |
| L_{C24} | R^{D24} | R^{D24} | L_{C216} | R^{D1} | R^{D81} | L_{C408} | R^{D17} | R^{D133} | L_{C600} | R^{D144} | R^{D41} |
| L_{C25} | R^{D25} | R^{D25} | L_{C217} | R^{D1} | R^{D87} | L_{C409} | R^{D17} | R^{D134} | L_{C601} | R^{D144} | R^{D42} |
| L_{C26} | R^{D26} | R^{D26} | L_{C218} | R^{D1} | R^{D88} | L_{C410} | R^{D17} | R^{D135} | L_{C602} | R^{D144} | R^{D43} |
| L_{C27} | R^{D27} | R^{D27} | L_{C219} | R^{D1} | R^{D89} | L_{C411} | R^{D17} | R^{D136} | L_{C603} | R^{D144} | R^{D48} |
| L_{C28} | R^{D28} | R^{D28} | L_{C220} | R^{D1} | R^{D93} | L_{C412} | R^{D17} | R^{D143} | L_{C604} | R^{D144} | R^{D49} |
| L_{C29} | R^{D29} | R^{D29} | L_{C221} | R^{D1} | R^{D116} | L_{C413} | R^{D17} | R^{D144} | L_{C605} | R^{D144} | R^{D54} |
| L_{C30} | R^{D30} | R^{D30} | L_{C222} | R^{D1} | R^{D117} | L_{C414} | R^{D17} | R^{D145} | L_{C606} | R^{D144} | R^{D58} |
| L_{C31} | R^{D31} | R^{D31} | L_{C223} | R^{D1} | R^{D118} | L_{C415} | R^{D17} | R^{D146} | L_{C607} | R^{D144} | R^{D59} |
| L_{C32} | R^{D32} | R^{D32} | L_{C224} | R^{D1} | R^{D119} | L_{C416} | R^{D17} | R^{D147} | L_{C608} | R^{D144} | R^{D78} |
| L_{C33} | R^{D33} | R^{D33} | L_{C225} | R^{D1} | R^{D120} | L_{C417} | R^{D17} | R^{D149} | L_{C609} | R^{D144} | R^{D79} |
| L_{C34} | R^{D34} | R^{D34} | L_{C226} | R^{D1} | R^{D133} | L_{C418} | R^{D17} | R^{D151} | L_{C610} | R^{D144} | R^{D81} |
| L_{C35} | R^{D35} | R^{D35} | L_{C227} | R^{D1} | R^{D134} | L_{C419} | R^{D17} | R^{D154} | L_{C611} | R^{D144} | R^{D87} |
| L_{C36} | R^{D36} | R^{D36} | L_{C228} | R^{D1} | R^{D135} | L_{C420} | R^{D17} | R^{D155} | L_{C612} | R^{D144} | R^{D88} |
| L_{C37} | R^{D37} | R^{D37} | L_{C229} | R^{D1} | R^{D136} | L_{C421} | R^{D17} | R^{D161} | L_{C613} | R^{D144} | R^{D89} |
| L_{C38} | R^{D38} | R^{D38} | L_{C230} | R^{D1} | R^{D143} | L_{C422} | R^{D17} | R^{D175} | L_{C614} | R^{D144} | R^{D93} |
| L_{C39} | R^{D39} | R^{D39} | L_{C231} | R^{D1} | R^{D144} | L_{C423} | R^{D50} | R^{D3} | L_{C615} | R^{D144} | R^{D116} |
| L_{C40} | R^{D40} | R^{D40} | L_{C232} | R^{D1} | R^{D145} | L_{C424} | R^{D50} | R^{D5} | L_{C616} | R^{D144} | R^{D117} |
| L_{C41} | R^{D41} | R^{D41} | L_{C233} | R^{D1} | R^{D146} | L_{C425} | R^{D50} | R^{D18} | L_{C617} | R^{D144} | R^{D118} |
| L_{C42} | R^{D42} | R^{D42} | L_{C234} | R^{D1} | R^{D147} | L_{C426} | R^{D50} | R^{D20} | L_{C618} | R^{D144} | R^{D119} |
| L_{C43} | R^{D43} | R^{D43} | L_{C235} | R^{D1} | R^{D149} | L_{C427} | R^{D50} | R^{D22} | L_{C619} | R^{D144} | R^{D120} |
| L_{C44} | R^{D44} | R^{D44} | L_{C236} | R^{D1} | R^{D151} | L_{C428} | R^{D50} | R^{D37} | L_{C620} | R^{D144} | R^{D133} |
| L_{C45} | R^{D45} | R^{D45} | L_{C237} | R^{D1} | R^{D154} | L_{C429} | R^{D50} | R^{D40} | L_{C621} | R^{D144} | R^{D134} |
| L_{C46} | R^{D46} | R^{D46} | L_{C238} | R^{D1} | R^{D155} | L_{C430} | R^{D50} | R^{D41} | L_{C622} | R^{D144} | R^{D135} |
| L_{C47} | R^{D47} | R^{D47} | L_{C239} | R^{D1} | R^{D161} | L_{C431} | R^{D50} | R^{D42} | L_{C623} | R^{D144} | R^{D136} |
| L_{C48} | R^{D48} | R^{D48} | L_{C240} | R^{D1} | R^{D175} | L_{C432} | R^{D50} | R^{D43} | L_{C624} | R^{D144} | R^{D145} |
| L_{C49} | R^{D49} | R^{D49} | L_{C241} | R^{D4} | R^{D3} | L_{C433} | R^{D50} | R^{D48} | L_{C625} | R^{D144} | R^{D146} |
| L_{C50} | R^{D50} | R^{D50} | L_{C242} | R^{D4} | R^{D5} | L_{C434} | R^{D50} | R^{D49} | L_{C626} | R^{D144} | R^{D147} |
| L_{C51} | R^{D51} | R^{D51} | L_{C243} | R^{D4} | R^{D9} | L_{C435} | R^{D50} | R^{D54} | L_{C627} | R^{D144} | R^{D149} |
| L_{C52} | R^{D52} | R^{D52} | L_{C244} | R^{D4} | R^{D10} | L_{C436} | R^{D50} | R^{D55} | L_{C628} | R^{D144} | R^{D151} |
| L_{C53} | R^{D53} | R^{D53} | L_{C245} | R^{D4} | R^{D17} | L_{C437} | R^{D50} | R^{D58} | L_{C629} | R^{D144} | R^{D154} |
| L_{C54} | R^{D54} | R^{D54} | L_{C246} | R^{D4} | R^{D18} | L_{C438} | R^{D50} | R^{D59} | L_{C630} | R^{D144} | R^{D155} |
| L_{C55} | R^{D55} | R^{D55} | L_{C247} | R^{D4} | R^{D20} | L_{C439} | R^{D50} | R^{D78} | L_{C631} | R^{D144} | R^{D161} |
| L_{C56} | R^{D56} | R^{D56} | L_{C248} | R^{D4} | R^{D22} | L_{C440} | R^{D50} | R^{D79} | L_{C632} | R^{D144} | R^{D175} |
| L_{C57} | R^{D57} | R^{D57} | L_{C249} | R^{D4} | R^{D37} | L_{C441} | R^{D50} | R^{D81} | L_{C633} | R^{D145} | R^{D3} |
| L_{C58} | R^{D58} | R^{D58} | L_{C250} | R^{D4} | R^{D40} | L_{C442} | R^{D50} | R^{D87} | L_{C634} | R^{D145} | R^{D5} |
| L_{C59} | R^{D59} | R^{D59} | L_{C251} | R^{D4} | R^{D41} | L_{C443} | R^{D50} | R^{D88} | L_{C635} | R^{D145} | R^{D17} |
| L_{C60} | R^{D60} | R^{D60} | L_{C252} | R^{D4} | R^{D42} | L_{C444} | R^{D50} | R^{D89} | L_{C636} | R^{D145} | R^{D18} |
| L_{C61} | R^{D61} | R^{D61} | L_{C253} | R^{D4} | R^{D43} | L_{C445} | R^{D50} | R^{D93} | L_{C637} | R^{D145} | R^{D20} |
| L_{C62} | R^{D62} | R^{D62} | L_{C254} | R^{D4} | R^{D48} | L_{C446} | R^{D50} | R^{D116} | L_{C638} | R^{D145} | R^{D22} |
| L_{C63} | R^{D63} | R^{D63} | L_{C255} | R^{D4} | R^{D49} | L_{C447} | R^{D50} | R^{D117} | L_{C639} | R^{D145} | R^{D37} |
| L_{C64} | R^{D64} | R^{D64} | L_{C256} | R^{D4} | R^{D50} | L_{C448} | R^{D50} | R^{D118} | L_{C640} | R^{D145} | R^{D40} |
| L_{C65} | R^{D65} | R^{D65} | L_{C257} | R^{D4} | R^{D54} | L_{C449} | R^{D50} | R^{D119} | L_{C641} | R^{D145} | R^{D41} |
| L_{C66} | R^{D66} | R^{D66} | L_{C258} | R^{D4} | R^{D55} | L_{C450} | R^{D50} | R^{D120} | L_{C642} | R^{D145} | R^{D42} |
| L_{C67} | R^{D67} | R^{D67} | L_{C259} | R^{D4} | R^{D58} | L_{C451} | R^{D50} | R^{D133} | L_{C643} | R^{D145} | R^{D43} |
| L_{C68} | R^{D68} | R^{D68} | L_{C260} | R^{D4} | R^{D59} | L_{C452} | R^{D50} | R^{D134} | L_{C644} | R^{D145} | R^{D48} |
| L_{C69} | R^{D69} | R^{D69} | L_{C261} | R^{D4} | R^{D78} | L_{C453} | R^{D50} | R^{D135} | L_{C645} | R^{D145} | R^{D49} |
| L_{C70} | R^{D70} | R^{D70} | L_{C262} | R^{D4} | R^{D79} | L_{C454} | R^{D50} | R^{D136} | L_{C646} | R^{D145} | R^{D54} |
| L_{C71} | R^{D71} | R^{D71} | L_{C263} | R^{D4} | R^{D81} | L_{C455} | R^{D50} | R^{D143} | L_{C647} | R^{D145} | R^{D58} |
| L_{C71} | R^{D72} | R^{D72} | L_{C264} | R^{D4} | R^{D87} | L_{C456} | R^{D50} | R^{D144} | L_{C648} | R^{D145} | R^{D59} |
| L_{C73} | R^{D73} | R^{D73} | L_{C265} | R^{D4} | R^{D88} | L_{C457} | R^{D50} | R^{D145} | L_{C649} | R^{D145} | R^{D78} |
| L_{C74} | R^{D74} | R^{D74} | L_{C266} | R^{D4} | R^{D89} | L_{C458} | R^{D50} | R^{D146} | L_{C650} | R^{D145} | R^{D79} |
| L_{C75} | R^{D75} | R^{D75} | L_{C267} | R^{D4} | R^{D93} | L_{C459} | R^{D50} | R^{D147} | L_{C651} | R^{D145} | R^{D81} |
| L_{C76} | R^{D76} | R^{D76} | L_{C268} | R^{D4} | R^{D116} | L_{C460} | R^{D50} | R^{D149} | L_{C652} | R^{D145} | R^{D87} |
| L_{C77} | R^{D77} | R^{D77} | L_{C269} | R^{D4} | R^{D117} | L_{C461} | R^{D50} | R^{D151} | L_{C653} | R^{D145} | R^{D88} |
| L_{C78} | R^{D78} | R^{D78} | L_{C270} | R^{D4} | R^{D118} | L_{C462} | R^{D50} | T^{D154} | L_{C654} | R^{D145} | R^{D89} |
| L_{C79} | R^{D79} | R^{D79} | L_{C271} | R^{D4} | R^{D119} | L_{C463} | R^{D50} | R^{D155} | L_{C655} | R^{D145} | R^{D93} |
| L_{C80} | R^{D80} | R^{D80} | L_{C272} | R^{D4} | R^{D120} | L_{C464} | R^{D50} | R^{D161} | L_{C656} | R^{D145} | R^{D116} |
| L_{C81} | R^{D81} | R^{D81} | L_{C273} | R^{D4} | R^{D133} | L_{C465} | R^{D50} | R^{D175} | L_{C657} | R^{D145} | R^{D117} |
| L_{C82} | R^{D82} | R^{D82} | L_{C274} | R^{D4} | R^{D134} | L_{C466} | R^{D55} | R^{D3} | L_{C658} | R^{D145} | R^{D118} |
| L_{C83} | R^{D83} | R^{D83} | L_{C275} | R^{D4} | R^{D135} | L_{C467} | R^{D55} | R^{D5} | L_{C659} | R^{D145} | R^{D119} |
| L_{C84} | R^{D84} | R^{D84} | L_{C276} | R^{D4} | R^{D136} | L_{C468} | R^{D55} | R^{D18} | L_{C660} | R^{D145} | R^{D120} |
| L_{C85} | R^{D85} | R^{D85} | L_{C277} | R^{D4} | R^{D143} | L_{C469} | R^{D55} | R^{D20} | L_{C661} | R^{D145} | R^{D133} |
| L_{C86} | R^{D86} | R^{D86} | L_{C278} | R^{D4} | R^{D144} | L_{C470} | R^{D55} | R^{D22} | L_{C662} | R^{D145} | R^{D134} |
| L_{C87} | R^{D87} | R^{D87} | L_{C279} | R^{D4} | R^{D145} | L_{C471} | R^{D55} | R^{D37} | L_{C663} | R^{D145} | R^{D135} |
| L_{C88} | R^{D88} | R^{D88} | L_{C280} | R^{D4} | R^{D146} | L_{C472} | R^{D55} | R^{D40} | L_{C664} | R^{D145} | R^{D136} |
| L_{C89} | R^{D89} | R^{D89} | L_{C281} | R^{D4} | R^{D147} | L_{C473} | R^{D55} | R^{D41} | L_{C665} | R^{D145} | R^{D146} |
| L_{C90} | R^{D90} | R^{D90} | L_{C282} | R^{D4} | R^{D149} | L_{C474} | R^{D55} | R^{D42} | L_{C666} | R^{D145} | R^{D147} |
| L_{C91} | R^{D91} | R^{D91} | L_{C283} | R^{D4} | R^{D151} | L_{C475} | R^{D55} | R^{D43} | L_{C667} | R^{D145} | R^{D149} |
| L_{C92} | R^{D92} | R^{D92} | L_{C284} | R^{D4} | R^{D 154} | L_{C476} | R^{D55} | R^{D48} | L_{C668} | R^{D145} | R^{D151} |
| L_{C93} | R^{D93} | R^{D93} | L_{C285} | R^{D4} | R^{D155} | L_{C477} | R^{D55} | R^{D49} | L_{C669} | R^{D145} | R^{D154} |
| L_{C94} | R^{D94} | R^{D94} | L_{C286} | R^{D4} | R^{D 161} | L_{C478} | R^{D55} | R^{D54} | L_{C670} | R^{D145} | R^{D155} |
| L_{C95} | R^{D95} | R^{D95} | L_{C287} | R^{D4} | R^{D175} | L_{C479} | R^{D55} | R^{D58} | L_{C671} | R^{D145} | R^{D161} |
| L_{C96} | R^{D96} | R^{D96} | L_{C288} | R^{D9} | R^{D3} | L_{C480} | R^{D55} | R^{D59} | L_{C672} | R^{D145} | R^{D175} |
| L_{C97} | R^{D97} | R^{D97} | L_{C289} | R^{D9} | R^{D5} | L_{C481} | R^{D55} | R^{D78} | L_{C673} | R^{D146} | R^{D3} |
| L_{C98} | R^{D98} | R^{D98} | L_{C290} | R^{D9} | R^{D10} | L_{C482} | R^{D55} | R^{D79} | L_{C674} | R^{D146} | R^{D5} |
| L_{C99} | R^{D99} | R^{D99} | L_{C291} | R^{D9} | R^{D17} | L_{C483} | R^{D55} | R^{D81} | L_{C675} | R^{D146} | R^{D17} |
| L_{C100} | R^{D100} | R^{D100} | L_{C292} | R^{D9} | R^{D18} | L_{C484} | R^{D55} | R^{D87} | L_{C676} | R^{D146} | R^{D18} |
| L_{C101} | R^{D101} | R^{D101} | L_{C293} | R^{D9} | R^{D20} | L_{C485} | R^{D55} | R^{D88} | L_{C677} | R^{D146} | R^{D20} |
| L_{C102} | R^{D102} | R^{D102} | L_{C294} | R^{D9} | R^{D22} | L_{C486} | R^{D55} | R^{D89} | L_{C678} | R^{D146} | R^{D22} |
| L_{C103} | R^{D103} | R^{D103} | L_{C295} | R^{D9} | R^{D37} | L_{C487} | R^{D55} | R^{D93} | L_{C679} | R^{D146} | R^{D37} |
| L_{C104} | R^{D104} | R^{D104} | L_{C296} | R^{D9} | R^{D40} | L_{C488} | R^{D55} | R^{D116} | L_{C680} | R^{D146} | R^{D40} |
| L_{C105} | R^{D105} | R^{D105} | L_{C297} | R^{D9} | R^{D41} | L_{C489} | R^{D55} | R^{D117} | L_{C681} | R^{D146} | R^{D41} |
| L_{C106} | R^{D106} | R^{D106} | L_{C298} | R^{D9} | R^{D42} | L_{C490} | R^{D55} | R^{D118} | L_{C682} | R^{D146} | R^{D42} |
| L_{C107} | R^{D107} | R^{D107} | L_{C299} | R^{D9} | R^{D43} | L_{C491} | R^{D55} | R^{D119} | L_{C683} | R^{D146} | R^{D43} |
| L_{C108} | R^{D108} | R^{D108} | L_{C300} | R^{D9} | R^{D48} | L_{C492} | R^{D55} | R^{D120} | L_{C684} | R^{D146} | R^{D48} |
| L_{C109} | R^{D109} | R^{D109} | L_{C301} | R^{D9} | R^{D49} | L_{C493} | R^{D55} | R^{D133} | L_{C685} | R^{D146} | R^{D49} |
| L_{C110} | R^{D110} | R^{D110} | L_{C302} | R^{D9} | R^{D50} | L_{C494} | R^{D55} | R^{D134} | L_{C686} | R^{D146} | R^{D54} |
| L_{C111} | R^{D111} | R^{D111} | L_{C303} | R^{D9} | R^{D54} | L_{C495} | R^{D55} | R^{D135} | L_{C687} | R^{D146} | R^{D58} |
| L_{C112} | R^{D112} | R^{D112} | L_{C304} | R^{D9} | R^{D55} | L_{C496} | R^{D55} | R^{D136} | L_{C688} | R^{D146} | R^{D59} |
| L_{C113} | R^{D113} | R^{D113} | L_{C305} | R^{D9} | R^{D58} | L_{C497} | R^{D55} | R^{D143} | L_{C689} | R^{D146} | R^{D78} |
| L_{C114} | R^{D114} | R^{D114} | L_{C306} | R^{D9} | R^{D59} | L_{C498} | R^{D55} | R^{D144} | L_{C690} | R^{D146} | R^{D79} |
| L_{C115} | R^{D115} | R^{D115} | L_{C307} | R^{D9} | R^{D78} | L_{C499} | R^{D55} | R^{D145} | L_{C691} | R^{D146} | R^{D81} |
| L_{C116} | R^{D116} | R^{D116} | L_{C308} | R^{D9} | R^{D79} | L_{C500} | R^{D55} | R^{D146} | L_{C692} | R^{D146} | R^{D87} |
| L_{C117} | R^{D117} | R^{D117} | L_{C309} | R^{D9} | R^{D81} | L_{C501} | R^{D55} | R^{D147} | L_{C693} | R^{D146} | R^{D88} |
| L_{C118} | R^{D118} | R^{D118} | L_{C310} | R^{D9} | R^{D87} | L_{C502} | R^{D55} | R^{D149} | L_{C694} | R^{D146} | R^{D89} |
| L_{C119} | R^{D119} | R^{D119} | R_{C311} | R^{D9} | R^{D88} | L_{C503} | R^{D55} | R^{D151} | L_{C695} | R^{D146} | R^{D93} |
| L_{C120} | R^{D120} | R^{D120} | L_{C312} | R^{D9} | R^{D89} | L_{C504} | R^{D55} | R^{D154} | L_{C696} | R^{D146} | R^{D117} |
| L_{C121} | R^{D121} | R^{D121} | L_{C313} | R^{D9} | R^{D93} | L_{C505} | R^{D55} | R^{D155} | L_{C697} | R^{D146} | R^{D119} |
| L_{C122} | R^{D122} | R^{D122} | L_{C314} | R^{D9} | R^{D116} | L_{C506} | R^{D55} | R^{D161} | L_{C698} | R^{D146} | R^{D119} |
| L_{C123} | R^{D123} | R^{D123} | L_{C315} | R^{D9} | R^{D117} | L_{C507} | R^{D55} | R^{D175} | L_{C699} | R^{D146} | R^{D120} |
| L_{C124} | R^{D124} | R^{D124} | L_{C316} | R^{D9} | R^{D118} | L_{C508} | R^{D116} | R^{D3} | L_{C700} | R^{D146} | R^{D133} |
| L_{C125} | R^{D125} | R^{D125} | L_{C317} | R^{D9} | R^{D119} | L_{C509} | R^{D116} | R^{D5} | L_{C701} | R^{D146} | R^{D134} |
| L_{C126} | R^{D126} | R^{D126} | L_{C318} | R^{D9} | R^{D120} | L_{C510} | R^{D116} | R^{D17} | L_{C702} | R^{D146} | R^{D135} |
| L_{C127} | R^{D127} | R^{D127} | L_{C319} | R^{D9} | R^{D133} | L_{C511} | R^{D116} | R^{D18} | L_{C703} | R^{D146} | R^{D136} |
| L_{C128} | R^{D128} | R^{D128} | L_{C320} | R^{D9} | R^{D134} | L_{C512} | R^{D116} | R^{D20} | L_{C704} | R^{D146} | R^{D146} |
| L_{C129} | R^{D129} | R^{D129} | L_{C321} | R^{D9} | R^{D135} | L_{C513} | R^{D116} | R^{D22} | L_{C705} | R^{D146} | R^{D147} |
| L_{C130} | R^{D130} | R^{D130} | L_{C322} | R^{D9} | R^{D136} | L_{C514} | R^{D116} | R^{D37} | L_{C706} | R^{D146} | R^{D149} |
| L_{C131} | R^{D131} | R^{D131} | L_{C323} | R^{D9} | R^{D143} | L_{C515} | R^{D116} | R^{D40} | L_{C707} | R^{D146} | R^{D151} |
| L_{C132} | R^{D132} | R^{D132} | L_{C324} | R^{D9} | R^{D144} | L_{C516} | R^{D116} | R^{D41} | L_{C708} | R^{D146} | R^{D154} |
| L_{C133} | R^{D133} | R^{D133} | L_{C325} | R^{D9} | R^{D145} | L_{C517} | R^{D116} | R^{D42} | L_{C709} | R^{D146} | R^{D155} |
| L_{C134} | R^{D134} | R^{D134} | L_{C326} | R^{D9} | R^{D146} | L_{C518} | R^{D116} | R^{D43} | L_{C710} | R^{D146} | R^{D161} |
| L_{C135} | R^{D135} | R^{D135} | L_{C327} | R^{D9} | R^{D147} | L_{C519} | R^{D116} | R^{D48} | L_{C711} | R^{D146} | R^{D175} |
| L_{C136} | R^{D136} | R^{D136} | L_{C328} | R^{D9} | R^{D149} | L_{C520} | R^{D116} | R^{D49} | L_{C712} | R^{D133} | R^{D3} |
| L_{C137} | R^{D137} | R^{D137} | L_{C329} | R^{D9} | R^{D151} | L_{C521} | R^{D116} | R^{D54} | L_{C713} | R^{D133} | R^{D5} |
| L_{C138} | R^{D138} | R^{D138} | L_{C330} | R^{D9} | R^{D154} | L_{C522} | R^{D116} | R^{D58} | L_{C714} | R^{D133} | R^{D3} |
| L_{C139} | R^{D139} | R^{D139} | L_{C331} | R^{D9} | R^{D155} | L_{C523} | R^{D116} | R^{D59} | L_{C715} | R^{D133} | R^{D18} |
| L_{C140} | R^{D140} | R^{D140} | L_{C332} | R^{D9} | R^{D161} | L_{C524} | R^{D116} | R^{D78} | L_{C716} | R^{D133} | R^{D20} |
| L_{C141} | R^{D141} | R^{D141} | L_{C333} | R^{D9} | R^{D175} | L_{C525} | R^{D116} | R^{D79} | L_{C717} | R^{D133} | R^{D22} |
| L_{C142} | R^{D142} | R^{D142} | L_{C334} | R^{D10} | R^{D3} | L_{C526} | R^{D116} | R^{D81} | L_{C718} | R^{D133} | R^{D37} |
| L_{C143} | R^{D143} | R^{D143} | L_{C335} | R^{D10} | R^{D5} | L_{C527} | R^{D116} | R^{D87} | L_{C719} | R^{D133} | R^{D40} |
| L_{C144} | R^{D144} | R^{D144} | L_{C336} | R^{D10} | R^{D17} | L_{C528} | R^{D116} | R^{D88} | L_{C720} | R^{D133} | R^{D41} |
| L_{C145} | R^{D145} | R^{D145} | L_{C337} | R^{D10} | R^{D18} | L_{C529} | R^{D116} | R^{D89} | L_{C721} | R^{D133} | R^{D42} |
| L_{C146} | R^{D146} | R^{D146} | L_{C338} | R^{D10} | R^{D20} | L_{C530} | R^{D116} | R^{D93} | L_{C722} | R^{D133} | R^{D43} |
| L_{C147} | R^{D147} | R^{D147} | L_{C339} | R^{D10} | R^{D22} | L_{C531} | R^{D116} | R^{D117} | L_{C723} | R^{D133} | R^{D48} |
| L_{C148} | R^{D148} | R^{D148} | L_{C340} | R^{D10} | R^{D37} | L_{C532} | R^{D116} | R^{D118} | L_{C724} | R^{D133} | R^{D49} |
| L_{C149} | R^{D149} | R^{D149} | L_{C341} | R^{D10} | R^{D40} | L_{C533} | R^{D116} | R^{D119} | L_{C725} | R^{D133} | R^{D54} |
| L_{C150} | R^{D150} | R^{D150} | L_{C342} | R^{D10} | R^{D41} | L_{C534} | R^{D116} | R^{D120} | L_{C726} | R^{D133} | R^{D58} |
| L_{C151} | R^{D151} | R^{D151} | L_{C343} | R^{D10} | R^{D42} | L_{C535} | R^{D116} | R^{D133} | L_{C727} | R^{D133} | R^{D59} |
| L_{C152} | R^{D152} | R^{D152} | L_{C344} | R^{D10} | R^{D43} | L_{C536} | R^{D116} | R^{D134} | L_{C728} | R^{D133} | R^{D78} |
| L_{C153} | R^{D153} | R^{D153} | L_{C345} | R^{D10} | R^{D48} | L_{C537} | R^{D116} | R^{D135} | L_{C729} | R^{D133} | R^{D79} |
| L_{C154} | R^{D154} | R^{D154} | L_{C346} | R^{D10} | R^{D49} | L_{C538} | R^{D116} | R^{D136} | L_{C730} | R^{D133} | R^{D81} |
| L_{C155} | R^{D155} | R^{D155} | L_{C347} | R^{D10} | R^{D50} | L_{C539} | R^{D116} | R^{D143} | L_{C731} | R^{D133} | R^{D87} |
| L_{C156} | R^{D156} | R^{D156} | L_{C348} | R^{D10} | R^{D54} | L_{C540} | R^{D116} | R^{D144} | L_{C732} | R^{D133} | R^{D88} |
| L_{C157} | R^{D157} | R^{D157} | L_{C349} | R^{D10} | R^{D55} | L_{C541} | R^{D116} | R^{D145} | L_{C733} | R^{D133} | R^{D89} |
| L_{C158} | R^{D158} | R^{D158} | L_{C350} | R^{D10} | R^{D58} | L_{C542} | R^{D116} | R^{D146} | L_{C734} | R^{D133} | R^{D93} |
| L_{C159} | R^{D159} | R^{D159} | L_{C351} | R^{D10} | R^{D59} | L_{C543} | R^{D116} | R^{D147} | L_{C735} | R^{D133} | R^{D117} |
| L_{C160} | R^{D160} | R^{D160} | L_{C352} | R^{D10} | R^{D78} | L_{C544} | R^{D116} | R^{D149} | L_{C736} | R^{D133} | R^{D118} |
| L_{C161} | R^{D161} | R^{D161} | L_{C353} | R^{D10} | R^{D79} | L_{C545} | R^{D116} | R^{D151} | L_{C737} | R^{D133} | R^{D119} |
| L_{C162} | R^{D162} | R^{D162} | L_{C354} | R^{D10} | R^{D81} | L_{C546} | R^{D116} | R^{D154} | L_{C738} | R^{D133} | R^{D120} |
| L_{C163} | R^{D163} | R^{D163} | L_{C355} | R^{D10} | R^{D87} | L_{C547} | R^{D116} | R^{D155} | L_{C739} | R^{D133} | R^{D133} |
| L_{C164} | R^{D164} | R^{D164} | L_{C356} | R^{D10} | R^{D88} | L_{C548} | R^{D116} | R^{D161} | L_{C740} | R^{D133} | R^{D134} |
| L_{C165} | R^{D165} | R^{D165} | L_{C357} | R^{D10} | R^{D89} | L_{C549} | R^{D116} | R^{D175} | L_{C741} | R^{D133} | R^{D135} |
| L_{C166} | R^{D166} | R^{D166} | L_{C358} | R^{D10} | R^{D93} | L_{C550} | R^{D143} | R^{D3} | L_{C742} | R^{D133} | R^{D136} |
| L_{C167} | R^{D167} | R^{D167} | L_{C359} | R^{D10} | R^{D116} | L_{C551} | R^{D143} | R^{D5} | L_{C743} | R^{D133} | R^{D146} |
| L_{C168} | R^{D168} | R^{D168} | L_{C360} | R^{D10} | R^{D117} | L_{C552} | R^{D143} | R^{D17} | L_{C744} | R^{D133} | R^{D147} |
| L_{C169} | R^{D169} | R^{D169} | L_{C361} | R^{D10} | R^{D118} | L_{C553} | R^{D143} | R^{D18} | L_{C745} | R^{D133} | R^{D149} |
| L_{C170} | R^{D170} | R^{D170} | L_{C362} | R^{D10} | R^{D119} | L_{C554} | R^{D143} | R^{D20} | L_{C746} | R^{D133} | R^{D151} |
| L_{C171} | R^{D171} | R^{D171} | L_{C363} | R^{D10} | R^{D120} | L_{C555} | R^{D143} | R^{D22} | L_{C747} | R^{D133} | R^{D154} |
| L_{C172} | R^{D172} | R^{D172} | L_{C364} | R^{D10} | R^{D133} | L_{C556} | R^{D143} | R^{D37} | L_{C748} | R^{D133} | R^{D155} |
| L_{C173} | R^{D173} | R^{D173} | L_{C365} | R^{D10} | R^{D134} | L_{C557} | R^{D143} | R^{D40} | L_{C749} | R^{D133} | R^{D161} |
| L_{C174} | R^{D174} | R^{D174} | L_{C366} | R^{D10} | R^{D135} | L_{C558} | R^{D143} | R^{D41} | L_{C750} | R^{D133} | R^{D175} |
| L_{C175} | R^{D175} | R^{D175} | L_{C367} | R^{D10} | R^{D136} | L_{C559} | R^{D143} | R^{D42} | L_{C751} | R^{D175} | R^{D3} |
| L_{C176} | R^{D176} | R^{D176} | L_{C368} | R^{D10} | R^{D143} | L_{C560} | R^{D143} | R^{D483} | L_{C752} | R^{D175} | R^{D5} |
| L_{C177} | R^{D177} | R^{D177} | L_{C369} | R^{D10} | R^{D144} | L_{C561} | R^{D143} | R^{D48} | L_{C753} | R^{D175} | R^{D18} |
| L_{C178} | R^{D178} | R^{D178} | L_{C370} | R^{D10} | R^{D145} | L_{C562} | R^{D143} | R^{D49} | L_{C754} | R^{D175} | R^{D20} |
| L_{C179} | R^{D179} | R^{D179} | L_{C371} | R^{D10} | R^{D146} | L_{C563} | R^{D143} | R^{D54} | L_{C755} | R^{D175} | R^{D22} |
| L_{C180} | R^{D180} | R^{D180} | L_{C372} | R^{D10} | R^{D147} | L_{C564} | R^{D143} | R^{D58} | L_{C756} | R^{D175} | R^{D37} |
| L_{C181} | R^{D181} | R^{D181} | L_{C373} | R^{D10} | R^{D149} | L_{C565} | R^{D143} | R^{D59} | L_{C757} | R^{D175} | R^{D40} |
| L_{C182} | R^{D182} | R^{D182} | L_{C374} | R^{D10} | R^{D151} | L_{C566} | R^{D143} | R^{D798} | L_{C758} | R^{D175} | R^{D41} |
| L_{C183} | R^{D183} | R^{D183} | L_{C375} | R^{D10} | R^{D154} | L_{C567} | R^{D143} | R^{D79} | L_{C759} | R^{D175} | R^{D42} |
| L_{C184} | R^{D184} | R^{D184} | L_{C376} | R^{D10} | R^{D155} | L_{C568} | R^{D143} | R^{D81} | L_{C760} | R^{D175} | R^{D43} |
| L_{C185} | R^{D185} | R^{D185} | L_{C377} | R^{D10} | R^{D161} | L_{C569} | R^{D143} | R^{D87} | L_{C761} | R^{D175} | R^{D48} |
| L_{C186} | R^{D186} | R^{D186} | L_{C378} | R^{D10} | R^{D175} | L_{C570} | R^{D143} | R^{D88} | L_{C762} | R^{D175} | R^{D49} |
| L_{C187} | R^{D187} | R^{D187} | L_{C379} | R^{D17} | R^{D3} | L_{C571} | R^{D143} | R^{D89} | L_{C763} | R^{D175} | R^{D54} |
| L_{C188} | R^{D188} | R^{D188} | L_{C380} | R^{D17} | R^{D5} | L_{C572} | R^{D143} | R^{D93} | L_{C764} | R^{D175} | R^{D58} |
| L_{C189} | R^{D189} | R^{D189} | L_{C381} | R^{D17} | R^{D18} | L_{C573} | R^{D143} | R^{D116} | L_{C765} | R^{D175} | R^{D59} |
| L_{C190} | R^{D190} | R^{D190} | L_{C382} | R^{D17} | R^{D20} | L_{C574} | R^{D143} | R^{D117} | L_{C766} | R^{D175} | R^{D78} |
| L_{C191} | R^{D191} | R^{D191} | L_{C383} | R^{D17} | R^{D22} | L_{C575} | R^{D143} | R^{D118} | L_{C767} | R^{D175} | R^{D79} |
| L_{C192} | R^{D192} | R^{D192} | L_{C384} | R^{D17} | R^{D37} | L_{C576} | R^{D143} | R^{D119} | L_{C768} | R^{D175} | R^{D81} |
| L_{C769} | R^{D193} | R^{D193} | L_{C877} | R^{D1} | R^{D193} | L_{C985} | R^{D4} | R^{D193} | L_{C1093} | R^{D9} | R^{D193} |
| L_{C770} | R^{D194} | R^{D194} | L_{C878} | R^{D1} | R^{D194} | L_{C986} | R^{D4} | R^{D194} | L_{C1094} | R^{D9} | R^{D194} |
| L_{C771} | R^{D195} | R^{D195} | L_{C879} | R^{D1} | R^{D195} | L_{C987} | R^{D4} | R^{D195} | L_{C1095} | R^{D9} | R^{D195} |
| L_{C772} | R^{D196} | R^{D196} | L_{C880} | R^{D1} | R^{D196} | L_{C988} | R^{D4} | R^{D196} | L_{C1096} | R^{D9} | R^{D196} |
| L_{C773} | R^{D197} | R^{D197} | L_{C881} | R^{D1} | R^{D197} | L_{C989} | R^{D4} | R^{D197} | L_{C1097} | R^{D9} | R^{D197} |
| L_{C774} | R^{D198} | R^{D198} | L_{C882} | R^{D1} | R^{D198} | L_{C990} | R^{D4} | R^{D198} | L_{C1098} | R^{D9} | R^{D198} |
| L_{C775} | R^{D199} | R^{D199} | L_{C883} | R^{D1} | R^{D199} | L_{C991} | R^{D4} | R^{D199} | L_{C1099} | R^{D9} | R^{D199} |
| L_{C776} | R^{D200} | R^{D200} | L_{C884} | R^{D1} | R^{D200} | L_{C992} | R^{D4} | R^{D200} | L_{C1100} | R^{D9} | R^{D200} |
| L_{C777} | R^{D201} | R^{D201} | L_{C885} | R^{D1} | R^{D201} | L_{C993} | R^{D4} | R^{D201} | L_{C1101} | R^{D9} | R^{D201} |
| L_{C778} | R^{D202} | R^{D202} | L_{C886} | R^{D1} | R^{D202} | L_{C994} | R^{D4} | R^{D202} | L_{C1102} | R^{D9} | R^{D202} |
| L_{C779} | R^{D203} | R^{D203} | L_{C887} | R^{D1} | R^{D203} | L_{C995} | R^{D4} | R^{D203} | L_{C1103} | R^{D9} | R^{D203} |
| L_{C780} | R^{D204} | R^{D204} | L_{C888} | R^{D1} | R^{D204} | L_{C996} | R^{D4} | R^{D204} | L_{C1104} | R^{D9} | R^{D204} |
| L_{C781} | R^{D205} | R^{D205} | L_{C889} | R^{D1} | R^{D205} | L_{C997} | R^{D4} | R^{D205} | L_{C1105} | R^{D9} | R^{D205} |
| L_{C782} | R^{D206} | R^{D206} | L_{C890} | R^{D1} | R^{D206} | L_{C998} | R^{D4} | R^{D206} | L_{C1106} | R^{D9} | R^{D206} |
| L_{C783} | R^{D207} | R^{D207} | L_{C891} | R^{D1} | R^{D207} | L_{C999} | R^{D4} | R^{D207} | L_{C1107} | R^{D9} | R^{D207} |
| L_{C784} | R^{D208} | R^{D208} | L_{C892} | R^{D1} | R^{D208} | L_{C1000} | R^{D4} | R^{D208} | L_{C1108} | R^{D9} | R^{D208} |
| L_{C785} | R^{D209} | R^{D209} | L_{C893} | R^{D1} | R^{D209} | L_{C1001} | R^{D4} | R^{D209} | L_{C1109} | R^{D9} | R^{D209} |
| L_{C786} | R^{D210} | R^{D210} | L_{C894} | R^{D1} | R^{D210} | L_{C1002} | R^{D4} | R^{D210} | L_{C1110} | R^{D9} | R^{D210} |
| L_{C787} | R^{D211} | R^{D211} | L_{C895} | R^{D1} | R^{D211} | L_{C1003} | R^{D4} | R^{D211} | L_{C1111} | R^{D9} | R^{D211} |
| L_{C788} | R^{D212} | R^{D212} | L_{C896} | R^{D1} | R^{D212} | L_{C1004} | R^{D4} | R^{D212} | L_{C1112} | R^{D9} | R^{D212} |
| L_{C789} | R^{D213} | R^{D213} | L_{C897} | R^{D1} | R^{D213} | L_{C1005} | R^{D4} | R^{D213} | L_{C1113} | R^{D9} | R^{D213} |
| L_{C790} | R^{D214} | R^{D214} | L_{C898} | R^{D1} | R^{D214} | L_{C1006} | R^{D4} | R^{D214} | L_{C1114} | R^{D9} | R^{D214} |
| L_{C791} | R^{D215} | R^{D215} | L_{C899} | R^{D1} | R^{D215} | L_{C1007} | R^{D4} | R^{D215} | L_{C1115} | R^{D9} | R^{D215} |
| L_{C792} | R^{D216} | R^{D216} | L_{C900} | R^{D1} | R^{D216} | L_{C1008} | R^{D4} | R^{D216} | L_{C1116} | R^{D9} | R^{D216} |
| L_{C793} | R^{D217} | R^{D217} | L_{C901} | R^{D1} | R^{D217} | L_{C1009} | R^{D4} | R^{D217} | L_{C1117} | R^{D9} | R^{D217} |
| L_{C794} | R^{D218} | R^{D218} | L_{C902} | R^{D1} | R^{D218} | L_{C1010} | R^{D4} | R^{D218} | L_{C1118} | R^{D9} | R^{D218} |
| L_{C795} | R^{D219} | R^{D219} | L_{C903} | R^{D1} | R^{D219} | L_{C1011} | R^{D4} | R^{D219} | L_{C1119} | R^{D9} | R^{D219} |
| L_{C796} | R^{D220} | R^{D220} | L_{C904} | R^{D1} | R^{D220} | L_{C1012} | R^{D4} | R^{D220} | L_{C1120} | R^{D9} | R^{D220} |
| L_{C797} | R^{D221} | R^{D221} | L_{C905} | R^{D1} | R^{D221} | L_{C1013} | R^{D4} | R^{D221} | L_{C1121} | R^{D9} | R^{D221} |
| L_{C798} | R^{D222} | R^{D222} | L_{C906} | R^{D1} | R^{D222} | L_{C1014} | R^{D4} | R^{D222} | L_{C1122} | R^{D9} | R^{D222} |
| L_{C799} | R^{D223} | R^{D223} | L_{C907} | R^{D1} | R^{D223} | L_{C1015} | R^{D4} | R^{D223} | L_{C1123} | R^{D9} | R^{D223} |
| L_{C800} | R^{D224} | R^{D224} | L_{C908} | R^{D1} | R^{D224} | L_{C1016} | R^{D4} | R^{D224} | L_{C1124} | R^{D9} | R^{D224} |
| L_{C801} | R^{D225} | R^{D225} | L_{C909} | R^{D1} | R^{D225} | L_{C1017} | R^{D4} | R^{D225} | L_{C1125} | R^{D9} | R^{D225} |
| L_{C802} | R^{D226} | R^{D226} | L_{C910} | R^{D1} | R^{D226} | L_{C1018} | R^{D4} | R^{D226} | L_{C1126} | R^{D9} | R^{D226} |
| L_{C803} | R^{D227} | R^{D227} | L_{C911} | R^{D1} | R^{D227} | L_{C1019} | R^{D4} | R^{D227} | L_{C1127} | R^{D9} | R^{D227} |
| L_{C804} | R^{D228} | R^{D228} | L_{C912} | R^{D1} | R^{D228} | L_{C1020} | R^{D4} | R^{D228} | L_{C1128} | R^{D9} | R^{D228} |
| L_{C805} | R^{D229} | R^{D229} | L_{C913} | R^{D1} | R^{D229} | L_{C1021} | R^{D4} | R^{D229} | L_{C1129} | R^{D9} | R^{D229} |
| L_{C806} | R^{D230} | R^{D230} | L_{C914} | R^{D1} | R^{D230} | L_{C1022} | R^{D4} | R^{D230} | L_{C1130} | R^{D9} | R^{D230} |
| L_{C807} | R^{D231} | R^{D231} | L_{C915} | R^{D1} | R^{D231} | L_{C1023} | R^{D4} | R^{D231} | L_{C1131} | R^{D9} | R^{D231} |
| L_{C808} | R^{D232} | R^{D232} | L_{C916} | R^{D1} | R^{D232} | L_{C1024} | R^{D4} | R^{D232} | L_{C1132} | R^{D9} | R^{D232} |
| L_{C809} | R^{D233} | R^{D233} | L_{C917} | R^{D1} | R^{D233} | L_{C1025} | R^{D4} | R^{D233} | L_{C1133} | R^{D9} | R^{D233} |
| L_{C810} | R^{D234} | R^{D234} | L_{C918} | R^{D1} | R^{D234} | L_{C1026} | R^{D4} | R^{D234} | L_{C1134} | R^{D9} | R^{D234} |
| L_{C811} | R^{D235} | R^{D235} | L_{C919} | R^{D1} | R^{D235} | L_{C1027} | R^{D4} | R^{D235} | L_{C1135} | R^{D9} | R^{D235} |
| L_{C812} | R^{D236} | R^{D236} | L_{C920} | R^{D1} | R^{D236} | L_{C1028} | R^{D4} | R^{D236} | L_{C1136} | R^{D9} | R^{D236} |
| L_{C813} | R^{D237} | R^{D237} | L_{C921} | R^{D1} | R^{D237} | L_{C1029} | R^{D4} | R^{D237} | L_{C1137} | R^{D9} | R^{D237} |
| L_{C814} | R^{D238} | R^{D238} | L_{C922} | R^{D1} | R^{D238} | L_{C1030} | R^{D4} | R^{D238} | L_{C1138} | R^{D9} | R^{D238} |
| L_{C815} | R^{D239} | R^{D239} | L_{C923} | R^{D1} | R^{D239} | L_{C1031} | R^{D4} | R^{D239} | L_{C1139} | R^{D9} | R^{D239} |
| L_{C816} | R^{D240} | R^{D240} | L_{C924} | R^{D1} | R^{D240} | L_{C1032} | R^{D4} | R^{D240} | L_{C1140} | R^{D9} | R^{D240} |
| L_{C817} | R^{D241} | R^{D241} | L_{C925} | R^{D1} | R^{D241} | L_{C1033} | R^{D4} | R^{D241} | L_{C1141} | R^{D9} | R^{D241} |
| L_{C818} | R^{D242} | R^{D242} | L_{C926} | R^{D1} | R^{D242} | L_{C1034} | R^{D4} | R^{D242} | L_{C1142} | R^{D9} | R^{D242} |
| L_{C819} | R^{D243} | R^{D243} | L_{C927} | R^{D1} | R^{D243} | L_{C1035} | R^{D4} | R^{D243} | L_{C1143} | R^{D9} | R^{D243} |
| L_{C820} | R^{D244} | R^{D244} | L_{C928} | R^{D1} | R^{D244} | L_{C1036} | R^{D4} | R^{D244} | L_{C1144} | R^{D9} | R^{D244} |
| L_{C821} | R^{D245} | R^{D245} | L_{C929} | R^{D1} | R^{D245} | L_{C1037} | R^{D4} | R^{D245} | L_{C1145} | R^{D9} | R^{D245} |
| L_{C822} | R^{D246} | R^{D246} | L_{C930} | R^{D1} | R^{D246} | L_{C1038} | R^{D4} | R^{D246} | L_{C1146} | R^{D9} | R^{D246} |
| L_{C823} | R^{D17} | R^{D193} | L_{C931} | R^{D}₅₀ | R^{D193} | L_{C1039} | R^{D145} | R^{D193} | L_{C1147} | R^{D168} | R^{D193} |
| L_{C824} | R^{D17} | R^{D194} | L_{C932} | R^{D}₅₀ | R^{D194} | L_{C1040} | R^{D145} | R^{D194} | L_{C1148} | R^{D168} | R^{D194} |
| L_{C825} | R^{D17} | R^{D195} | L_{C933} | R^{D}₅₀ | R^{D195} | L_{C1041} | R^{D145} | R^{D195} | L_{C1149} | R^{D168} | R^{D195} |
| L_{C826} | R^{D17} | R^{D196} | L_{C934} | R^{D}₅₀ | R^{D196} | L_{C1042} | R^{D145} | R^{D196} | L_{C1150} | R^{D168} | R^{D196} |
| L_{C827} | R^{D17} | R^{D197} | L_{C935} | R^{D}₅₀ | R^{D197} | L_{C1043} | R^{D145} | R^{D197} | L_{C1151} | R^{D168} | R^{D197} |
| L_{C828} | R^{D17} | R^{D198} | L_{C936} | R^{D}₅₀ | R^{D198} | L_{C1044} | R^{D145} | R^{D198} | L_{C1152} | R^{D168} | R^{D198} |
| L_{C829} | R^{D17} | R^{D199} | L_{C937} | R^{D}₅₀ | R^{D199} | L_{C1045} | R^{D145} | R^{D199} | L_{C1153} | R^{D168} | R^{D199} |
| L_{C830} | R^{D17} | R^{D200} | L_{C938} | R^{D}₅₀ | R^{D200} | L_{C1046} | R^{D145} | R^{D200} | L_{C1154} | R^{D168} | R^{D200} |
| L_{C831} | R^{D17} | R^{D201} | L_{C939} | R^{D}₅₀ | R^{D201} | L_{C1047} | R^{D145} | R^{D201} | L_{C1155} | R^{D168} | R^{D201} |
| L_{C832} | R^{D17} | R^{D202} | L_{C940} | R^{D}₅₀ | R^{D202} | L_{C1048} | R^{D145} | R^{D202} | L_{C1156} | R^{D168} | R^{D202} |
| L_{C833} | R^{D17} | R^{D203} | L_{C941} | R^{D}₅₀ | R^{D203} | L_{C1049} | R^{D145} | R^{D203} | L_{C1157} | R^{D168} | R^{D203} |
| L_{C834} | R^{D17} | R^{D204} | L_{C942} | R^{D}₅₀ | R^{D204} | L_{C1050} | R^{D145} | R^{D204} | L_{C1158} | R^{D168} | R^{D204} |
| L_{C835} | R^{D17} | R^{D205} | L_{C943} | R^{D}₅₀ | R^{D205} | L_{C1051} | R^{D145} | R^{D205} | L_{C1159} | R^{D168} | R^{D205} |
| L_{C836} | R^{D17} | R^{D206} | L_{C944} | R^{D}₅₀ | R^{D206} | L_{C1052} | R^{D145} | R^{D206} | L_{C1160} | R^{D168} | R^{D206} |
| L_{C837} | R^{D17} | R^{D207} | L_{C945} | R^{D}₅₀ | R^{D207} | L_{C1053} | R^{D145} | R^{D207} | L_{C1161} | R^{D168} | R^{D207} |
| L_{C838} | R^{D17} | R^{D208} | L_{C946} | R^{D}₅₀ | R^{D208} | L_{C1054} | R^{D145} | R^{D208} | L_{C1162} | R^{D168} | R^{D208} |
| L_{C839} | R^{D17} | R^{D209} | L_{C947} | R^{D}₅₀ | R^{D209} | L_{C1055} | R^{D145} | R^{D209} | L_{C1163} | R^{D168} | R^{D209} |
| L_{C840} | R^{D17} | R^{D210} | L_{C948} | R^{D}₅₀ | R^{D210} | L_{C1056} | R^{D145} | R^{D210} | L_{C1164} | R^{D168} | R^{D210} |
| L_{C841} | R^{D17} | R^{D211} | L_{C949} | R^{D}₅₀ | R^{D211} | L_{C1057} | R^{D145} | R^{D211} | L_{C1165} | R^{D168} | R^{D211} |
| L_{C842} | R^{D17} | R^{D212} | L_{C950} | R^{D}₅₀ | R^{D212} | L_{C1058} | R^{D145} | R^{D212} | L_{C1166} | R^{D168} | R^{D212} |
| L_{C843} | R^{D17} | R^{D213} | L_{C951} | R^{D}₅₀ | R^{D213} | L_{C1059} | R^{D145} | R^{D213} | L_{C1167} | R^{D168} | R^{D213} |
| L_{C844} | R^{D17} | R^{D214} | L_{C952} | R^{D}₅₀ | R^{D214} | L_{C1060} | R^{D145} | R^{D214} | L_{C1168} | R^{D168} | R^{D214} |
| L_{C845} | R^{D17} | R^{D215} | L_{C953} | R^{D}₅₀ | R^{D215} | L_{C1061} | R^{D145} | R^{D215} | L_{C1169} | R^{D168} | R^{D215} |
| L_{C846} | R^{D17} | R^{D216} | L_{C954} | R^{D}₅₀ | R^{D216} | L_{C1062} | R^{D145} | R^{D216} | L_{C1170} | R^{D168} | R^{D216} |
| L_{C847} | R^{D17} | R^{D217} | L_{C955} | R^{D}₅₀ | R^{D217} | L_{C1063} | R^{D145} | R^{D217} | L_{C1171} | R^{D168} | R^{D217} |
| L_{C848} | R^{D17} | R^{D218} | L_{C956} | R^{D}₅₀ | R^{D218} | L_{C1064} | R^{D145} | R^{D218} | L_{C1172} | R^{D168} | R^{D218} |
| L_{C849} | R^{D17} | R^{D219} | L_{C957} | R^{D}₅₀ | R^{D219} | L_{C1065} | R^{D145} | R^{D219} | L_{C1173} | R^{D168} | R^{D219} |
| L_{C850} | R^{D17} | R^{D220} | L_{C958} | R^{D}₅₀ | R^{D220} | L_{C1066} | R^{D145} | R^{D220} | L_{C1174} | R^{D168} | R^{D220} |
| L_{C851} | R^{D17} | R^{D221} | L_{C959} | R^{D}₅₀ | R^{D221} | L_{C1067} | R^{D145} | R^{D221} | L_{C1175} | R^{D168} | R^{D221} |
| L_{C852} | R^{D17} | R^{D222} | L_{C960} | R^{D}₅₀ | R^{D222} | L_{C1068} | R^{D145} | R^{D222} | L_{C1176} | R^{D168} | R^{D222} |
| L_{C853} | R^{D17} | R^{D223} | L_{C961} | R^{D}₅₀ | R^{D223} | L_{C1069} | R^{D145} | R^{D223} | L_{C1177} | R^{D168} | R^{D223} |
| L_{C854} | R^{D17} | R^{D224} | L_{C962} | R^{D}₅₀ | R^{D224} | L_{C1070} | R^{D145} | R^{D224} | L_{C1178} | R^{D168} | R^{D224} |
| L_{C855} | R^{D17} | R^{D225} | L_{C963} | R^{D}₅₀ | R^{D225} | L_{C1071} | R^{D145} | R^{D225} | L_{C1179} | R^{D168} | R^{D225} |
| L_{C856} | R^{D17} | R^{D226} | L_{C964} | R^{D}₅₀ | R^{D226} | L_{C1072} | R^{D145} | R^{D226} | L_{C1180} | R^{D168} | R^{D226} |
| L_{C857} | R^{D17} | R^{D227} | L_{C965} | R^{D}₅₀ | R^{D227} | L_{C1073} | R^{D145} | R^{D227} | L_{C1181} | R^{D168} | R^{D227} |
| L_{C858} | R^{D17} | R^{D228} | L_{C966} | R^{D}₅₀ | R^{D228} | L_{C1074} | R^{D145} | R^{D228} | L_{C1182} | R^{D168} | R^{D228} |
| L_{C859} | R^{D17} | R^{D229} | L_{C967} | R^{D}₅₀ | R^{D229} | L_{C1075} | R^{D145} | R^{D229} | L_{C1183} | R^{D168} | R^{D229} |
| L_{C860} | R^{D17} | R^{D230} | L_{C968} | R^{D}₅₀ | R^{D230} | L_{C1076} | R^{D145} | R^{D230} | L_{C1184} | R^{D168} | R^{D230} |
| L_{C861} | R^{D17} | R^{D231} | L_{C969} | R^{D}₅₀ | R^{D231} | L_{C1077} | R^{D145} | R^{D231} | L_{C1185} | R^{D168} | R^{D231} |
| L_{C862} | R^{D17} | R^{D232} | L_{C970} | R^{D}₅₀ | R^{D232} | L_{C1078} | R^{D145} | R^{D232} | L_{C1186} | R^{D168} | R^{D232} |
| L_{C863} | R^{D17} | R^{D233} | L_{C971} | R^{D}₅₀ | R^{D233} | L_{C1079} | R^{D145} | R^{D233} | L_{C1187} | R^{D168} | R^{D233} |
| L_{C864} | R^{D17} | R^{D234} | L_{C972} | R^{D}₅₀ | R^{D234} | L_{C1080} | R^{D145} | R^{D234} | L_{C1188} | R^{D168} | R^{D234} |
| L_{C865} | R^{D17} | R^{D235} | L_{C973} | R^{D}₅₀ | R^{D235} | L_{C1081} | R^{D145} | R^{D235} | L_{C1189} | R^{D168} | R^{D235} |
| L_{C866} | R^{D17} | R^{D236} | L_{C974} | R^{D}₅₀ | R^{D236} | L_{C1082} | R^{D145} | R^{D236} | L_{C1190} | R^{D168} | R^{D236} |
| L_{C867} | R^{D17} | R^{D237} | L_{C975} | R^{D}₅₀ | R^{D237} | L_{C1083} | R^{D145} | R^{D237} | L_{C1191} | R^{D168} | R^{D237} |
| L_{C868} | R^{D17} | R^{D238} | L_{C976} | R^{D}₅₀ | R^{D238} | L_{C1084} | R^{D145} | R^{D238} | L_{C1192} | R^{D168} | R^{D238} |
| L_{C869} | R^{D17} | R^{D239} | L_{C977} | R^{D}₅₀ | R^{D239} | L_{C1085} | R^{D145} | R^{D239} | L_{C1193} | R^{D168} | R^{D239} |
| L_{C870} | R^{D17} | R^{D240} | L_{C978} | R^{D}₅₀ | R^{D240} | L_{C1086} | R^{D145} | R^{D240} | L_{C1194} | R^{D168} | R^{D240} |
| L_{C871} | R^{D17} | R^{D241} | L_{C979} | R^{D}₅₀ | R^{D241} | L_{C1087} | R^{D145} | R^{D241} | L_{C1195} | R^{D168} | R^{D241} |
| L_{C872} | R^{D17} | R^{D242} | L_{C980} | R^{D}₅₀ | R^{D242} | L_{C1088} | R^{D145} | R^{D242} | L_{C1196} | R^{D168} | R^{D242} |
| L_{C873} | R^{D17} | R^{D243} | L_{C981} | R^{D}₅₀ | R^{D243} | L_{C1089} | R^{D145} | R^{D243} | L_{C1197} | R^{D168} | R^{D243} |
| L_{C874} | R^{D17} | R^{D244} | L_{C982} | R^{D}₅₀ | R^{D244} | L_{C1090} | R^{D145} | R^{D244} | L_{C1198} | R^{D168} | R^{D244} |
| L_{C875} | R^{D17} | R^{D245} | L_{C983} | R^{D}₅₀ | R^{D245} | L_{C1091} | R^{D145} | R^{D245} | L_{C1199} | R^{D168} | R^{D245} |
| L_{C876} | R^{D17} | R^{D246} | L_{C984} | R^{D}₅₀ | R^{D246} | L_{C1092} | R^{D145} | R^{D246} | L_{C1200} | R^{D168} | R^{D246} |
| L_{C1201} | R^{D10} | R^{D193} | L_{C1255} | R^{D55} | R^{D193} | L_{C1309} | R^{D37} | R^{D193} | L_{C1363} | R^{D143} | R^{D193} |
| L_{C1202} | R^{D10} | R^{D194} | L_{C1256} | R^{D55} | R^{D194} | L_{C1310} | R^{D37} | R^{D194} | L_{C1364} | R^{D143} | R^{D194} |
| L_{C1203} | R^{D10} | R^{D195} | L_{C1257} | R^{D55} | R^{D195} | L_{C1311} | R^{D37} | R^{D195} | L_{C1365} | R^{D143} | R^{D195} |
| L_{C1204} | R^{D10} | R^{D196} | L_{C1258} | R^{D55} | R^{D196} | L_{C1312} | R^{D37} | R^{D196} | L_{C1366} | R^{D143} | R^{D196} |
| L_{C1205} | R^{D10} | R^{D197} | L_{C1259} | R^{D55} | R^{D197} | L_{C1313} | R^{D37} | R^{D197} | L_{C1367} | R^{D143} | R^{D197} |
| L_{C1206} | R^{D10} | R^{D198} | L_{C1260} | R^{D55} | R^{D198} | L_{C1314} | R^{D37} | R^{D198} | L_{C1368} | R^{D143} | R^{D198} |
| L_{C1207} | R^{D10} | R^{D199} | L_{C1261} | R^{D55} | R^{D199} | L_{C1315} | R^{D37} | R^{D199} | L_{C1369} | R^{D143} | R^{D199} |
| L_{C1208} | R^{D10} | R^{D200} | L_{C1262} | R^{D55} | R^{D200} | L_{C1316} | R^{D37} | R^{D200} | L_{C1370} | R^{D143} | R^{D200} |
| L_{C1209} | R^{D10} | R^{D201} | L_{C1263} | R^{D55} | R^{D201} | L_{C1317} | R^{D37} | R^{D201} | L_{C1371} | R^{D143} | R^{D201} |
| L_{C1210} | R^{D10} | R^{D202} | L_{C1264} | R^{D55} | R^{D202} | L_{C1318} | R^{D37} | R^{D202} | L_{C1372} | R^{D143} | R^{D202} |
| L_{C1211} | R^{D10} | R^{D203} | L_{C1265} | R^{D55} | R^{D203} | L_{C1319} | R^{D37} | R^{D203} | L_{C1373} | R^{D143} | R^{D203} |
| L_{C1212} | R^{D10} | R^{D204} | L_{C1266} | R^{D55} | R^{D204} | L_{C1320} | R^{D37} | R^{D204} | L_{C1374} | R^{D143} | R^{D204} |
| L_{C1213} | R^{D10} | R^{D205} | L_{C1267} | R^{D55} | R^{D205} | L_{C1321} | R^{D37} | R^{D205} | L_{C1375} | R^{D143} | R^{D205} |
| L_{C1214} | R^{D10} | R^{D206} | L_{C1268} | R^{D55} | R^{D206} | L_{C1322} | R^{D37} | R^{D206} | L_{C1376} | R^{D143} | R^{D206} |
| L_{C1215} | R^{D10} | R^{D207} | L_{C1269} | R^{D55} | R^{D207} | L_{C1323} | R^{D37} | R^{D207} | L_{C1377} | R^{D143} | R^{D207} |
| L_{C1216} | R^{D10} | R^{D208} | L_{C1270} | R^{D55} | R^{D208} | L_{C1324} | R^{D37} | R^{D208} | L_{C1378} | R^{D143} | R^{D208} |
| L_{C1217} | R^{D10} | R^{D209} | L_{C1271} | R^{D55} | R^{D209} | L_{C1325} | R^{D37} | R^{D209} | L_{C1379} | R^{D143} | R^{D209} |
| L_{C1218} | R^{D10} | R^{D210} | L_{C1272} | R^{D55} | R^{D210} | L_{C1326} | R^{D37} | R^{D210} | L_{C1380} | R^{D143} | R^{D210} |
| L_{C1219} | R^{D10} | R^{D211} | L_{C1273} | R^{D55} | R^{D211} | L_{C1327} | R^{D37} | R^{D211} | L_{C1381} | R^{D143} | R^{D211} |
| L_{C1220} | R^{D10} | R^{D212} | L_{C1274} | R^{D55} | R^{D212} | L_{C1328} | R^{D37} | R^{D212} | L_{C1382} | R^{D143} | R^{D212} |
| L_{C1221} | R^{D10} | R^{D213} | L_{C1275} | R^{D55} | R^{D213} | L_{C1329} | R^{D37} | R^{D213} | L_{C1383} | R^{D143} | R^{D213} |
| L_{C1222} | R^{D10} | R^{D214} | L_{C1276} | R^{D55} | R^{D214} | L_{C1330} | R^{D37} | R^{D214} | L_{C1384} | R^{D143} | R^{D214} |
| L_{C1223} | R^{D10} | R^{D215} | L_{C1277} | R^{D55} | R^{D215} | L_{C1331} | R^{D37} | R^{D215} | L_{C1385} | R^{D143} | R^{D215} |
| L_{C1224} | R^{D10} | R^{D216} | L_{C1278} | R^{D55} | R^{D216} | L_{C1332} | R^{D37} | R^{D216} | L_{C1386} | R^{D143} | R^{D216} |
| L_{C1225} | R^{D10} | R^{D217} | L_{C1279} | R^{D55} | R^{D217} | L_{C1333} | R^{D37} | R^{D217} | L_{C1387} | R^{D143} | R^{D217} |
| L_{C1226} | R^{D10} | R^{D218} | L_{C1280} | R^{D55} | R^{D218} | L_{C1334} | R^{D37} | R^{D218} | L_{C1388} | R^{D143} | R^{D218} |
| L_{C1227} | R^{D10} | R^{D219} | L_{C1281} | R^{D55} | R^{D219} | L_{C1335} | R^{D37} | R^{D219} | L_{C1389} | R^{D143} | R^{D219} |
| L_{C1228} | R^{D10} | R^{D220} | L_{C1282} | R^{D55} | R^{D220} | L_{C1336} | R^{D37} | R^{D220} | L_{C1390} | R^{D143} | R^{D220} |
| L_{C1229} | R^{D10} | R^{D221} | L_{C1283} | R^{D55} | R^{D221} | L_{C1337} | R^{D37} | R^{D221} | L_{C1391} | R^{D143} | R^{D221} |
| L_{C1230} | R^{D10} | R^{D222} | L_{C1284} | R^{D55} | R^{D222} | L_{C1338} | R^{D37} | R^{D222} | L_{C1392} | R^{D143} | R^{D222} |
| L_{C1231} | R^{D10} | R^{D223} | L_{C1285} | R^{D55} | R^{D223} | L_{C1339} | R^{D37} | R^{D223} | L_{C1393} | R^{D143} | R^{D223} |
| L_{C1232} | R^{D10} | R^{D224} | L_{C1286} | R^{D55} | R^{D224} | L_{C1340} | R^{D37} | R^{D224} | L_{C1394} | R^{D143} | R^{D224} |
| L_{C1233} | R^{D10} | R^{D225} | L_{C1287} | R^{D55} | R^{D225} | L_{C1341} | R^{D37} | R^{D225} | L_{C1395} | R^{D143} | R^{D225} |
| L_{C1234} | R^{D10} | R^{D226} | L_{C1288} | R^{D55} | R^{D226} | L_{C1342} | R^{D37} | R^{D226} | L_{C1396} | R^{D143} | R^{D226} |
| L_{C1235} | R^{D10} | R^{D227} | L_{C1289} | R^{D55} | R^{D227} | L_{C1343} | R^{D37} | R^{D227} | L_{C1397} | R^{D143} | R^{D227} |
| L_{C1236} | R^{D10} | R^{D228} | L_{C1290} | R^{D55} | R^{D228} | L_{C1344} | R^{D37} | R^{D228} | L_{C1398} | R^{D143} | R^{D228} |
| L_{C1237} | R^{D10} | R^{D229} | L_{C1291} | R^{D55} | R^{D229} | L_{C1345} | R^{D37} | R^{D229} | L_{C1399} | R^{D143} | R^{D229} |
| L_{C1238} | R^{D10} | R^{D230} | L_{C1292} | R^{D55} | R^{D230} | L_{C1346} | R^{D37} | R^{D230} | L_{C1400} | R^{D143} | R^{D230} |
| L_{C1239} | R^{D10} | R^{D231} | L_{C1293} | R^{D55} | R^{D231} | L_{C1347} | R^{D37} | R^{D231} | L_{C1401} | R^{D143} | R^{D231} |
| L_{C1240} | R^{D10} | R^{D232} | L_{C1294} | R^{D55} | R^{D232} | L_{C1348} | R^{D37} | R^{D232} | L_{C1402} | R^{D143} | R^{D232} |
| L_{C1241} | R^{D10} | R^{D233} | L_{C1295} | R^{D55} | R^{D233} | L_{C1349} | R^{D37} | R^{D233} | L_{C1403} | R^{D143} | R^{D233} |
| L_{C1242} | R^{D10} | R^{D234} | L_{C1296} | R^{D55} | R^{D234} | L_{C1350} | R^{D37} | R^{D234} | L_{C1404} | R^{D143} | R^{D234} |
| L_{C1243} | R^{D10} | R^{D235} | L_{C1297} | R^{D55} | R^{D235} | L_{C1351} | R^{D37} | R^{D235} | L_{C1405} | R^{D143} | R^{D235} |
| L_{C1244} | R^{D10} | R^{D236} | L_{C1298} | R^{D55} | R^{D236} | L_{C1352} | R^{D37} | R^{D236} | L_{C1406} | R^{D143} | R^{D236} |
| L_{C1245} | R^{D10} | R^{D237} | L_{C1299} | R^{D55} | R^{D237} | L_{C1353} | R^{D37} | R^{D237} | L_{C1407} | R^{D143} | R^{D237} |
| L_{C1246} | R^{D10} | R^{D238} | L_{C1300} | R^{D55} | R^{D238} | L_{C1354} | R^{D37} | R^{D238} | L_{C1408} | R^{D143} | R^{D238} |
| L_{C1247} | R^{D10} | R^{D239} | L_{C1301} | R^{D55} | R^{D239} | L_{C1355} | R^{D37} | R^{D239} | L_{C1409} | R^{D143} | R^{D239} |
| L_{C1248} | R^{D10} | R^{D240} | L_{C1302} | R^{D55} | R^{D240} | L_{C1356} | R^{D37} | R^{D240} | L_{C1410} | R^{D143} | R^{D240} |
| L_{C1249} | R^{D10} | R^{D241} | L_{C1303} | R^{D55} | R^{D241} | L_{C1357} | R^{D37} | R^{D241} | L_{C1411} | R^{D143} | R^{D241} |
| L_{C1250} | R^{D10} | R^{D242} | L_{C1304} | R^{D55} | R^{D242} | L_{C1358} | R^{D37} | R^{D242} | L_{C1412} | R^{D143} | R^{D242} |
| L_{C1251} | R^{D10} | R^{D243} | L_{C1305} | R^{D55} | R^{D243} | L_{C1359} | R^{D37} | R^{D243} | L_{C1413} | R^{D143} | R^{D243} |
| L_{C1252} | R^{D10} | R^{D244} | L_{C1306} | R^{D55} | R^{D244} | L_{C1360} | R^{D37} | R^{D244} | L_{C1414} | R^{D143} | R^{D244} |
| L_{C1253} | R^{D10} | R^{D245} | L_{C1307} | R^{D55} | R^{D245} | L_{C1361} | R^{D37} | R^{D245} | L_{C1415} | R^{D143} | R^{D245} |
| L_{C1254} | R^{D10} | R^{D246} | L_{C1308} | R^{D55} | R^{D246} | L_{C1362} | R^{D37} | R^{D246} | L_{C1416} | R^{D143} | R^{D246}; |

wherein R^{D1} to R^{D246} have the following structures:

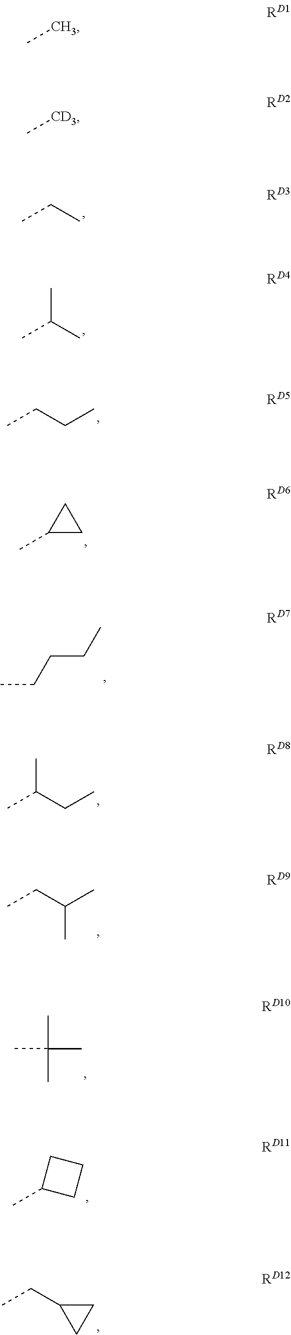

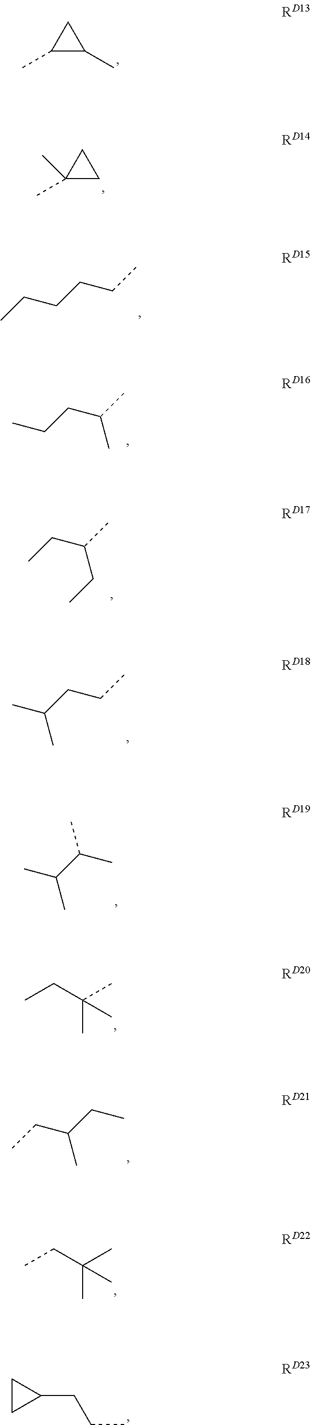

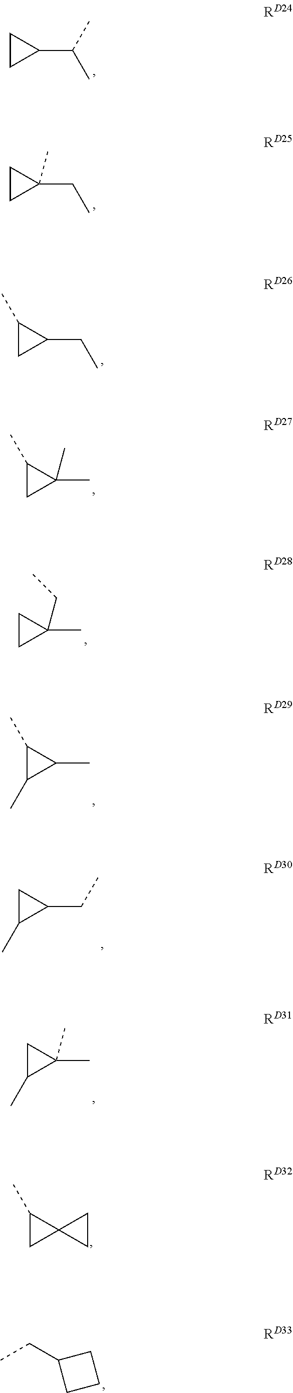

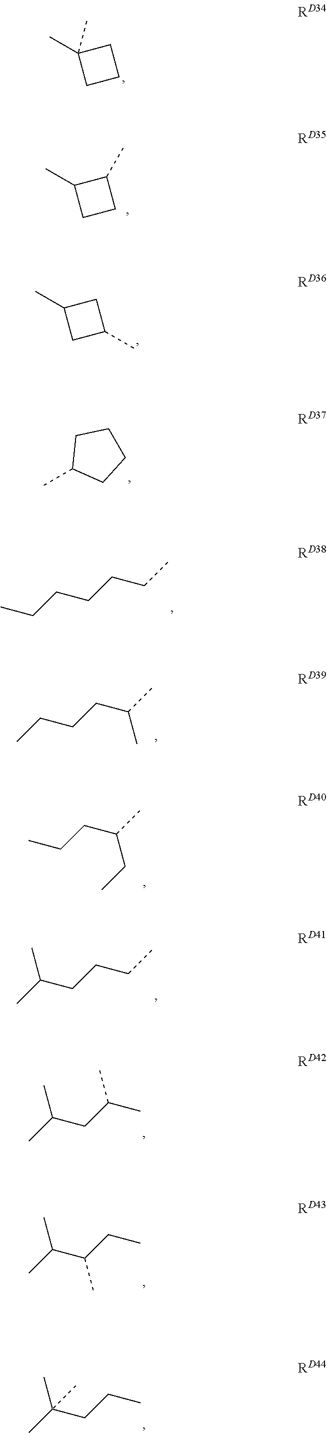

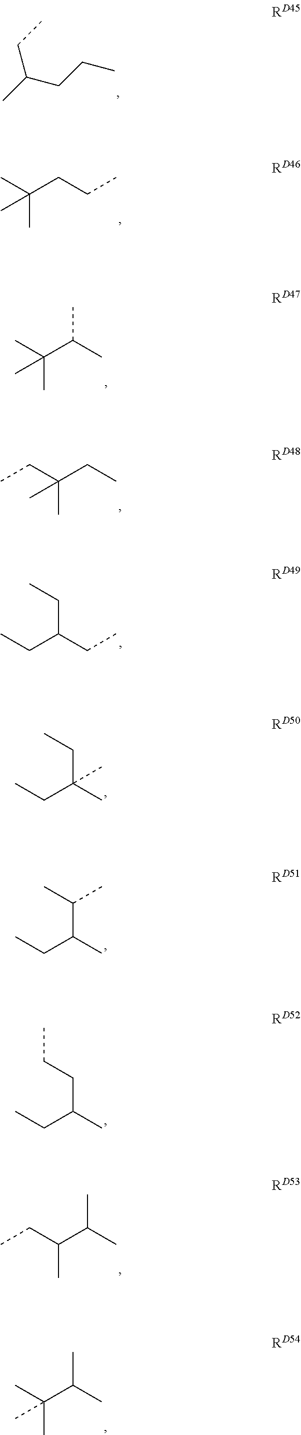

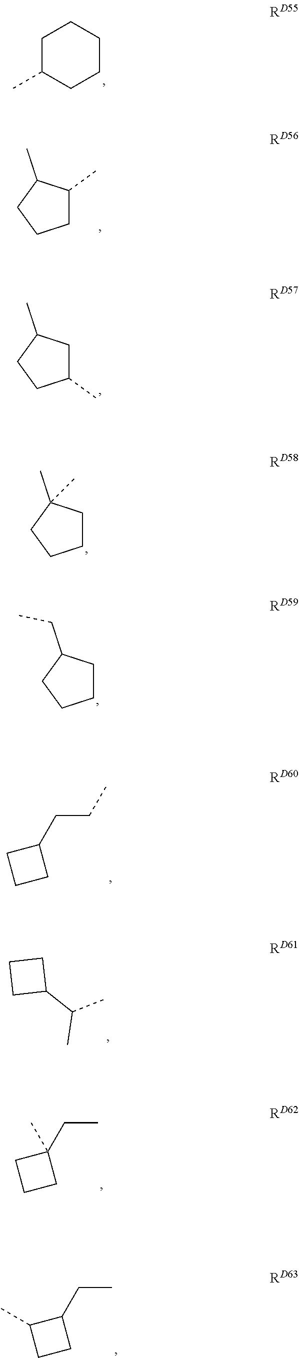

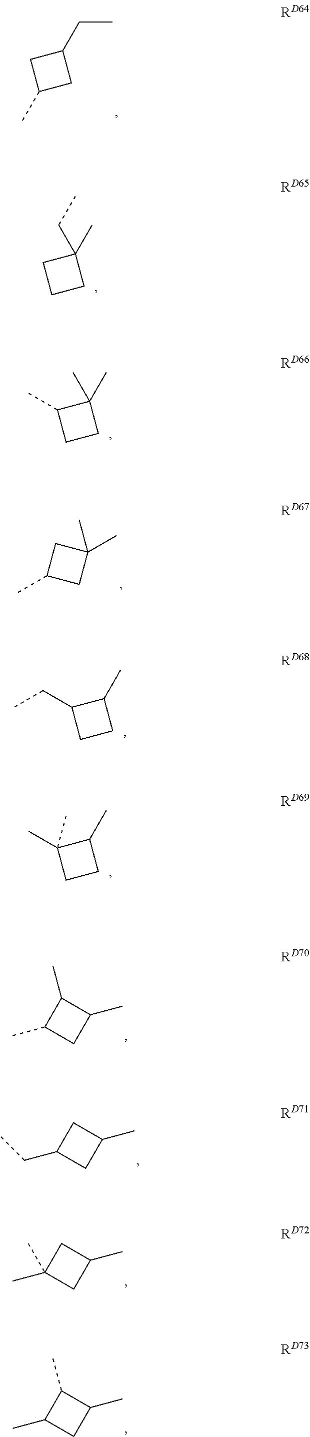

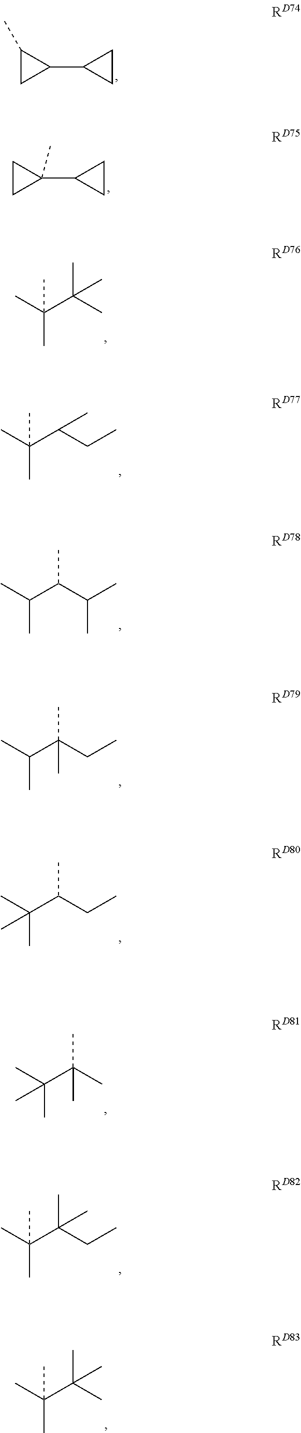

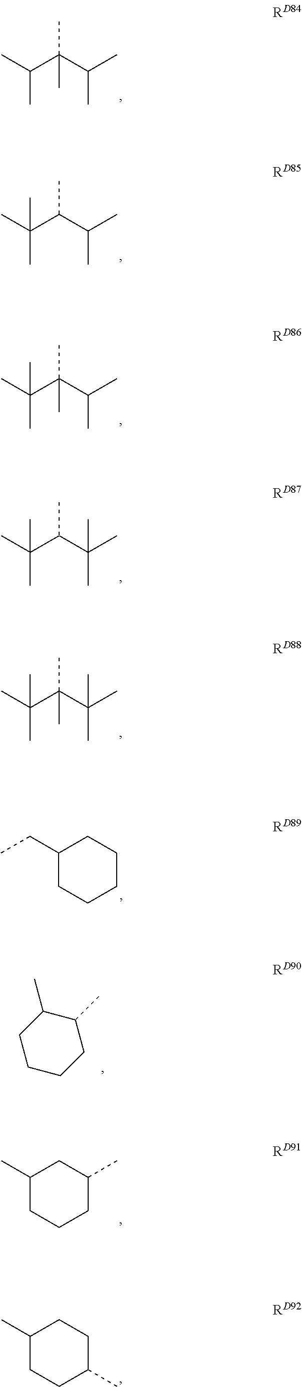

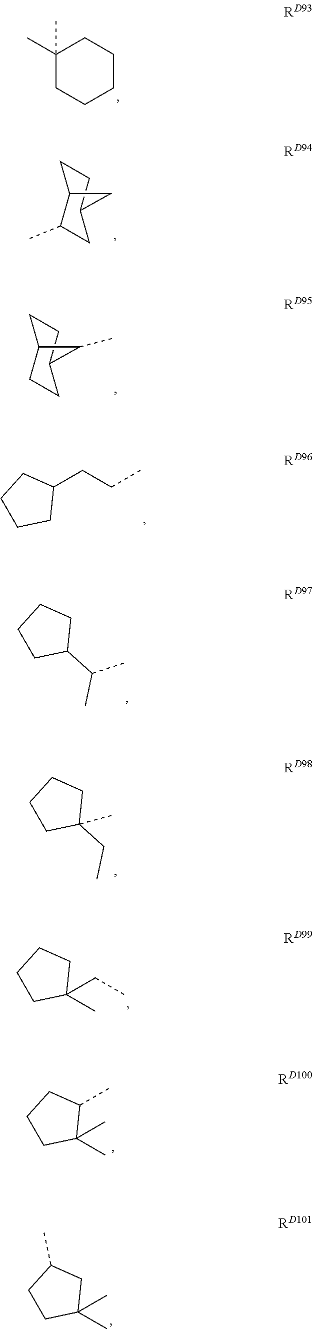

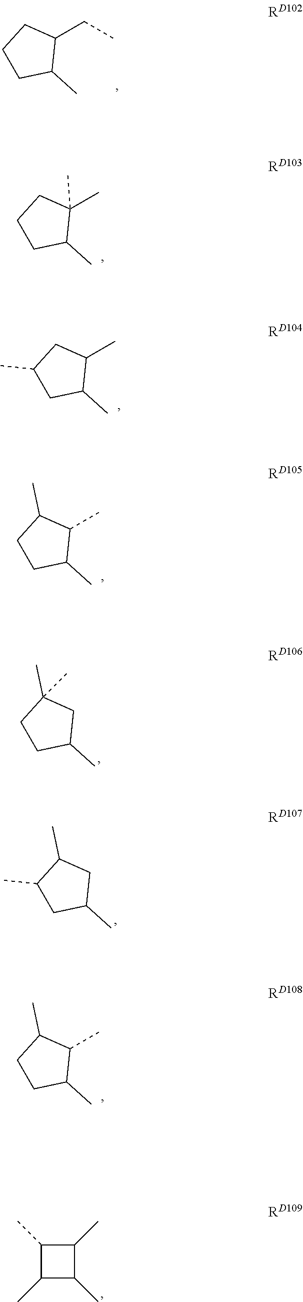

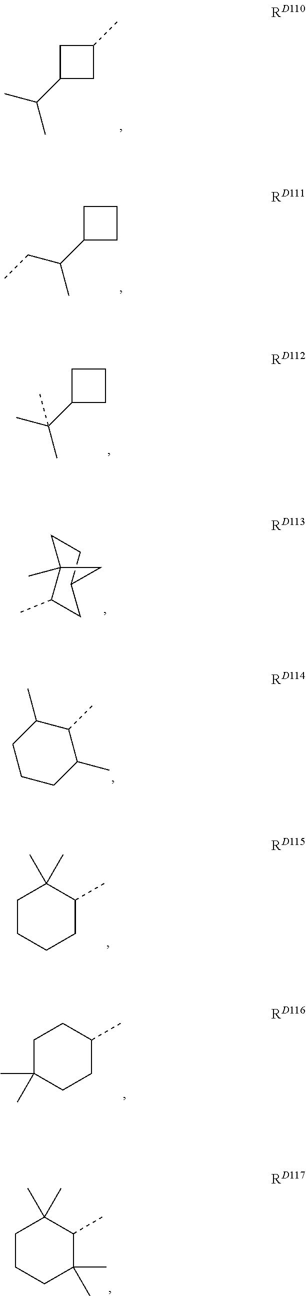

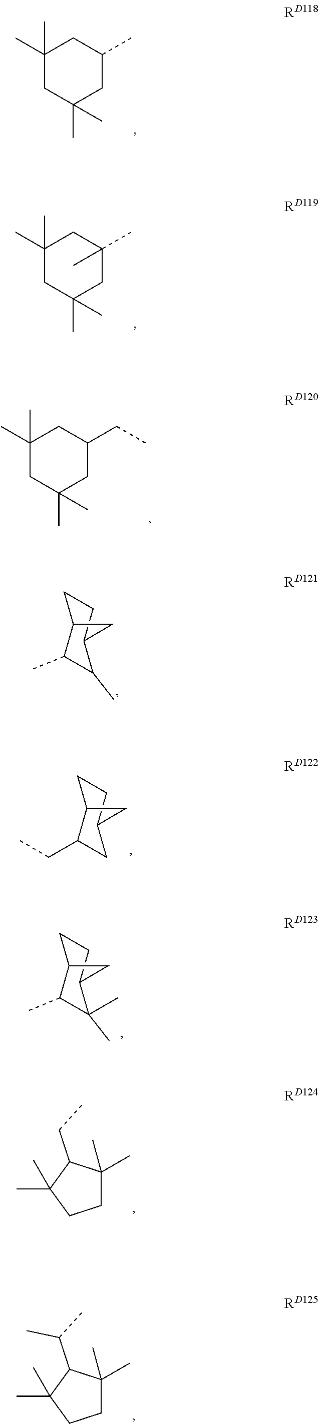

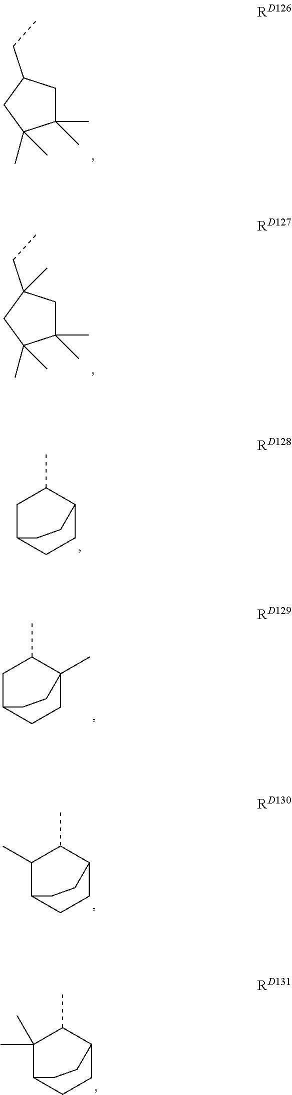

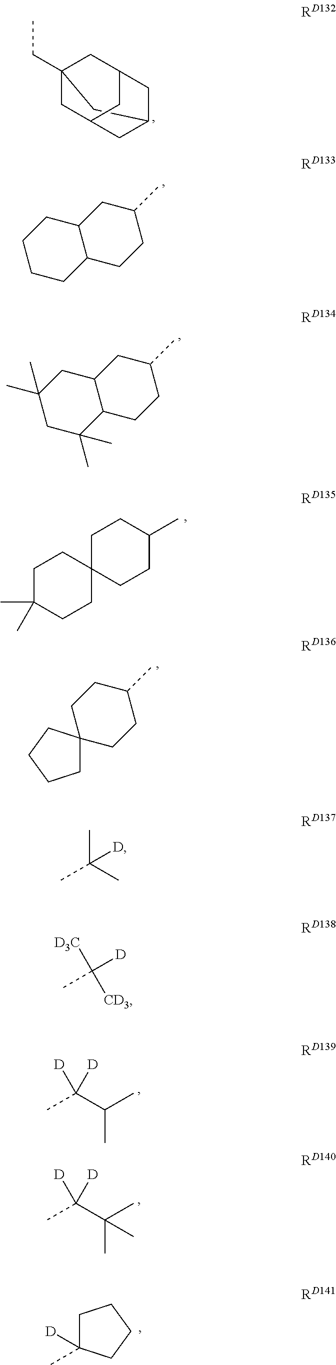

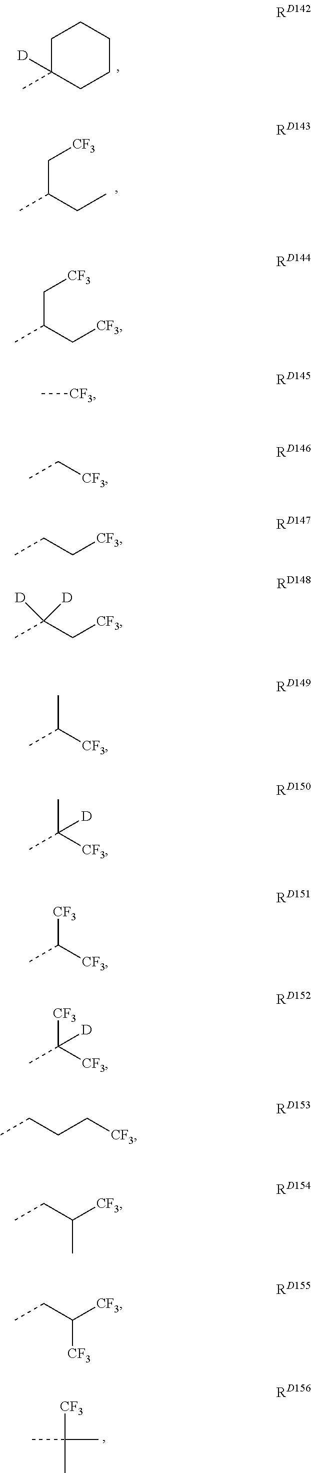

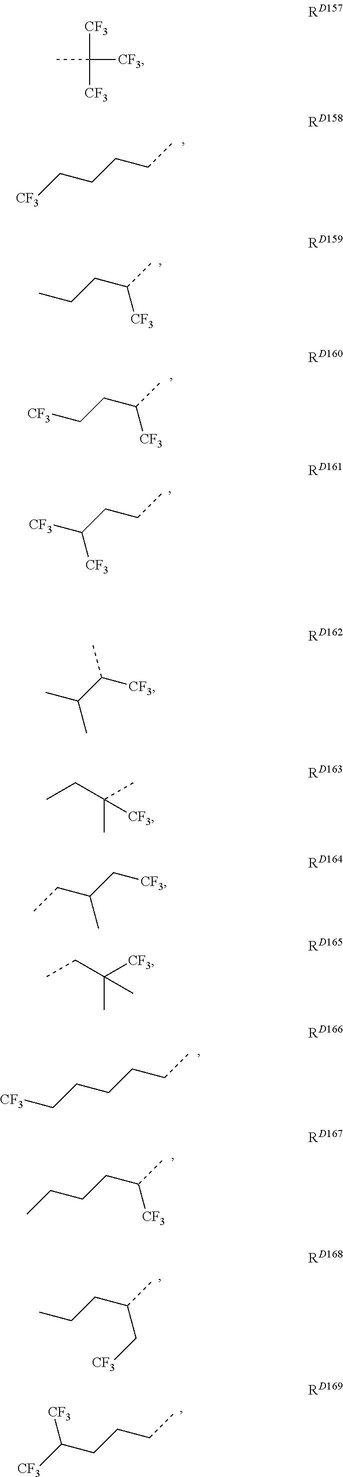

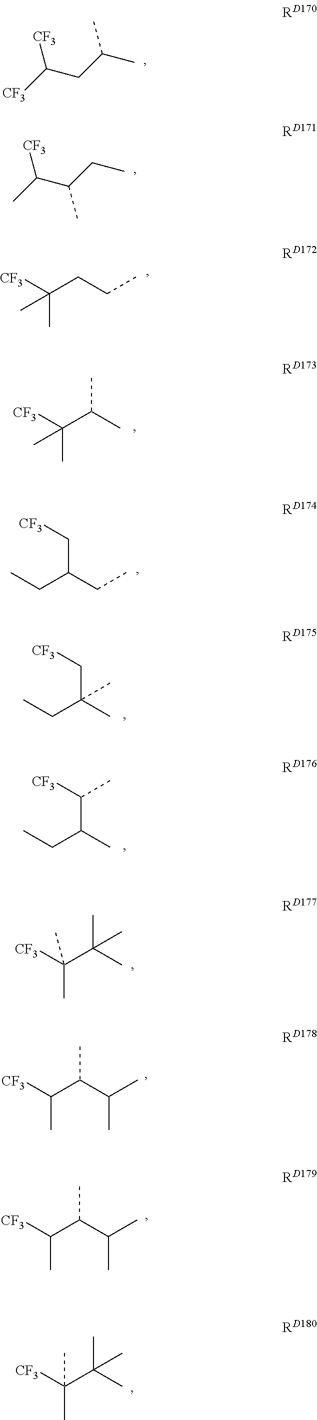

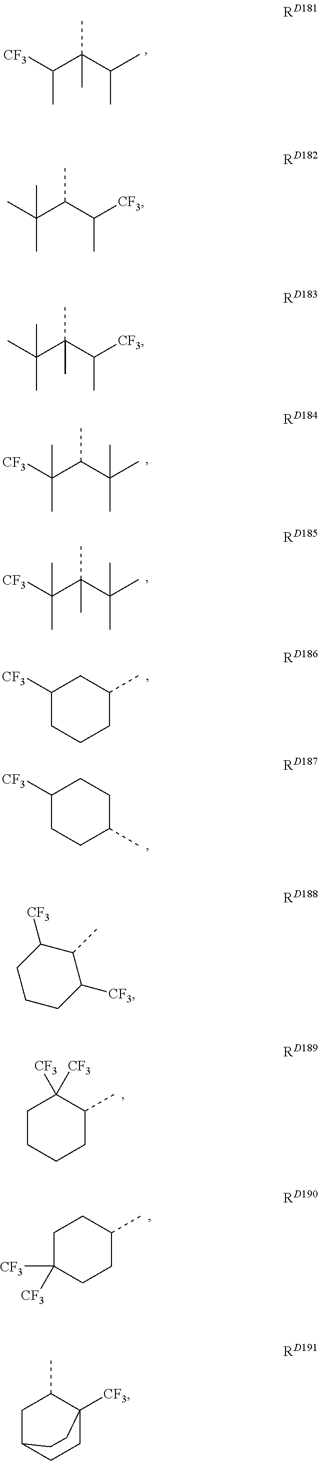

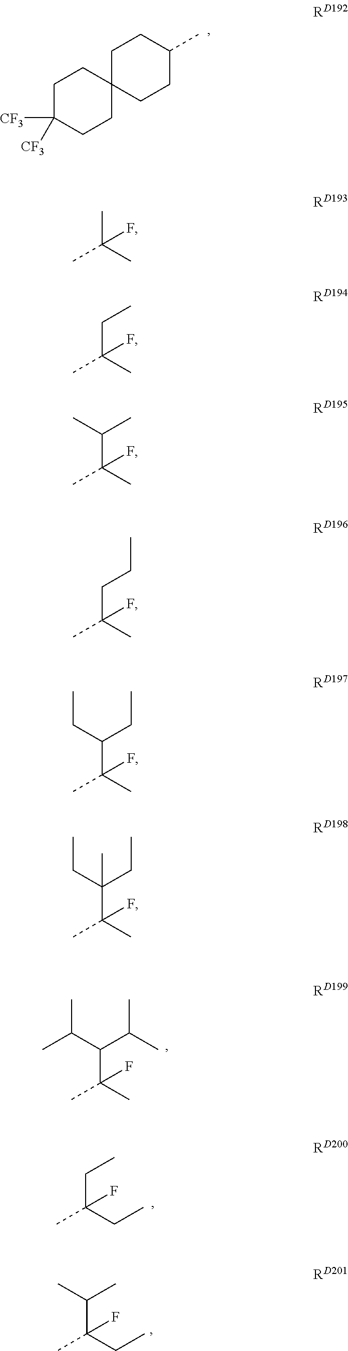

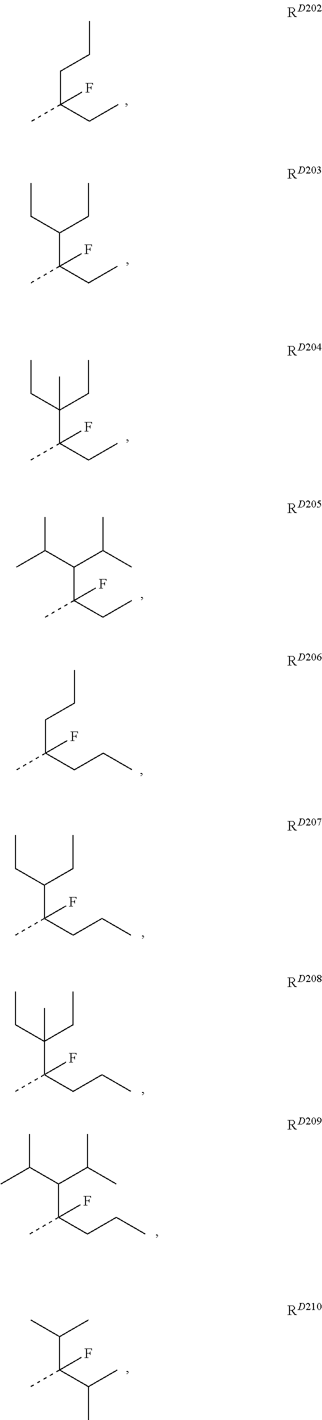

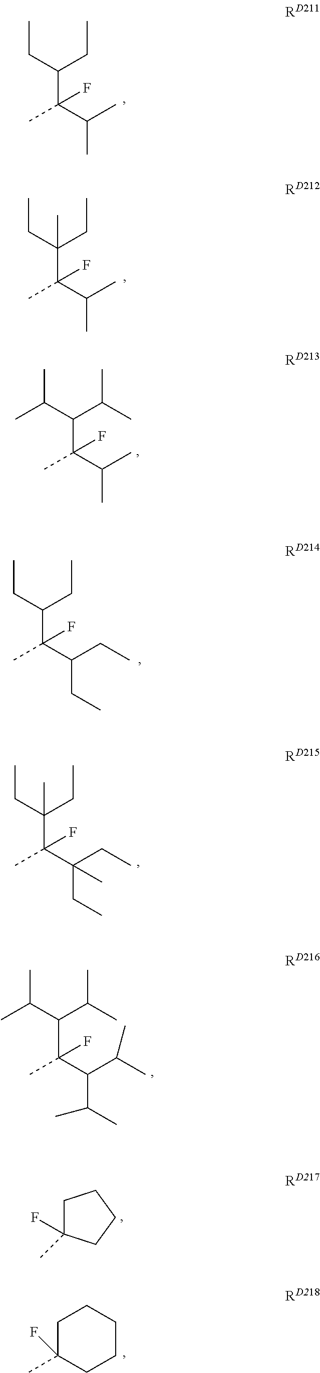

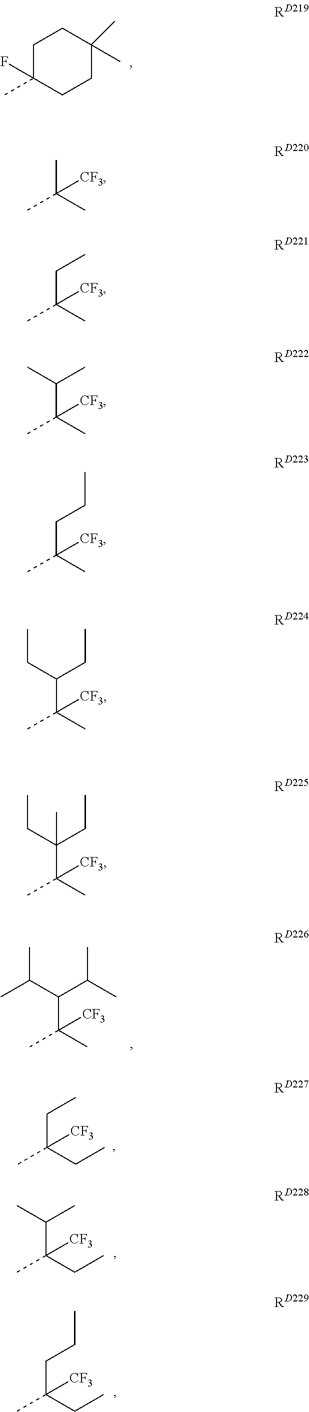

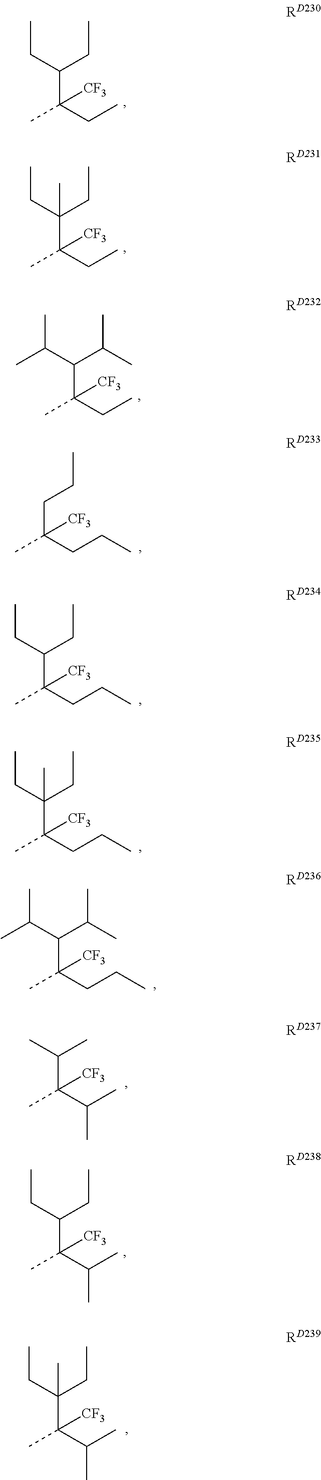

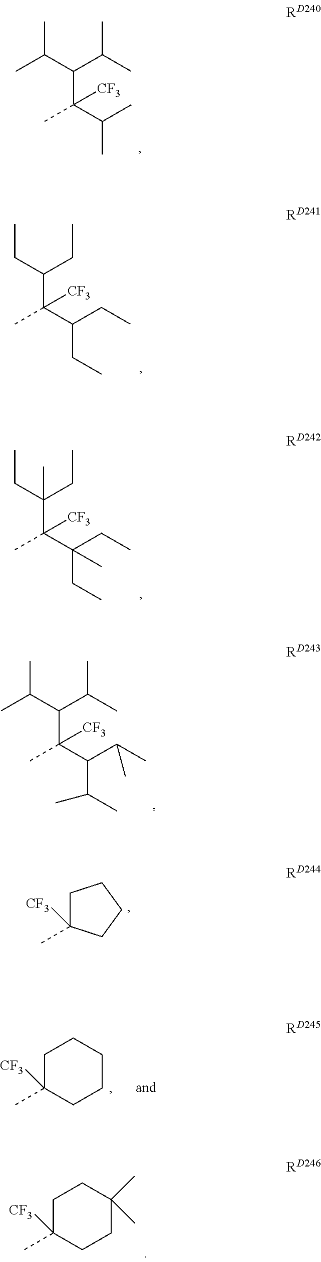

15. The compound of claim 14, wherein the compound is selected from the group consisting of:

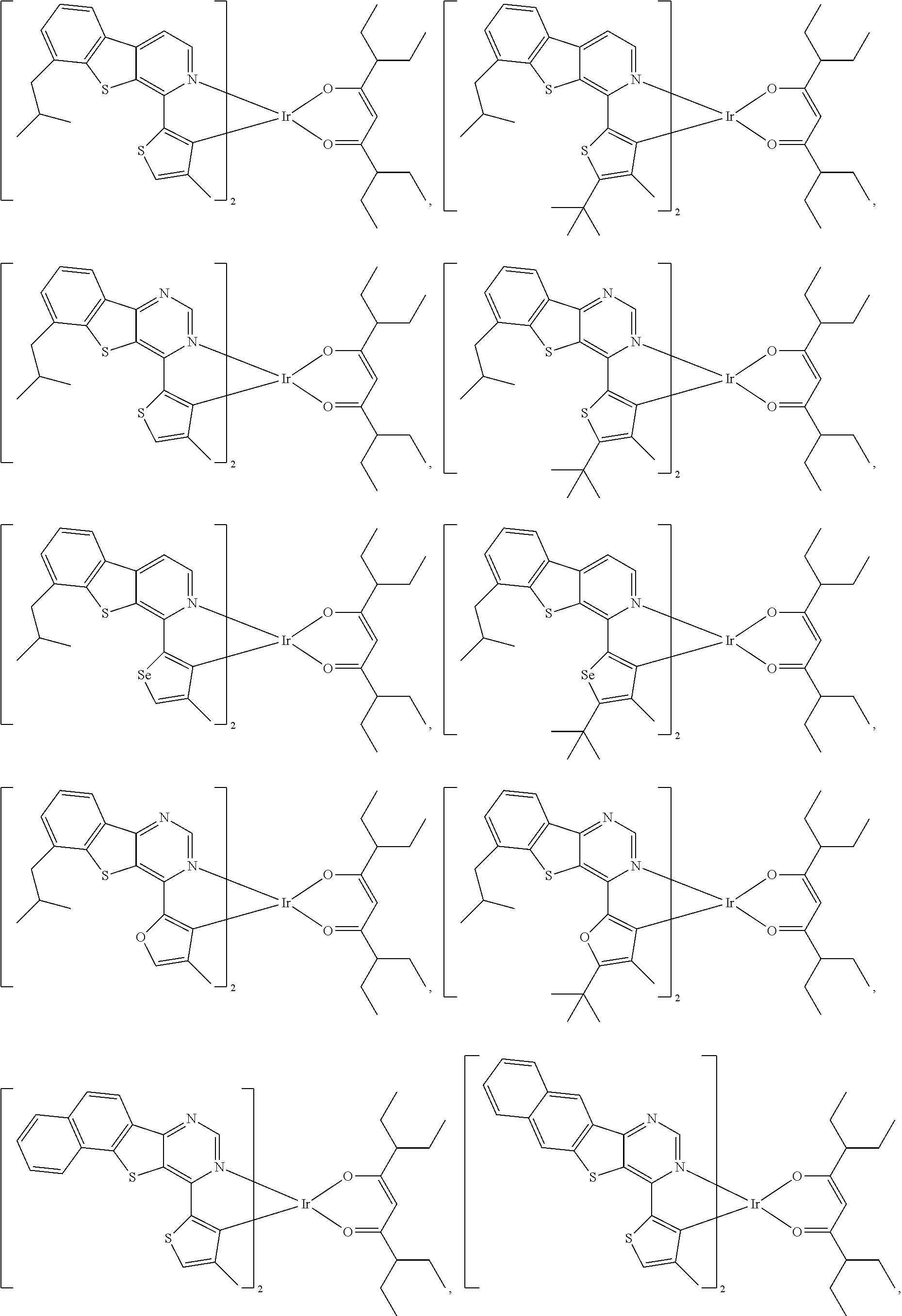

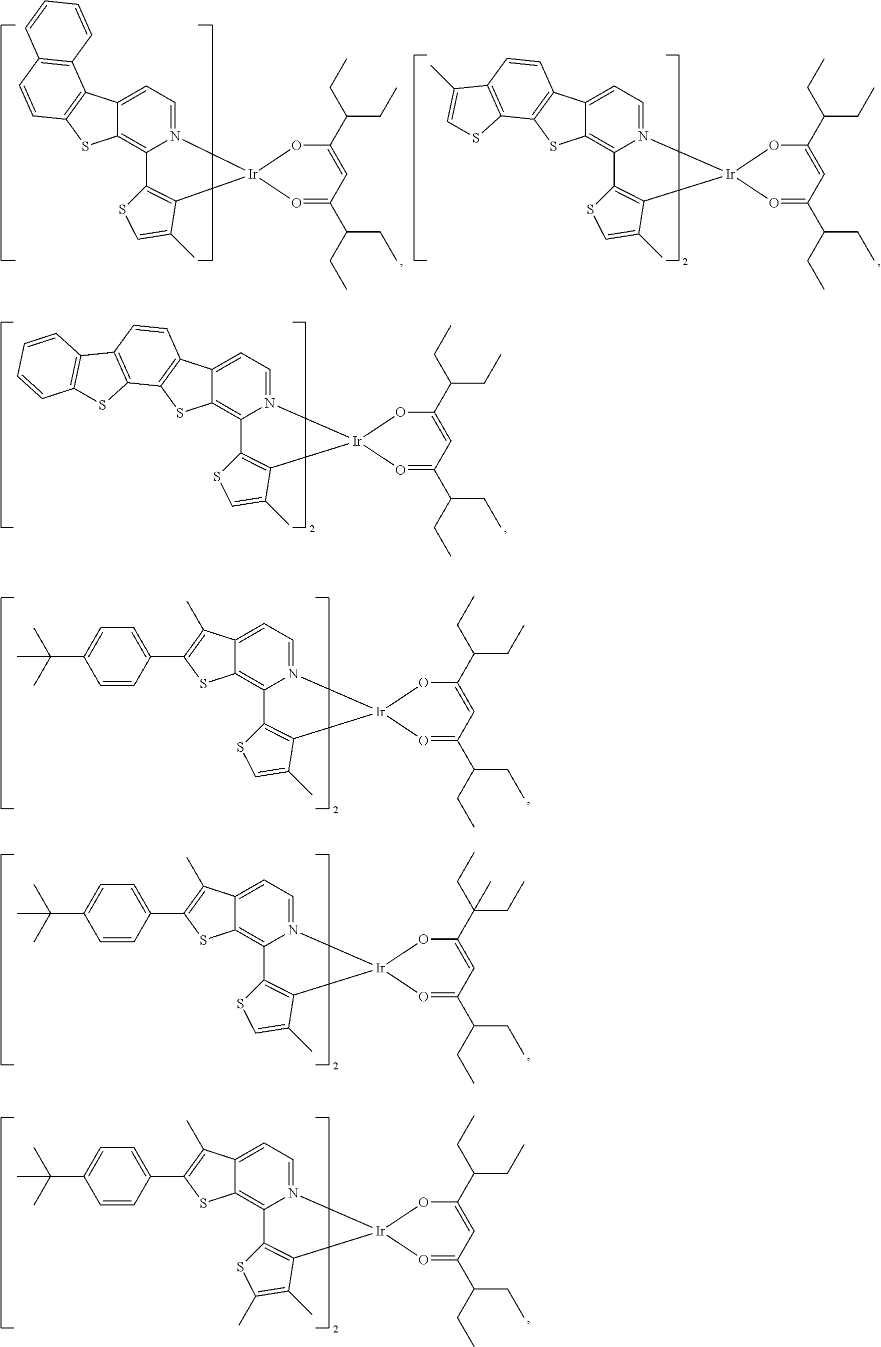

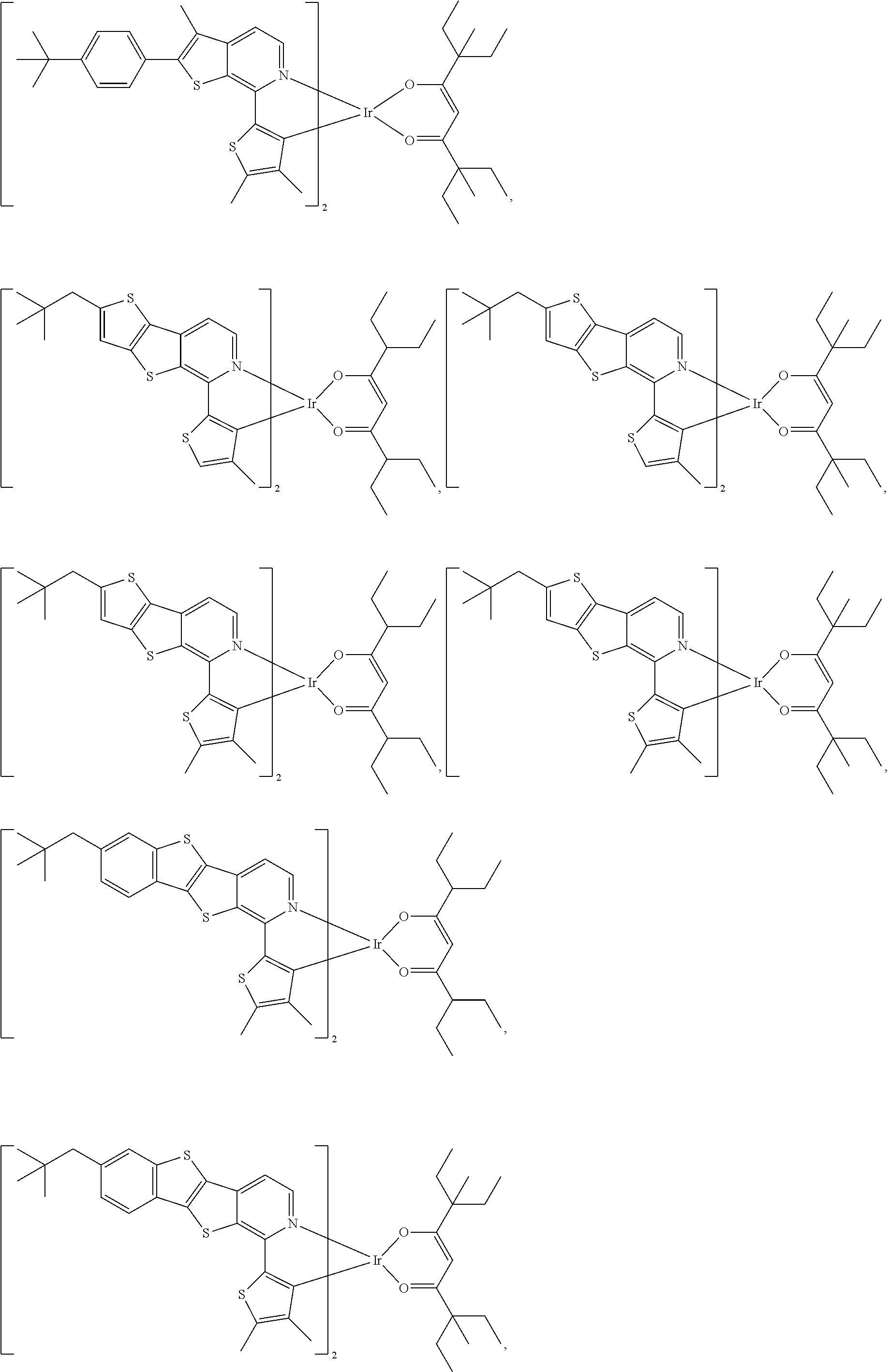

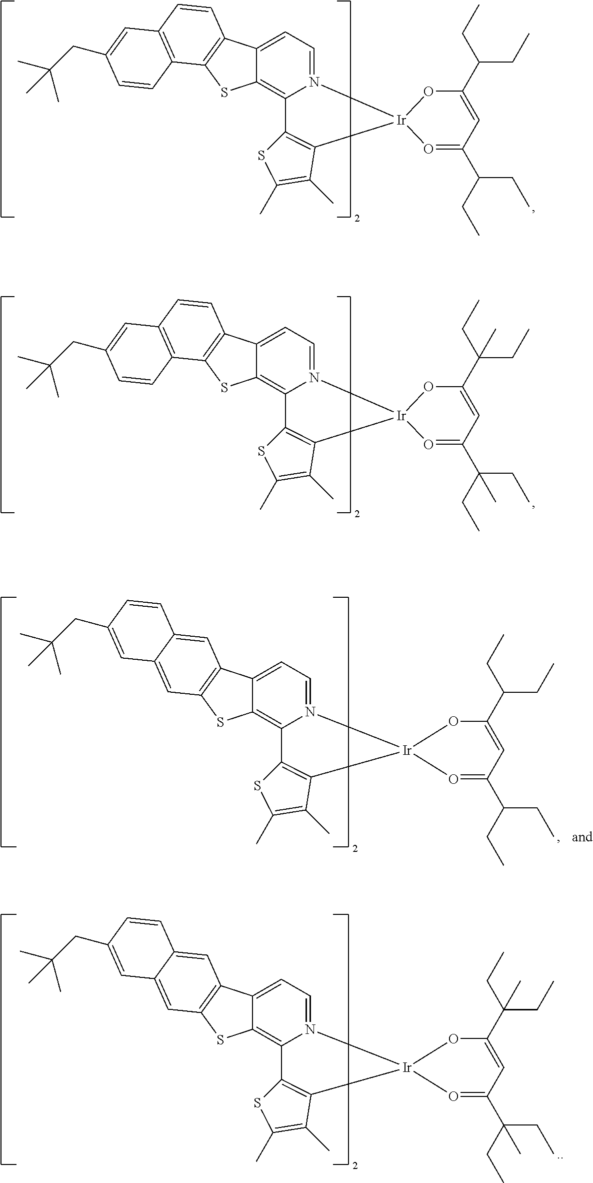

16. The compound of claim 11, wherein the compound has a structure of Formula III, 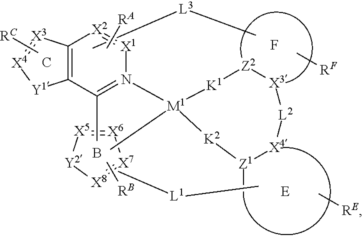
wherein:
M¹ is Pd or Pt;
moieties E and F are each independently a monocyclic or polycyclic fused ring structure comprising 5-membered and/or 6-membered carbocyclic or heterocyclic rings;
Z¹ and Z² are each independently C or N;
K¹ and K² are each independently selected from the group consisting of a direct bond, O, and S, wherein at least one of K¹ and K² is a direct bond; L¹, L², and L³ are each independently selected from the group consisting of a single bond, absent a bond, O, S, SO, SO₂, C═O, C═NR′, C═CR′R″, CR′R″, SiR′R″, BR′, and NR′, wherein at least one of L¹ and L² is present;
X^{3′} and X^{4′} are each independently C or N;
R^{E} and R^{F} each independently represent mono, or up to a maximum allowed substitution, or no substitutions;
each of R′, R″, R^{E}, and R^{F} is independently a hydrogen or a substituent selected from the group consisting of deuterium, fluorine, alkyl, cycloalkyl, heteroalkyl, alkoxy, aryloxy, amino, silyl, boryl, alkenyl, cycloalkenyl, heteroalkenyl, aryl, heteroaryl, nitrile, isonitrile, sulfanyl, and combinations thereof; and
any two adjacent R, R′, R″, R^{A}, R^{B}, R^{C}, R^{E}, and R^{F} can be joined or fused together to form a ring.

17. An organic light emitting device (OLED) comprising:
an anode;
a cathode; and
an organic layer disposed between the anode and the cathode, wherein the organic layer comprises a compound according to claim 1.

18. The OLED of claim 17, wherein the organic layer further comprises a host, wherein host comprises at least one chemical moiety selected from the group consisting of triphenylene, carbazole, indolocarbazole, dibenzothiophene, dibenzofuran, dibenzoselenophene, 5,9-dioxa-13b-boranaphtho[3,2,1-de]anthracene, aza-triphenylene, aza-carbazole, aza-indolocarbazole, aza-dibenzothiophene, aza-dibenzofuran, aza-dibenzoselenophene, and aza-(5,9-dioxa-13b-boranaphtho[3,2,1-de]anthracene).

19. The OLED of claim 18, wherein the host is selected from the group consisting of: 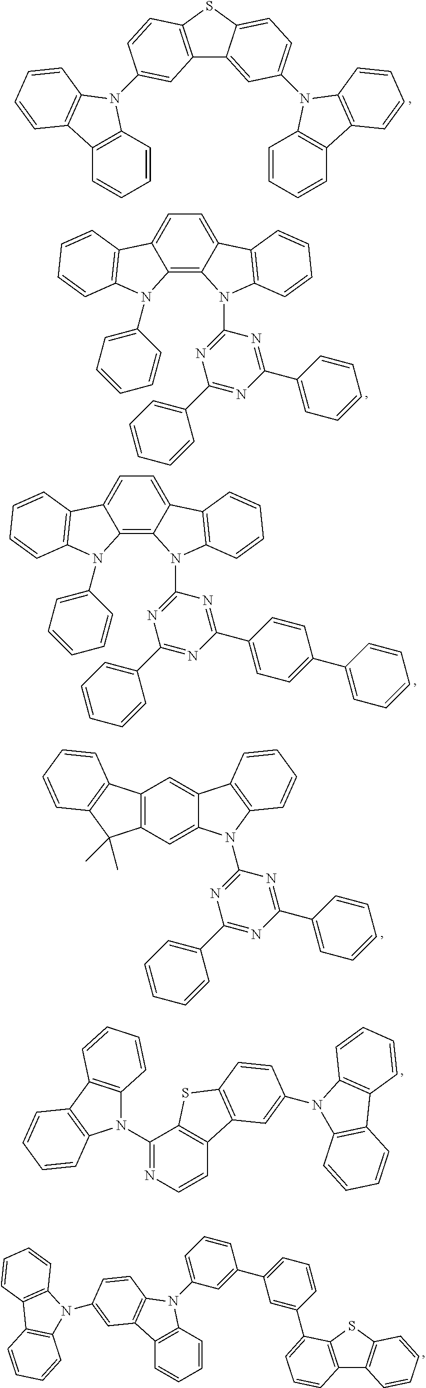 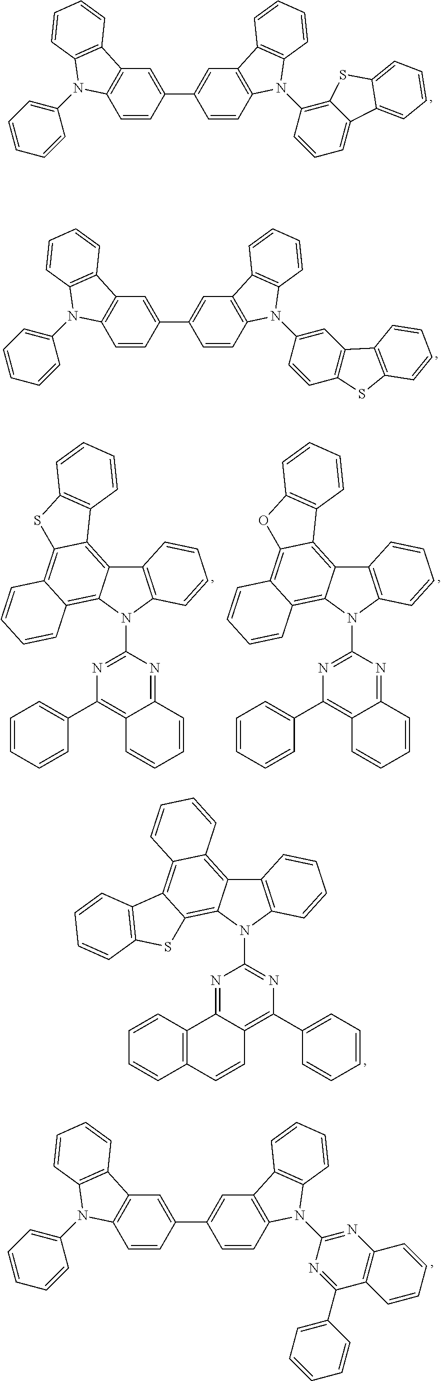 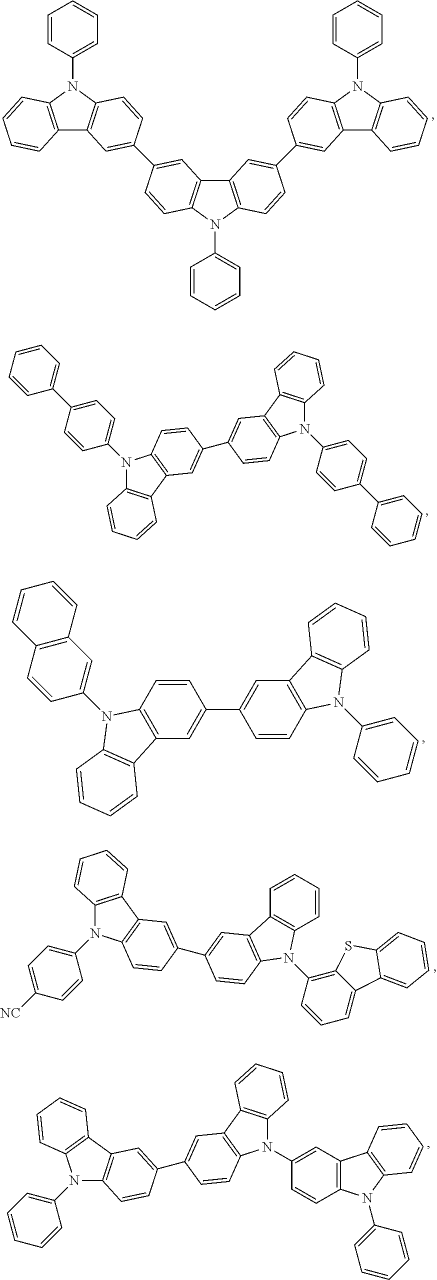 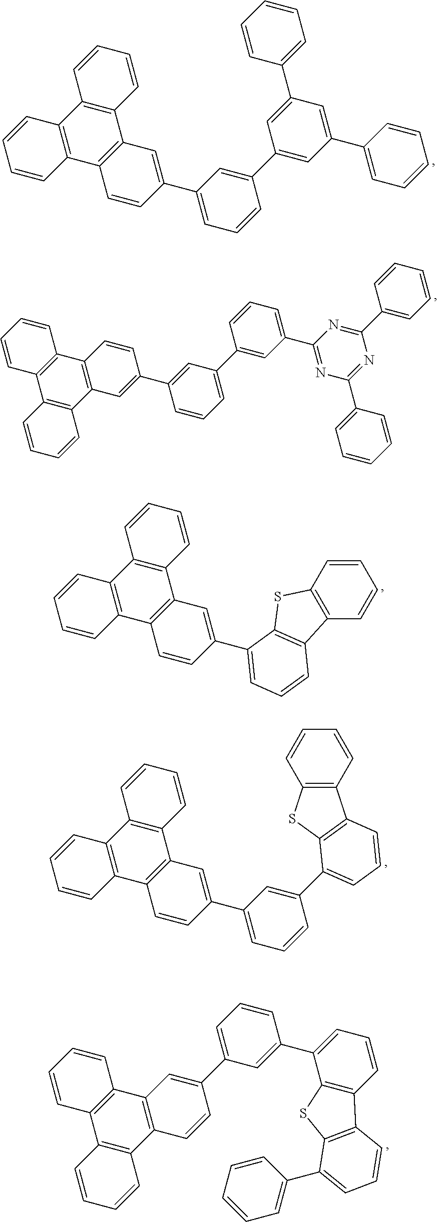 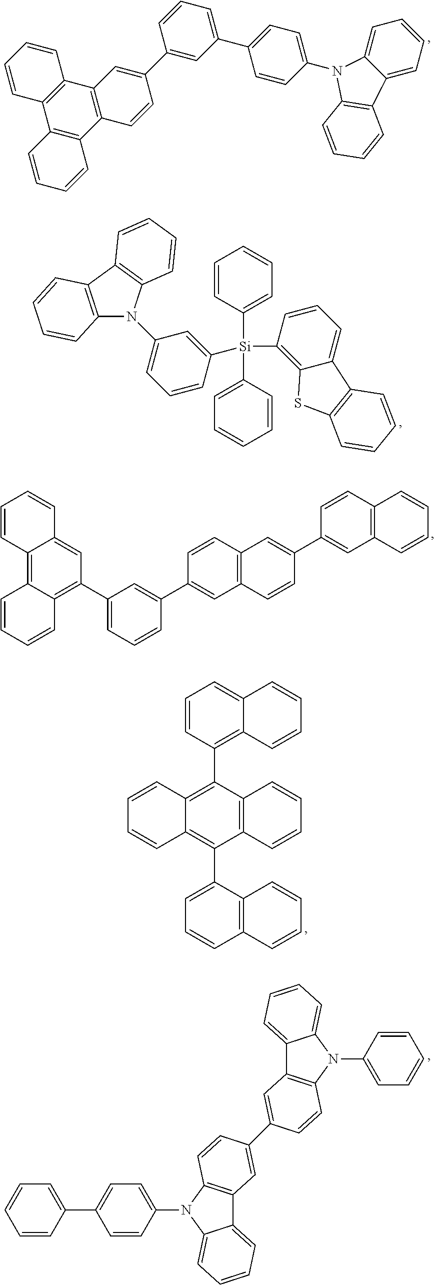 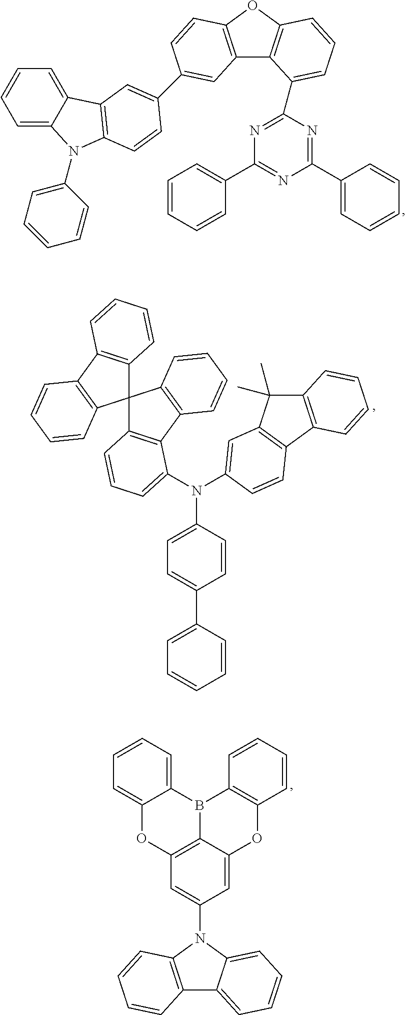 [SMILES: c1ccc(-c2nc(-c3ccccc3)nc(-c3cccc4oc5ccc(-c6ccc7c(c6)c6ccccc6n7-c6ccccc6)cc5c34)n2)cc1 ; "," ; CC1(C)c2ccccc2-c2ccc(N(c3ccc(-c4ccccc4)cc3)c3cccc4c3-c3ccccc3C43c4ccccc4-c4ccccc43)cc21 ; "," ; c1ccc2c(c1)Oc1cc(-n3c4ccccc4c4ccccc43)cc3c1B2c1ccccc1O3 ; ","] 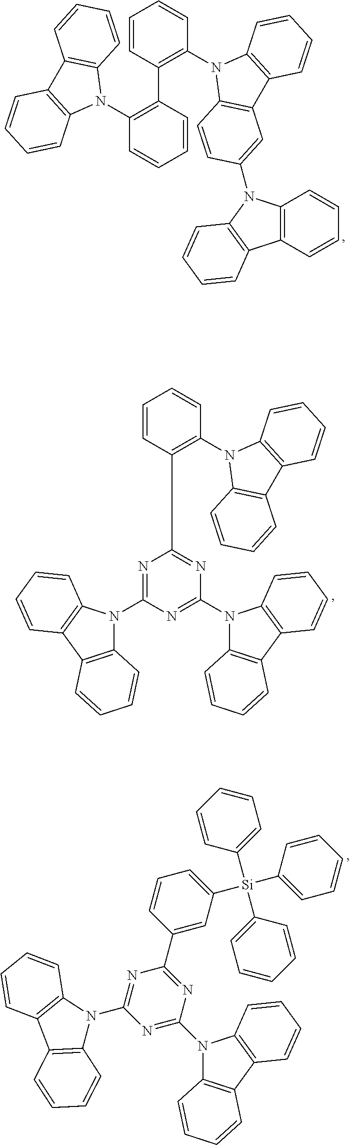 [SMILES: c1ccc(-n2c3ccccc3c3ccccc32)c(-c2ccccc2-n2c3ccccc3c3cc(-n4c5ccccc5c5ccccc54)ccc32)c1 ; "," ; c1ccc(-n2c3ccccc3c3ccccc32)c(-c2nc(-n3c4ccccc4c4ccccc43)nc(-n3c4ccccc4c4ccccc43)n2)c1 ; "," ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; ","]
and combinations thereof.

20. A consumer product comprising an organic light-emitting device comprising:
an anode;
a cathode; and
an organic layer disposed between the anode and the cathode, wherein the organic layer comprises a compound according to claim 1.
